(19) United States
(12) Patent Application Publication
(10) Pub. No.: US 2022/0066319 A1
(43) Pub. Date: Mar. 3, 2022

(54) POSITIVE RESIST MATERIAL AND PATTERNING PROCESS

(71) Applicant: SHIN-ETSU CHEMICAL CO., LTD., Tokyo (JP)

(72) Inventors: Jun HATAKEYAMA, Joetsu-shi (JP); Takeshi NAGATA, Joetsu-shi (JP); Chuanwen LIN, Joetsu-shi (JP); Tomomi WATANABE, Joetsu-shi (JP)

(73) Assignee: SHIN-ETSU CHEMICAL CO., LTD., Tokyo (JP)

(21) Appl. No.: 17/403,952

(22) Filed: Aug. 17, 2021

(30) Foreign Application Priority Data
Sep. 3, 2020 (JP) 2020-148521

(51) Int. Cl. G03F 7/039; G03F 7/004; G03F 7/20

(52) U.S. Cl. CPC G03F 7/0397; G03F 7/2006; G03F 7/0045

(57) ABSTRACT

The present invention is a positive resist material containing: an acid generator, being a sulfonium salt having at least one fluorine atom in both an anion moiety of a sulfonate ion bonded to a polymer main chain and a cation moiety of a sulfonium ion; and a quencher, being a sulfonium salt containing an anion moiety of a carboxylate ion, a sulfonamide ion, an alkoxide ion, or a sulfonate ion having no fluorine atom at a position and a cation moiety of a sulfonium ion, the quencher having a total of two or more fluorine atoms in the anion moiety and the cation moiety. An object of the present invention is to provide: a positive resist material having sensitivity higher than that of conventional positive resist materials, and having little dimensional variation (CDU) in an exposure pattern; and a patterning process using the positive resist material.

### TECHNICAL FIELD

The present invention relates to: a positive resist material; and a patterning process.

### BACKGROUND ART

As LSIs advance toward higher integration and higher processing speed, miniaturization of pattern rule is progressing rapidly. Especially, the expansion of logic memory market caused by the spread of smartphones leads this miniaturization. As a cutting-edge technology for miniaturization, 10-nm node devices have been mass-produced by double patterning using ArF immersion lithography. The starting up of the mass production is in progress for 7-nm node, similarly by double patterning, for the next generation. For the following-generation 5-nm node, extreme ultraviolet ray (EUV) lithography is given as a candidate.

The wavelength of EUV 13.5 nm is 1 over 14.3 of the wavelength of an ArF excimer laser 193 nm, and this makes it possible to form fine patterns. However, since the photon number in EUV exposure is 1 over 14.3 of the photon number in ArF exposure, edge roughness (LWR) becomes large due to variation in photon number, and a problem of shot noise such as degradation of critical dimension uniformity (CDU) occurs (Non Patent Document 1).

It is pointed out that dimensions vary due to variation in acid generator and quencher components within a resist film in addition to variation due to shot noise (Non Patent Document 2). A homogeneous dispersion resist is required in EUV lithography for forming in extremely fine dimensions.

The introduction of fluorine into a cation moiety of a sulfonium salt used for an acid generator or a quencher is being considered (Patent Documents 1 to 5). It is shown that by introducing fluorine into a cation moiety of a sulfonium salt, not only is absorption of EUV light increased, but higher sensitivity is achieved by the improvement of decomposition efficiency. Furthermore, fluorine is also being introduced into a cation moiety of a sulfonium salt having a fluorosulfonic acid bonded to a polymer main chain (Patent Document 6).

### CITATION LIST

### Patent Literature

Patent Document 1: JP 2017-015777 A
Patent Document 2: JP 2015-200886 A
Patent Document 3: JP 2018-503624 A
Patent Document 4: JP 2010-066705 A
Patent Document 5: JP 2020-15716 A
Patent Document 6: JP 2012-107151 A

### Non Patent Literature

Non Patent Document 1: SPIE Vol. 3331 p531 (1998)
Non Patent Document 2: SPIE Vol. 9776 p97760V-1 (2016)

### SUMMARY OF INVENTION

### Technical Problem

The present invention has been made in view of the above-described circumstances, and an object thereof is to provide: a positive resist material having sensitivity higher than that of conventional positive resist materials, and having little dimensional variation (CDU) in an exposure pattern; and a patterning process using the positive resist material.

### Solution to Problem

To solve the above problems, the present invention provides

a positive resist material comprising:

an acid generator, being a sulfonium salt having at least one fluorine atom in both an anion moiety of a sulfonate ion bonded to a polymer main chain and a cation moiety of a sulfonium ion; and

a quencher, being a sulfonium salt comprising an anion moiety of a carboxylate ion, a sulfonamide ion, an alkoxide ion, or a sulfonate ion having no fluorine atom at a position and a cation moiety of a sulfonium ion, the quencher having a total of two or more fluorine atoms in the anion moiety and the cation moiety.

The quencher is preferably a quencher which is a sulfonium salt having a total of three or more fluorine atoms in an anion moiety and a cation moiety.

The quencher is preferably a sulfonium salt having two or more fluorine atoms in the cation moiety or having a total of five or more fluorine atoms in the anion moiety and the cation moiety.

Such a positive resist material has higher sensitivity and resolution than conventional positive resist materials, smaller edge roughness (LER, LWR) and dimensional variation (CDU), as well as favorable pattern profile after exposure.

In addition, the present invention provides a positive resist material comprising:

an acid generator, being a sulfonium salt having at least one fluorine atom in both an anion moiety of a sulfonate ion and a cation moiety of a sulfonium ion; and

a quencher, being a sulfonium salt comprising at least one fluorine atom in both an anion moiety of a carboxylate ion or a sulfonamide ion and a cation moiety of a sulfonium ion.

Such a positive resist material has higher sensitivity and resolution than conventional positive resist materials, smaller edge roughness (LER, LWR) and dimensional variation (CDU), as well as favorable pattern profile after exposure.

Furthermore, the acid generator is preferably contained in a base polymer comprising a repeating unit represented by the following general formula (a1) and/or (a2),

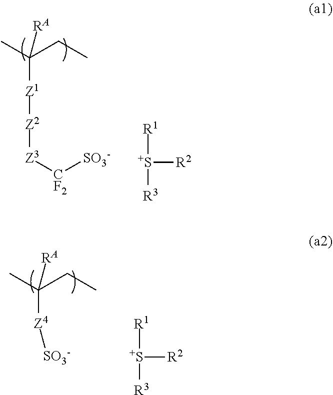

wherein each R^{A} independently represents a hydrogen atom or a methyl group; Z¹ represents a single bond, an ester bond, or a phenylene group; Z² represents a single bond, —Z²¹—C(═O)—O—, —Z²¹—O—, or —Z²¹—O—C(═O)—; Z²¹ represents a hydrocarbylene group having 1 to 12 carbon atoms, a phenylene group, or a group which is a combination thereof having 7 to 18 carbon atoms, the Z²¹ optionally containing a carbonyl group, an ester bond, an ether bond, a sulfur atom, an oxygen atom, a bromine atom, or an iodine atom; Z³ represents a methylene group, a 2,2,2-trifluoro-1,1-ethanediyl group, a hydrocarbon group having 2 to 4 carbon atoms optionally substituted with fluorine, or a carbonyl group; Z⁴ represents a fluorinated phenylene group, a trifluoromethyl group, a phenylene group substituted with an iodine atom, —O—Z⁴¹—, —C(═O)—O—Z⁴¹—, or —C(═O)—NH—Z⁴¹—, and has at least one fluorine atom; Z⁴¹ represents a fluorinated phenylene group, a phenylene group substituted with a trifluoromethyl group or an iodine atom, or a hydrocarbylene group having 1 to 15 carbon atoms substituted with a halogen atom, optionally containing an ester group or an aromatic hydrocarbon group therein; R¹ to R³ each independently represent a hydrocarbyl group having 1 to 20 carbon atoms, and optionally have an oxygen atom, a sulfur atom, a nitrogen atom, or a halogen atom other than fluorine; and R¹ and R², or R¹ and R³ are optionally bonded with each other to form a ring with a sulfur atom that is bonded thereto, wherein at least one fluorine atom is contained among R¹ to R³.

Furthermore, the base polymer preferably comprises a repeating unit represented by the following general formula (b1) in which a hydrogen atom of a carboxy group is substituted with an acid labile group and/or a repeating unit represented by the following general formula (b2) in which a hydrogen atom of a phenolic hydroxy group is substituted with an acid labile group,

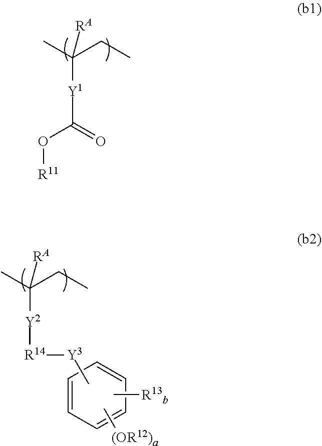

wherein each R^{A} independently represents a hydrogen atom or a methyl group; Y¹ represents a single bond, a phenylene group, a naphthylene group, or a linking group having 1 to 15 carbon atoms containing at least one selected from an ester bond, an ether bond, and a lactone ring; Y² represents a single bond, an ester bond, or an amide bond; Y³ represents a single bond, an ether bond, or an ester bond; R¹¹ and R¹² each represent an acid labile group; R¹³ represents a fluorine atom, a trifluoromethyl group, a cyano group, or a saturated hydrocarbyl group having 1 to 6 carbon atoms; R¹⁴ represents a single bond or an alkanediyl group having 1 to 6 carbon atoms, and some of the carbon atoms are optionally substituted with an ether bond or an ester bond; and “a” represents 1 or 2, and “b” represents an integer of 0 to 4, with 1≤a+b≤5.

Such a positive resist material can further improve the advantageous effects of the present invention.

In addition, the base polymer preferably further comprises a repeating unit comprising an adhesive group selected from a hydroxy group, a carboxy group, a lactone ring, a carbonate group, a thiocarbonate group, a carbonyl group, a cyclic acetal group, an ether bond, an ester bond, a sulfonic acid ester group, a cyano group, an amide bond, —O—C(═O)—S—, and —O—C(═O)—NH—.

Such a positive resist material can enhance adhesiveness.

Furthermore, the quencher is preferably represented by one of the following general formulae (1)-1 to (1)-4,

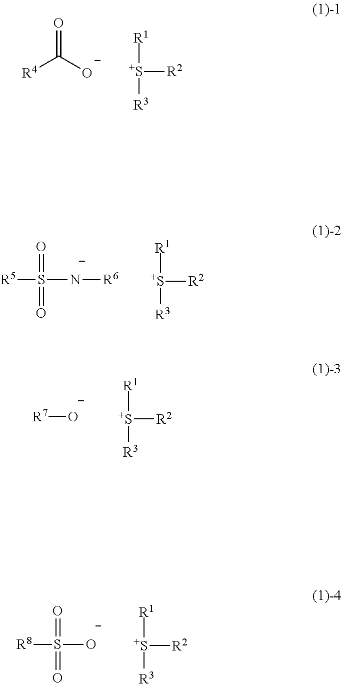

wherein R⁴ and R⁵ each represent a fluorine atom or a hydrocarbyl group having 1 to 40 carbon atoms, and optionally have an oxygen atom, a sulfur atom, a nitrogen atom, or a halogen atom; R⁶ represents a hydrogen atom or a hydrocarbyl group having 1 to 20 carbon atoms, and these optionally have an oxygen atom, a sulfur atom, a nitrogen atom, or a halogen atom; R⁷ represents a linear, branched, or cyclic alkyl group or aryl group having 1 to 8 carbon atoms, and has at least two fluorine atoms; R⁷ optionally has a nitro group; R⁸ represents a linear, branched, or cyclic alkyl group or aryl group having 1 to 12 carbon atoms, optionally having an amino group, an ether group, or an ester group, and optionally substituted with a halogen atom, a hydroxy group, a carboxy group, an alkoxy group, an acyl group, or an acyloxy group; no fluorine atom is contained at a position of a sulfo group; and R¹ to R³ are the same as above.

R⁴ and R⁵ in the general formulae (1)-1 and (1)-2 preferably each represent a hydrocarbyl group having 1 to 40 carbon atoms, optionally having an oxygen atom, a sulfur atom, a nitrogen atom, or a halogen atom other than fluorine, and having at least one fluorine atom.

Such a quencher has electrical repulsion and does not cohere, and is dispersed uniformly.

The positive resist material preferably further comprises one or more out of an acid generator other than the acid generator being the sulfonium salt, an organic solvent, a quencher other than the quencher being the sulfonium salt, and a surfactant.

In this manner, the inventive positive resist material has a favorable effect as a chemically amplified positive resist material.

In addition, the present invention provides a patterning process comprising:

forming a resist film on a substrate by using the above-described positive resist material;

exposing the resist film to a high-energy beam; and

developing the exposed resist film by using a developer.

In addition, the high-energy beam is preferably an i-line beam, a KrF excimer laser beam, an ArF excimer laser beam, an electron beam, or an extreme ultraviolet ray having a wavelength of 3 to 15 nm.

According to such a patterning process, the target positive pattern can be formed favorably.

### Advantageous Effects of Invention

The inventive positive resist material has favorable edge roughness and dimensional variation, since an acid generator and a quencher are homogeneously dispersed within a resist film. Because of these excellent properties, the inventive positive resist material is quite highly practical and very useful as a material for forming fine patterns particularly for manufacturing very LSI circuits or for photomask in EB (electron beam) drawing, or as a material for forming patterns for EB or EUV exposure. The inventive positive resist material is applicable to not only lithography in forming, for example, semiconductor circuits, but also formations of mask circuit patterns, micro-machines, and thin-film magnetic head circuits.

### DESCRIPTION OF EMBODIMENTS

The present inventors have earnestly studied to achieve a positive resist material having high resolution and little edge roughness and dimensional variation required in recent years, and considered that to achieve this, it is necessary to prevent the cohesion of an acid generator and a quencher, which are resist components, and for each to be homogeneously dispersed. The present inventors have considered that for this purpose, it is effective to use the electrical repulsive force of fluorine to prevent each component from cohering. To achieve this, the present inventors have found out a combination of: an acid generator, being a sulfonium salt having at least one fluorine atom in both an anion moiety of a sulfonate ion and a cation moiety of a sulfonium ion; and a quencher, being a sulfonium salt containing at least one fluorine atom in both an anion moiety of a carboxylate ion or a sulfonamide ion and a cation moiety of a sulfonium ion, for achieving homogeneous dispersion by the repulsion of the acid generator and the quencher. Thus, the present invention has been completed.

In addition, the present inventors have earnestly studied to achieve a positive resist material having high resolution and little edge roughness and dimensional variation required in recent years, and considered that to achieve this, it is necessary to prevent the cohesion of an acid generator and a quencher, which are resist components, and for each to be homogeneously dispersed. The present inventors have considered that for this purpose, it is effective to use the electrical repulsive force of fluorine to prevent each component from cohering. To achieve this, the present inventors have found out a combination of: an acid generator, being a sulfonium salt having at least one fluorine atom in both an anion moiety of a sulfonate ion bonded to a polymer main chain and a cation moiety of a sulfonium ion; and a quencher, being a sulfonium salt containing a carboxylate ion, a sulfonamide ion, an alkoxide ion, or a sulfonate ion having no fluorine at a position and containing a fluorine atom in a cation moiety of a sulfonium ion, the quencher having a sum total of two or more fluorine atoms in the anion moiety and the cation moiety, for achieving homogeneous dispersion by the repulsion of the acid generator and the quencher. Thus, the present invention has been completed.

That is, the present invention is

a positive resist material comprising:

an acid generator, being a sulfonium salt having at least one fluorine atom in both an anion moiety of a sulfonate ion and a cation moiety of a sulfonium ion; and

a quencher, being a sulfonium salt comprising at least one fluorine atom in both an anion moiety of a carboxylate ion or a sulfonamide ion and a cation moiety of a sulfonium ion.

In addition, the present invention is

a positive resist material comprising:

an acid generator, being a sulfonium salt having at least one fluorine atom in both an anion moiety of a sulfonate ion bonded to a polymer main chain and a cation moiety of a sulfonium ion; and

a quencher, being a sulfonium salt comprising an anion moiety of a carboxylate ion, a sulfonamide ion, an alkoxide ion, or a sulfonate ion having no fluorine atom at a position and a cation moiety of a sulfonium ion, the quencher having a total of two or more fluorine atoms in the anion moiety and the cation moiety.

Hereinafter, the present invention will be described in detail, but the present invention is not limited thereto.

### [Positive Resist Material]

The inventive positive resist material contains: an acid generator, being a sulfonium salt having at least one fluorine atom in both an anion moiety of a sulfonate ion and a cation moiety of a sulfonium ion; and a quencher, being a sulfonium salt containing at least one fluorine atom in both an anion moiety of a carboxylate ion or a sulfonamide ion and a cation moiety of a sulfonium ion. Since a fluorine atom is contained in both the cation and anion of the sulfonium salt of the acid generator and the quencher, the acid generators, the quenchers, and the acid generator and the quencher electrically repel each other, so that they do not cohere, and are uniformly dispersed. Thus, LWR and CDU of resist patterns after development can be improved.

Furthermore, the inventive positive resist material contains an acid generator, being a sulfonium salt having at least one fluorine atom in both an anion moiety of a sulfonate ion bonded to a polymer main chain and a cation moiety of a sulfonium ion; and a quencher, being a sulfonium salt containing a carboxylate ion, a sulfonamide ion, an alkoxide ion, or a sulfonate ion having no fluorine at a position and containing a fluorine atom a cation moiety of a sulfonium ion, the quencher having a sum total of two or more fluorine atoms in the anion moiety and the cation moiety, preferably three or more, more preferably two or more fluorine atoms in the cation moiety or a sum total of five or more fluorine atoms in the anion moiety and the cation moiety. Since a fluorine atom is contained in both the cation and anion of the sulfonium salt of the acid generator and the cation of the sulfonium salt of the quencher, the acid generators, the quenchers, and the acid generator and the quencher electrically repel each other, so that they do not cohere, and are uniformly dispersed. Thus, LWR and CDU of resist patterns after development can be improved.

As the acid generator, a sulfonium salt of a fluorosulfonic acid bonded to a polymer main chain is preferable, and is represented by the following general formulae (a1) and (a2).

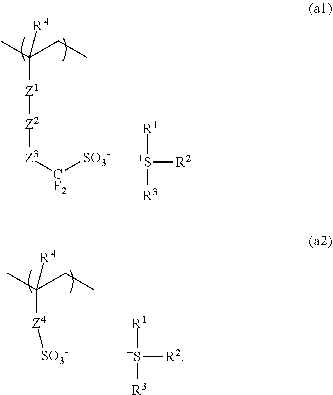

In the formulae, each R^{A} independently represents a hydrogen atom or a methyl group. Z¹ represents a single bond, an ester bond, or a phenylene group. Z² represents a single bond, —Z²¹—C(═O)—O—, —Z²¹—O—, or —Z²¹—O—C(═O)—. Z²¹ represents a hydrocarbylene group having 1 to 12 carbon atoms, a phenylene group, or a group which is a combination thereof having 7 to 18 carbon atoms, the Z²¹ optionally containing a carbonyl group, an ester bond, an ether bond, a sulfur atom, an oxygen atom, a bromine atom, or an iodine atom. Z³ represents a methylene group, a 2,2,2-trifluoro-1,1-ethanediyl group, a hydrocarbon group having 2 to 4 carbon atoms optionally substituted with fluorine, or a carbonyl group. Z⁴ represents a fluorinated phenylene group, a trifluoromethyl group, a phenylene group substituted with an iodine atom, —O—Z⁴¹—, —C(═O)—O—Z⁴¹—, or —C(═O)—NH—Z⁴¹—, and has at least one fluorine atom. Z⁴¹ represents a fluorinated phenylene group, a phenylene group substituted with a trifluoromethyl group or an iodine atom, or a hydrocarbylene group having 1 to 15 carbon atoms substituted with a halogen atom, optionally containing an ester group or an aromatic hydrocarbon group therein. R¹ to R³ each independently represent a hydrocarbyl group having 1 to 20 carbon atoms, and optionally have an oxygen atom, a sulfur atom, a nitrogen atom, or a halogen atom other than fluorine. In addition, R¹ and R², or R¹ and R³ are optionally bonded with each other to form a ring with a sulfur atom that is bonded thereto, where at least one fluorine atom is contained among R¹ to R³.

There is at least one fluorine atom in R¹ to R³, preferably two or more, more preferably three or more. There is at least one fluorine atom in the sulfonate ion in a1 and a2, preferably two or more, more preferably three or more, and further preferably four or more.

Examples of the anion of a monomer to give the repeating unit a1 include, but are not limited to those shown below. Incidentally, in the following formulae, R^{A} is the same as above.

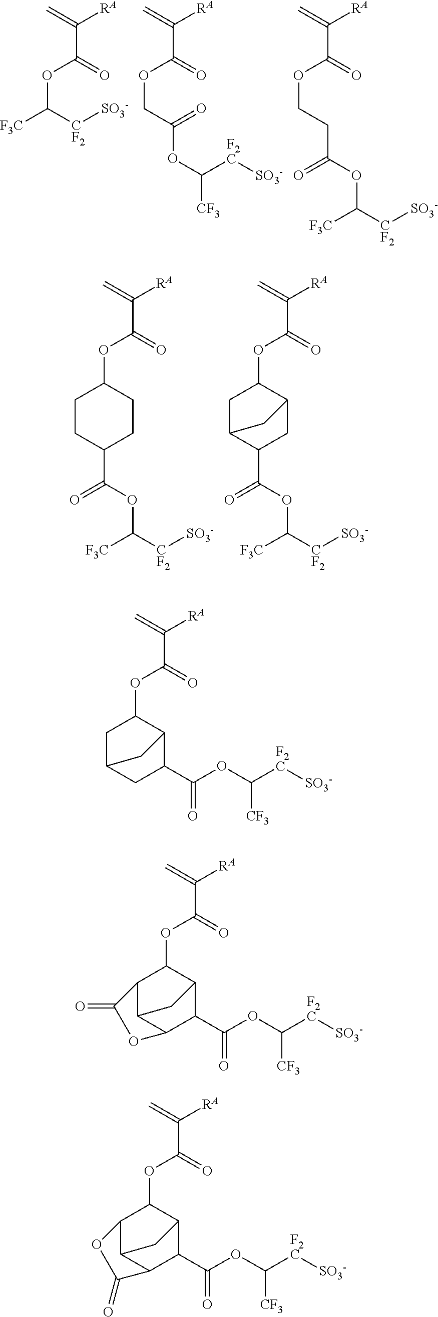

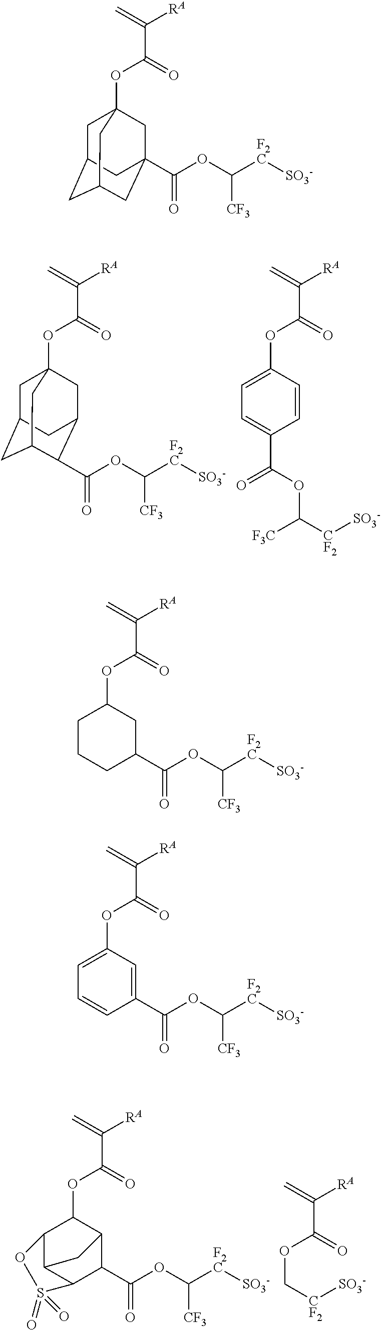

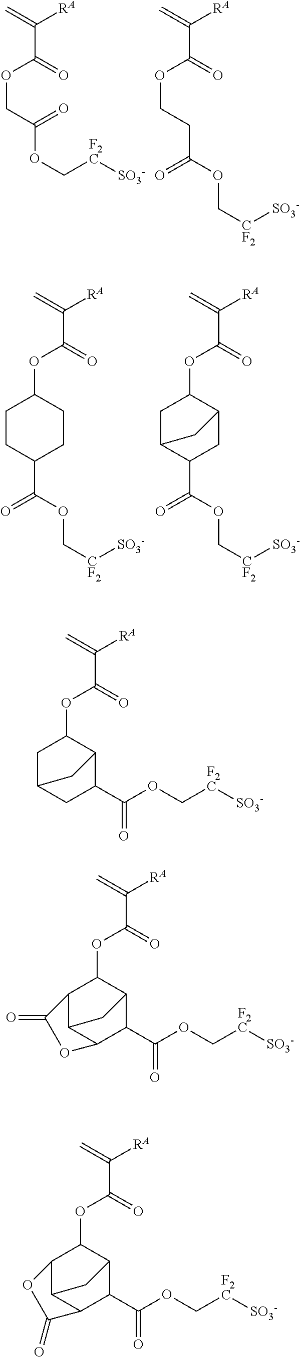

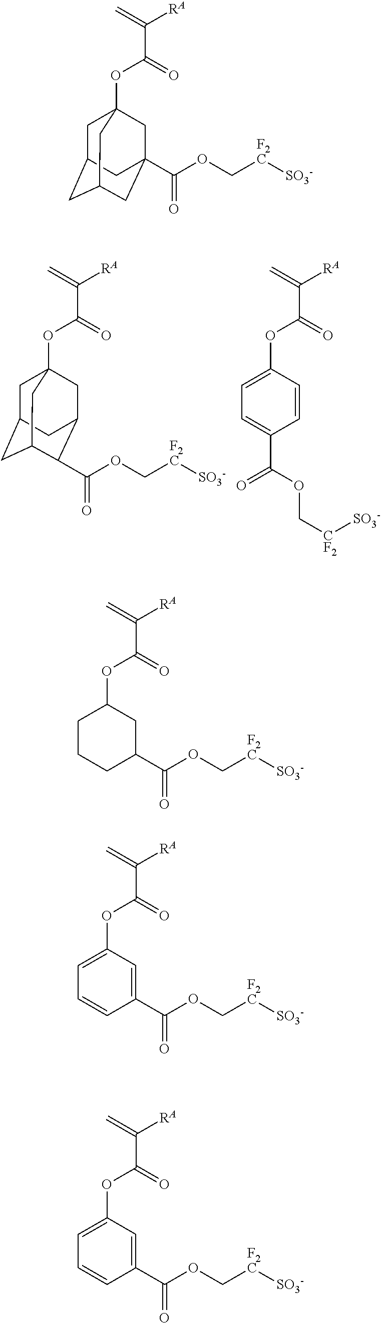

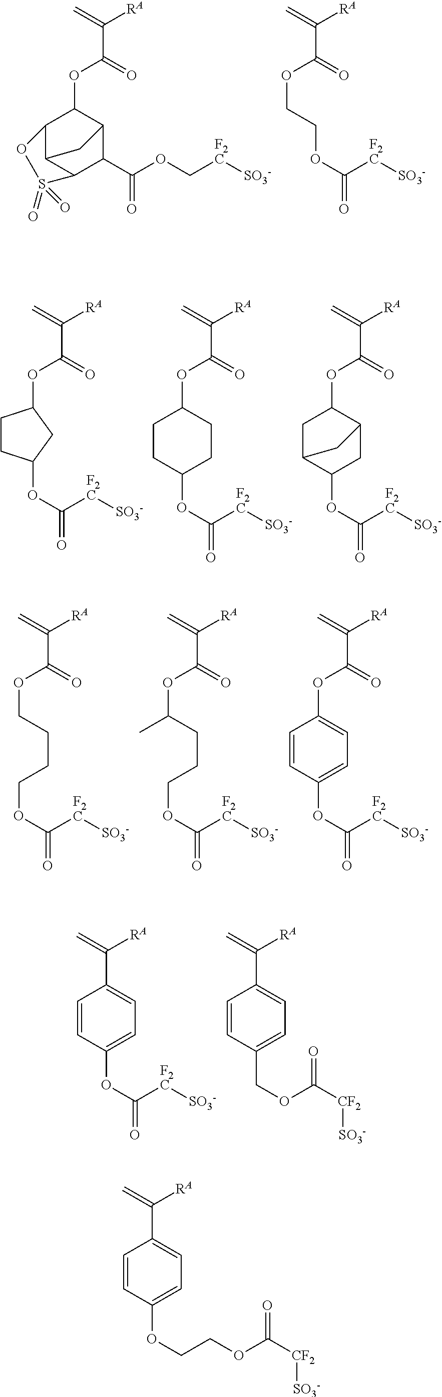

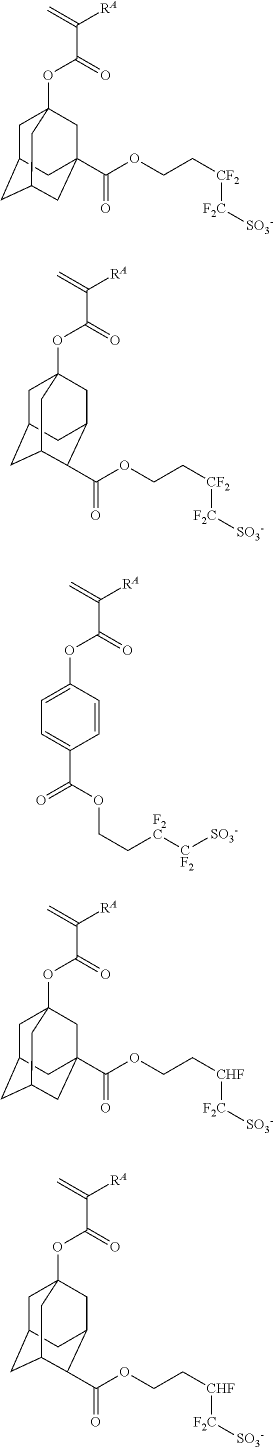

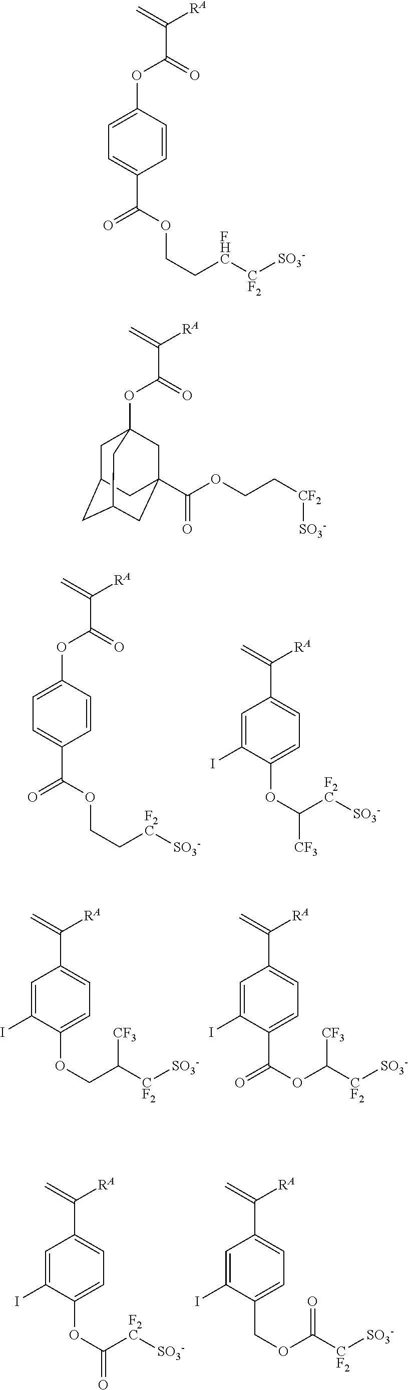

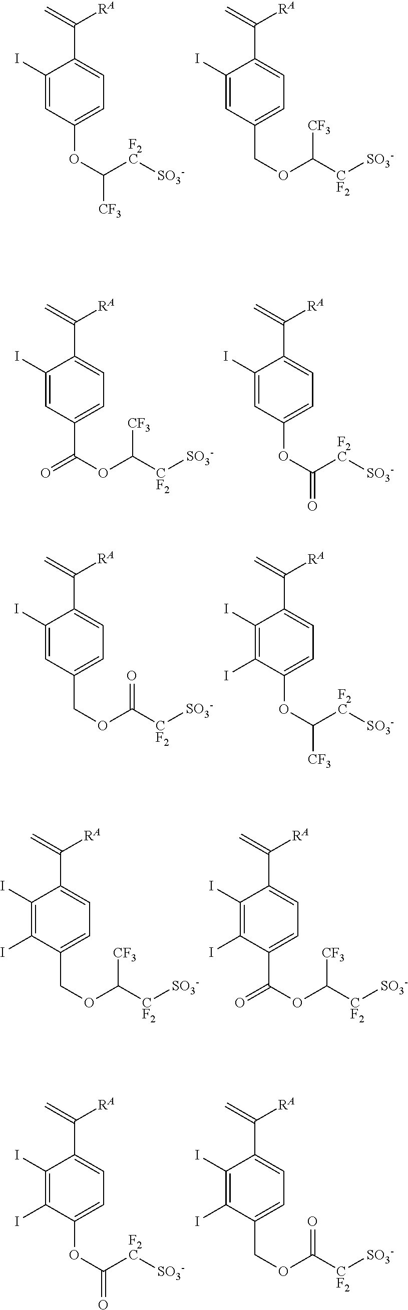

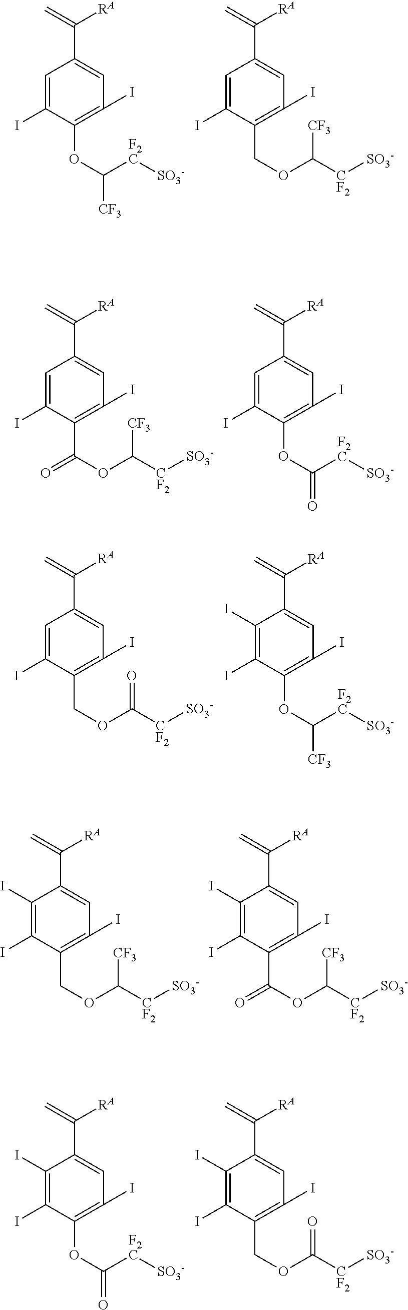

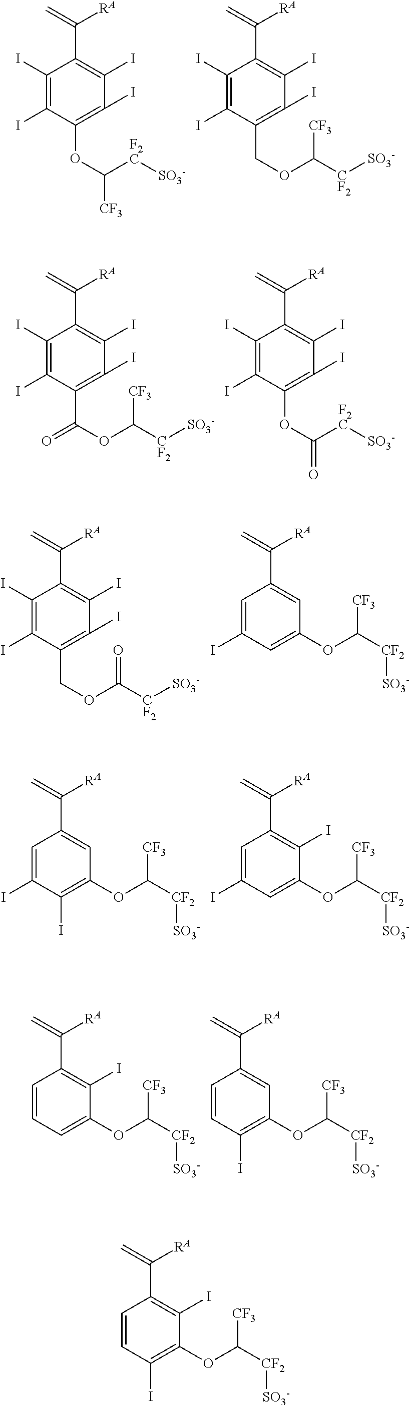

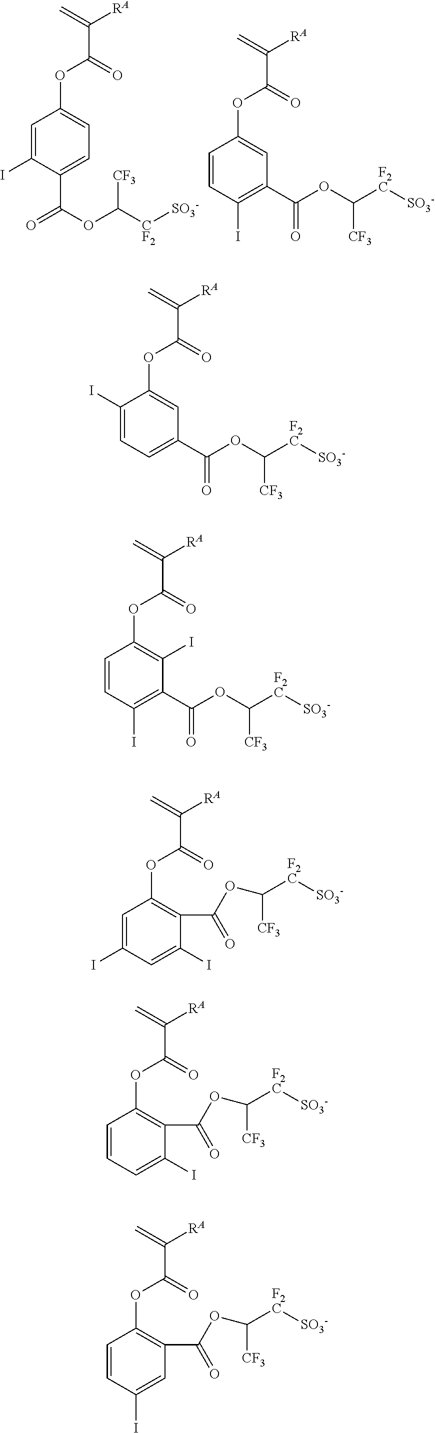

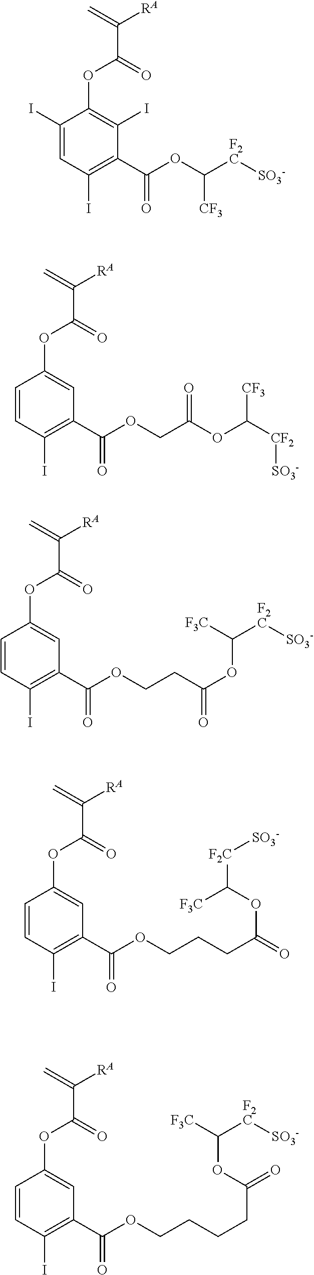

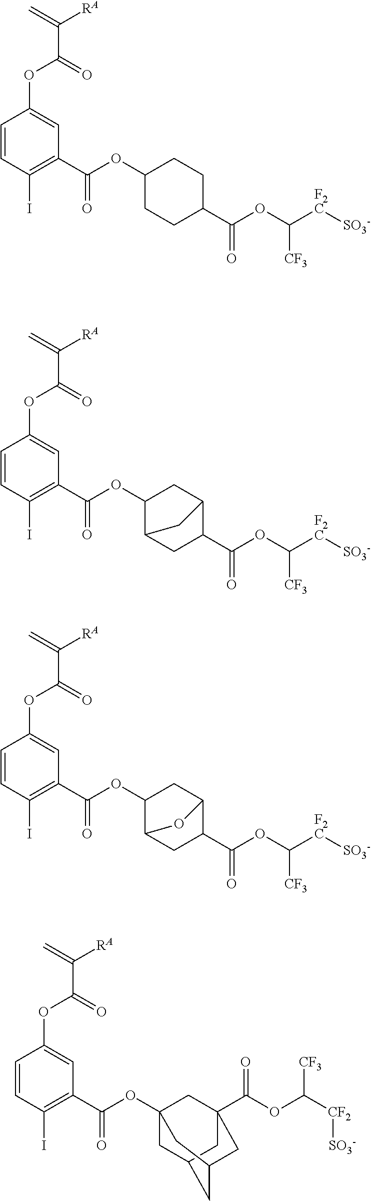

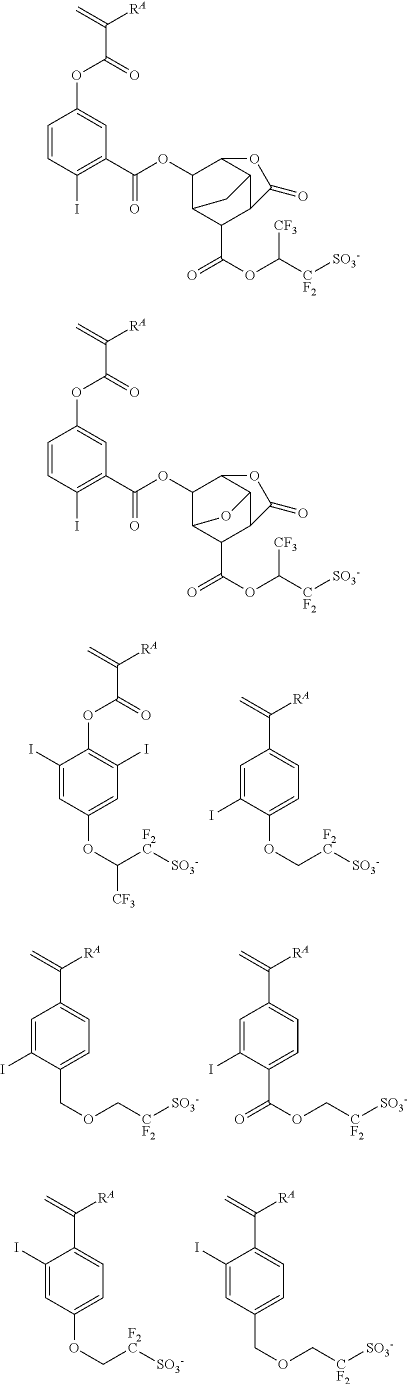

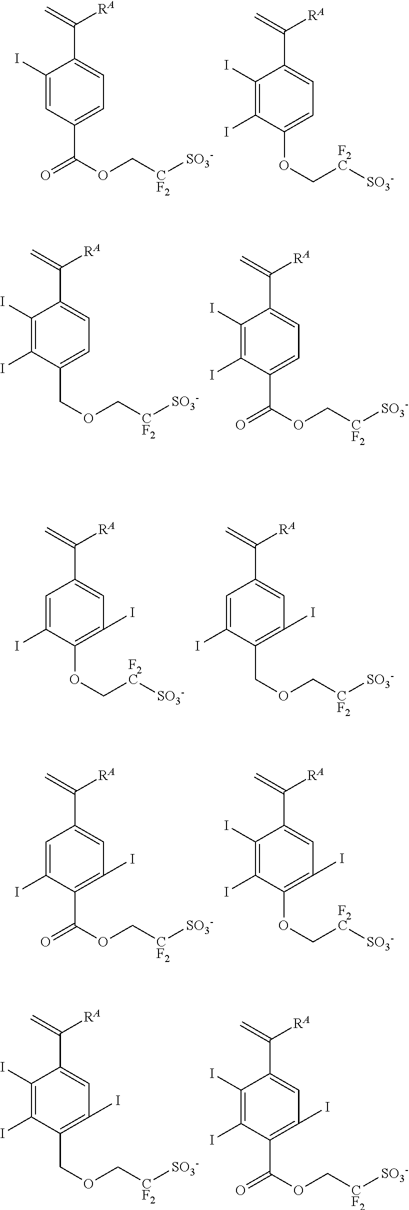

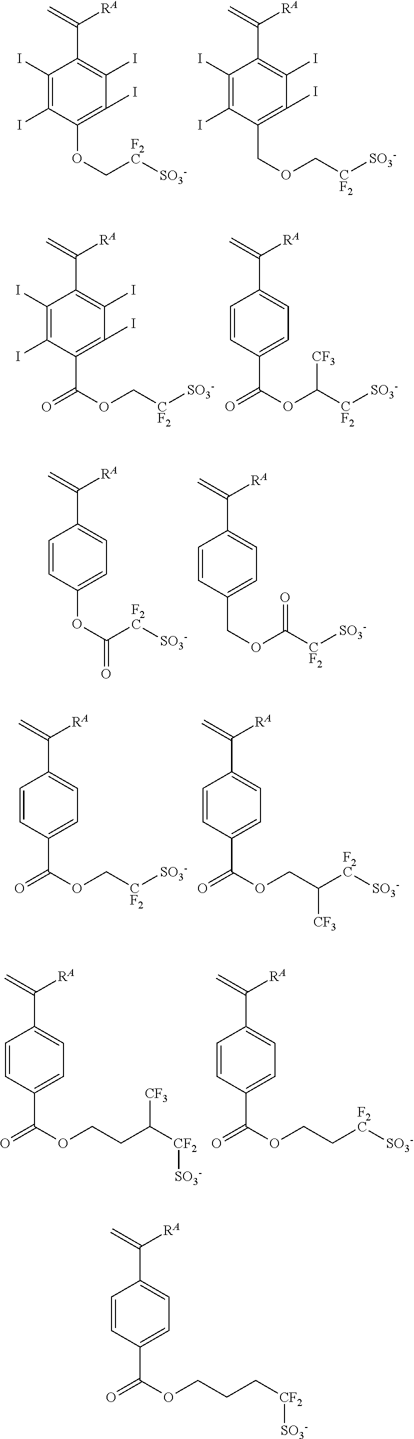

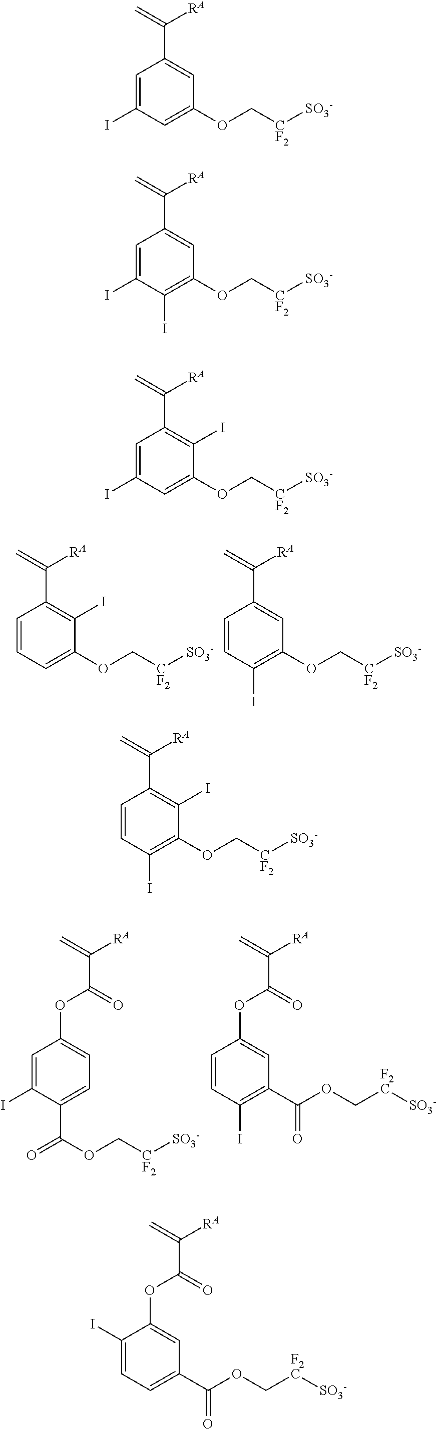

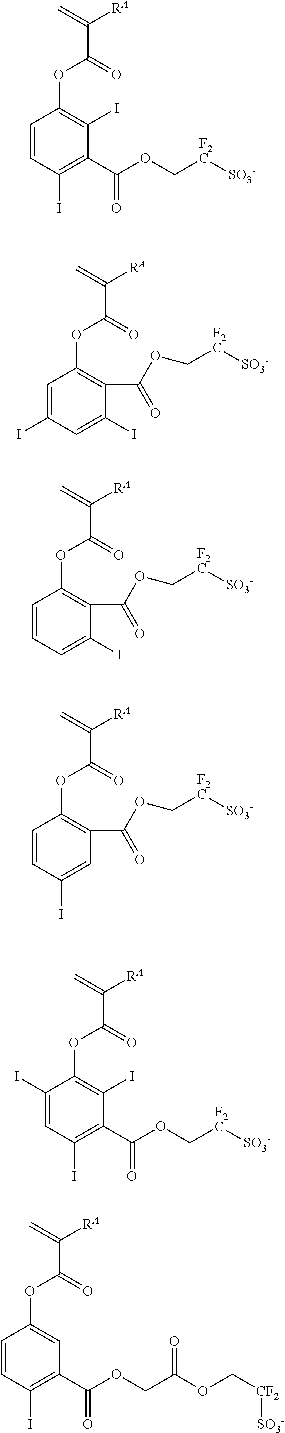

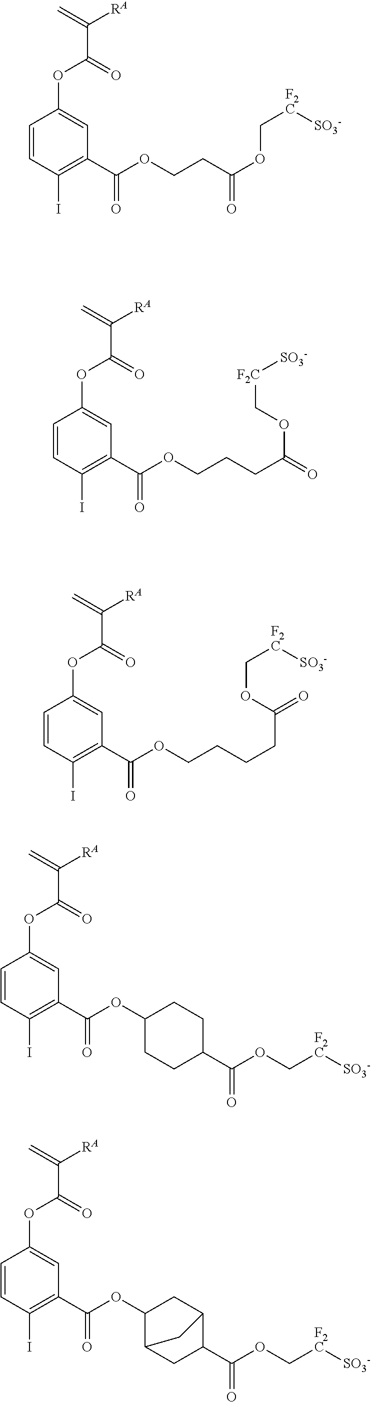

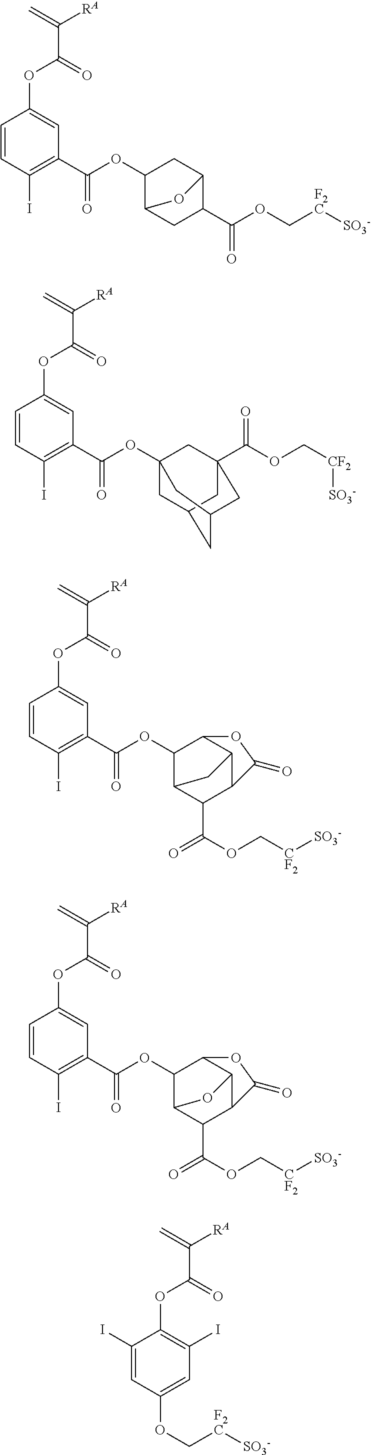

Examples of the anion of a monomer to give the repeating unit a2 include, but are not limited to those shown below. Incidentally, in the following formulae, R^{A} is the same as above.

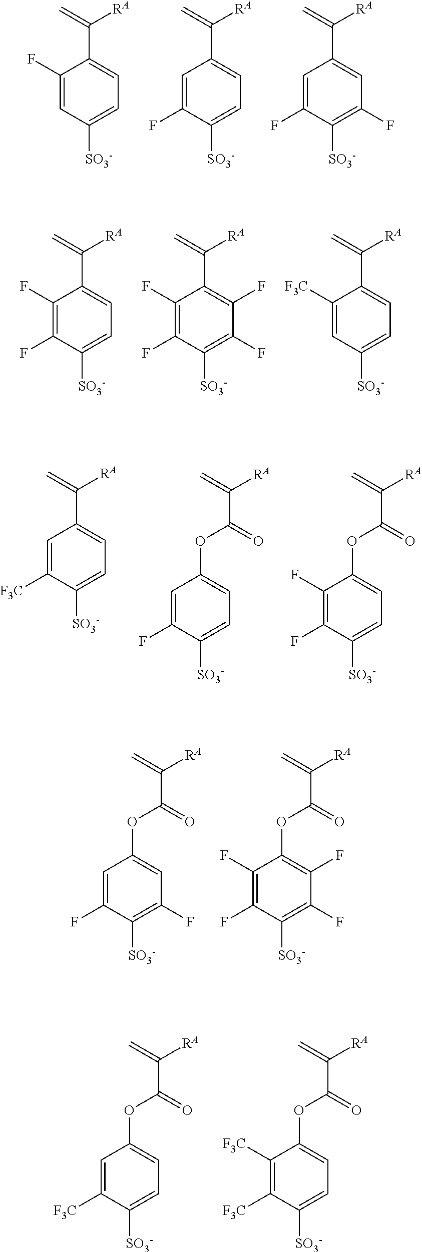

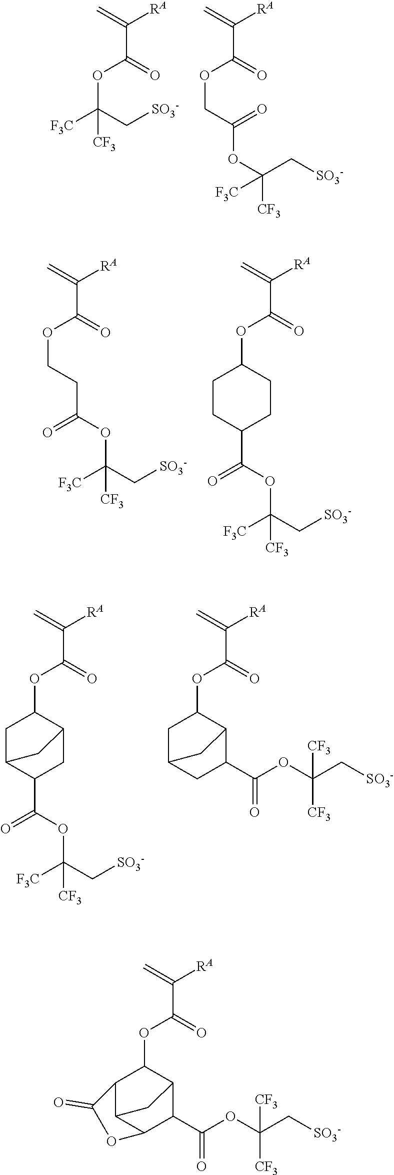

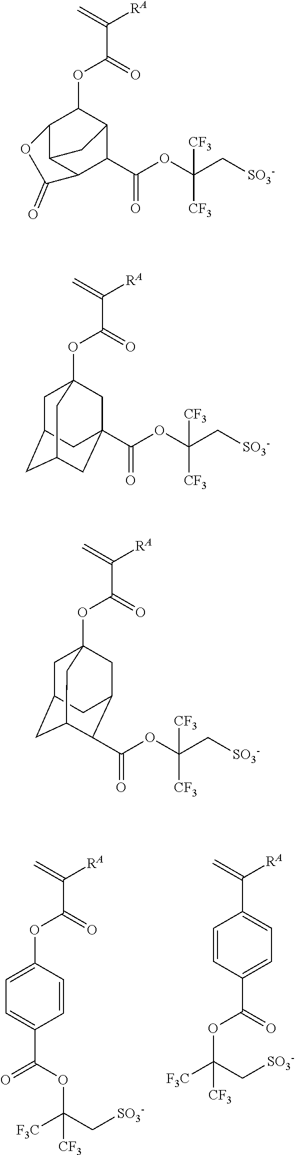

The repeating unit in which the hydrogen atom of the carboxy group is substituted with an acid labile group and the repeating unit in which the hydrogen atom of the phenolic hydroxy group is substituted with an acid labile group are respectively the repeating unit represented by the following general formula (b1) and the repeating unit represented by the following general formula (b2).

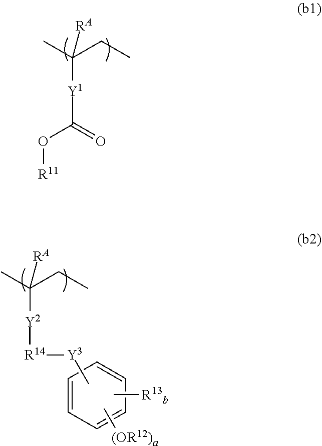

In the formulae, each R^{A} independently represents a hydrogen atom or a methyl group. Y¹ represents a single bond, a phenylene group, a naphthylene group, or a linking group having 1 to 15 carbon atoms containing at least one selected from an ester bond, an ether bond, and a lactone ring. Y² represents a single bond, an ester bond, or an amide bond. Y³ represents a single bond, an ether bond, or an ester bond. R¹¹ and R¹² each represent an acid labile group. R¹³ represents a fluorine atom, a trifluoromethyl group, a cyano group, or a saturated hydrocarbyl group having 1 to 6 carbon atoms. R¹⁴ represents a single bond or an alkanediyl group having 1 to 6 carbon atoms, and some of the carbon atoms are optionally substituted with an ether bond or an ester bond. “a” represents 1 or 2, and “b” represents an integer of 0 to 4, with 1≤a+b≤5.

Examples of a monomer to give the repeating unit (repeating unit b1) represented by the formula (b1) include, but are not limited to those shown below. Incidentally, in the following formulae, R^{A} and R¹¹ are the same as above.

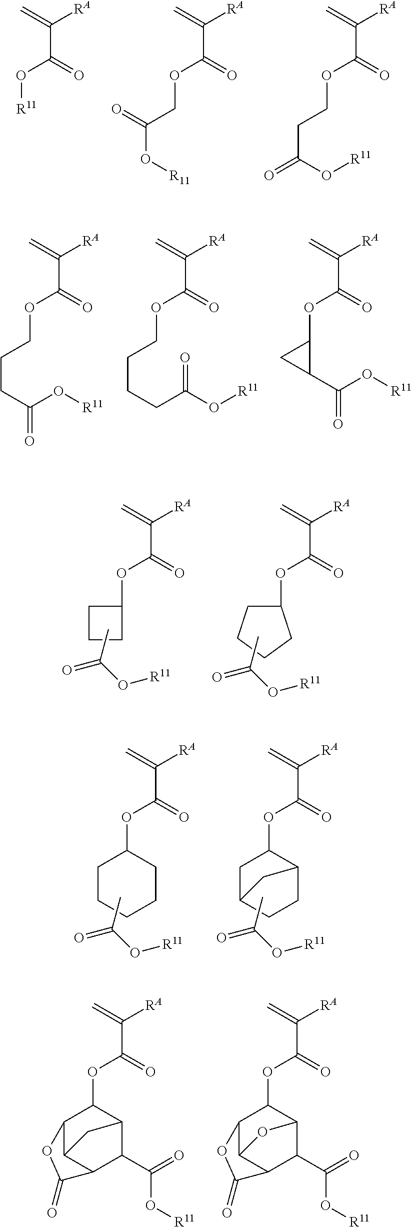

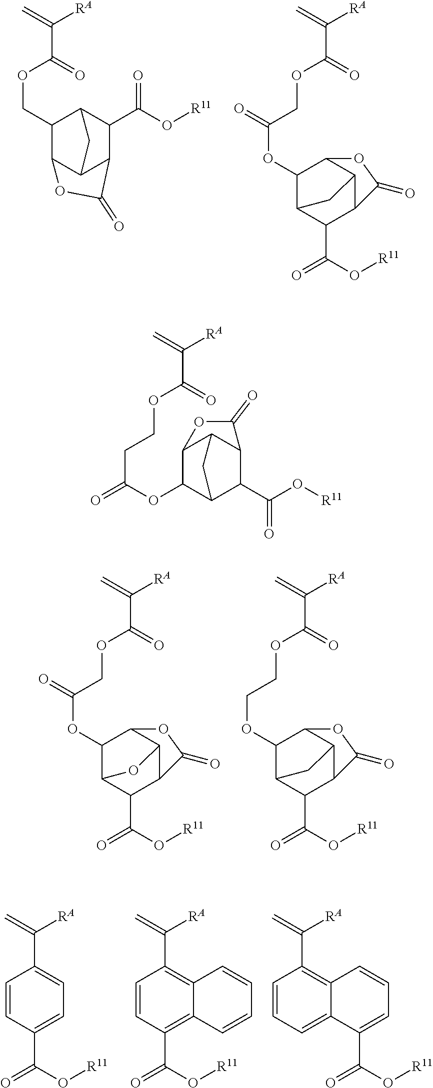

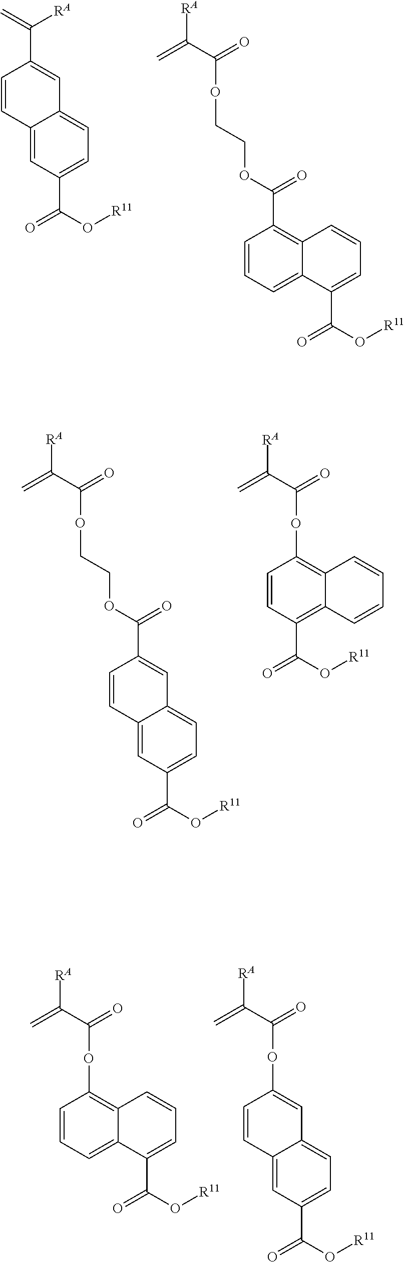

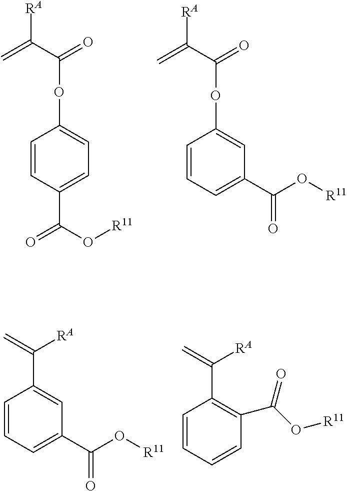

Examples of a monomer to give the repeating unit b2 include, but are not limited to those shown below. Incidentally, in the following formulae, R^{A} and R¹² are the same as above.

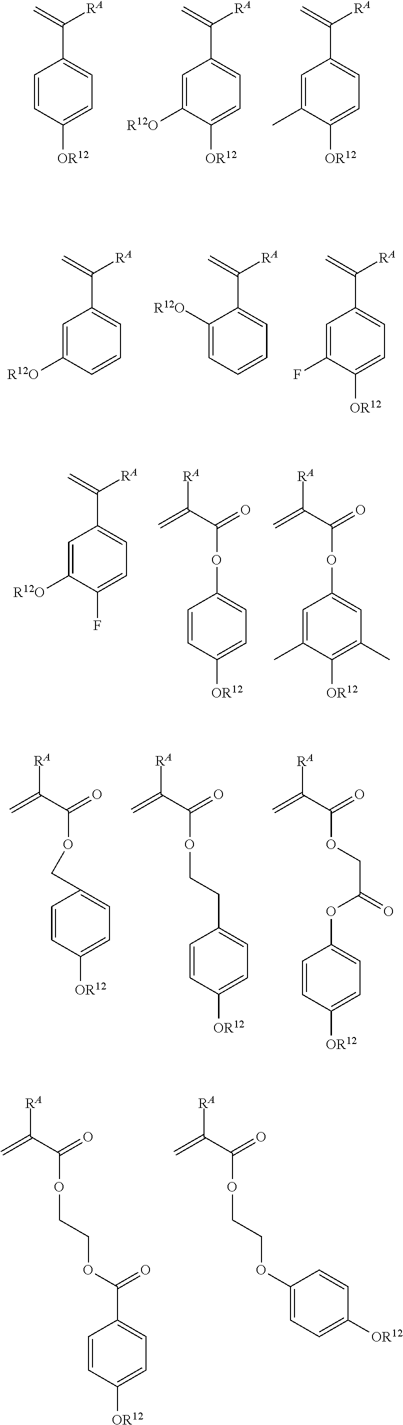

Various acid labile groups shown by R¹¹ or R¹² can be selected. Examples thereof include ones shown by the following general formulae (AL-1) to (AL-3).

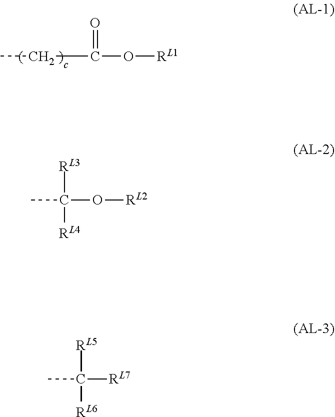

In the formula (AL-1), “c” represents an integer of 0 to 6. R^{L1} represents a tertiary hydrocarbyl group having 4 to 61 carbon atoms, preferably 4 to 15 carbon atoms, a trihydrocarbylsilyl group in which hydrocarbyl groups are each a saturated hydrocarbyl group having 1 to 6 carbon atoms, a saturated hydrocarbyl group having 4 to 20 carbon atoms containing a carbonyl group, an ether bond, or an ester bond, or a group shown by the formula (AL-3).

The tertiary hydrocarbyl group represented by R^{L1} may be saturated or unsaturated, and may be branched or cyclic. Specific examples thereof include a tert-butyl group, a tert-pentyl group, a 1,1-diethylpropyl group, a 1-ethylcyclopentyl group, a 1-butylcyclopentyl group, a 1-ethylcyclohexyl group, a 1-butylcyclohexyl group, a 1-ethyl-2-cyclopentenyl group, a 1-ethyl-2-cyclohexenyl group, a 2-methyl-2-adamantyl group, etc. Examples of the trialkylsilyl group (trihydrocarbylsilyl group) include a trimethylsilyl group, a triethylsilyl group, a dimethyl-tert-butylsilyl group, etc. The saturated hydrocarbyl group containing a carbonyl group, an ether bond, or an ester bond may be linear, branched, or cyclic, and is preferably cyclic. Specific examples thereof include a 3-oxocyclohexyl group, a 4-methyl-2-oxooxan-4-yl group, a 5-methyl-2-oxooxolan-5-yl group, a 2-tetrahydropyranyl group, a 2-tetrahydrofuranyl group, etc.

Examples of the acid labile group shown by the formula (AL-1) include a tert-butoxycarbonyl group, a tert-butoxycarbonylmethyl group, a tert-pentyloxycarbonyl group, a tert-pentyloxycarbonylmethyl group, a 1,1-diethylpropyloxycarbonyl group, a 1,1-diethylpropyloxycarbonylmethyl group, a 1-ethylcyclopentyloxycarbonyl group, a 1-ethylcyclopentyloxycarbonylmethyl group, a 1-ethyl-2-cyclopentenyloxycarbonyl group, a 1-ethyl-2-cyclopentenyloxycarbonylmethyl group, a 1-ethoxyethoxycarbonylmethyl group, a 2-tetrahydropyranyloxycarbonylmethyl group, a 2-tetrahydrofuranyloxycarbonylmethyl group, etc.

Other examples of the acid labile group shown by the formula (AL-1) include groups shown by the following formulae (AL-1)-1 to (AL-1)-10.

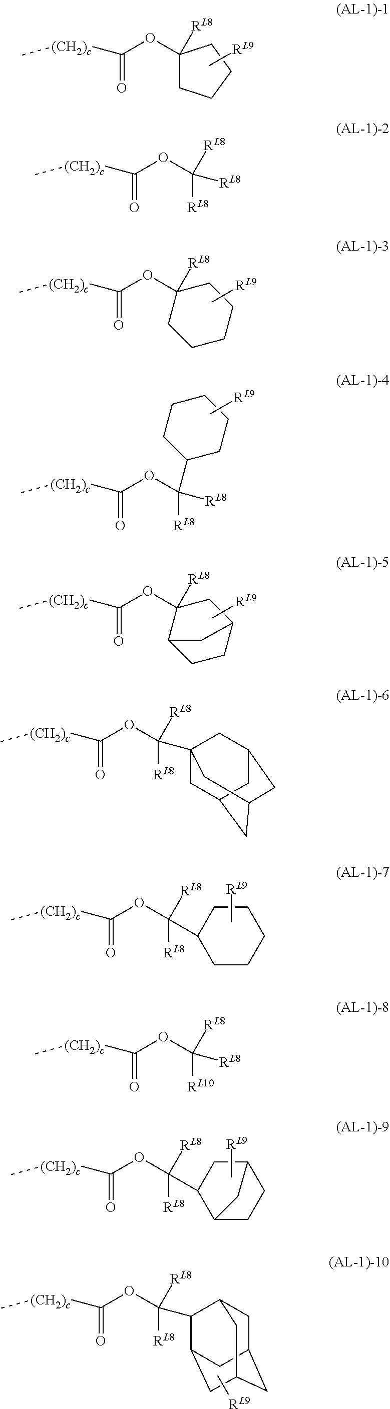

In the formulae, each broken line represents an attachment point.

In the formulae (AL-1)-1 to (AL-1)-10, “c” is as defined above. R^{L8} each independently represent a saturated hydrocarbyl group having 1 to 10 carbon atoms or an aryl group having 6 to 20 carbon atoms. R^{L9} represents a hydrogen atom or a saturated hydrocarbyl group having 1 to 10 carbon atoms. R^{L10} represents a saturated hydrocarbyl group having 2 to 10 carbon atoms or an aryl group having 6 to 20 carbon atoms. The saturated hydrocarbyl group may be linear, branched, or cyclic.

In the formula (AL-2), R^{L3} and R^{L4} each independently represent a hydrogen atom or a saturated hydrocarbyl group having 1 to 18 carbon atoms, preferably 1 to 10 carbon atoms. The saturated hydrocarbyl group may be linear, branched, or cyclic. Specific examples thereof include a methyl group, an ethyl group, a propyl group, an isopropyl group, an n-butyl group, a sec-butyl group, a tert-butyl group, a cyclopentyl group, a cyclohexyl group, a 2-ethylhexyl group, an n-octyl group, etc.

In the formula (AL-2), R^{L2} represents a hydrocarbyl group having 1 to 18 carbon atoms, preferably 1 to 10 carbon atoms, and optionally contains a heteroatom. The hydrocarbyl group may be saturated or unsaturated, and may be linear, branched, or cyclic. Examples of the hydrocarbyl group include saturated hydrocarbyl groups each having 1 to 18 carbon atoms, etc., and some of the hydrogen atoms thereof may be substituted with a hydroxy group, an alkoxy group, an oxo group, an amino group, an alkylamino group, or the like. Examples of such substituted saturated hydrocarbyl groups include ones shown below, etc.

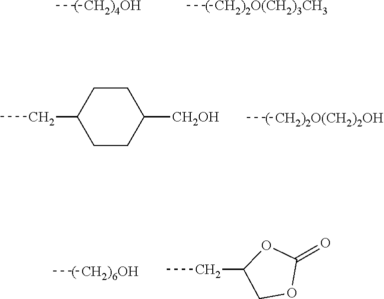

In the formulae, each broken line represents an attachment point.

R^{L2} and R^{L3}, R^{L2} and R^{L4}, or R^{L3} and R^{L4}, optionally bond with each other to form a ring together with a carbon atom bonded therewith, or together with the carbon atom and an oxygen atom. In this case, R^{L2} and R^{L3}, R^{L2} and R^{L4}, or R^{L3} and R^{L4}, involved in the ring formation each independently represent an alkanediyl group having 1 to 18 carbon atoms, preferably 1 to 10 carbon atoms. The number of carbon atoms in the ring obtained by bonding these is preferably 3 to 10, more preferably 4 to 10.

Examples of the linear and branched acid labile groups shown by the formula (AL-2) include ones shown by the following formulae (AL-2)-1 to (AL-2)-69, but are not limited thereto. Note that, in the following formulae, each broken line represents an attachment point.

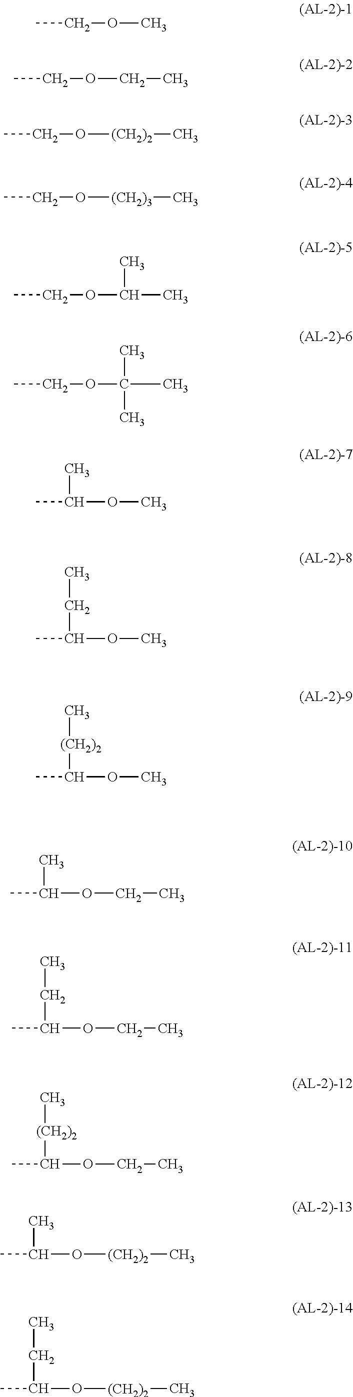

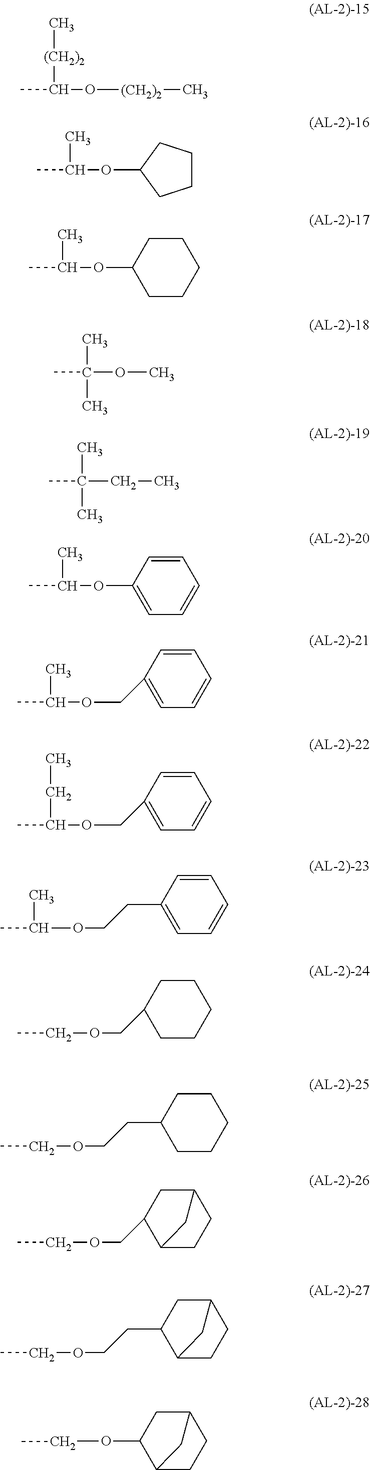

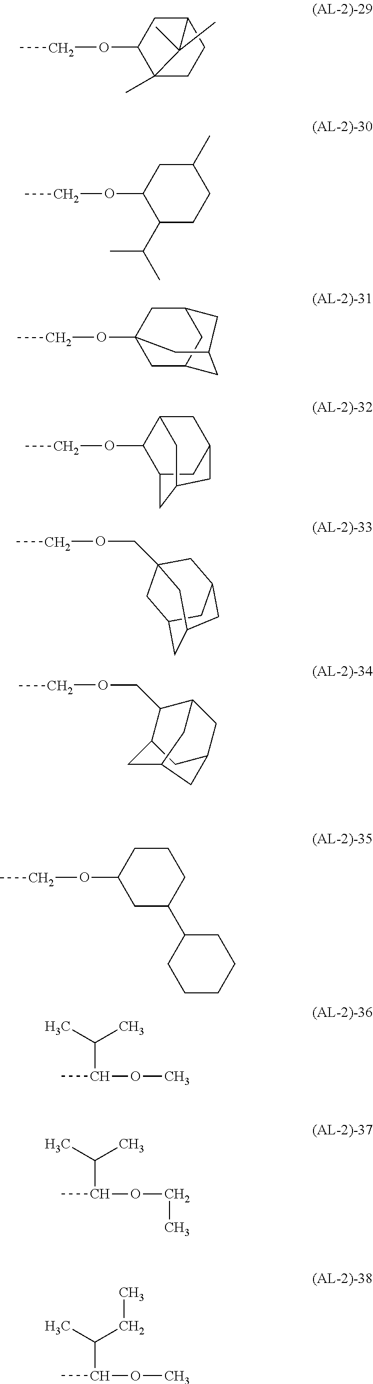

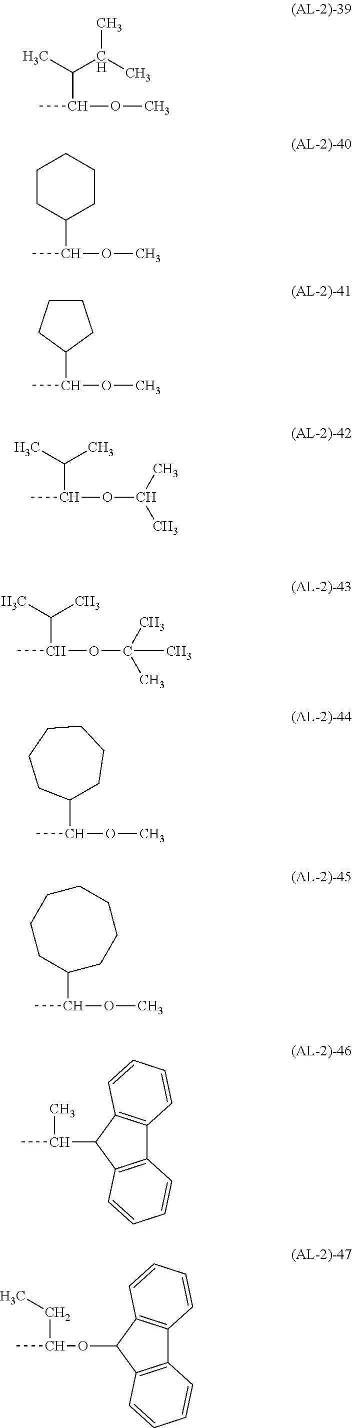

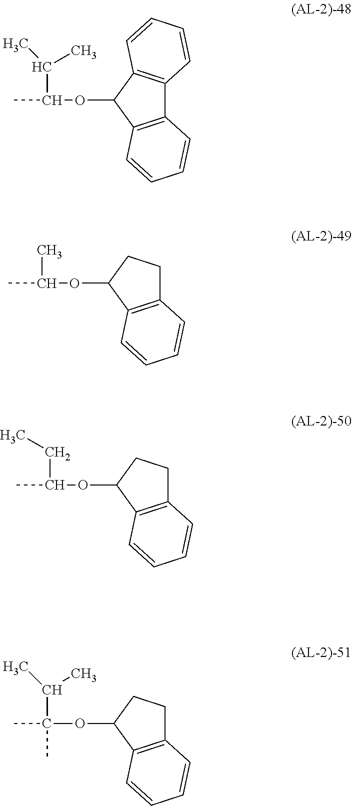

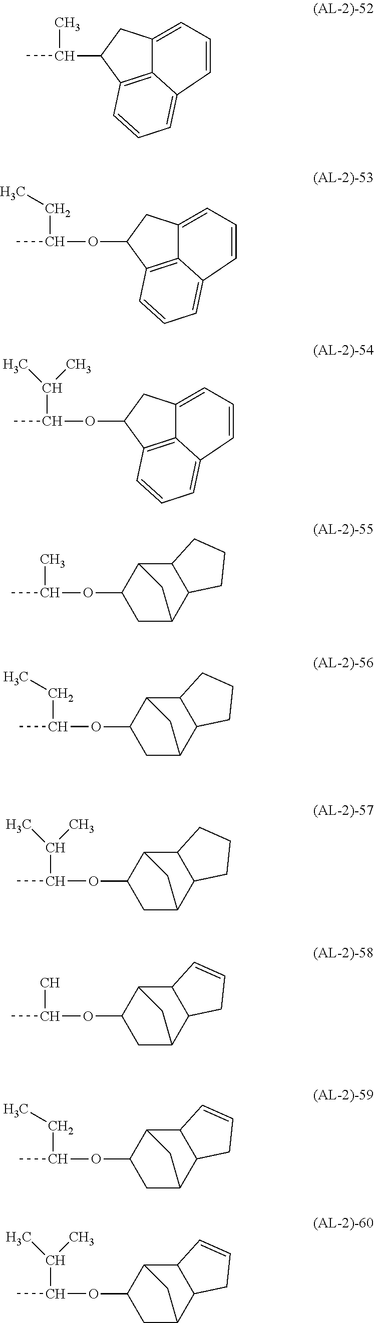

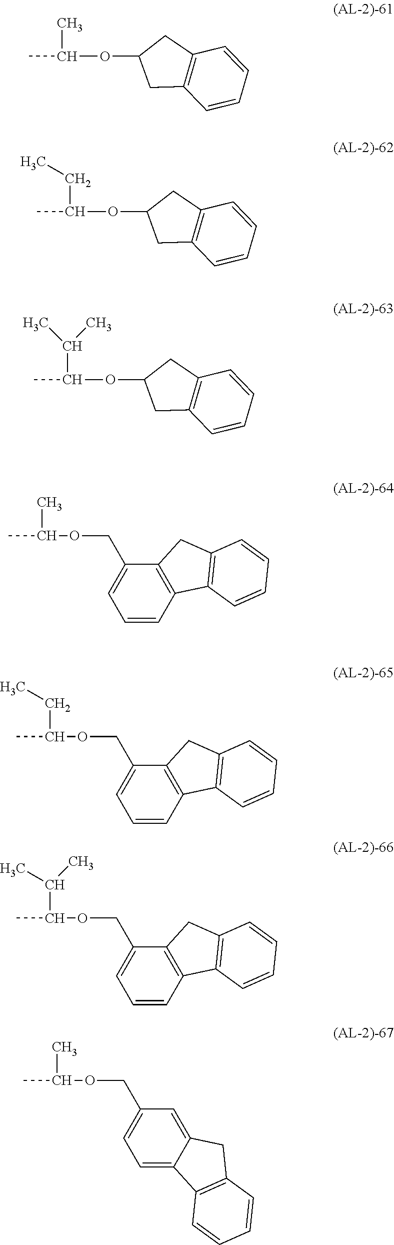

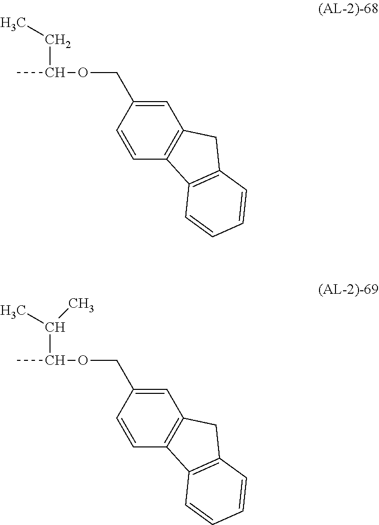 [SMILES: CC[C@@H](C)OCc1ccc2c(c1)Cc1ccccc1-2 ; CC(C)[C@@H](C)OCc1ccc2c(c1)Cc1ccccc1-2]

Examples of the cyclic acid labile group shown by the formula (AL-2) include a tetrahydrofuran-2-yl group, a 2-methyltetrahydrofuran-2-yl group, a tetrahydropyran-2-yl group, a 2-methyltetrahydropyran-2-yl group, etc.

In addition, examples of the acid labile groups include crosslinking acetal groups shown by the following general formula (AL-2a) or (AL-2b). The acid labile group may crosslink the base polymer intermolecularly or intramolecularly.

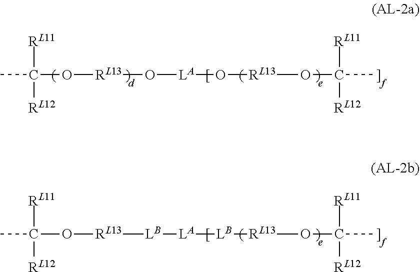

In the formulae, each broken line represents an attachment point.

In the formula (AL-2a) or (AL-2b), R^{L11} and R^{L12} each independently represent a hydrogen atom or a saturated hydrocarbyl group having 1 to 8 carbon atoms. The saturated hydrocarbyl group may be linear, branched, or cyclic. Alternatively, R^{L11} and R^{L12} may bond with each other to form a ring together with a carbon atom bonded therewith. In this case, R^{L11} and R^{L12} each independently represent an alkanediyl group having 1 to 8 carbon atoms. Each R^{L13} independently represents a saturated hydrocarbylene group having 1 to 10 carbon atoms. The saturated hydrocarbylene group may be linear, branched, or cyclic. “d” and “e” each independently represent an integer of 0 to 10, preferably an integer of 0 to 5. “f” represents an integer of 1 to 7, preferably an integer of 1 to 3.

In the formula (AL-2a) or (AL-2b), L^{A} represents an aliphatic saturated hydrocarbon group having a valency of (f+1) with 1 to 50 carbon atoms, an alicyclic saturated hydrocarbon group having a valency of (f+1) with 3 to 50 carbon atoms, an aromatic hydrocarbon group having a valency of (f+1) with 6 to 50 carbon atoms, or a heterocyclic group having a valency of (f+1) with 3 to 50 carbon atoms. Some of the carbon atoms of these groups may be substituted with a heteroatom-containing group, and some hydrogen atoms bonded to the carbon atoms of these groups may be substituted with a hydroxy group, a carboxy group, an acyl group, or a fluorine atom. L^{A} is preferably an arylene group having 6 to 30 carbon atoms, a saturated hydrocarbon group, such as a saturated hydrocarbylene group, a trivalent saturated hydrocarbon group, and a tetravalent saturated hydrocarbon group each of which have 1 to 20 carbon atoms, or the like. The saturated hydrocarbon group may be linear, branched, or cyclic. L^{B} represents —C(═O)—O—, —NH—C(═O)—O—, or —NH—C(═O)—NH—.

Examples of the crosslinking acetal group shown by the formulae (AL-2a) and (AL-2b) include groups shown by the following formulae (AL-2)-70 to (AL-2)-77, etc.

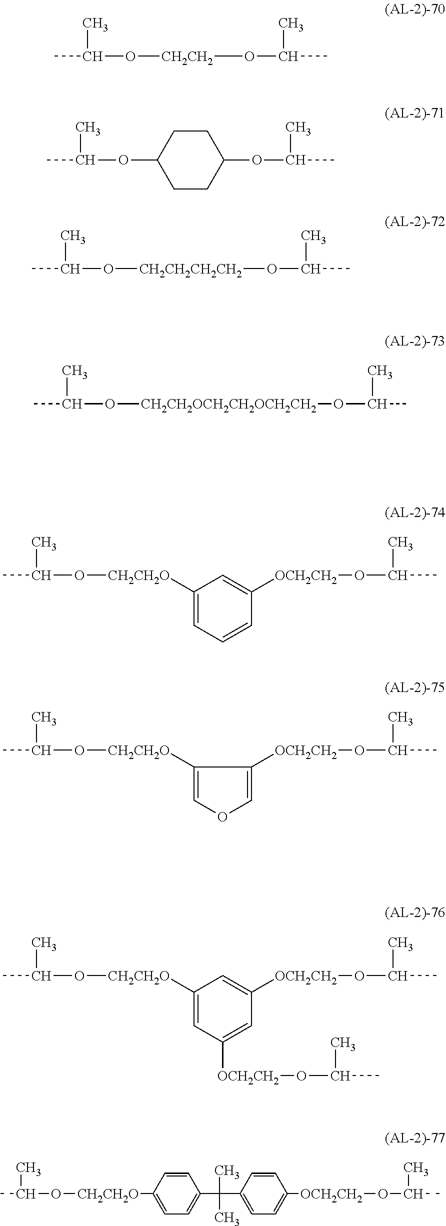

In the formulae, each broken line represents an attachment point.

In the formula (AL-3), R^{L5}, R^{L6}, and R^{L7} each independently represent a hydrocarbyl group having 1 to 20 carbon atoms, and optionally contain a heteroatom such as an oxygen atom, a sulfur atom, a nitrogen atom, and a fluorine atom. The hydrocarbyl group may be saturated or unsaturated, and may be linear, branched, or cyclic. Specific examples thereof include alkyl groups having 1 to 20 carbon atoms, cyclic saturated hydrocarbyl groups having 3 to 20 carbon atoms, alkenyl groups having 2 to 20 carbon atoms, cyclic unsaturated hydrocarbyl groups having 3 to 20 carbon atoms, aryl groups having 6 to 10 carbon atoms, etc. Alternatively, R^{L5} and R^{L6}, R^{L5} and R^{L7}, or R^{L6} and R^{L7}, may bond with each other to form an alicyclic group having 3 to 20 carbon atoms, together with a carbon atom bonded therewith.

Examples of the group shown by the formula (AL-3) include a tert-butyl group, a 1,1-diethylpropyl group, a 1-ethylnorbornyl group, a 1-methylcyclopentyl group, a 1-isopropylcyclopentyl group, a 1-ethylcyclopentyl group, a 1-methylcyclohexyl group, a 2-(2-methyl)adamantyl group, a 2-(2-ethyl)adamantyl group, a tert-pentyl group, etc.

The examples of the group shown by the formula (AL-3) also include groups shown by the following formulae (AL-3)-1 to (AL-3)-19.

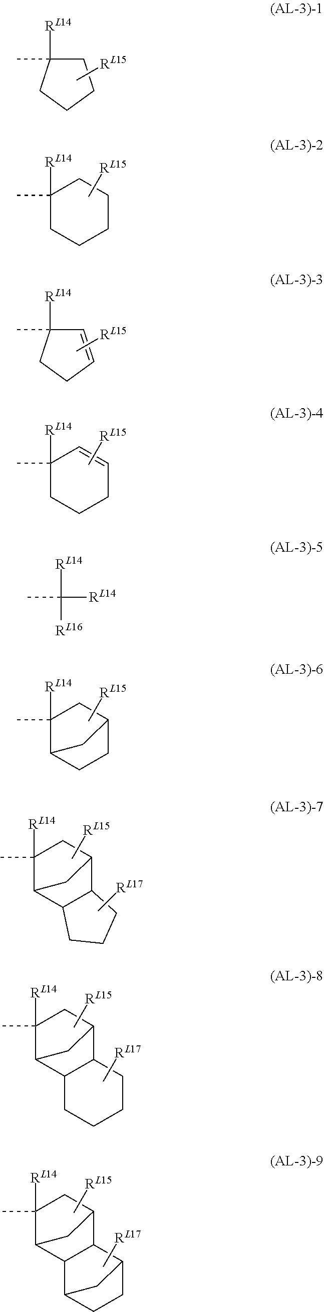

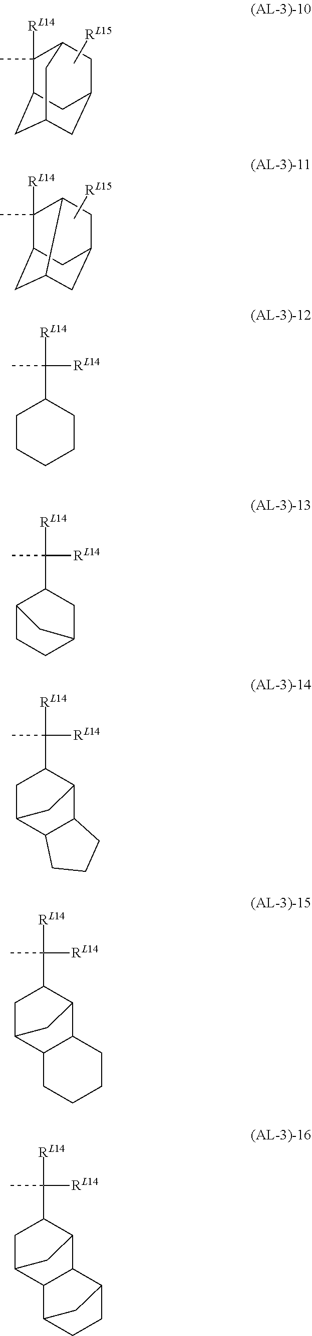

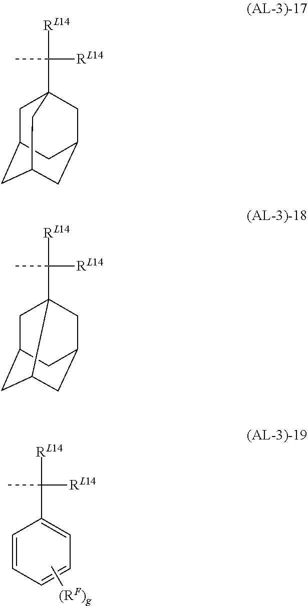

In the formulae, each broken line represents an attachment point.

In the formulae (AL-3)-1 to (AL-3)-19, each R^{L14} independently represents a saturated hydrocarbyl group having 1 to 8 carbon atoms, an unsaturated hydrocarbyl group having 1 to 8 carbon atoms, or an aryl group having 6 to 20 carbon atoms. R^{L15} and R^{L17} each independently represent a hydrogen atom or a saturated hydrocarbyl group having 1 to 20 carbon atoms. R^{L16} represents an aryl group having 6 to 20 carbon atoms. The saturated hydrocarbyl group may be linear, branched, or cyclic. The aryl groups are preferably a phenyl group or the like. R^{F} represents a fluorine atom or a trifluoromethyl group. “g” represents an integer of 1 to 5.

Specific examples of (AL-3)-19 include the following.

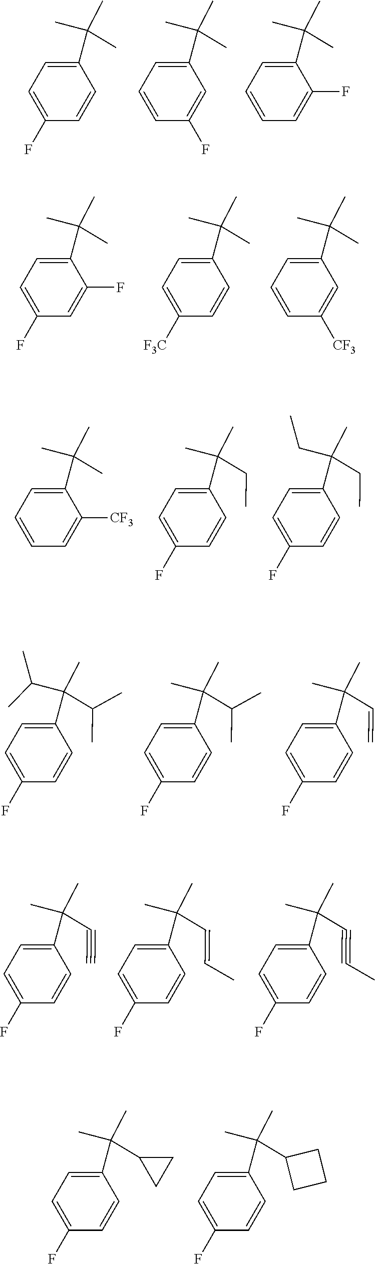

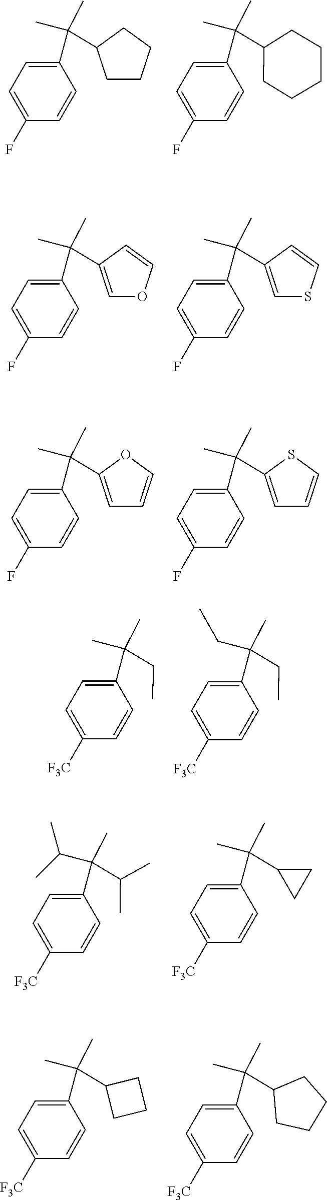

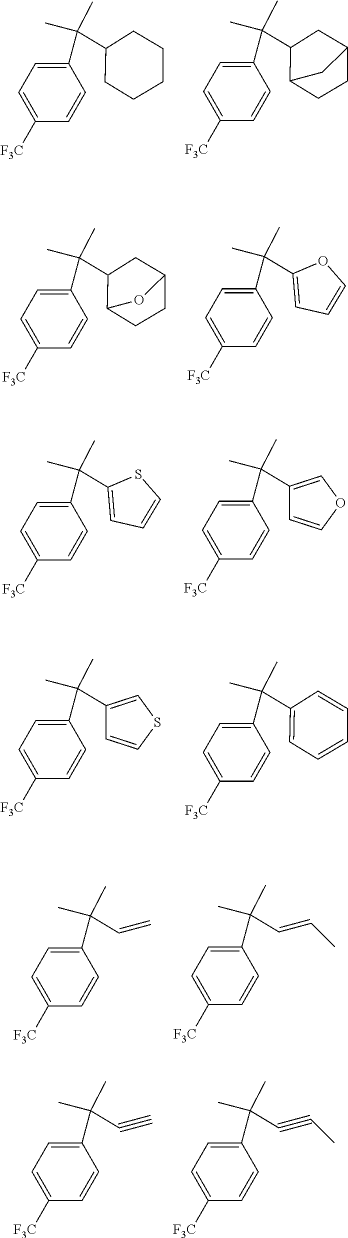

An aromatic acid labile group having a nitrogen atom can also be used. Specific examples include the following.

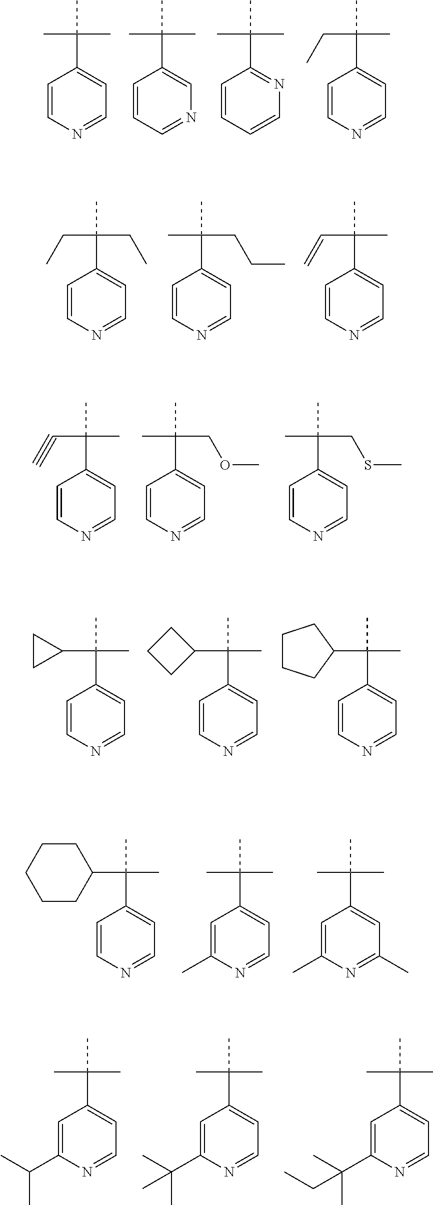

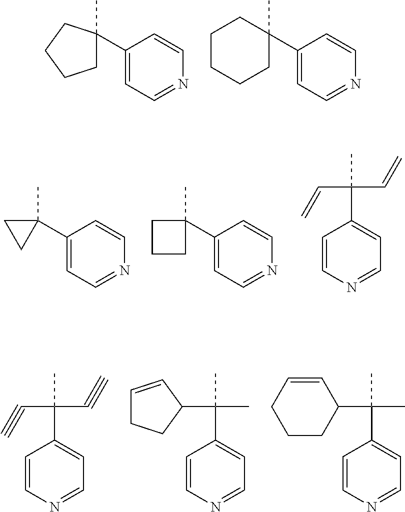

Examples of the acid labile group further include groups shown by the following formula (AL-3)-20 or (AL-3)-21. The acid labile group may crosslink the polymer intramolecularly or intermolecularly.

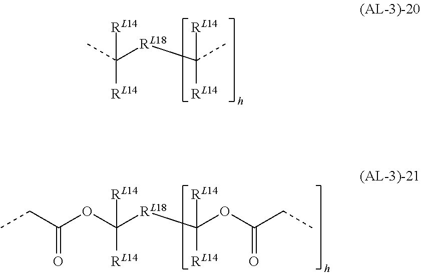

In the formulae, each broken line represents an attachment point.

In the formulae (AL-3)-20 and (AL-3)-21, R^{L14} is as defined above. R^{L18} represents a saturated hydrocarbylene group having a valency of (h+1) with 1 to 20 carbon atoms, or an arylene group having a valency of (h+1) with 6 to 20 carbon atoms, and optionally contains a heteroatom such as an oxygen atom, a sulfur atom, and a nitrogen atom. The saturated hydrocarbylene group may be linear, branched, or cyclic. “h” represents an integer of 1 to 3.

Examples of a monomer to give the repeating unit containing the acid labile group shown by the formula (AL-3) include (meth)acrylate having an exo-form structure shown by the following formula (AL-3)-22.

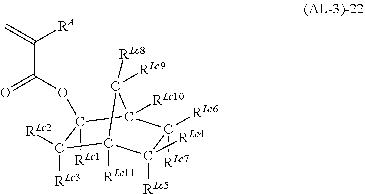

In the formula (AL-3)-22, R^{A} is as defined above. R^{Lc1} represents a saturated hydrocarbyl group having 1 to 8 carbon atoms, or an aryl group having 6 to 20 carbon atoms and optionally containing a substituent. The saturated hydrocarbyl group may be linear, branched, or cyclic. R^{Lc2} to R^{Lc11} each independently represent a hydrogen atom, or a hydrocarbyl group having 1 to 15 carbon atoms and optionally containing a heteroatom. Examples of the heteroatom include oxygen atom etc. Examples of the hydrocarbyl group include alkyl groups having 1 to 15 carbon atoms, aryl groups having 6 to 15 carbon atoms, etc. R^{Lc2} and R^{Lc3}, R^{Lc4} and R^{Lc6}, R^{Lc4} and R^{Lc7}, R^{Lc5} and R^{Lc7}, R^{Lc5} and R^{Lc11}, R^{Lc6} and R^{Lc10}, R^{Lc8} and R^{Lc9}, or R^{Lc9} and R^{Lc10}, may bond with each other to form a ring together with a carbon atom bonded therewith. In this case, a group involved in the bonding is a hydrocarbylene group having 1 to 15 carbon atoms and optionally containing a heteroatom. Alternatively, R^{Lc2} and R^{Lc11}, R^{Lc8} and R^{Lc11}, or R^{Lc4} and R^{Lc6}, all pairs of which are attached to carbon atoms next to each other, may directly bond with each other to form a double bond. Note that the formula also represents an enantiomer.

Examples of the monomer shown by the formula (AL-3)-22 to give the repeating unit include ones disclosed in JP 2000-327633 A, etc. Specific examples thereof include ones shown below, but are not limited thereto. Note that, in the following formulae, R^{A} is as defined above.

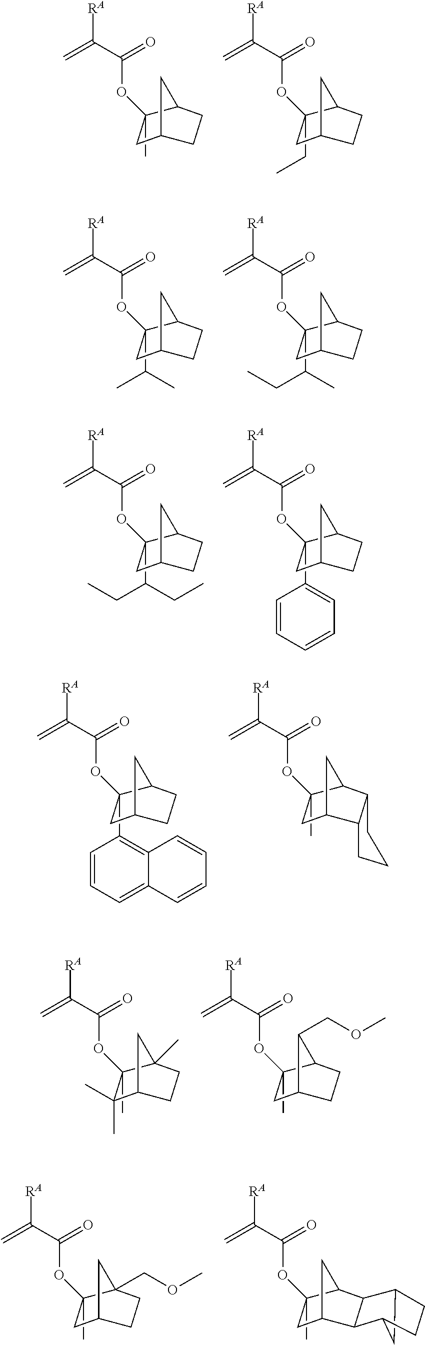

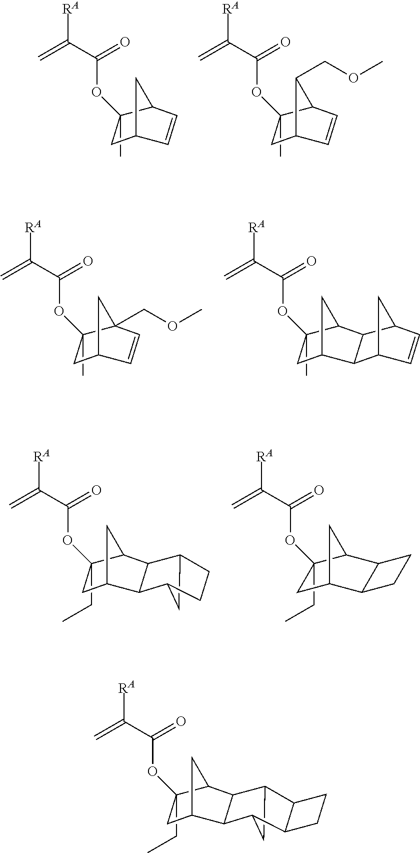

Other examples of the monomer to give the repeating unit containing the acid labile group shown by the formula (AL-3) include (meth)acrylate containing a furandiyl group, a tetrahydrofurandiyl group, or an oxanorbornanediyl group as shown by the following formula (AL-3)-23.

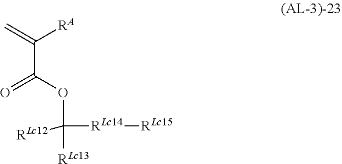

In the formula (AL-3)-23, R^{A} is as defined above. R^{Lc12} and R^{Lc13} each independently represent a hydrocarbyl group having 1 to 10 carbon atoms. R^{Lc12} and R^{Lc13} may bond with each other to form an alicyclic group together with a carbon atom bonded therewith. R^{Lc14} represents a furandiyl group, a tetrahydrofurandiyl group, or an oxanorbornanediyl group. R^{LC15} represents a hydrogen atom, or a hydrocarbyl group having 1 to 10 carbon atoms and optionally containing a heteroatom. The hydrocarbyl group may be linear, branched, or cyclic. Specific examples thereof include a saturated hydrocarbyl group having 1 to 10 carbon atoms, etc.

Examples of the monomer shown by the formula (AL-3)-23 to give the repeating unit include, but are not limited to, ones shown below. Note that, in the following formulae, R^{A} is as defined above, Ac represents an acetyl group, and Me represents a methyl group.

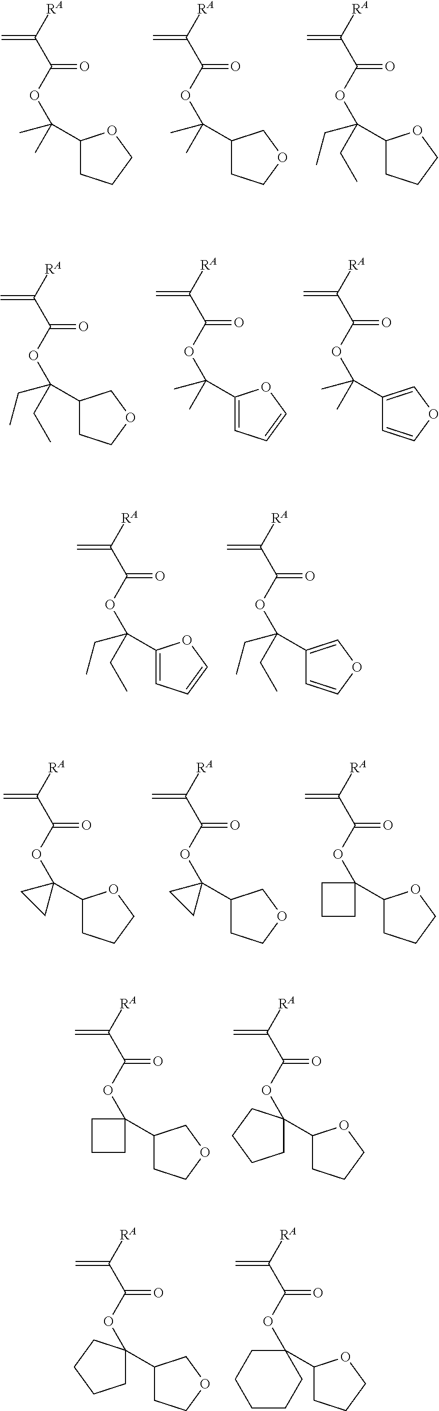

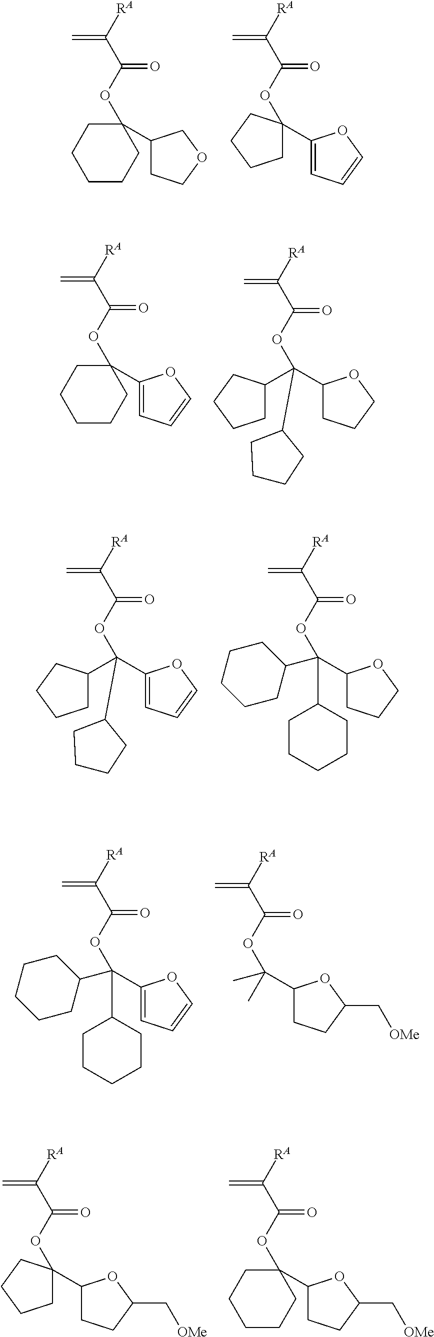

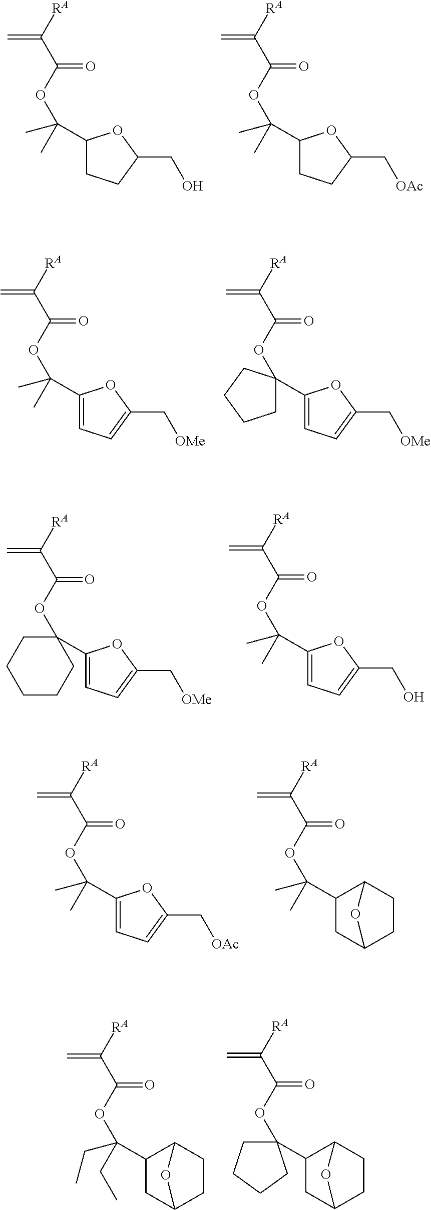

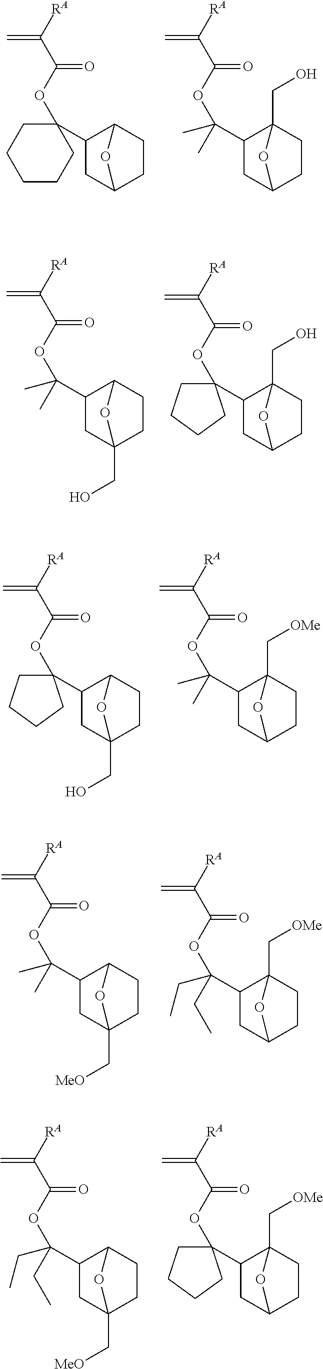

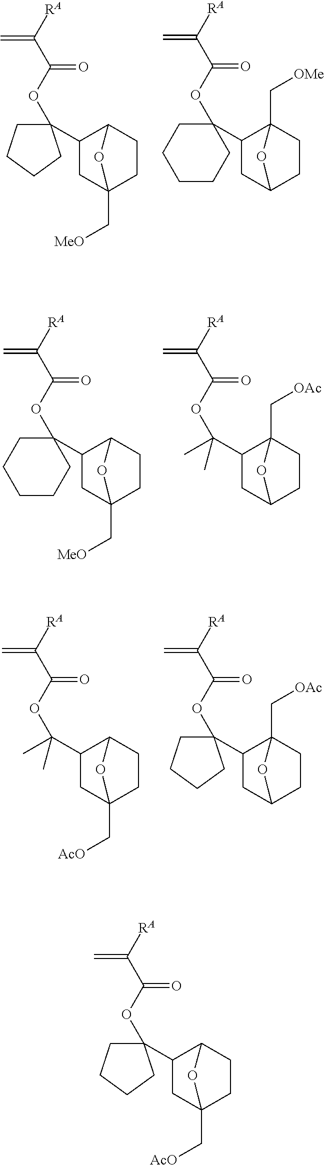

The base polymer may further contain a repeating unit-c containing an adhesive group selected from the group consisting of a hydroxy group, a carboxy group, a lactone ring, a carbonate group, a thiocarbonate group, a carbonyl group, a cyclic acetal group, an ether bond, an ester bond, a sulfonic acid ester group, a cyano group, an amide bond, —O—C(═O)—S—, and —O—C(═O)—NH—.

Examples of a monomer to give the repeating unit-c include those shown below, but are not limited thereto. Note that, in the following formulae, R^{A} is as defined above.

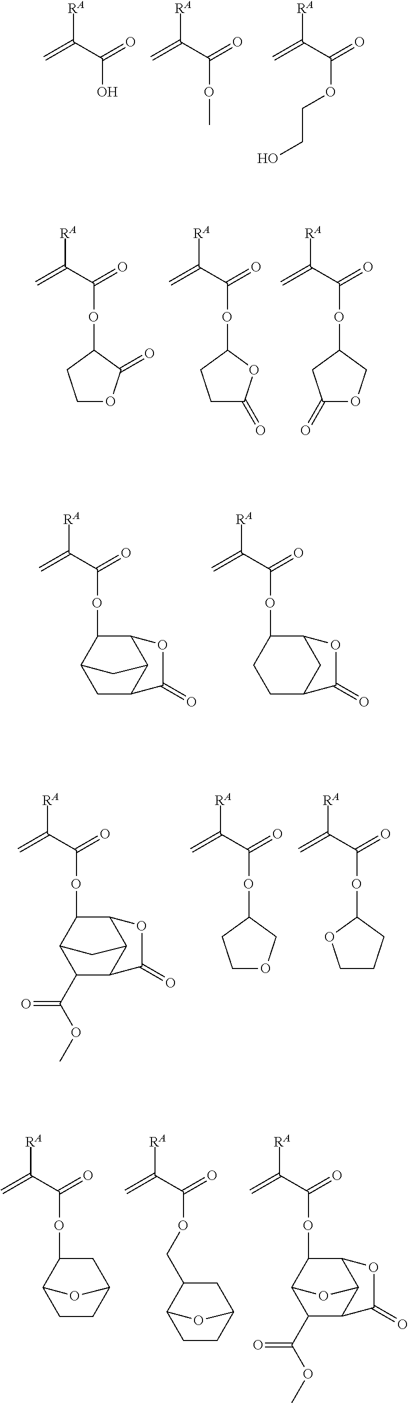

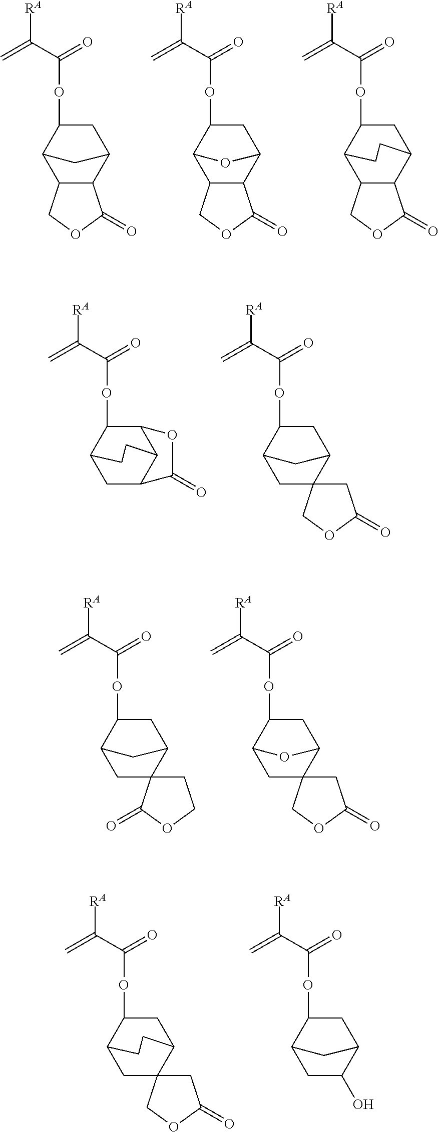

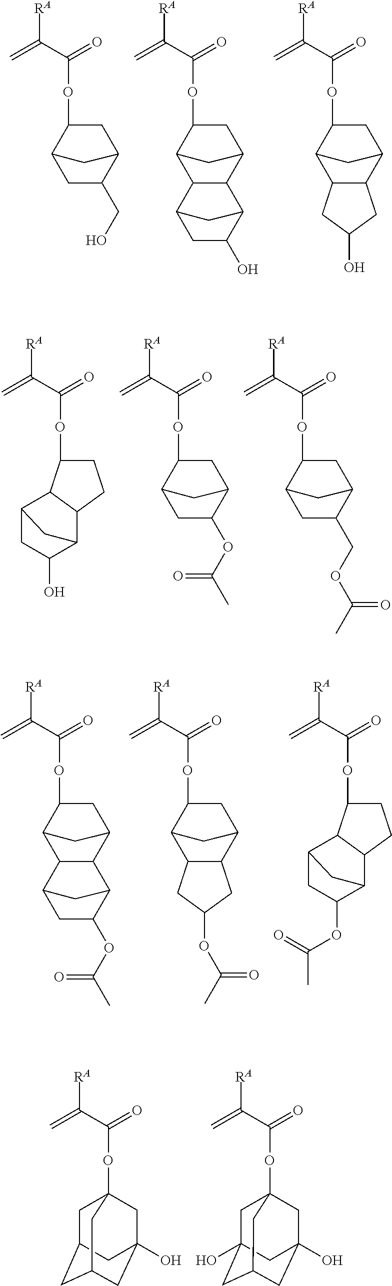

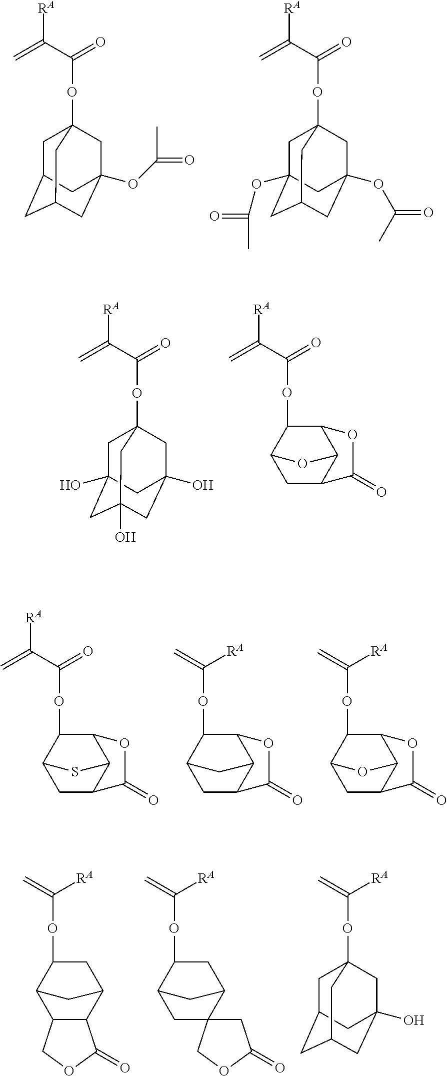

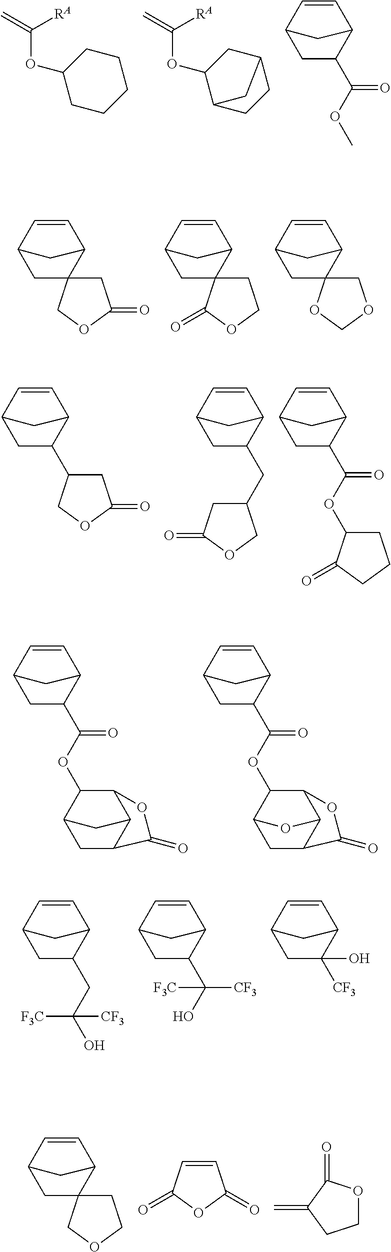

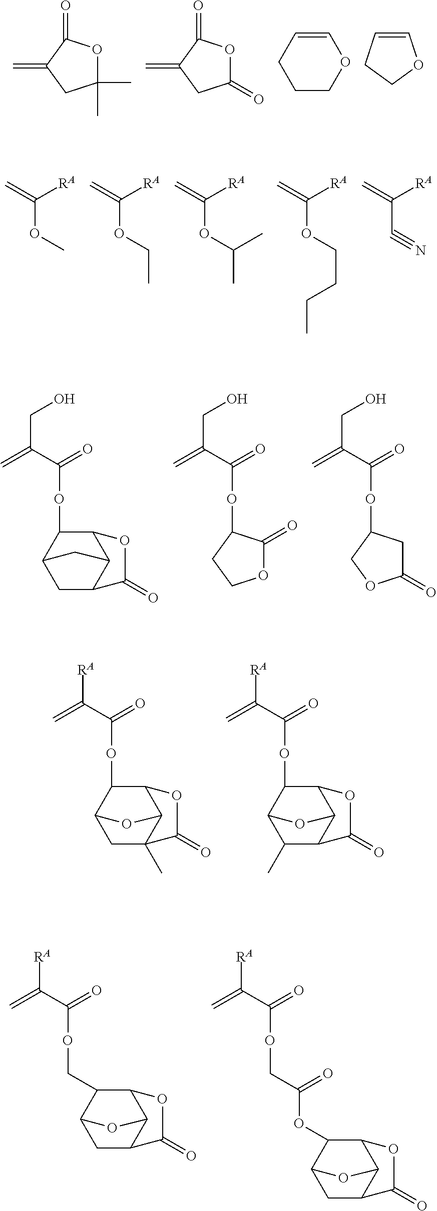

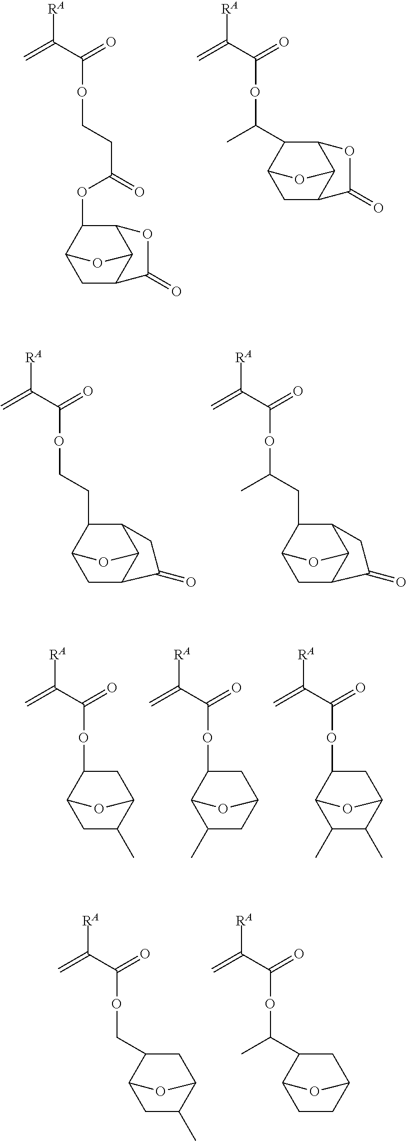

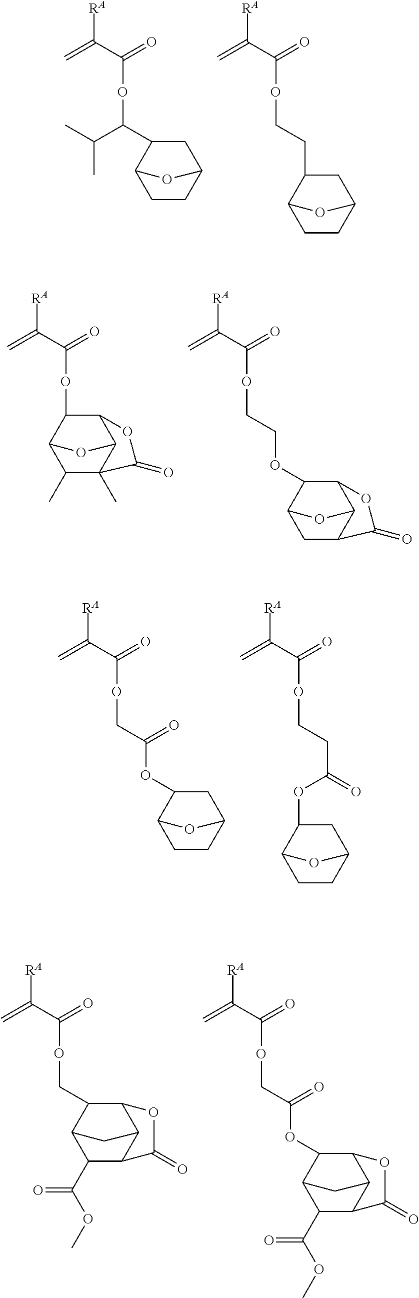

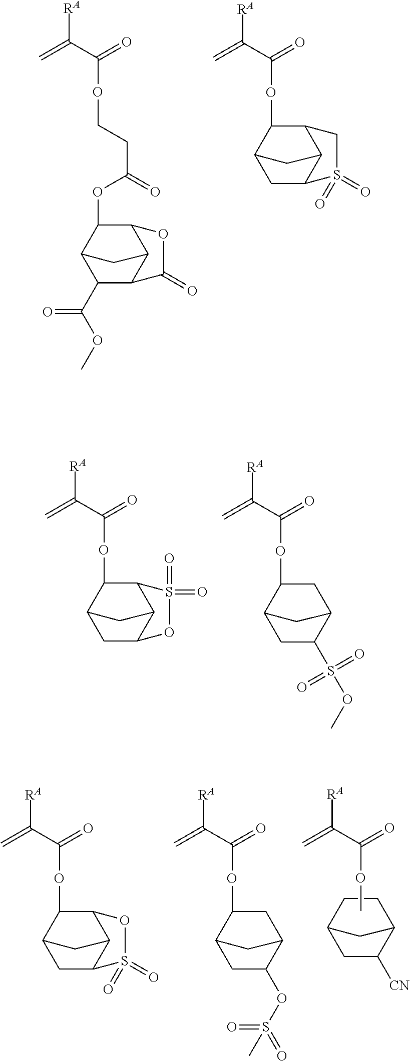

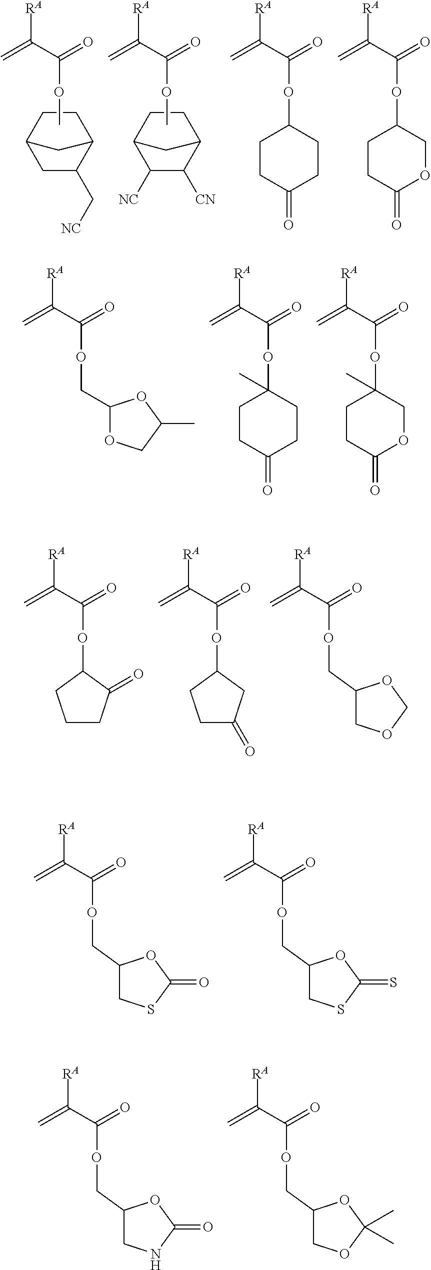

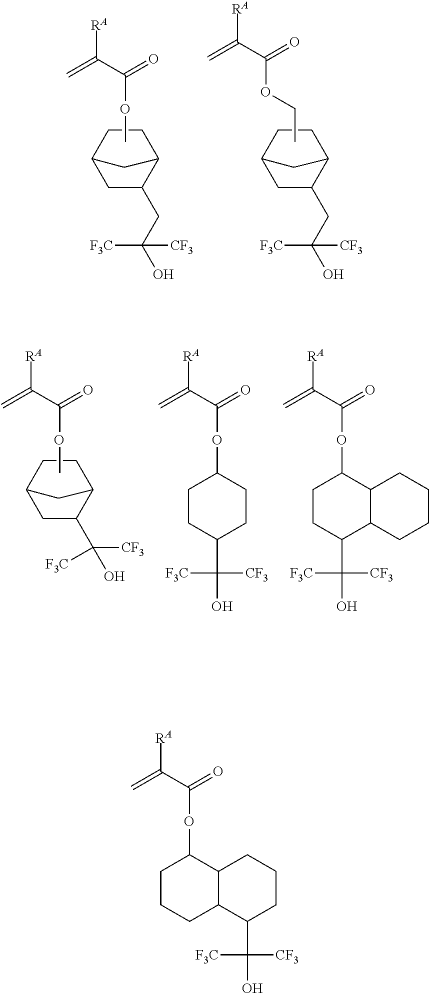

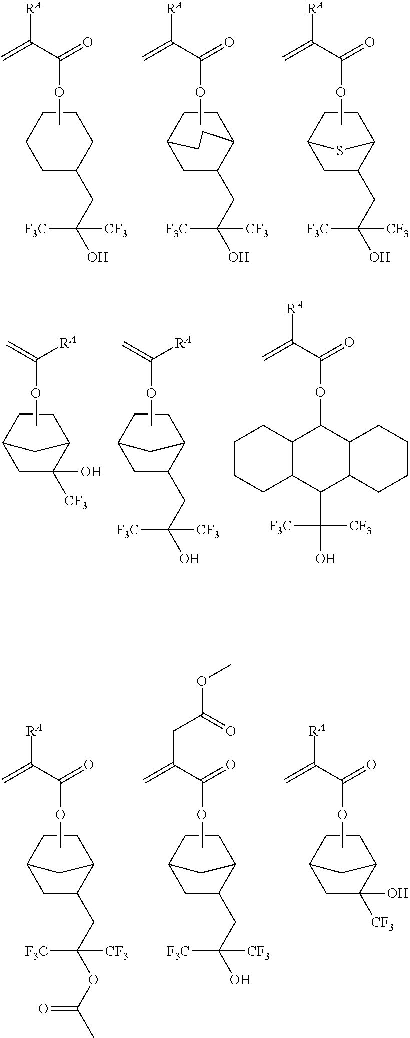

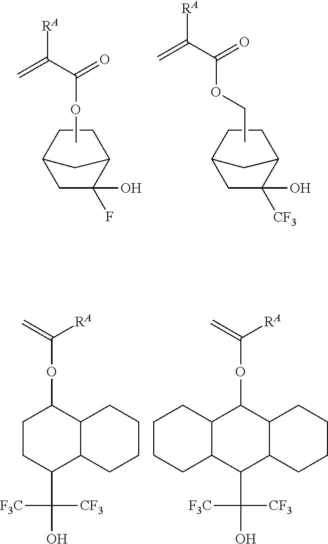

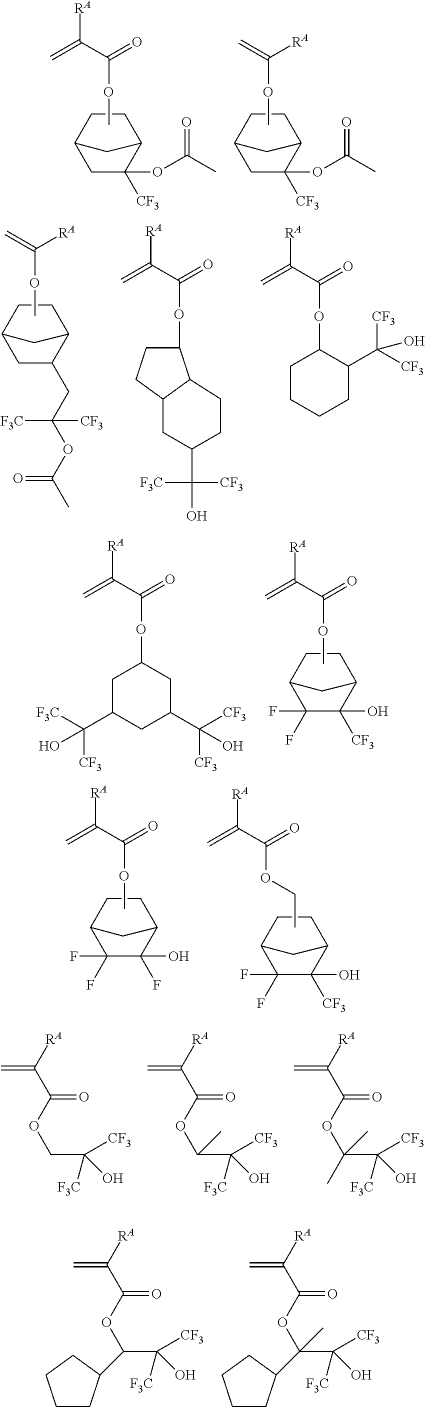

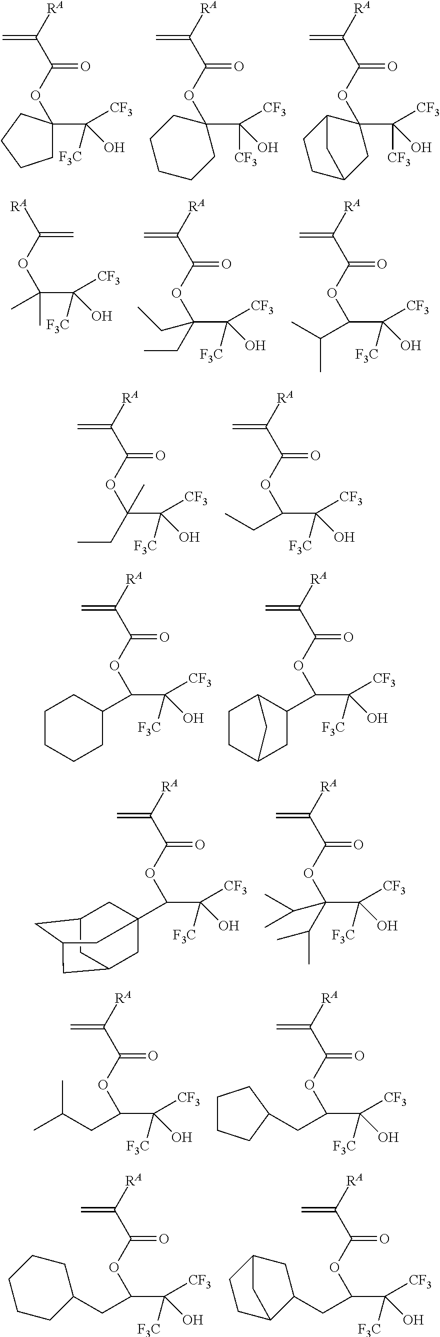

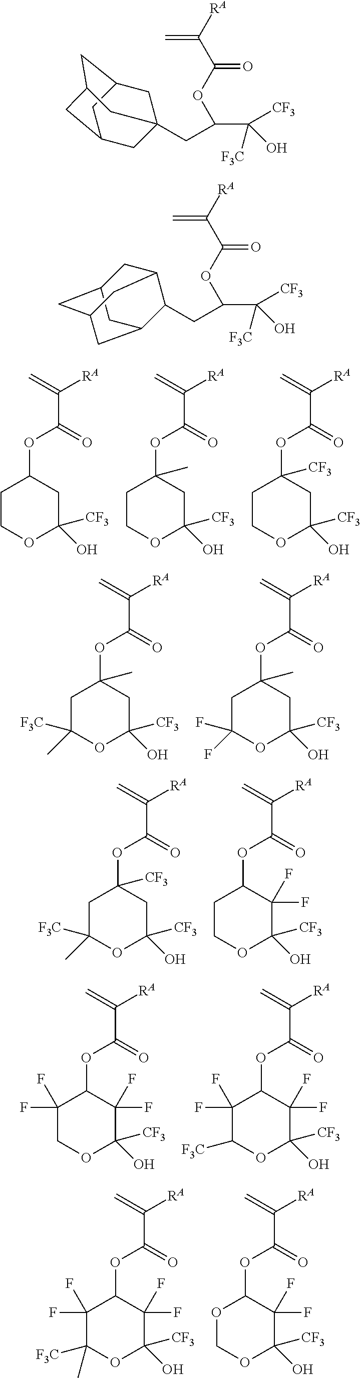

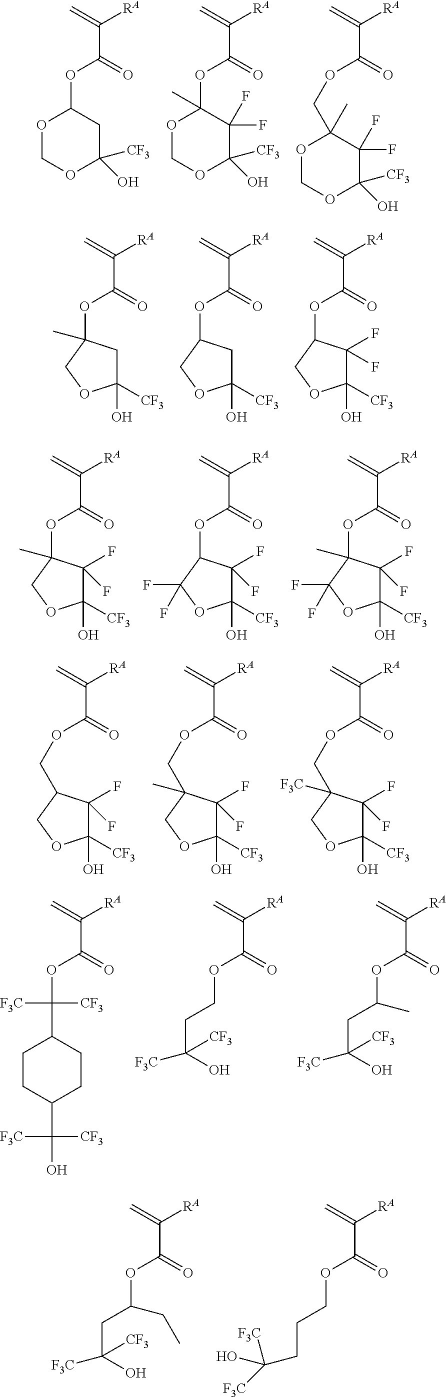

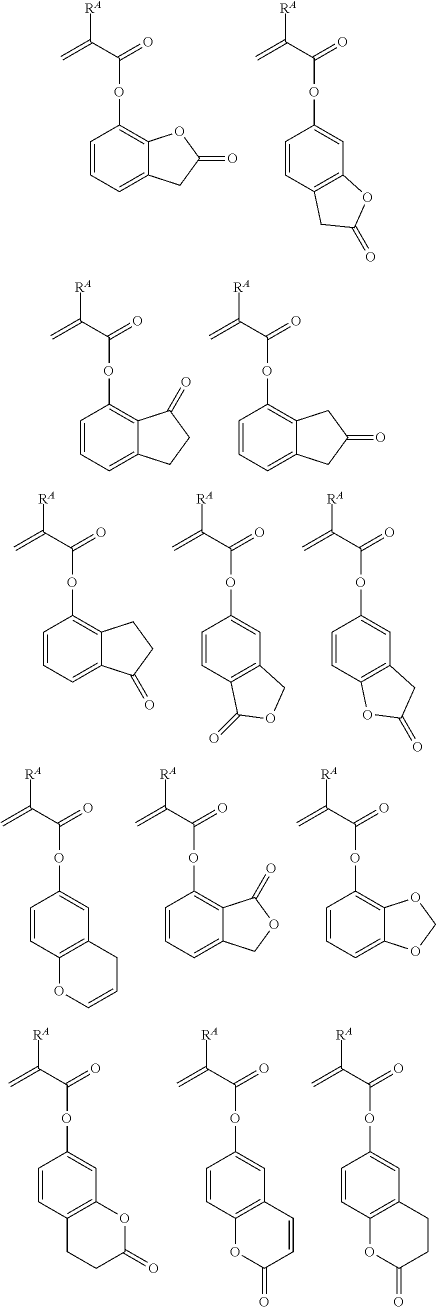

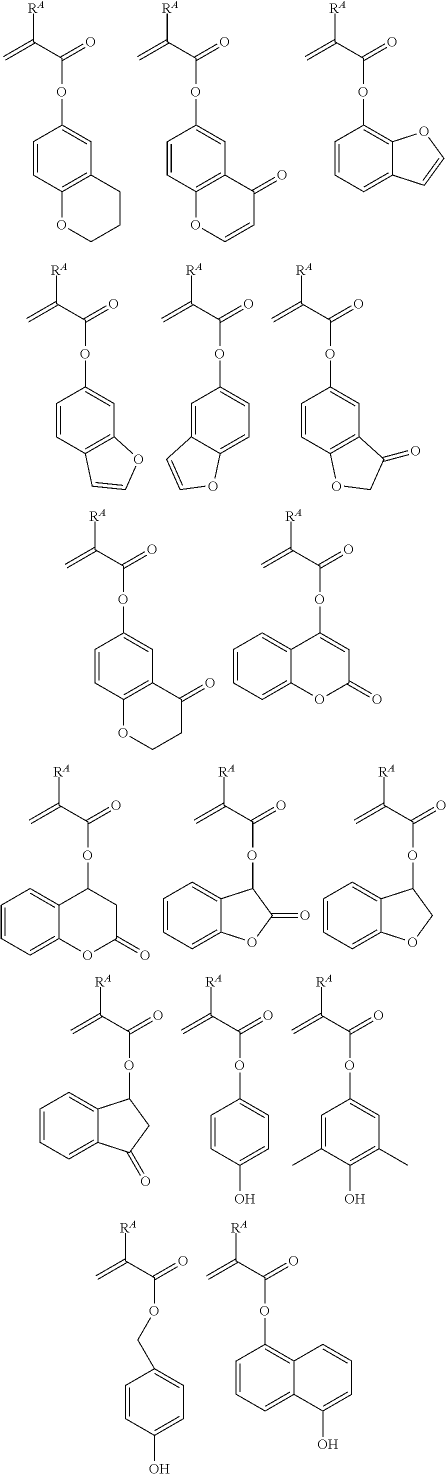

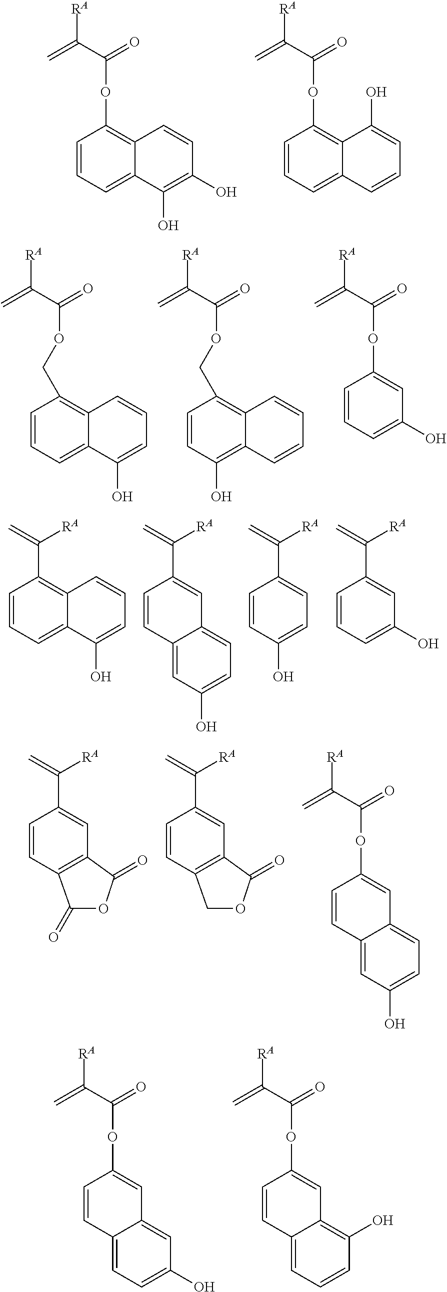

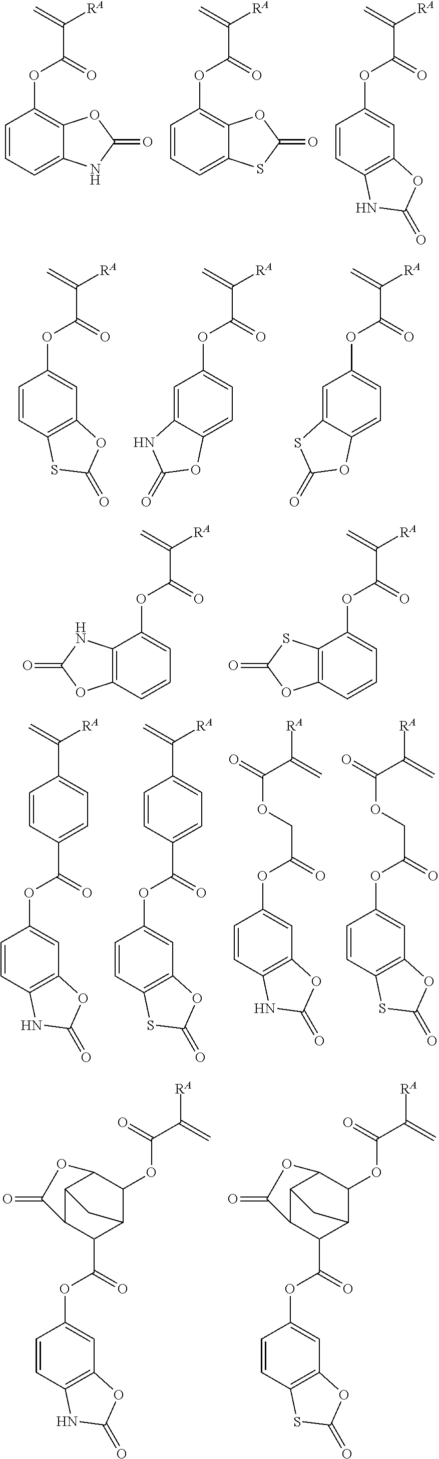

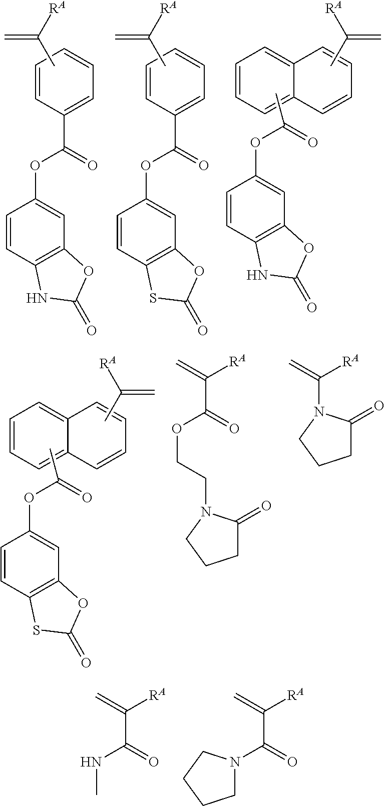

The base polymer may contain a repeating unit-d different from the above-described repeating units. Examples of the repeating unit-d include those derived from styrene, acenaphthylene, indene, coumarin, coumarone, etc.

In the base polymer, the content ratios of the repeating units-a1, -a2, -b1, -b2, -c, and -d are preferably 0≤a1<1.0, 0≤a2<1.0, 0.01≤a1+a2<1.0, 0≤b1≤0.9, 0≤b2≤0.9, 0.1≤b1+b2≤0.9, 0≤c≤0.9, and 0≤d≤0.5; more preferably 0≤a1≤0.6, 0≤a2<0.6, 0.02≤a1+a2≤0.6, 0≤b1≤0.8, 0≤b2≤0.8, 0.2≤b1+b2≤0.8, 0≤c≤0.8, and 0≤d≤0.4; further preferably 0≤a1≤0.5, 0≤a2<0.5, 0.03≤a1+a2≤0.5, 0≤b1≤0.7, 0≤b2≤0.7, 0.3≤b1+b2≤0.7, 0≤c≤0.7, and 0≤d≤0.3, given that a1+a2+b1+b2+c+d=1.0.

The base polymer may be synthesized, for example, by subjecting the monomers to give the repeating units described above to heat polymerization in an organic solvent to which a radical polymerization initiator has been added.

Examples of the organic solvent used in the polymerization include toluene, benzene, tetrahydrofuran (THF), diethyl ether, dioxane, etc. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, lauroyl peroxide, etc. The temperature during the polymerization is preferably 50 to 80° C. The reaction time is preferably 2 to 100 hours, more preferably 5 to 20 hours.

In the case where the monomer containing a hydroxy group is copolymerized, the process may include: substituting the hydroxy group with an acetal group susceptible to deprotection with acid, such as an ethoxy group, prior to the polymerization; and the deprotection performing with weak acid and water after the polymerization. Alternatively, the process may include: substituting the hydroxy group with an acetyl group, a formyl group, a pivaloyl group, or the like; and performing alkaline hydrolysis after the polymerization.

In a case where hydroxystyrene or hydroxyvinylnaphthalene is copolymerized, at first, acetoxystyrene or acetoxyvinylnaphthalene may be used in place of hydroxystyrene or hydroxyvinylnaphthalene; after the polymerization, the acetoxy group may be deprotected by the alkaline hydrolysis as described above to convert the acetoxystyrene or acetoxyvinylnaphthalene to hydroxystyrene or hydroxyvinylnaphthalene.

In the alkaline hydrolysis, a base such as ammonia water or triethylamine is usable. The reaction temperature is preferably −20 to 100° C., more preferably 0 to 60° C. The reaction time is preferably 0.2 to 100 hours, more preferably 0.5 to 20 hours.

The base polymer has a polystyrene-based weight-average molecular weight (Mw) of preferably 1,000 to 500,000, more preferably 2,000 to 30,000, which is determined by gel permeation chromatography (GPC) using THF as a solvent. When the Mw is 1,000 or more, the resist material has excellent heat resistance. When the Mw is 500,000 or less, the alkali solubility is not decreased, and a footing phenomenon after pattern formation is prevented.

Further, when the base polymer has a molecular weight distribution (Mw/Mn) of 1.0 to 2.0, there is no low-molecular-weight or high-molecular-weight polymer. This can eliminate possibilities that foreign matters are observed on the pattern after the exposure, and that the pattern profile is degraded. The finer the pattern rule, the stronger the influences of Mw and Mw/Mn. Hence, in order to obtain a resist material suitably used for finer pattern dimension, the base polymer preferably has a narrow dispersity Mw/Mn of 1.0 to 2.0, particularly preferably 1.0 to 1.5.

The base polymer may contain two or more kinds of polymers that differ in composition ratio, Mw, and Mw/Mn. Alternatively, a polymer containing the repeating unit-a1 and/or -a2 may be blended with a polymer not containing the repeating unit-a1 or a2 but containing the repeating unit-b1 and/or -b2.

The quencher, being a sulfonium salt containing at least two fluorine atoms in the anion moiety of a carboxylate ion, a sulfonamide ion, an alkoxide ion (fluoroalcohol), or a sulfonate ion having no fluorine at a position and a cation moiety of a sulfonium ion is preferably represented by one of the following general formulae (1)-1 to (1)-4.

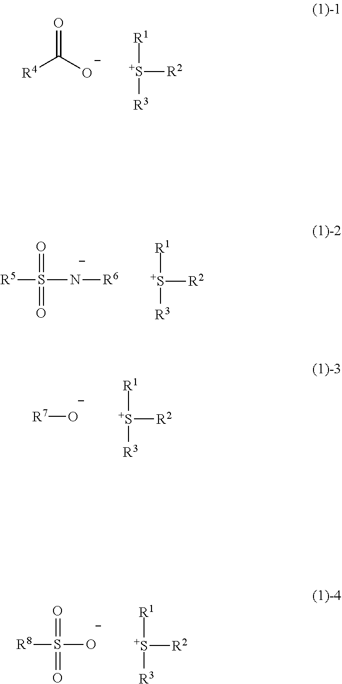

In the formulae, R⁴ and R⁵ each represent a fluorine atom or a hydrocarbyl group having 1 to 40 carbon atoms, and optionally have an oxygen atom, a sulfur atom, a nitrogen atom, or a halogen atom. R⁶ represents a hydrogen atom or a hydrocarbyl group having 1 to 20 carbon atoms, and these optionally have an oxygen atom, a sulfur atom, a nitrogen atom, or a halogen atom. R⁷ represents a linear, branched, or cyclic alkyl group or aryl group having 1 to 8 carbon atoms, and has at least two fluorine atoms. R⁷ optionally has a nitro group. R⁸ represents a linear, branched, or cyclic alkyl group or aryl group having 1 to 12 carbon atoms, optionally having an amino group, an ether group, or an ester group, and optionally substituted with a halogen atom, a hydroxy group, a carboxy group, an alkoxy group, an acyl group, or an acyloxy group. No fluorine atom is contained at a position of a sulfo group. R¹ to R³ are the same as above.

The hydrocarbyl group of R⁴ and R⁵ having 1 to 40 carbon atoms may be an aryl group having 6 to 10 carbon atoms, and the hydrocarbyl group of R⁶ having 1 to 20 carbon atoms may be an aryl group having 6 to 10 carbon atoms.

The number of fluorine atoms in R¹ to R³ is preferably one or more, more preferably two or more, and further preferably three or more. A fluorine atom does not need to be contained in R⁴. R⁵ preferably has one or more fluorine atoms, more preferably two or more, and further preferably three or more. R⁷ preferably has three or more fluorine atoms, more preferably four or more, and further preferably five or more. R⁸ preferably does not contain a fluorine atom.

Specific examples of the carboxylate anion shown by (1)-1 include the following.

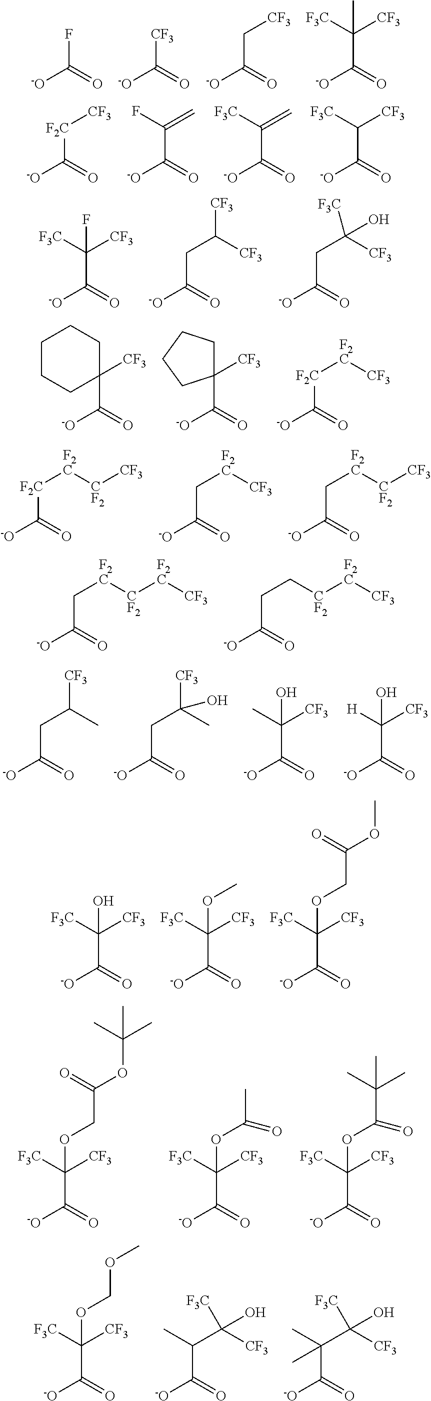

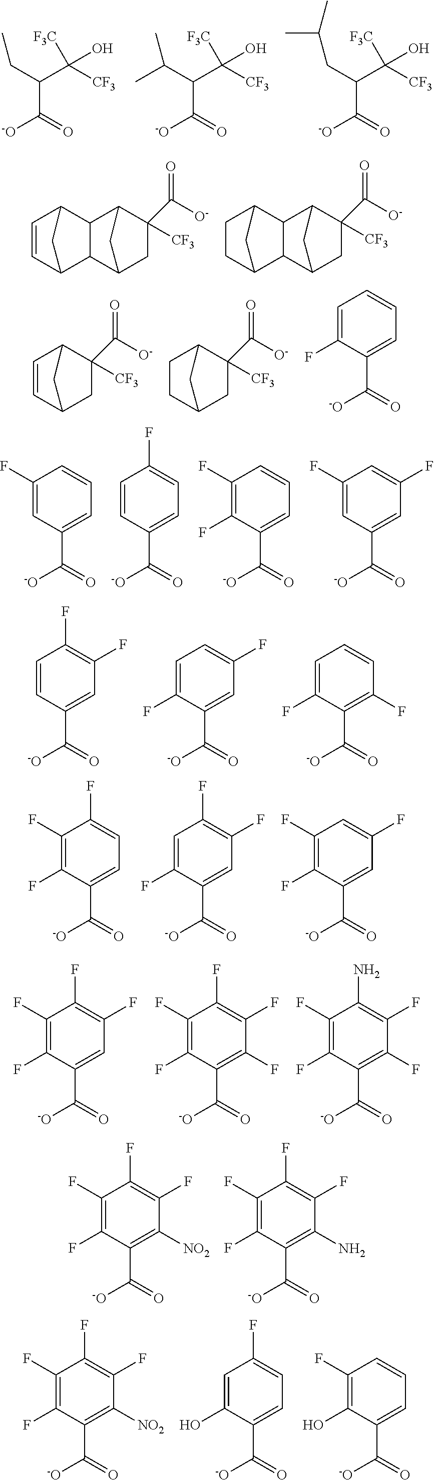

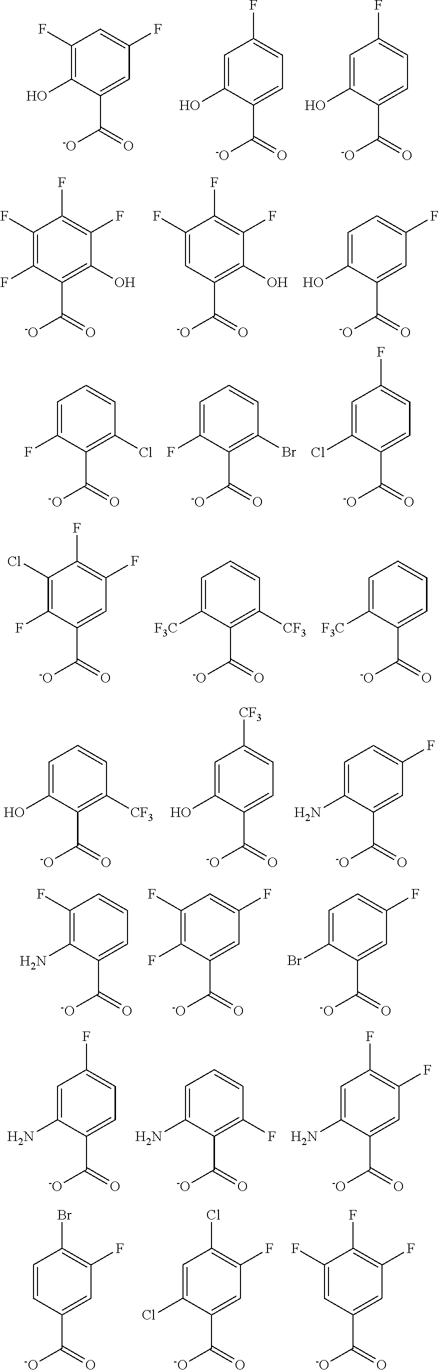

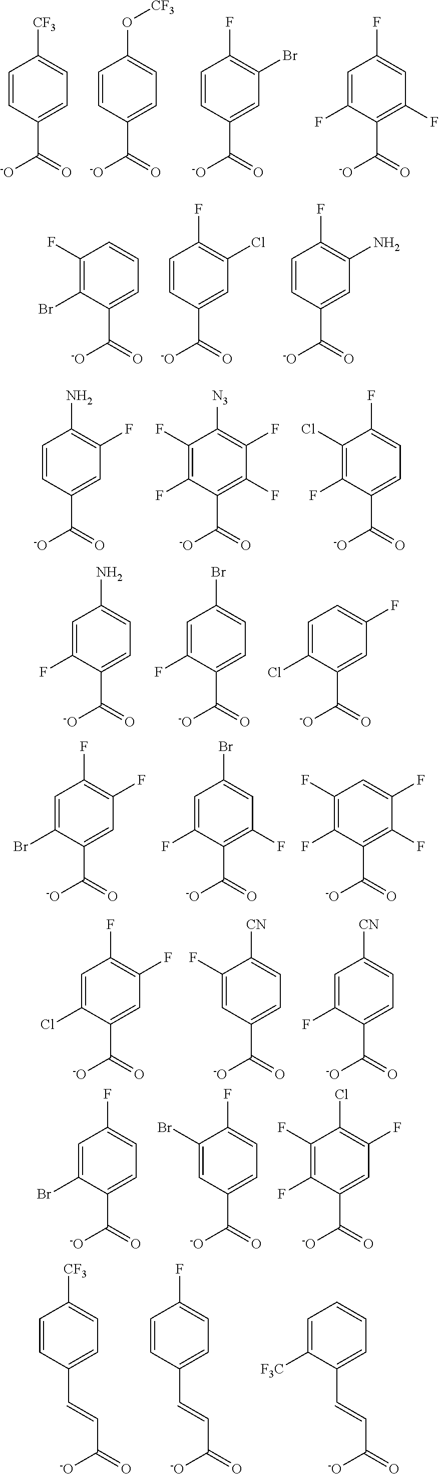

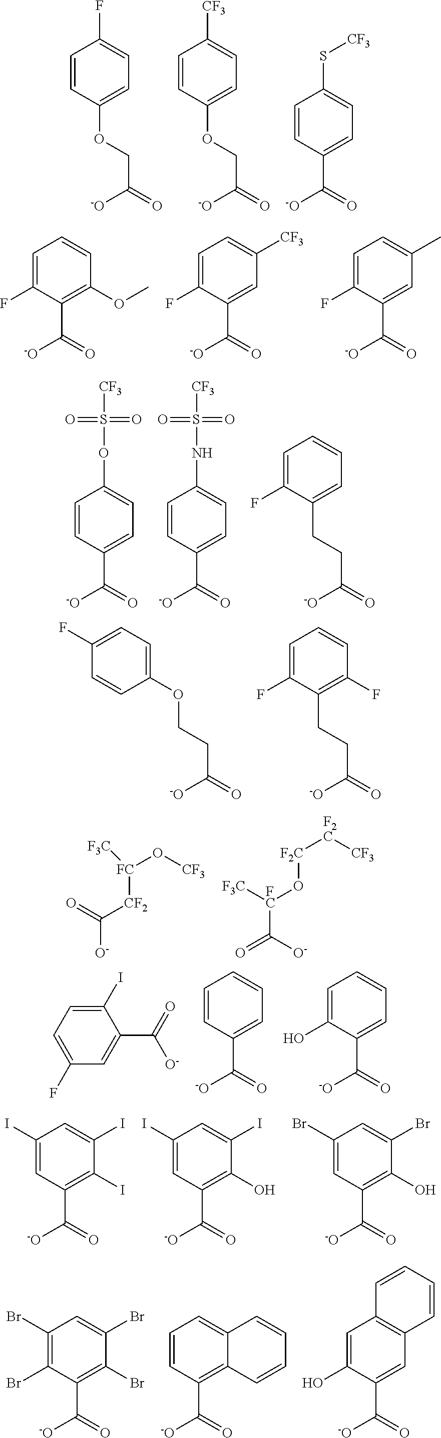

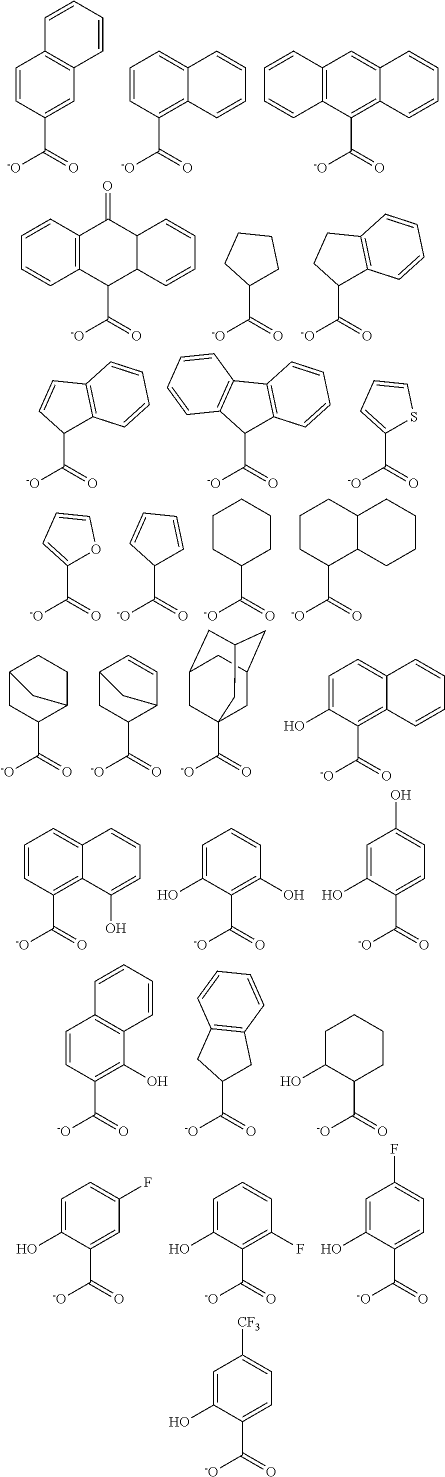

Examples of the sulfonamide anion shown in the general formula (1)-2 include the following, but are not limited thereto.

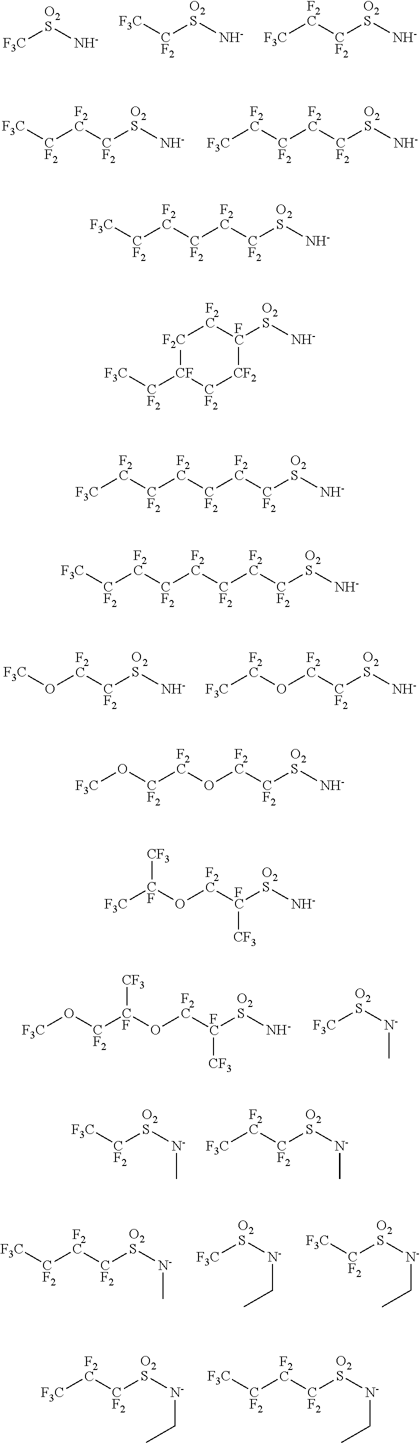

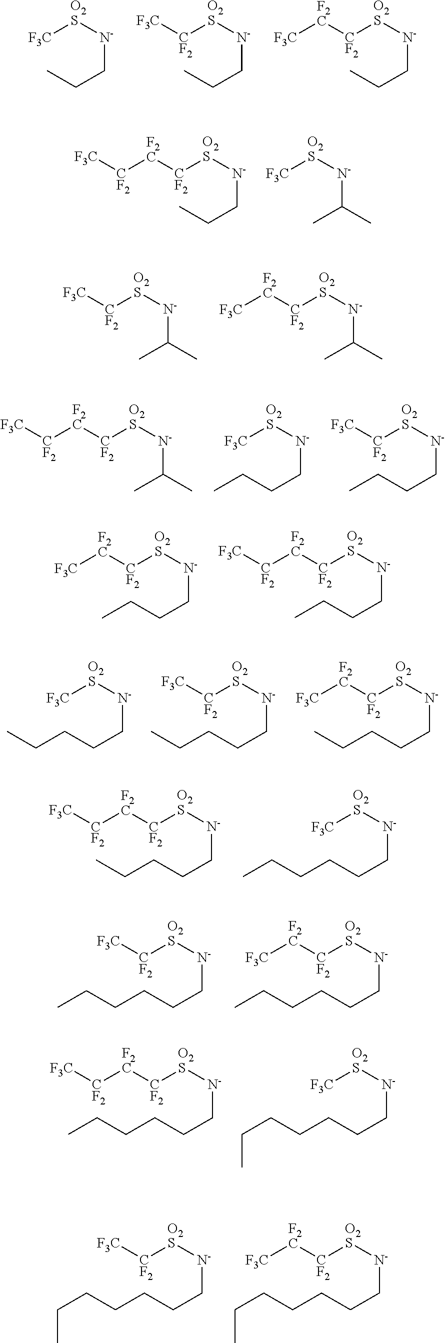

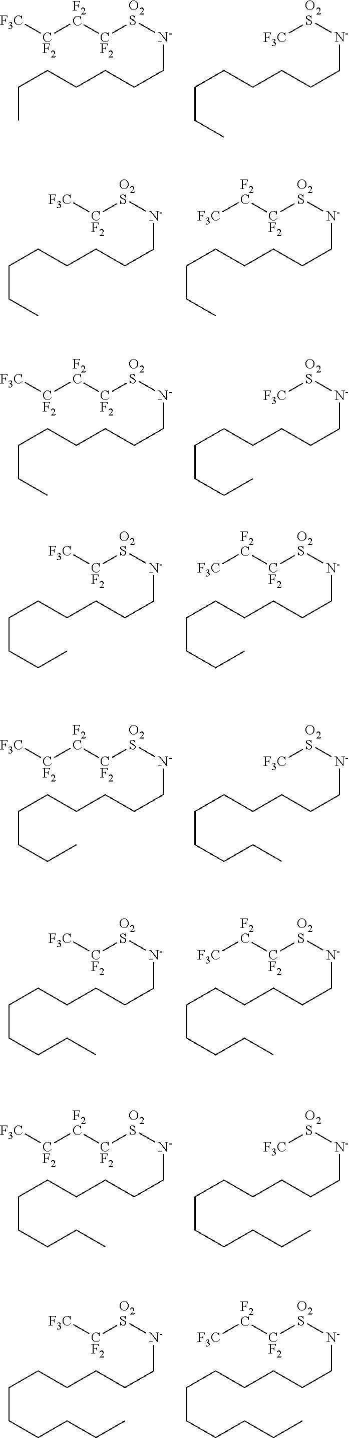

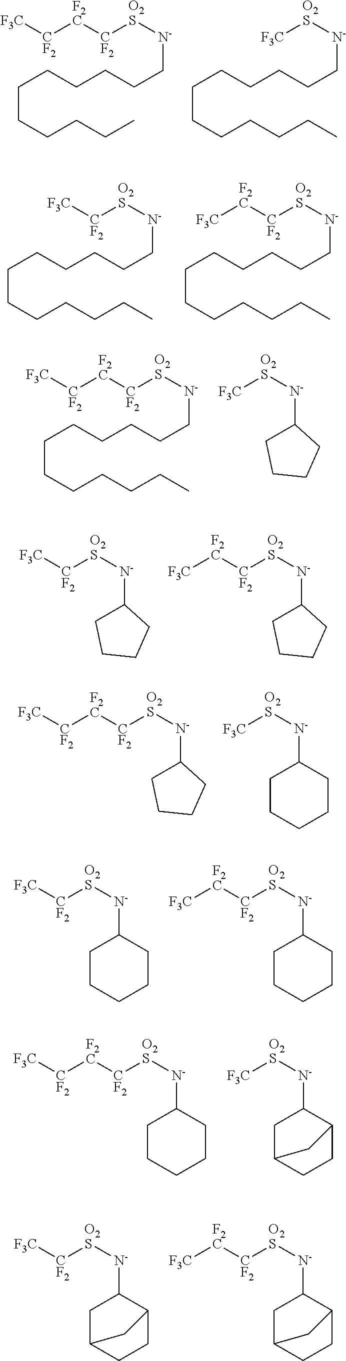

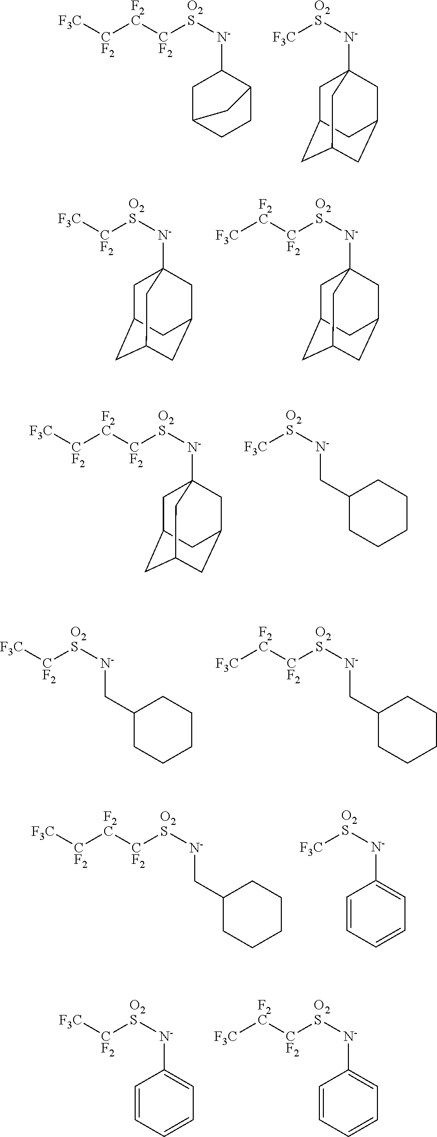

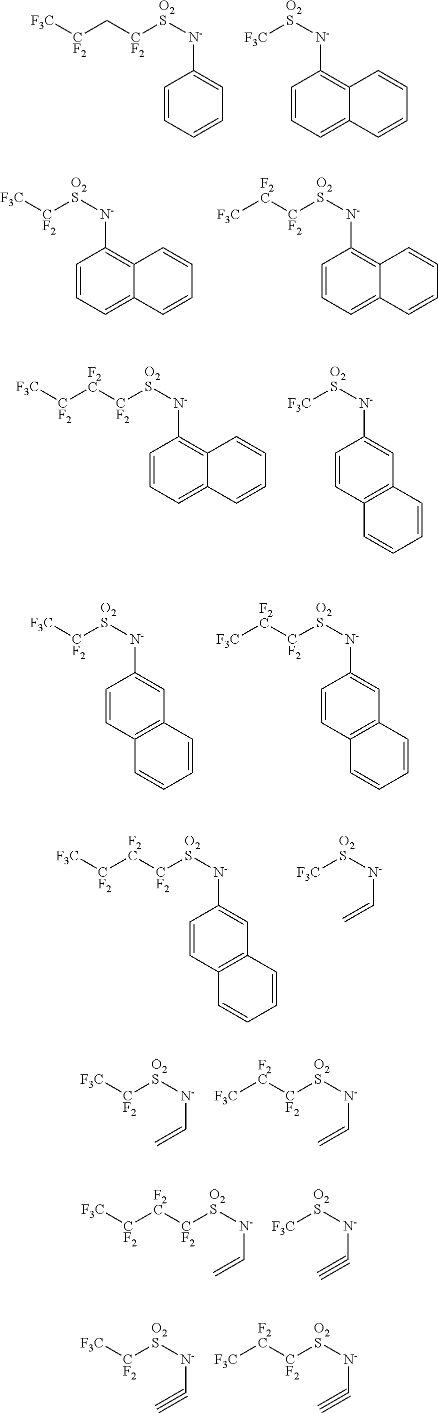

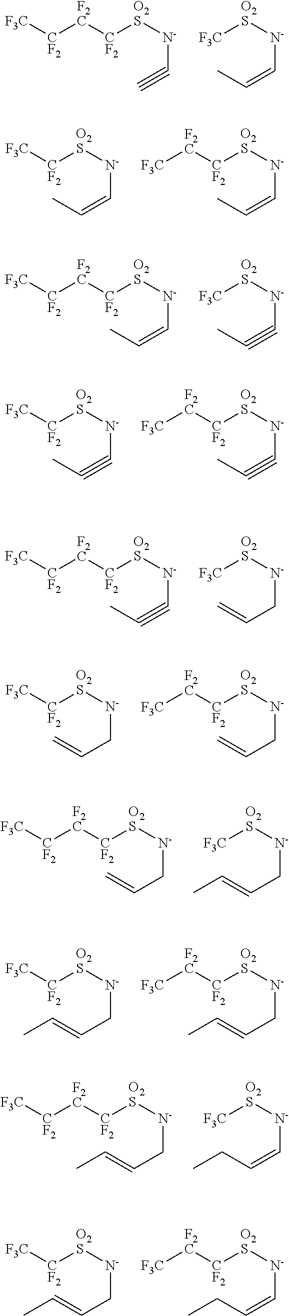

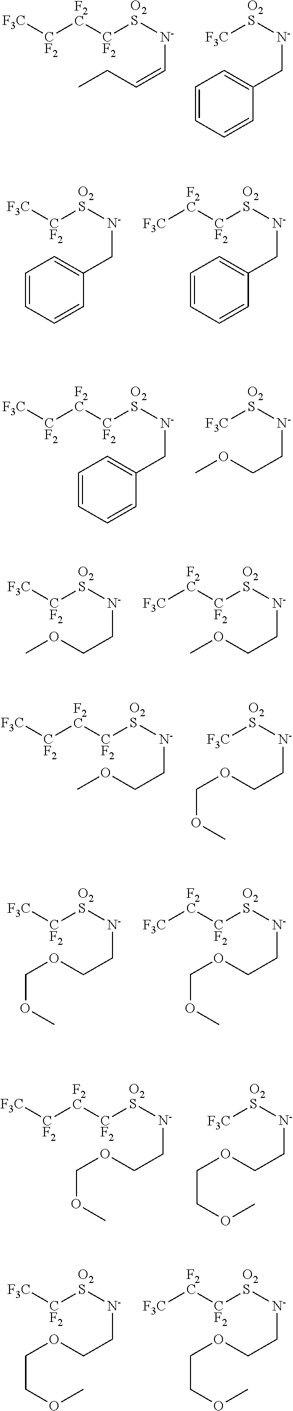

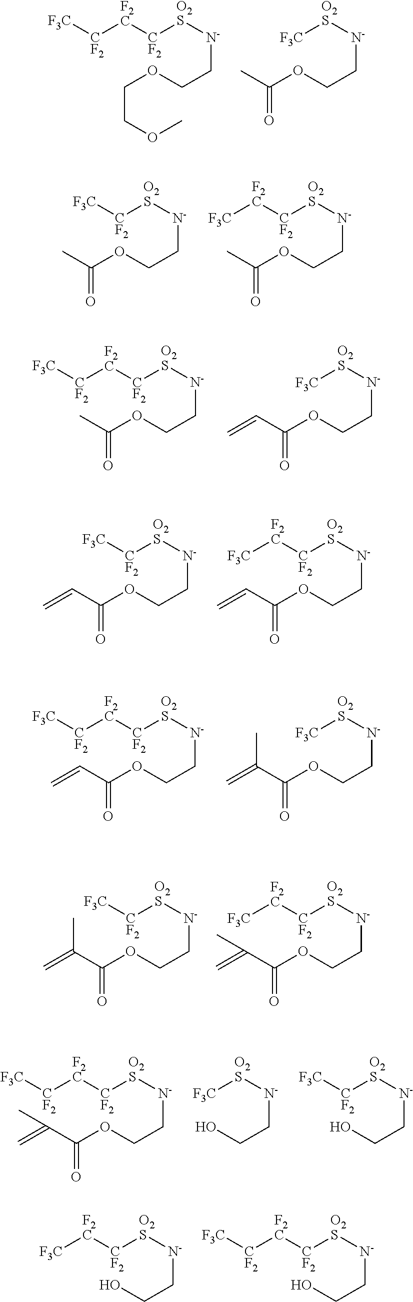

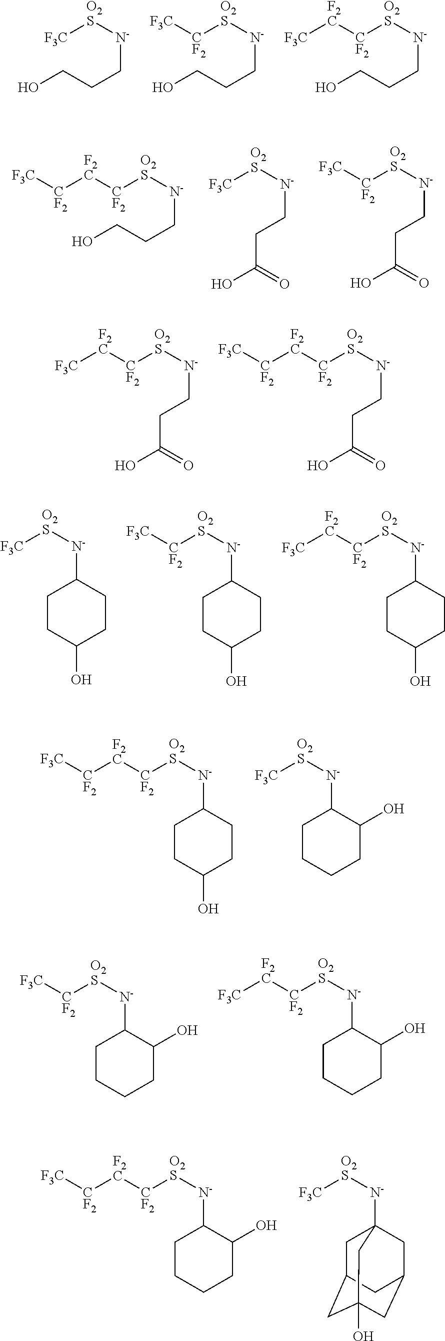

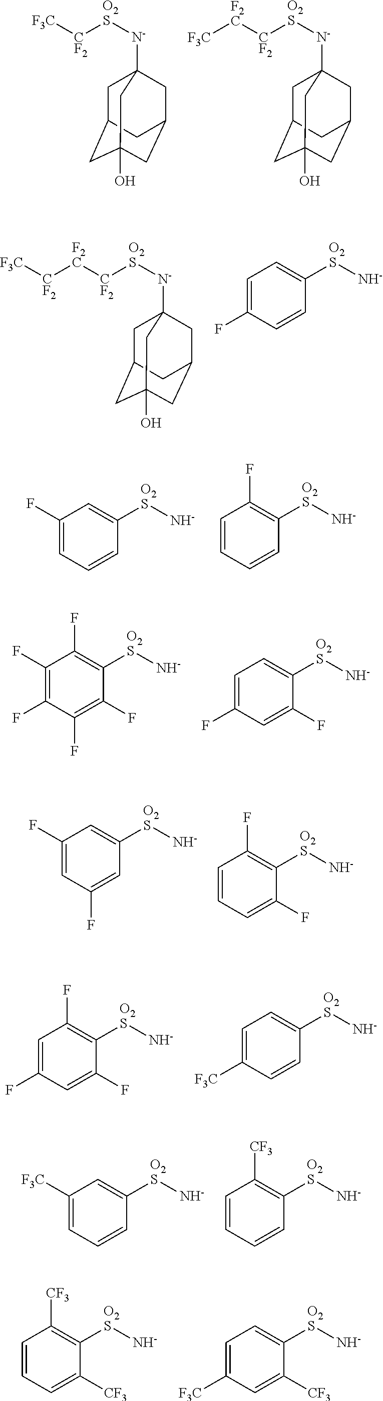

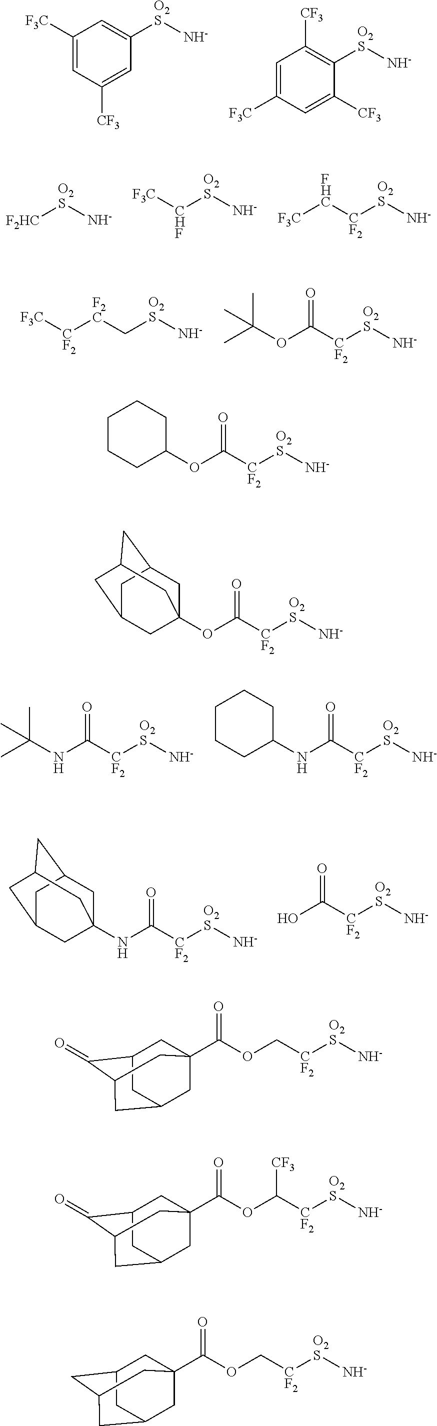

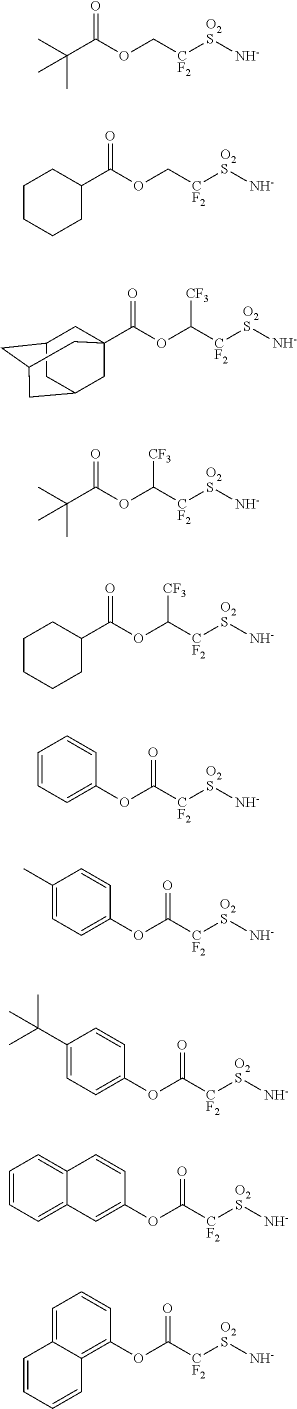

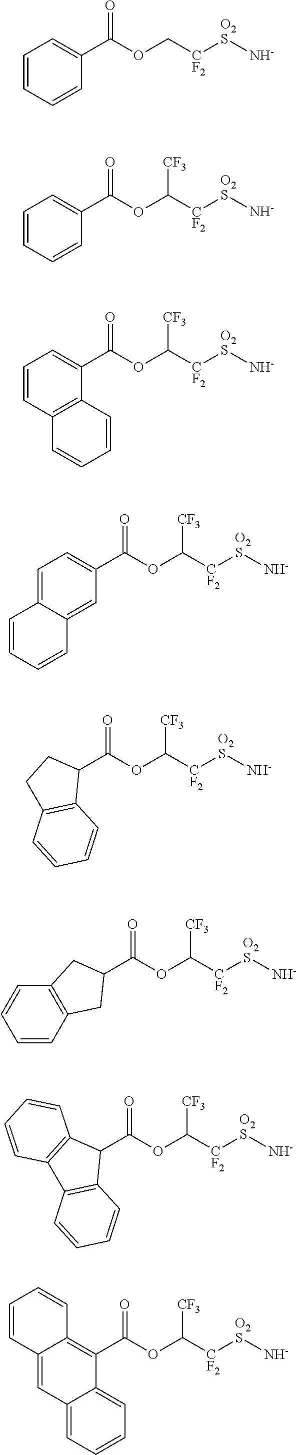

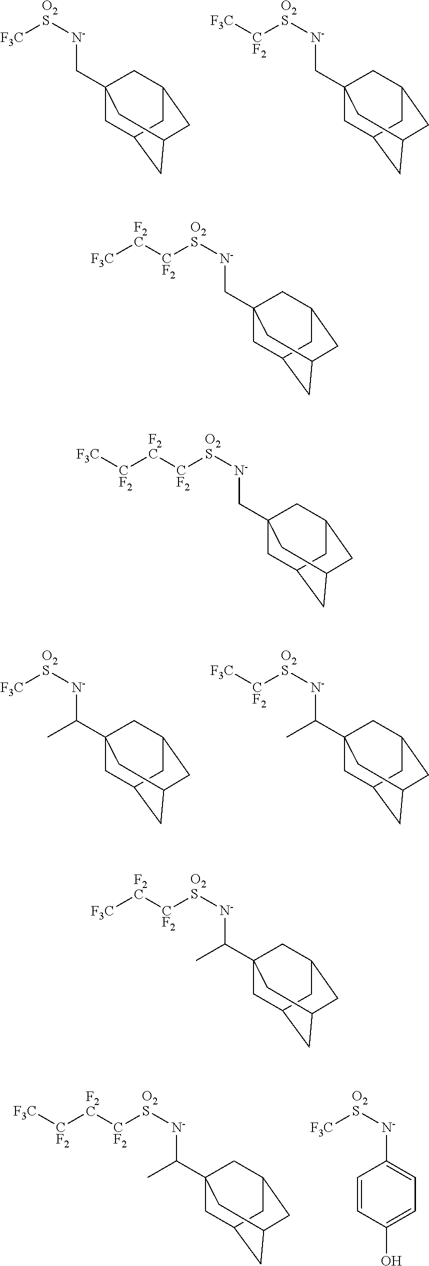

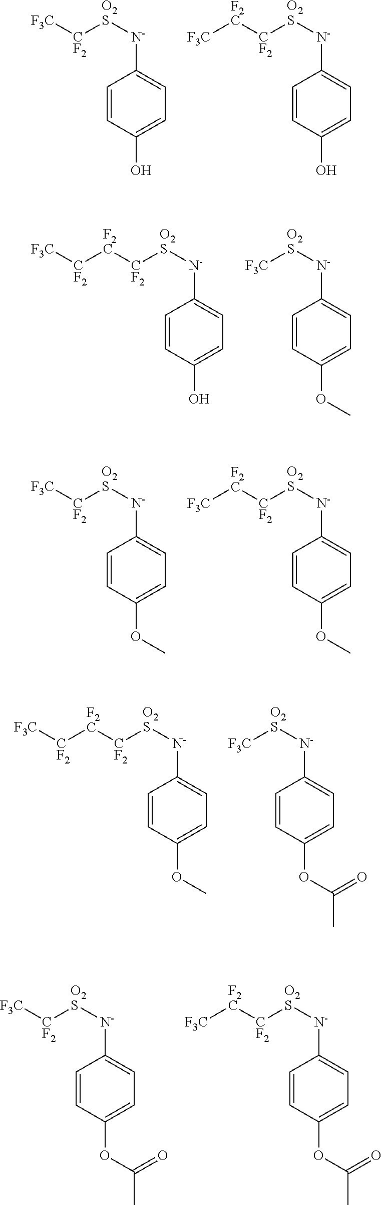

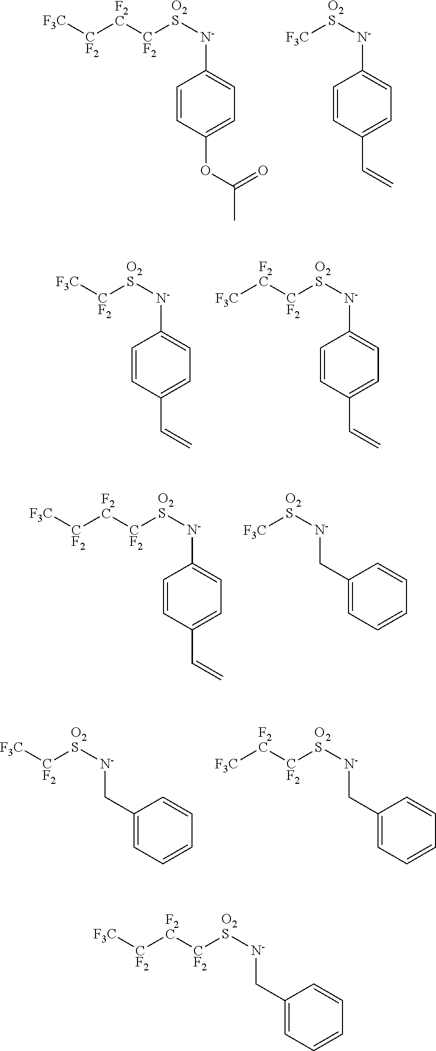

Examples of the alkoxide ion shown in the general formula (1)-3 include the following, but are not limited thereto.

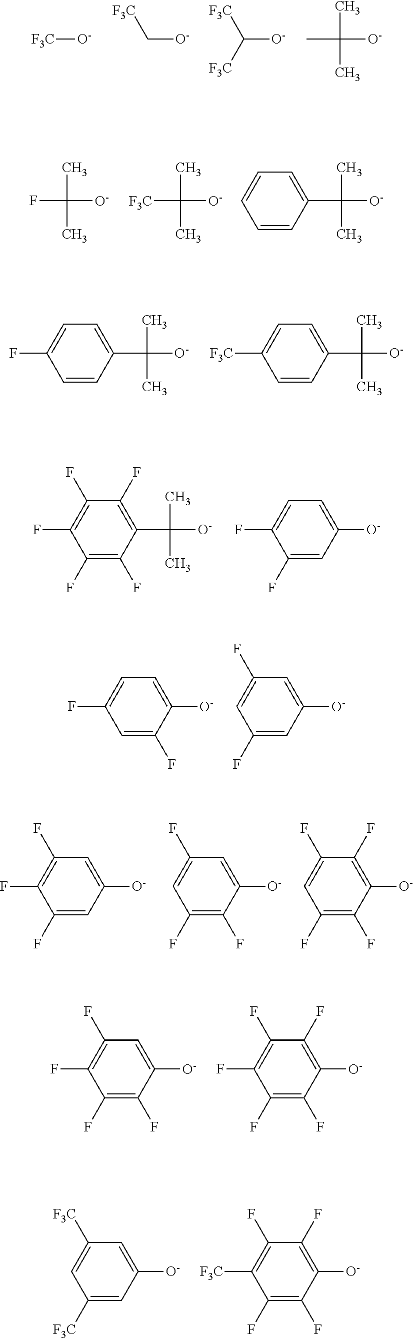

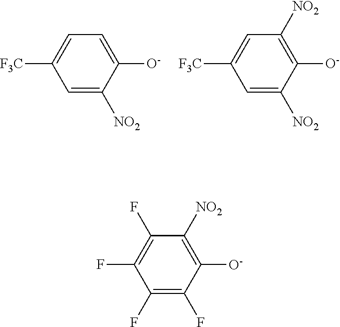

Examples of the sulfonate ion shown in the general formula (1)-4 include the following, but are not limited thereto.

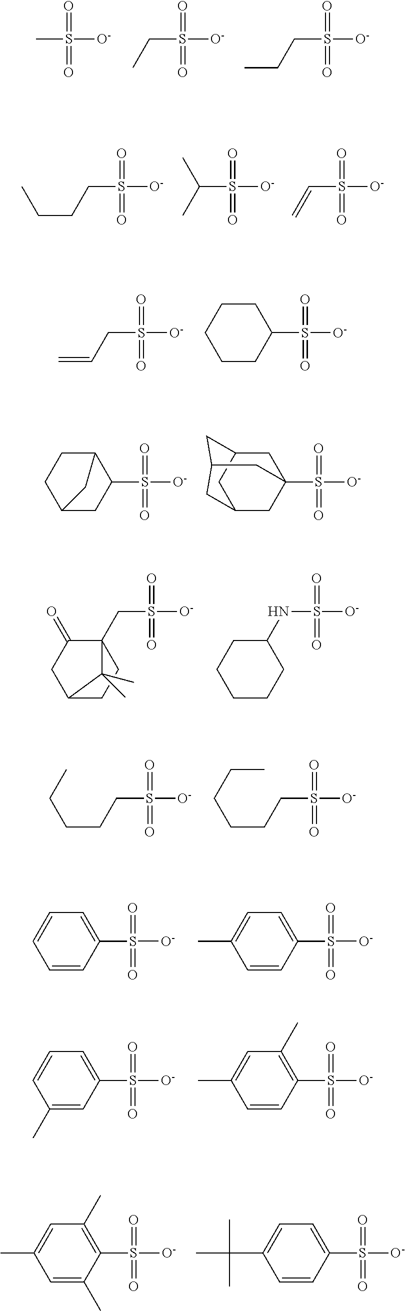

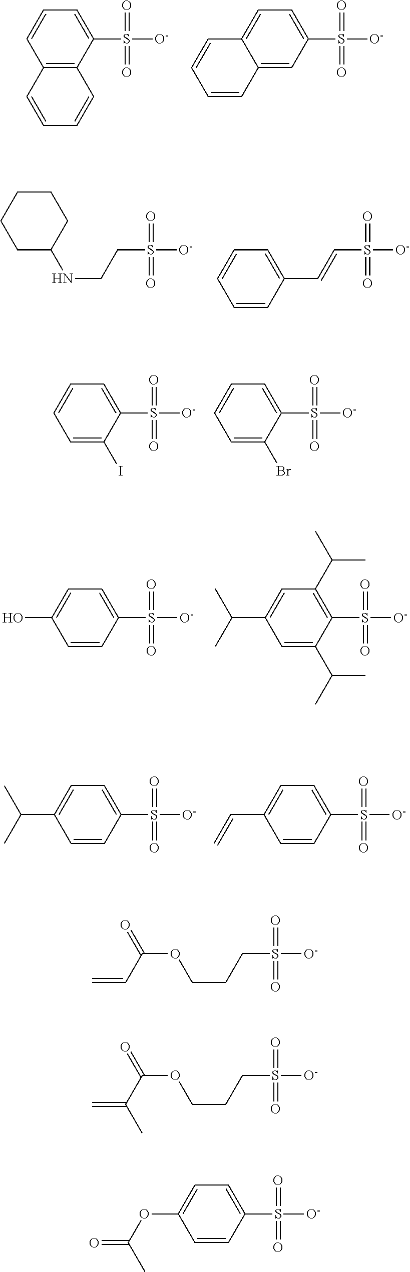

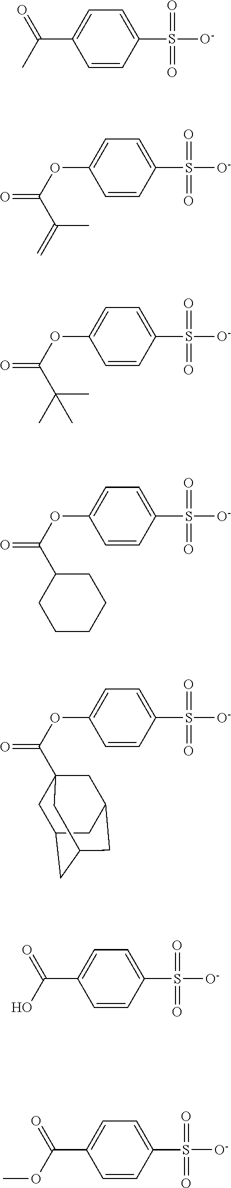

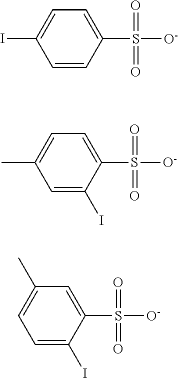

A fluorine atom is not essential to the anions shown in the general formulae (1)-1 and (1)-2, but a fluorine atom is preferably contained from the viewpoint of preventing coherence. Specifically, R⁴ and R⁵ in the general formulae (1)-1 and (1)-2 are each a hydrocarbyl group having 1 to 40 carbon atoms, may have an oxygen atom, a sulfur atom, a nitrogen atom, or a halogen atom other than fluorine, and preferably has at least one fluorine atom.

At least one fluorine atom is contained in the cation moiety of the sulfonium salt of the fluorosulfonic acid ion bonded to the polymer main chain of the general formulae (a1) and (a2), and preferably, the sulfonium salt of the carboxylate ion, the sulfonamide ion, the alkoxide ion, and the sulfonate ion having no fluorine atom at α position shown in the general formulae (1)-1 to (1)-4 each having a fluorine atom. Specific examples include the following.

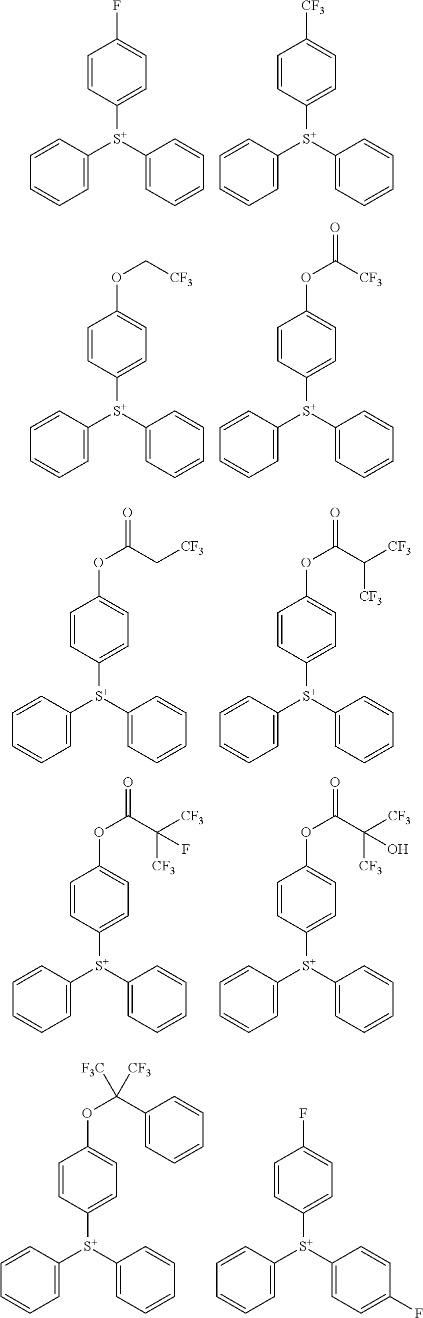

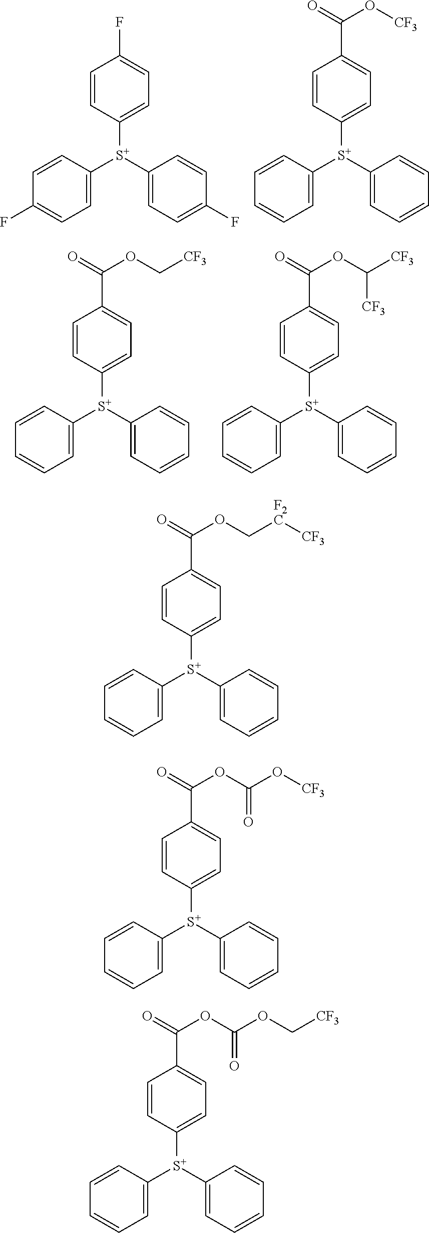

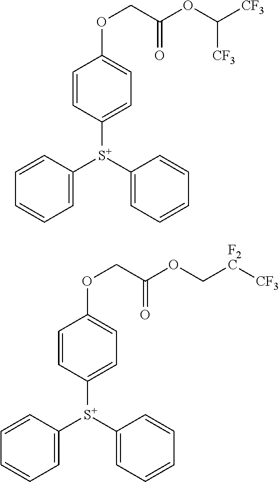

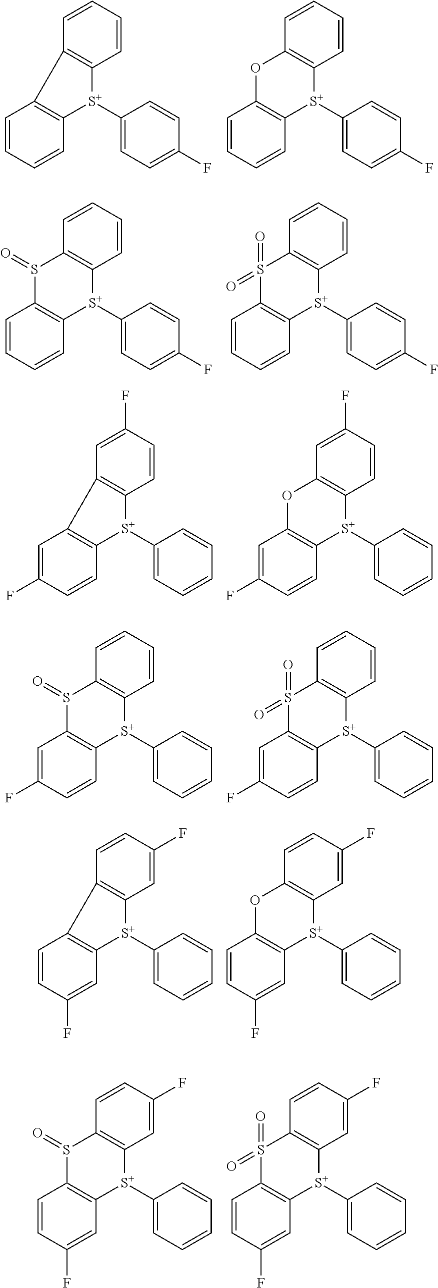

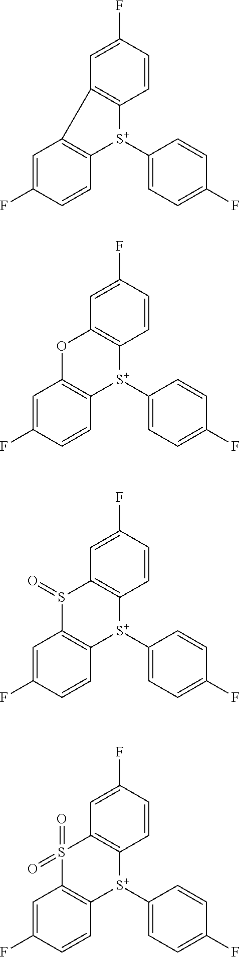

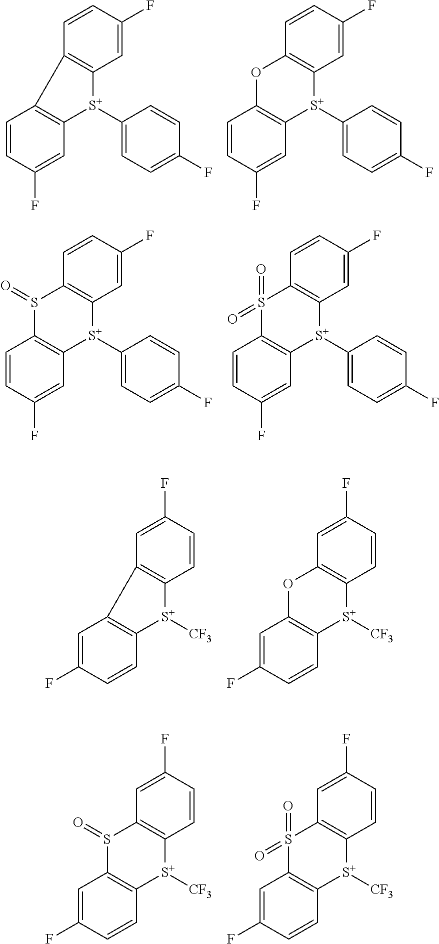

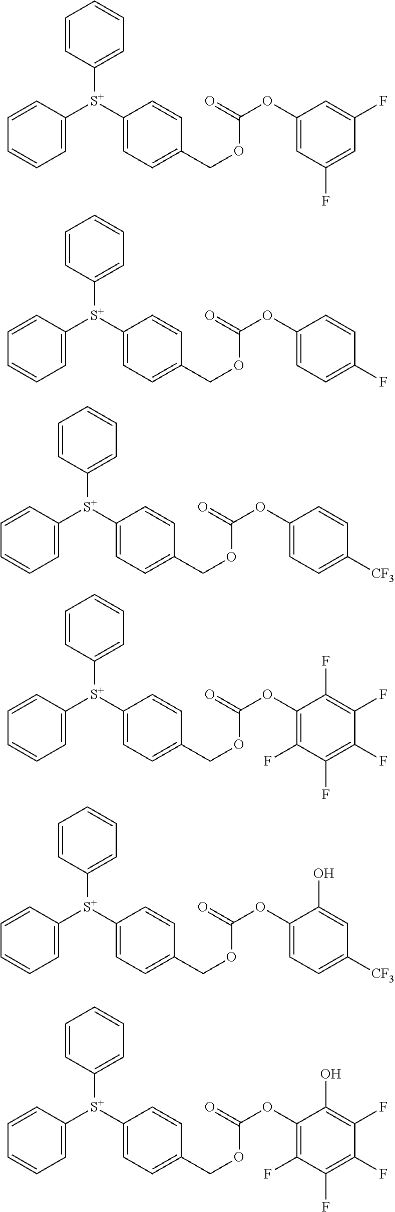

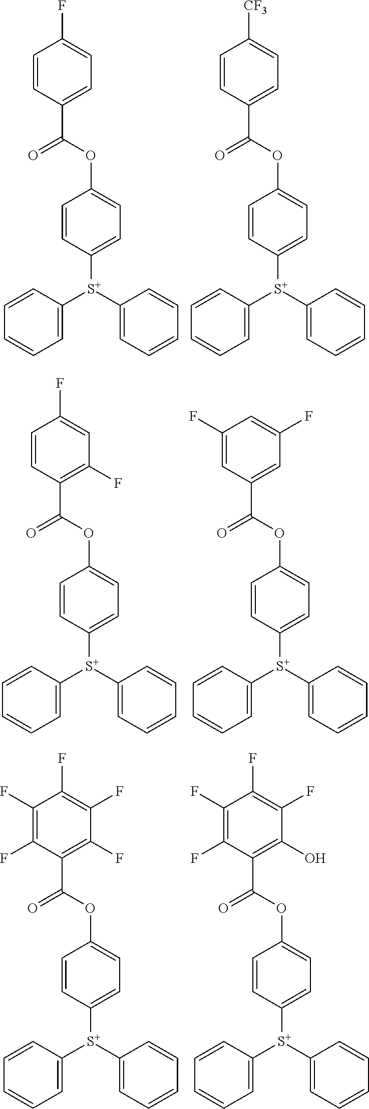

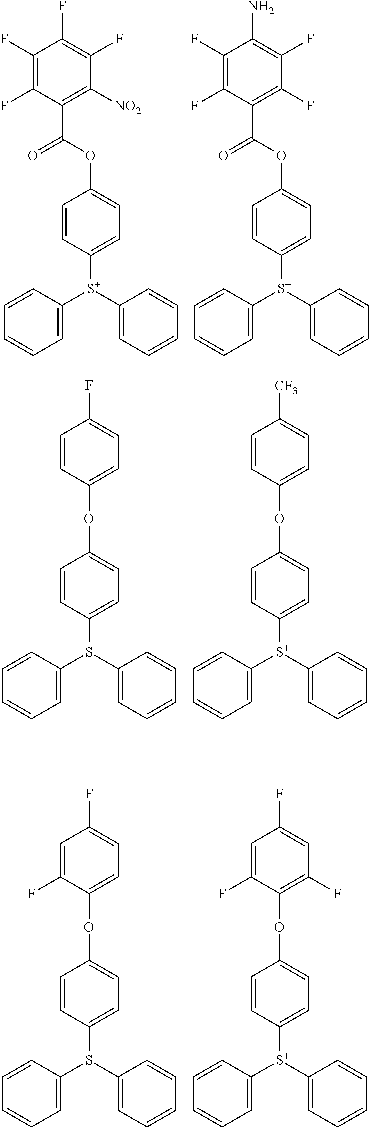

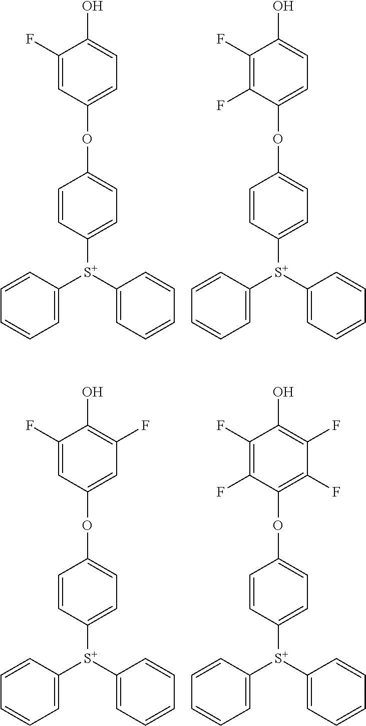

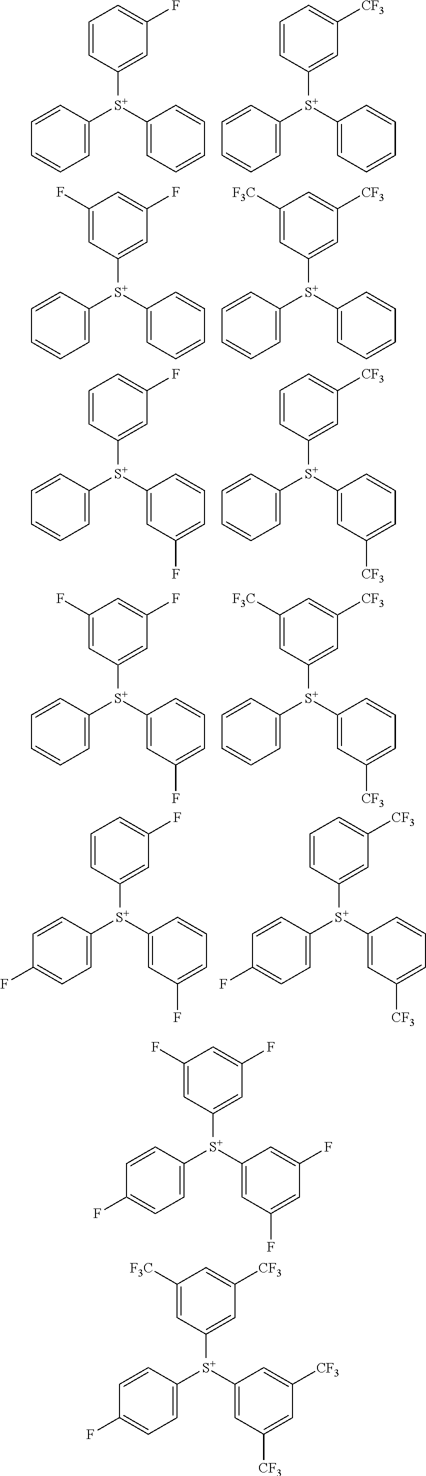

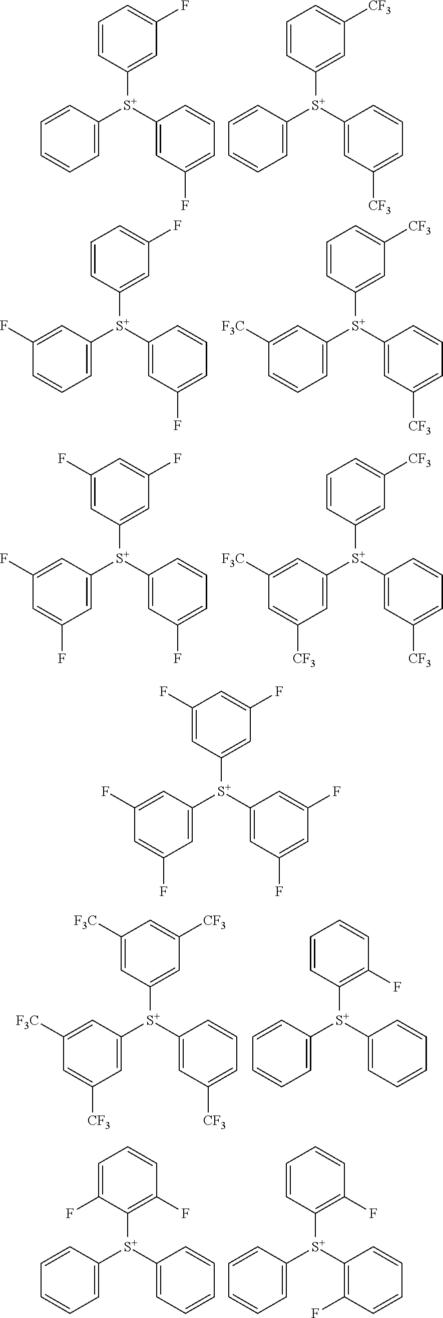

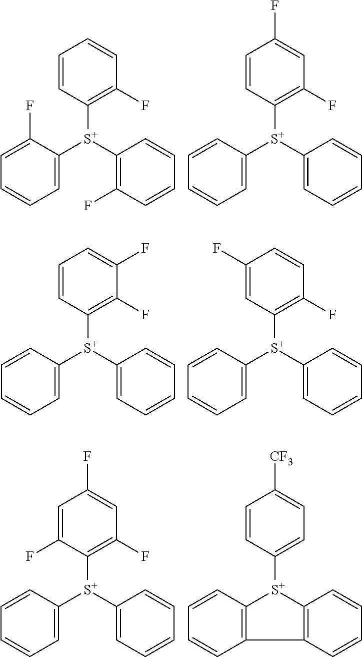

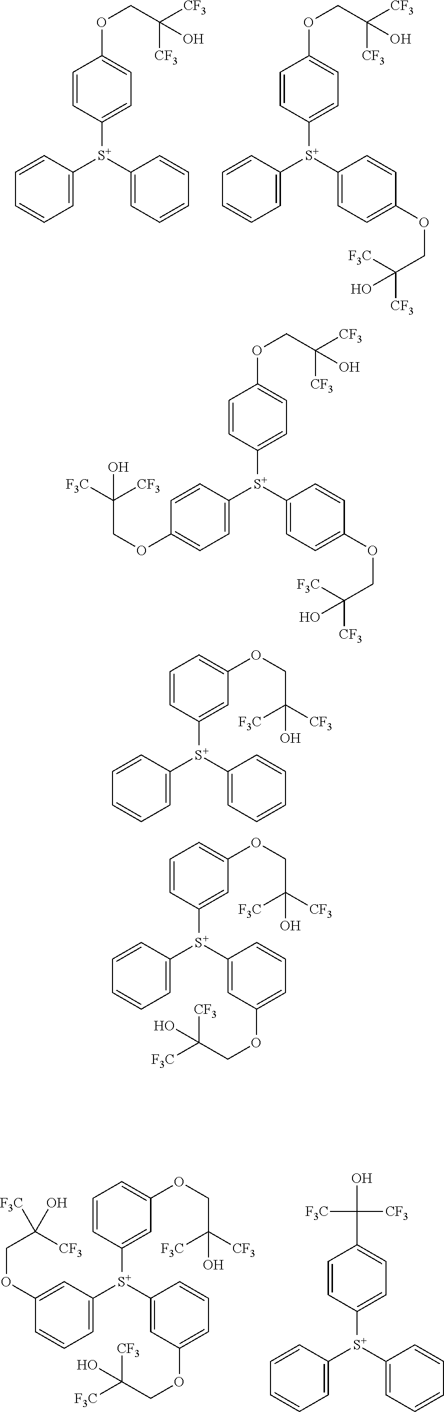

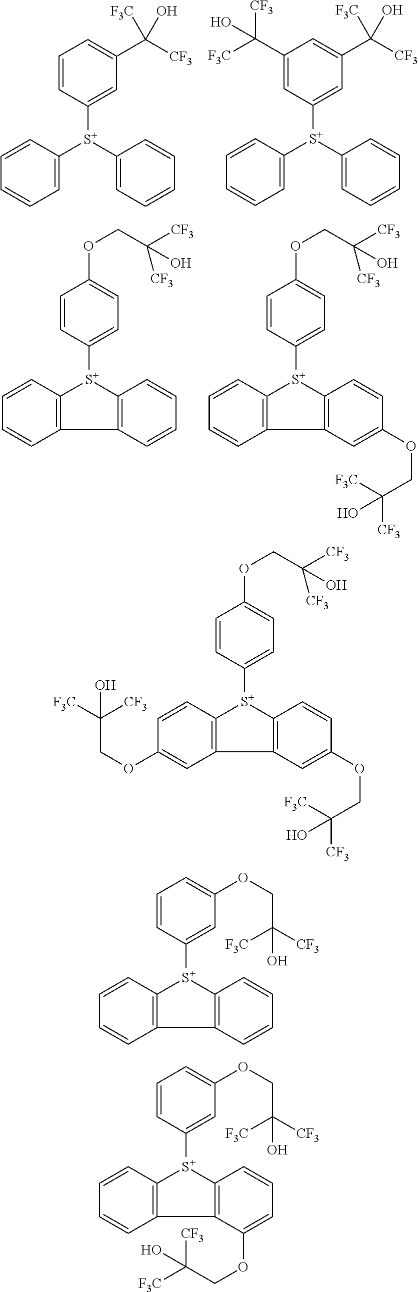

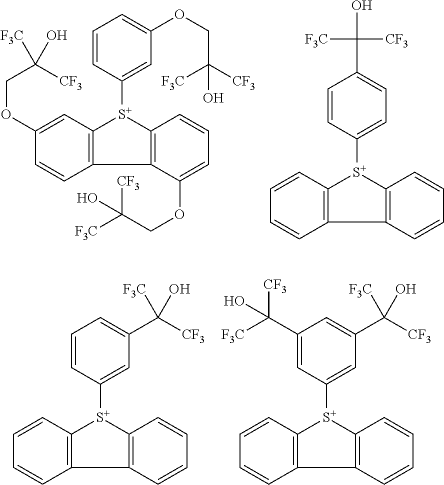

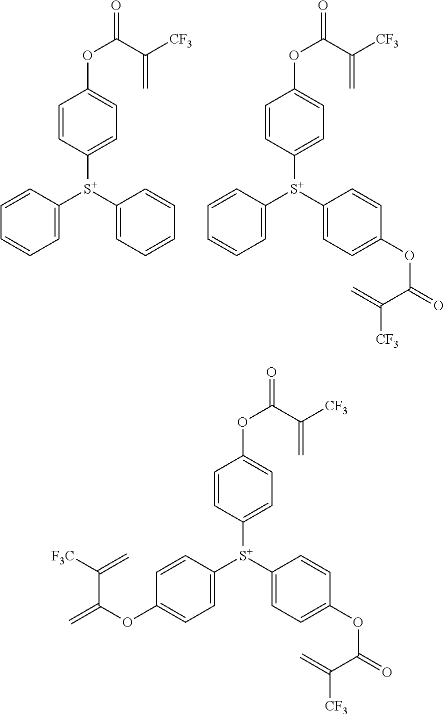

### [Additive-Type Acid Generator]

The inventive positive resist material may further contain an acid generator that generates a strong acid (hereinafter also referred to as additive-type acid generator). Here, the term strong acid means a compound that has sufficient acidity to cause deprotection reaction of the acid labile group of the base polymer. Examples of the acid generator include compounds that generate acids in response to actinic light or radiation (photo-acid generator). The photo-acid generator is not particularly limited, as long as the compound generates an acid upon high-energy beam irradiation. Preferably, the photo-acid generator generates a sulfonic acid, imide acid, or methide acid. Suitable photo-acid generators are sulfonium salt, iodonium salt, sulfonyldiazomethane, N-sulfonyloxyimide, oxime-O-sulfonate type acid generators, etc. Specific examples of the photo-acid generator include ones disclosed in paragraphs [0122] to [0142] of JP 2008-111103 A.

Moreover, a sulfonium salt shown by the following general formula (10-1) and an iodonium salt shown by the following general formula (10-2) can also be used suitably as photo-acid generators.

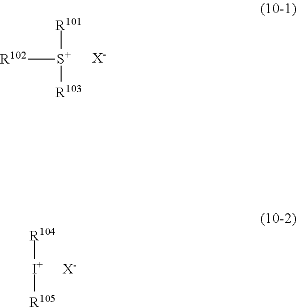

In the formulae (10-1) and (10-2), R¹⁰¹ to R¹⁰⁵ each independently represent a hydrocarbyl group having 1 to 25 carbon atoms and optionally containing a fluorine atom, a chlorine atom, a bromine atom, an iodine atom, or a heteroatom. X⁻ represents an anion.

The hydrocarbyl group represented by R¹⁰¹ to R¹⁰⁵ may be saturated or unsaturated, and may be linear, branched, or cyclic. Specific examples thereof include alkyl groups having 1 to 20 carbon atoms, such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyl group, an n-decyl group, an undecyl group, a dodecyl group, a tridecyl group, a tetradecyl group, a pentadecyl group, a heptadecyl group, an octadecyl group, an nonadecyl group, and an eicosyl group; cyclic saturated hydrocarbyl groups having 3 to 20 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms, such as a vinyl group, a propenyl group, a butenyl group, and a hexenyl group; cyclic unsaturated aliphatic hydrocarbyl groups having 2 to 20 carbon atoms, such as a cyclohexenyl group and a norbornenyl group; alkynyl groups having 2 to 20 carbon atoms, such as an ethynyl group, a propynyl group, and a butynyl group; aryl groups having 6 to 20 carbon atoms, such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group, and a tert-butylnaphthyl group; aralkyl groups having 7 to 20 carbon atoms, such as a benzyl group and a phenethyl group; etc. Additionally, these groups may have some hydrogen atoms substituted with a group containing a heteroatom, such as an oxygen atom, a sulfur atom, a nitrogen atom, or a halogen atom, while these groups may have some carbon atoms substituted with a group containing a heteroatom, such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester group, a carbonate group, a lactone ring, a sultone ring, carboxylic anhydride, a haloalkyl group, etc.

Alternatively, R¹⁰¹ and R¹⁰² may bond with each other to form a ring together with a sulfur atom bonded therewith. In this event, the ring preferably has any of the structures shown below.

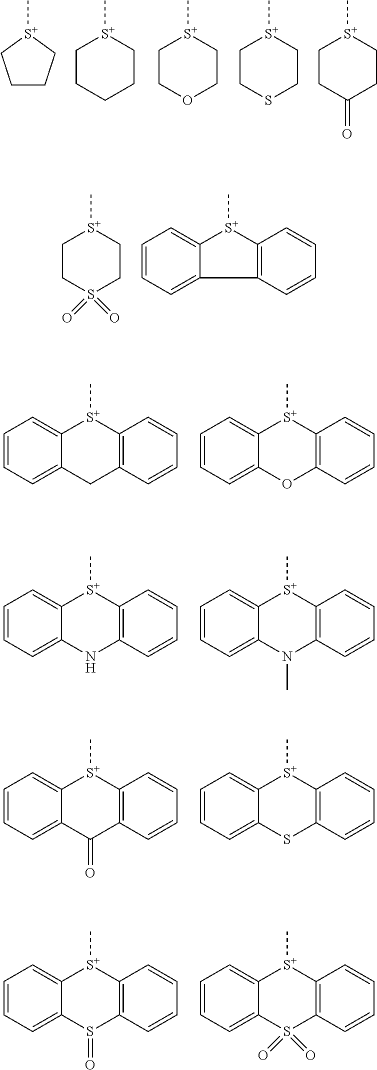

In the formulae, each broken line represents an attachment point to R¹⁰³.

Examples of a cation of the sulfonium salt shown by the formula (10-1) include ones shown below, but are not limited thereto.

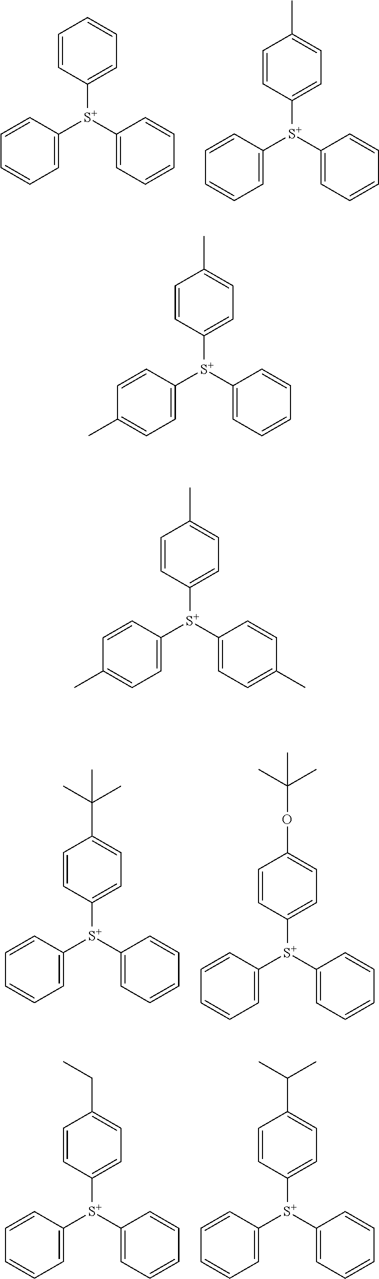

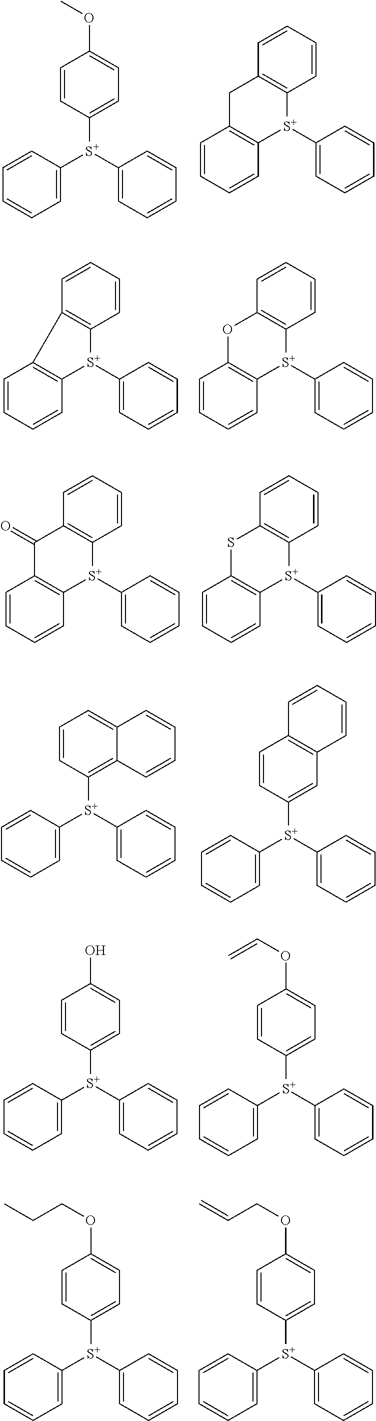

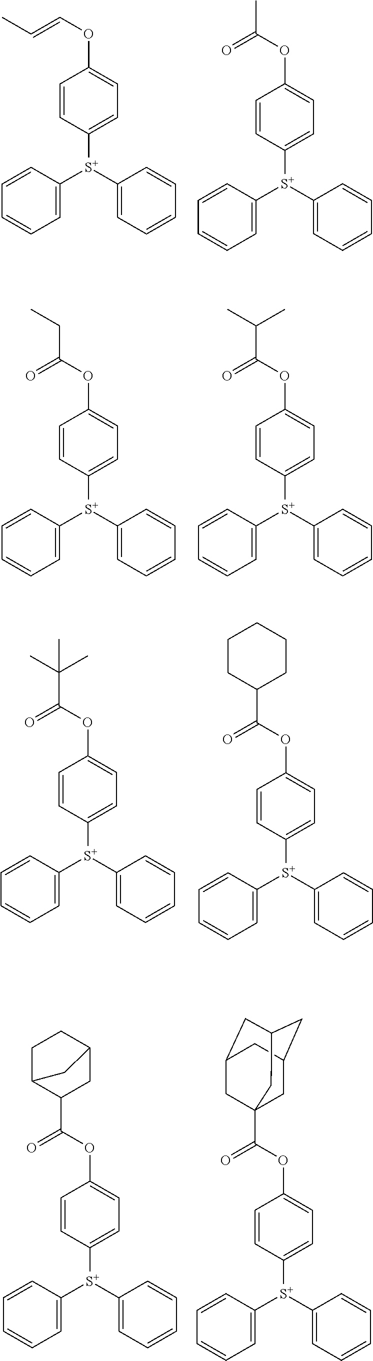

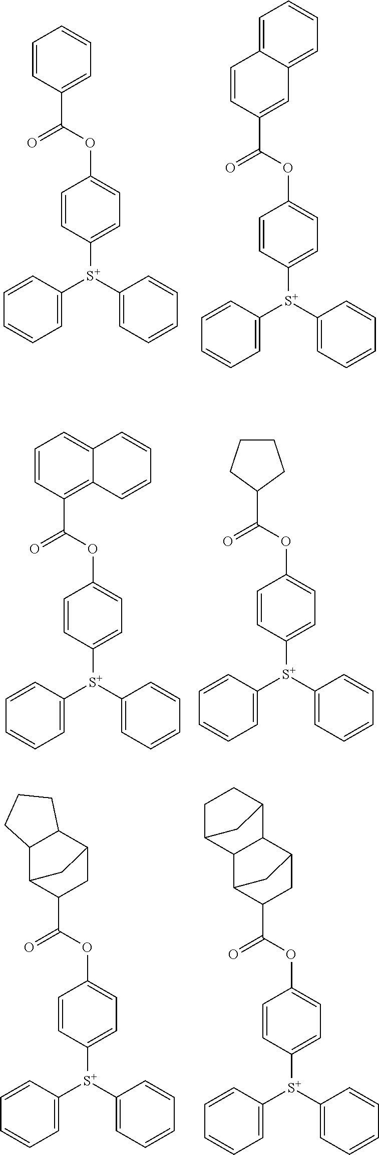 [SMILES: O=C(Oc1ccc([S+](c2ccccc2)c2ccccc2)cc1)c1ccccc1 ; O=C(Oc1ccc([S+](c2ccccc2)c2ccccc2)cc1)c1ccc2ccccc2c1 ; O=C(Oc1ccc([S+](c2ccccc2)c2ccccc2)cc1)c1cccc2ccccc12 ; O=C(Oc1ccc([S+](c2ccccc2)c2ccccc2)cc1)C1CCCC1 ; O=C(Oc1ccc([S+](c2ccccc2)c2ccccc2)cc1)C1CC2CC1C1CCCC21 ; O=C(Oc1ccc([S+](c2ccccc2)c2ccccc2)cc1)C1CC2CC1C1C3CCC(C3)C21]

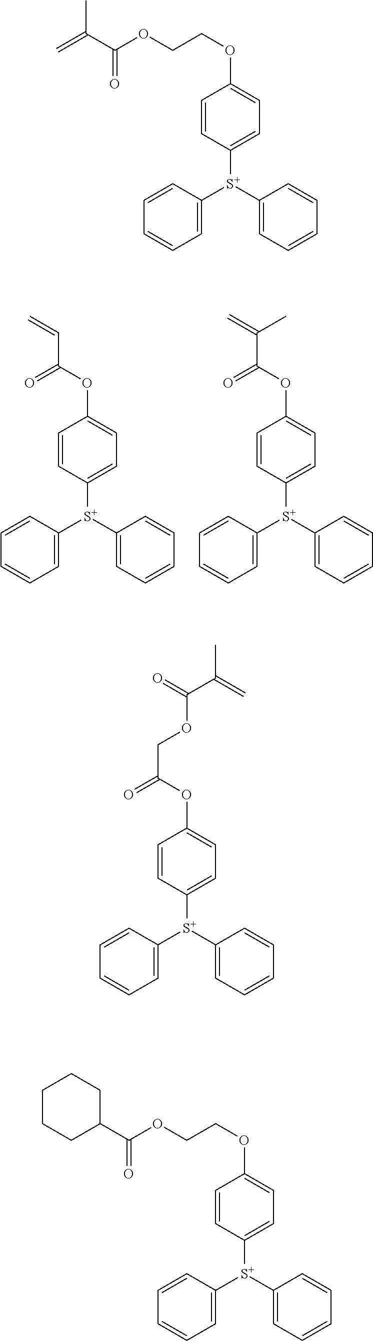 [SMILES: C=C(C)C(=O)OCCOc1ccc([S+](c2ccccc2)c2ccccc2)cc1 ; C=CC(=O)Oc1ccc([S+](c2ccccc2)c2ccccc2)cc1 ; C=C(C)C(=O)Oc1ccc([S+](c2ccccc2)c2ccccc2)cc1 ; C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1]

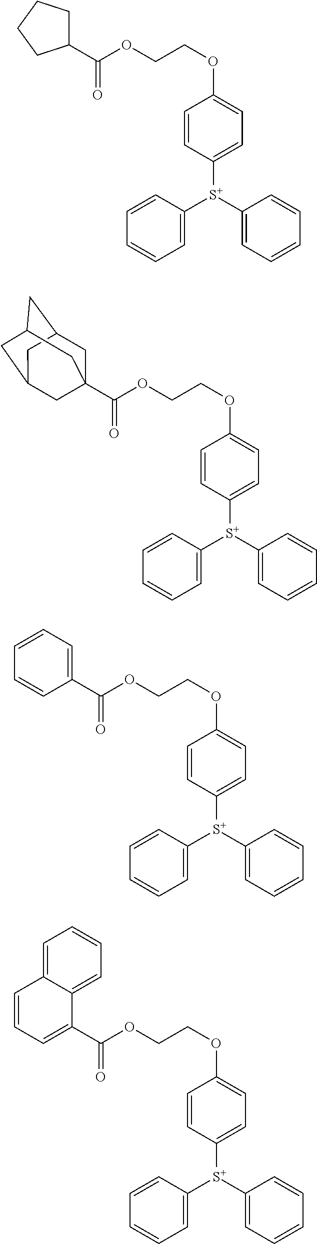 [SMILES: O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2 ; O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12]

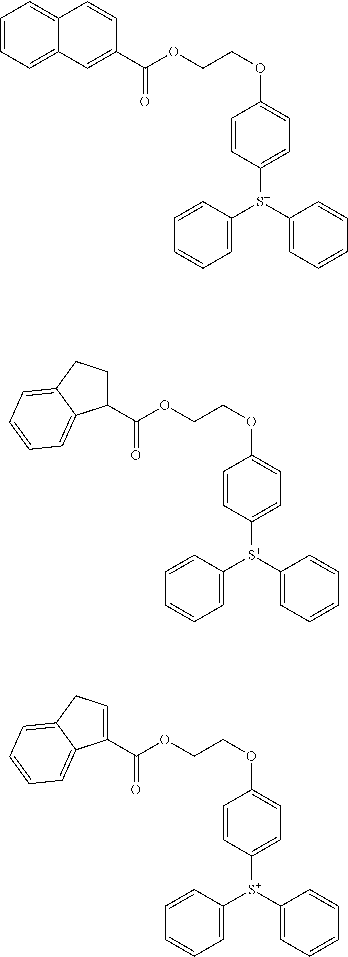 [SMILES: O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21 ; O=C(OCCOc1ccc([S+](c2ccccc2)c2ccccc2)cc1)C1=CCc2ccccc21]

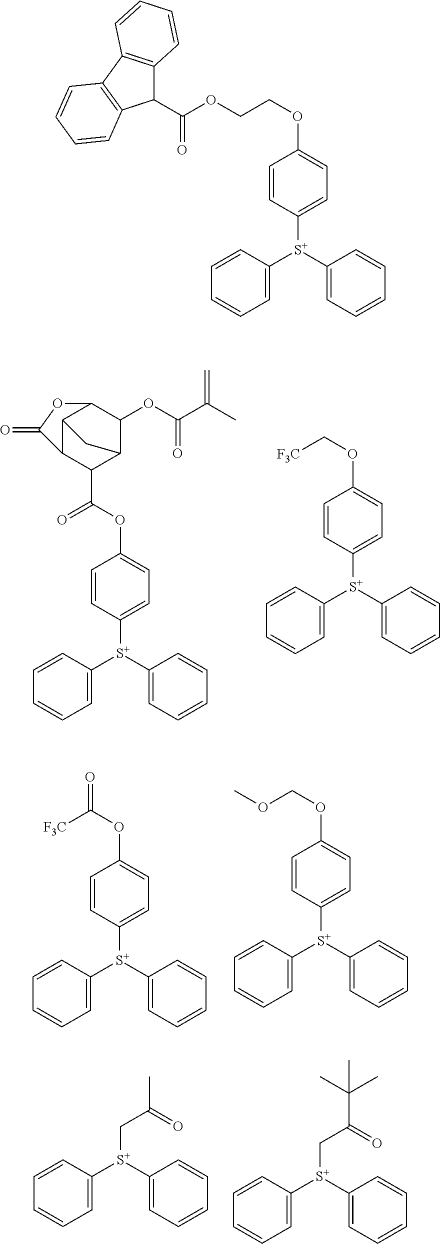

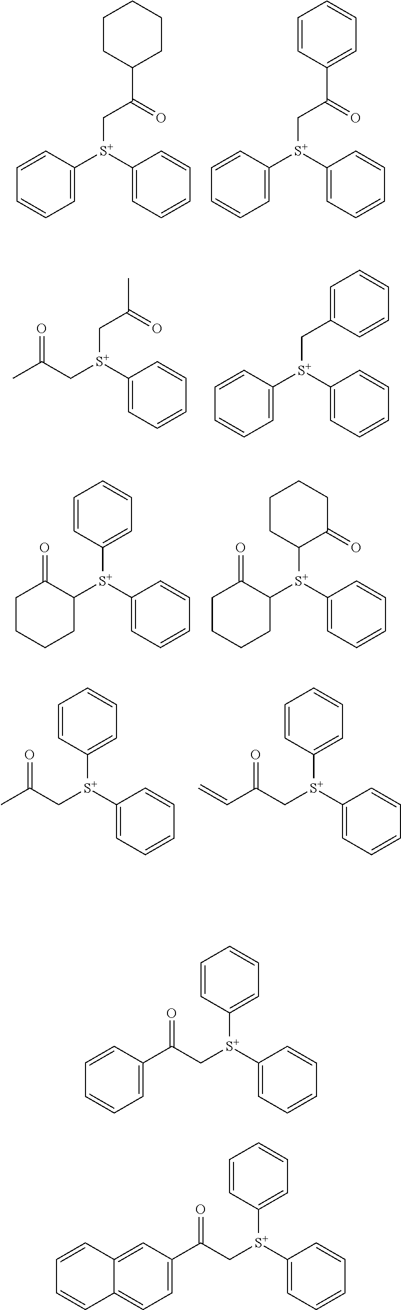

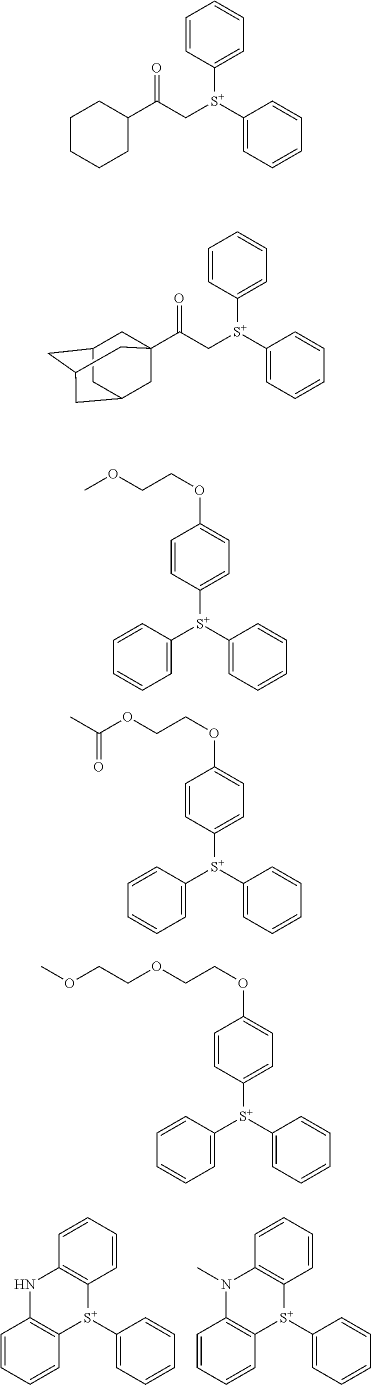

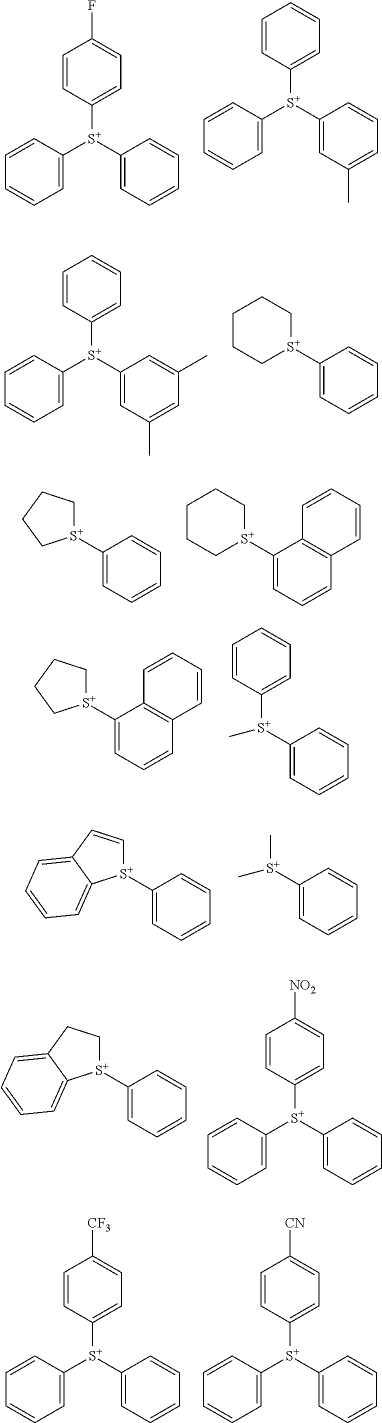

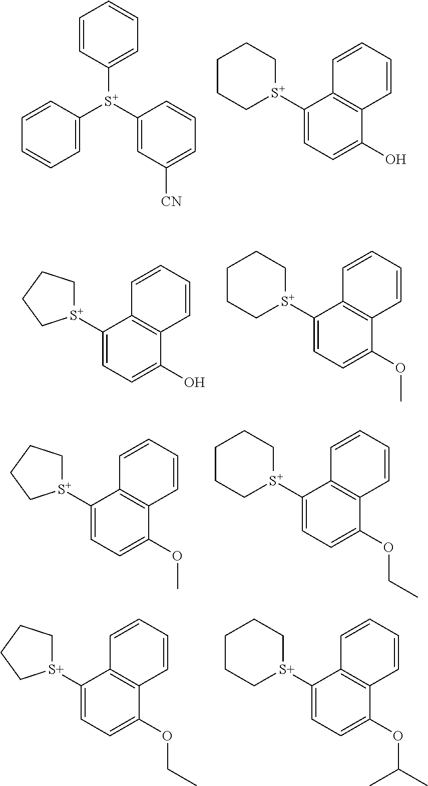

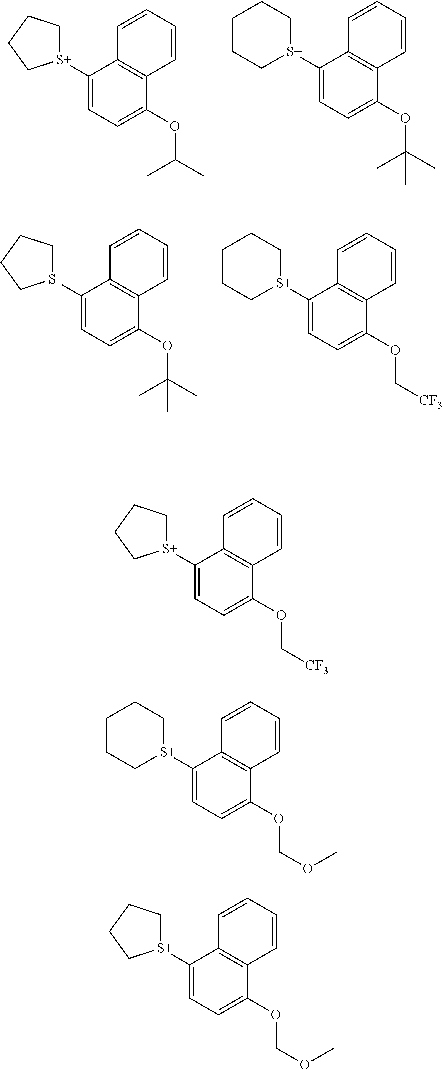

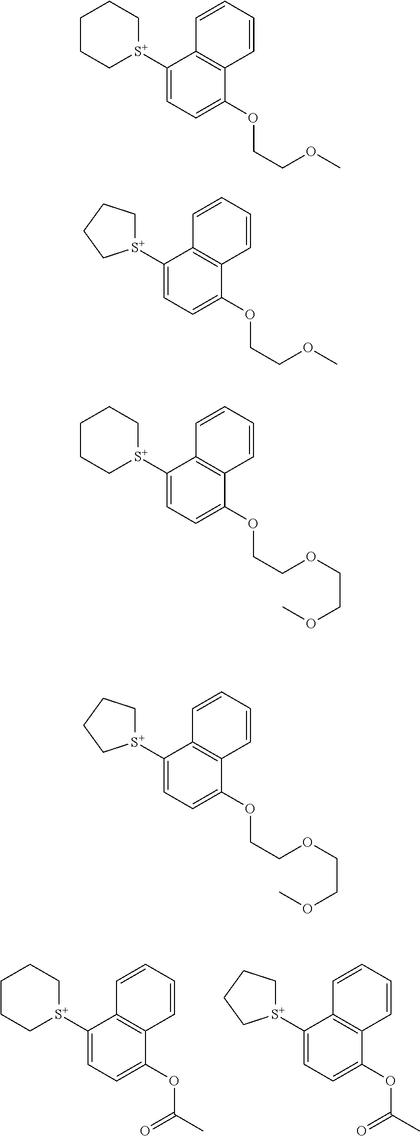 [SMILES: COCCOc1ccc([S+]2CCCCC2)c2ccccc12 ; COCCOc1ccc([S+]2CCCC2)c2ccccc12 ; COCCOCCOc1ccc([S+]2CCCCC2)c2ccccc12 ; COCCOCCOc1ccc([S+]2CCCC2)c2ccccc12 ; CC(=O)Oc1ccc([S+]2CCCCC2)c2ccccc12 ; CC(=O)Oc1ccc([S+]2CCCC2)c2ccccc12]

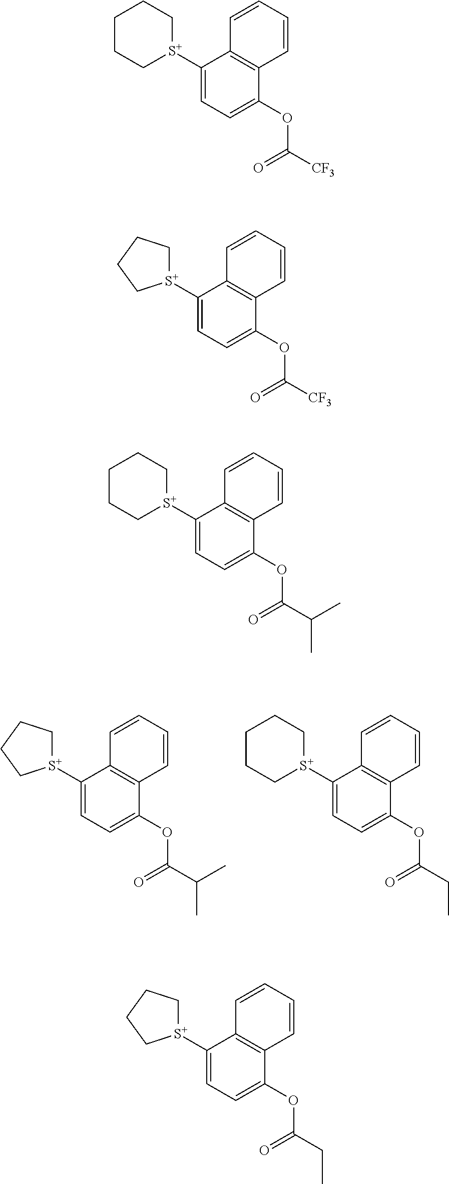 [SMILES: O=C(Oc1ccc([S+]2CCCCC2)c2ccccc12)C(F)(F)F ; O=C(Oc1ccc([S+]2CCCC2)c2ccccc12)C(F)(F)F ; CC(C)C(=O)Oc1ccc([S+]2CCCCC2)c2ccccc12 ; CC(C)C(=O)Oc1ccc([S+]2CCCC2)c2ccccc12 ; CCC(=O)Oc1ccc([S+]2CCCCC2)c2ccccc12 ; CCC(=O)Oc1ccc([S+]2CCCC2)c2ccccc12]

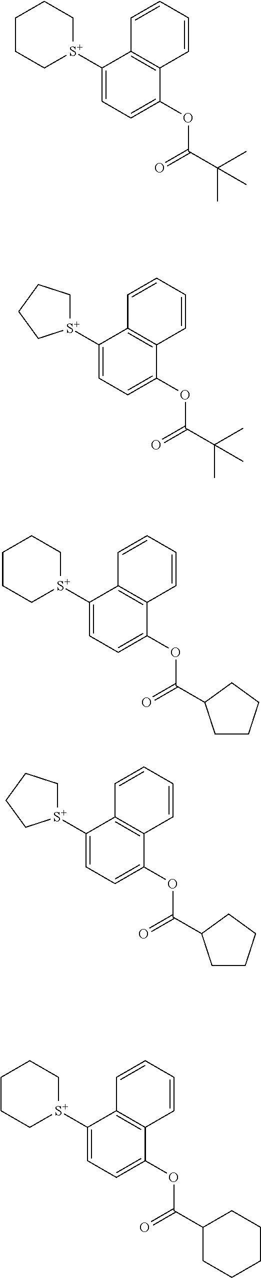 [SMILES: CC(C)(C)C(=O)Oc1ccc([S+]2CCCCC2)c2ccccc12 ; CC(C)(C)C(=O)Oc1ccc([S+]2CCCC2)c2ccccc12 ; O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1]

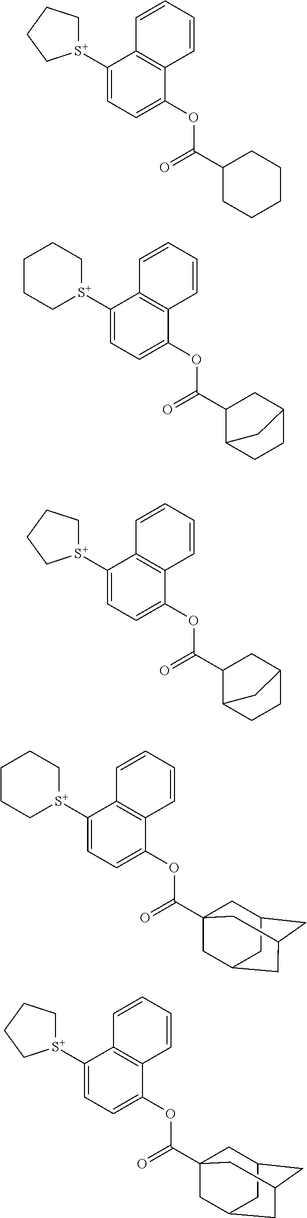 [SMILES: O=C(Oc1ccc([S+]2CCCC2)c2ccccc12)C1CCCCC1 ; O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2]

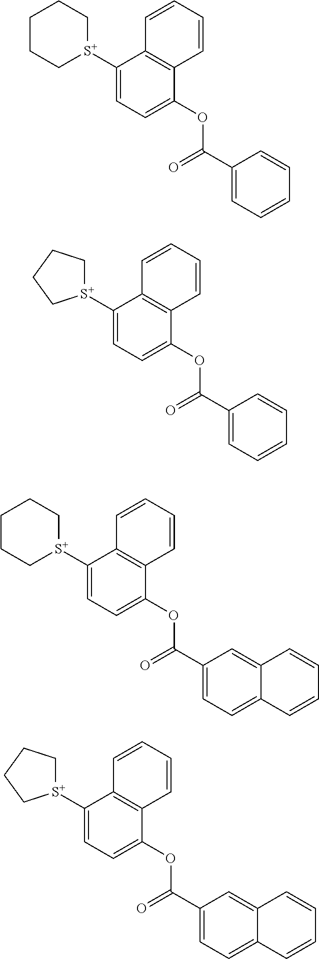 [SMILES: O=C(Oc1ccc([S+]2CCCCC2)c2ccccc12)c1ccccc1 ; O=C(Oc1ccc([S+]2CCCC2)c2ccccc12)c1ccccc1 ; O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1]

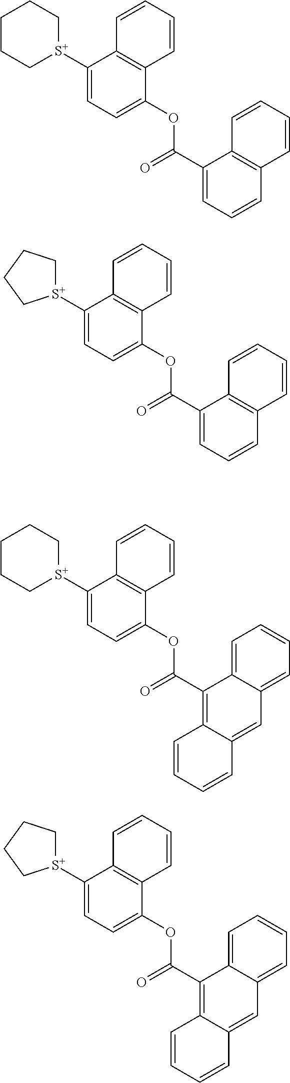 [SMILES: O=C(Oc1ccc([S+]2CCCCC2)c2ccccc12)c1cccc2ccccc12 ; O=C(Oc1ccc([S+]2CCCC2)c2ccccc12)c1cccc2ccccc12 ; O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12]

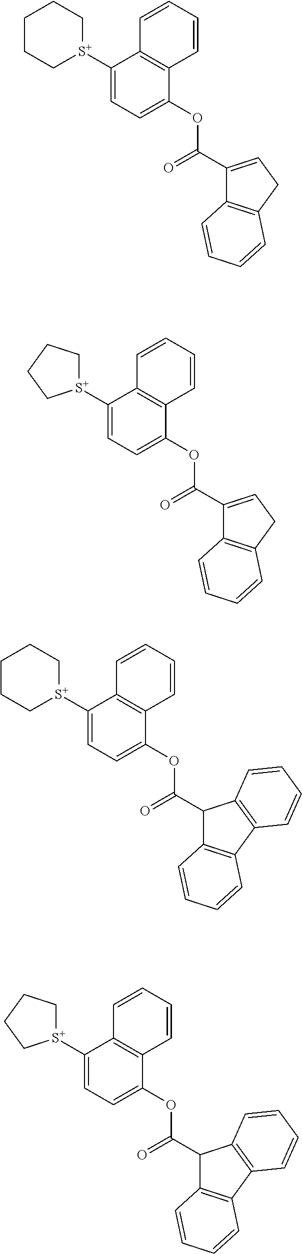 [SMILES: O=C(Oc1ccc([S+]2CCCCC2)c2ccccc12)C1=CCc2ccccc21 ; O=C(Oc1ccc([S+]2CCCC2)c2ccccc12)C1=CCc2ccccc21 ; O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21]

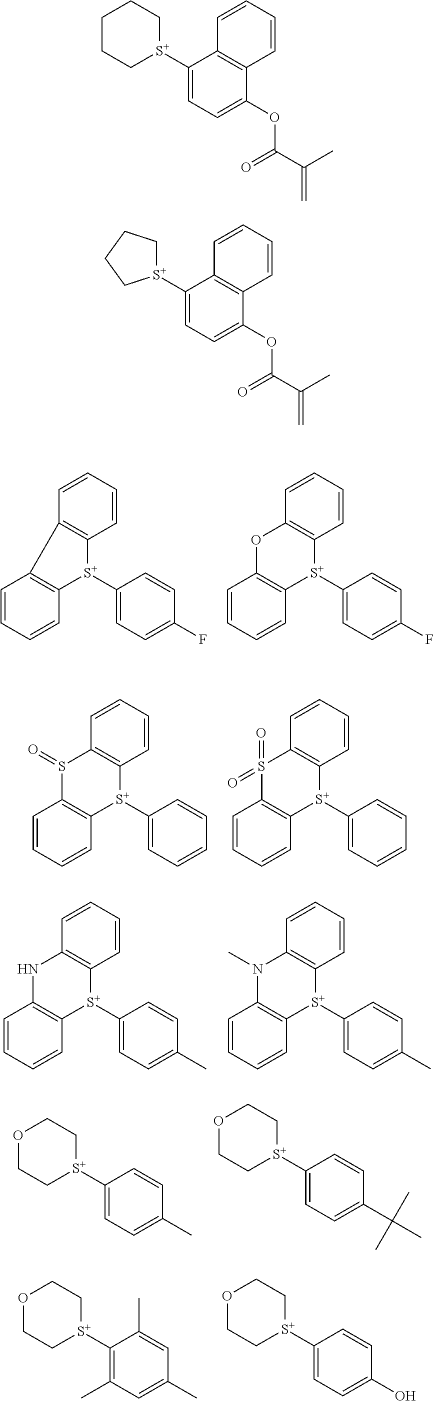

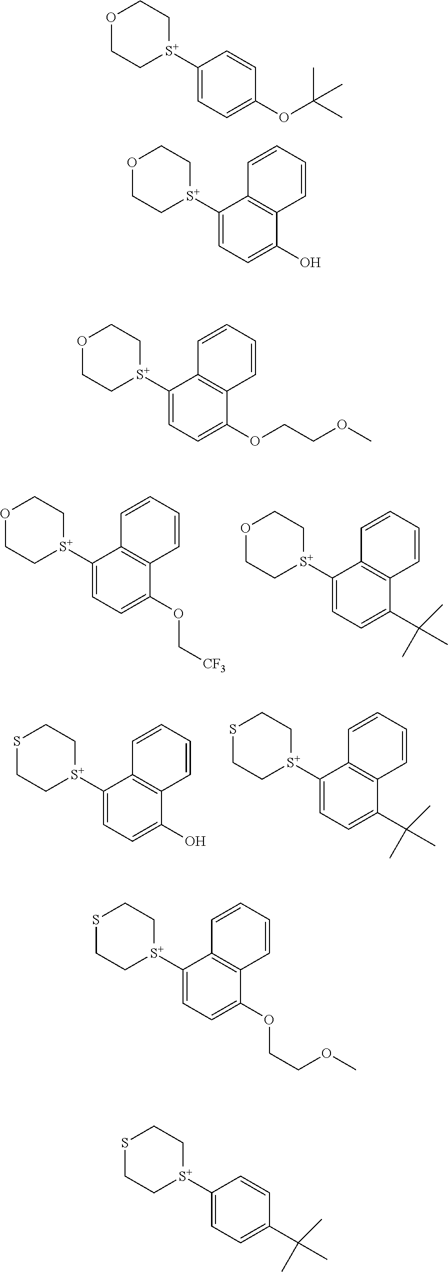

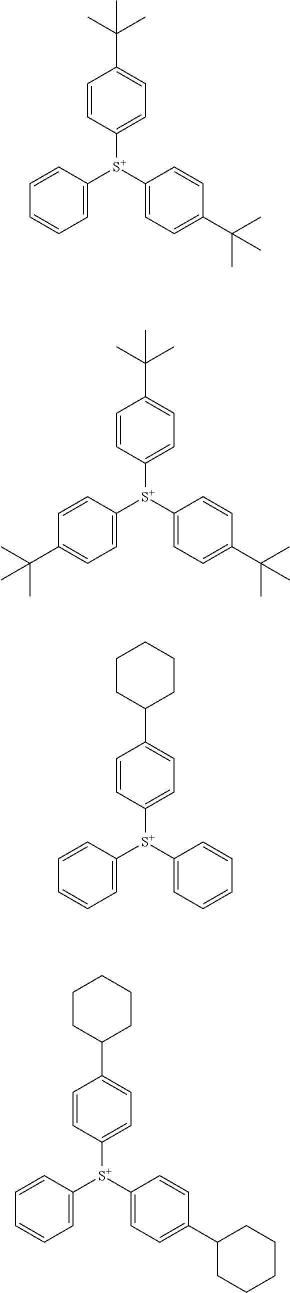

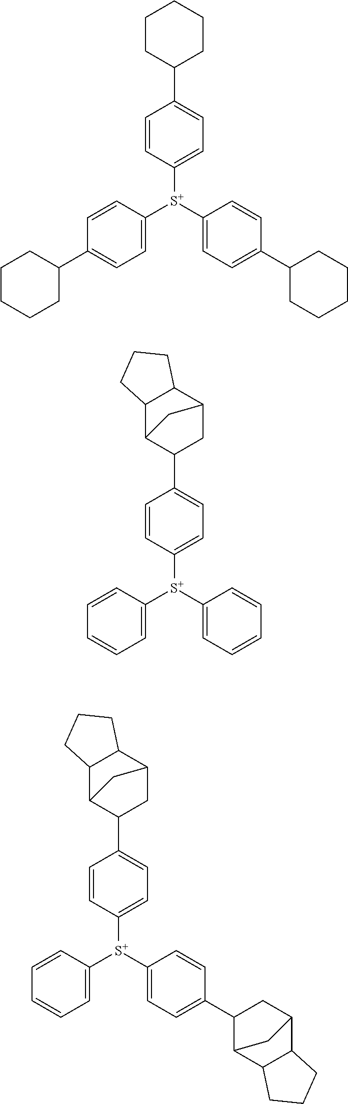 [SMILES: c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1]

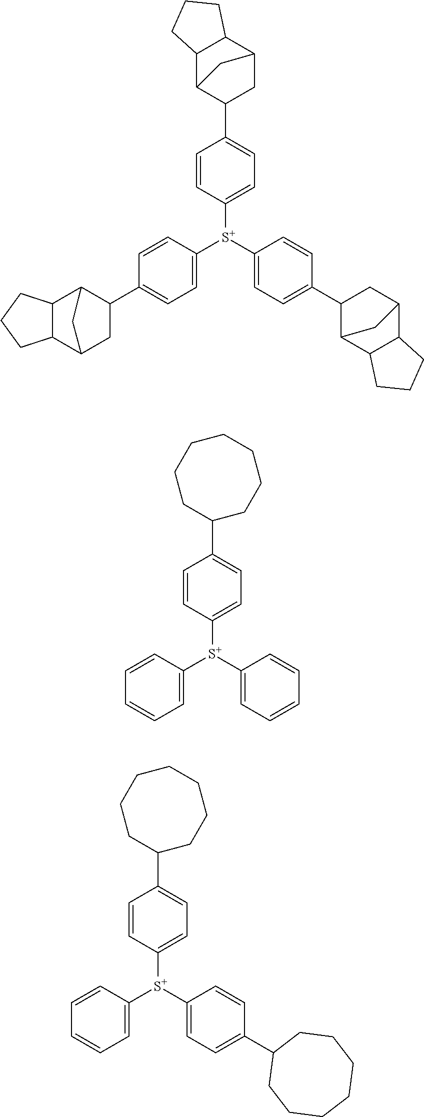 [SMILES: c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1]

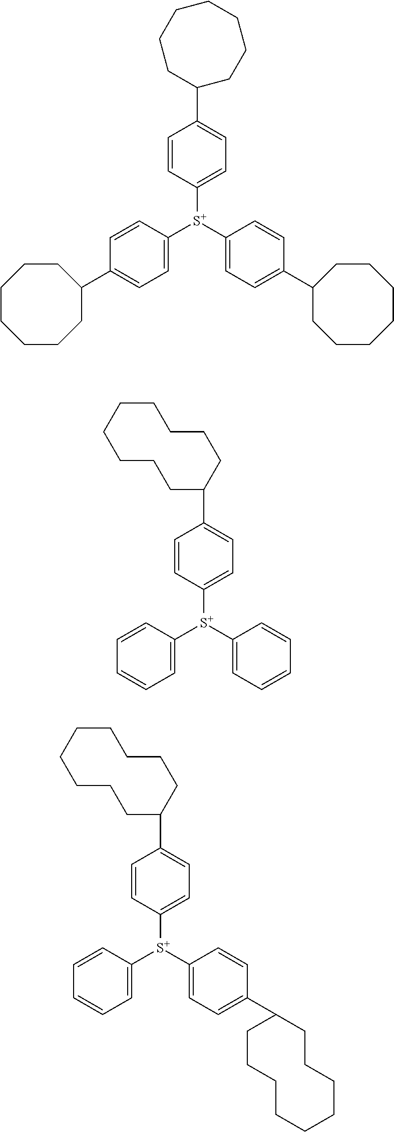 [SMILES: c1cc([S+](c2ccc(C3CCCCCCC3)cc2)c2ccc(C3CCCCCCC3)cc2)ccc1C1CCCCCCC1 ; c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1]

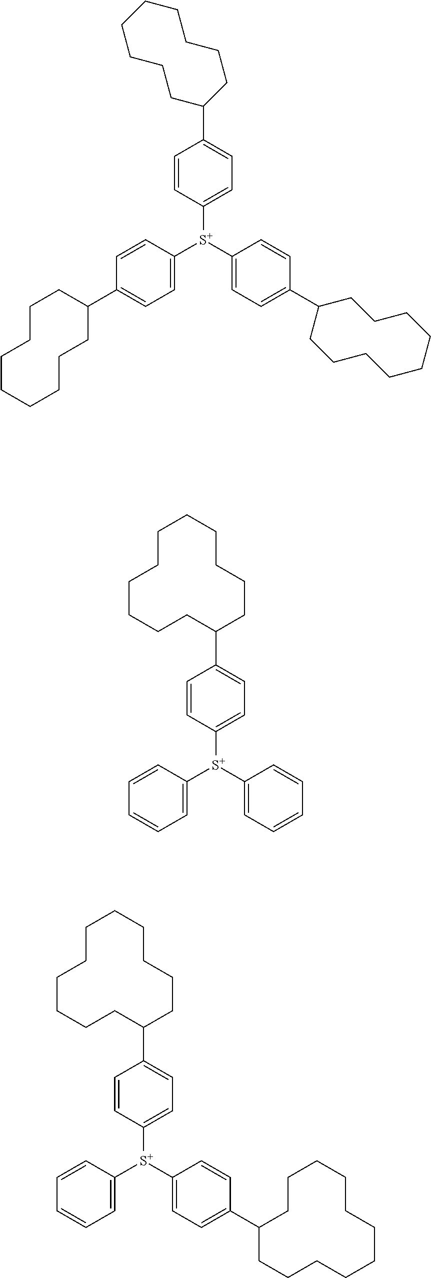 [SMILES: c1cc([S+](c2ccc(C3CCCCCCCCC3)cc2)c2ccc(C3CCCCCCCCC3)cc2)ccc1C1CCCCCCCCC1 ; c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1]

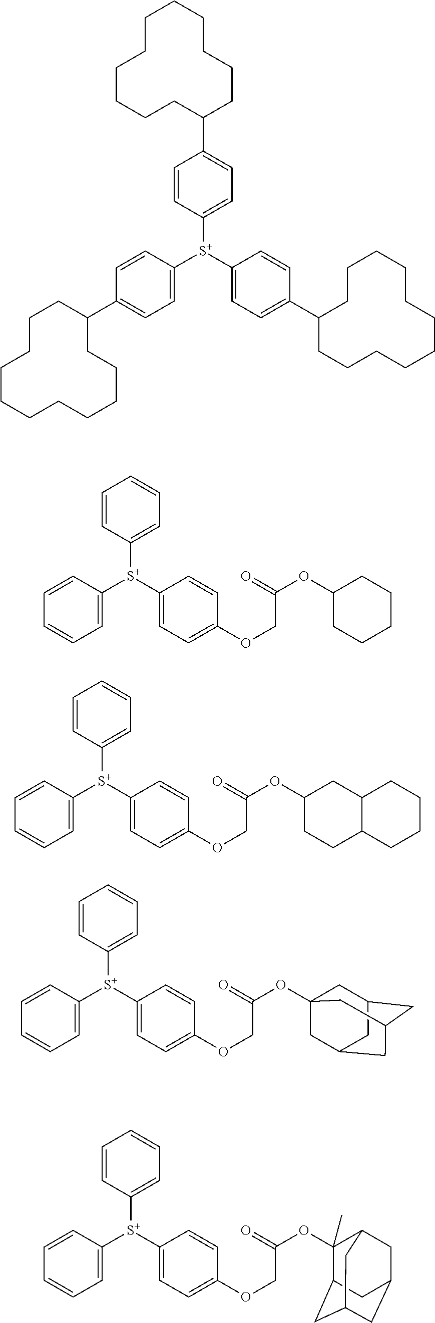 [SMILES: c1cc([S+](c2ccc(C3CCCCCCCCCCC3)cc2)c2ccc(C3CCCCCCCCCCC3)cc2)ccc1C1CCCCCCCCCCC1 ; O=C(COc1ccc([S+](c2ccccc2)c2ccccc2)cc1)OC1CCCCC1 ; O=C(COc1ccc([S+](c2ccccc2)c2ccccc2)cc1)OC1CCC2CCCCC2C1 ; O=C(COc1ccc([S+](c2ccccc2)c2ccccc2)cc1)OC12CC3CC(CC(C3)C1)C2 ; CC1(OC(=O)COc2ccc([S+](c3ccccc3)c3ccccc3)cc2)C2CC3CC(C2)CC1C3]

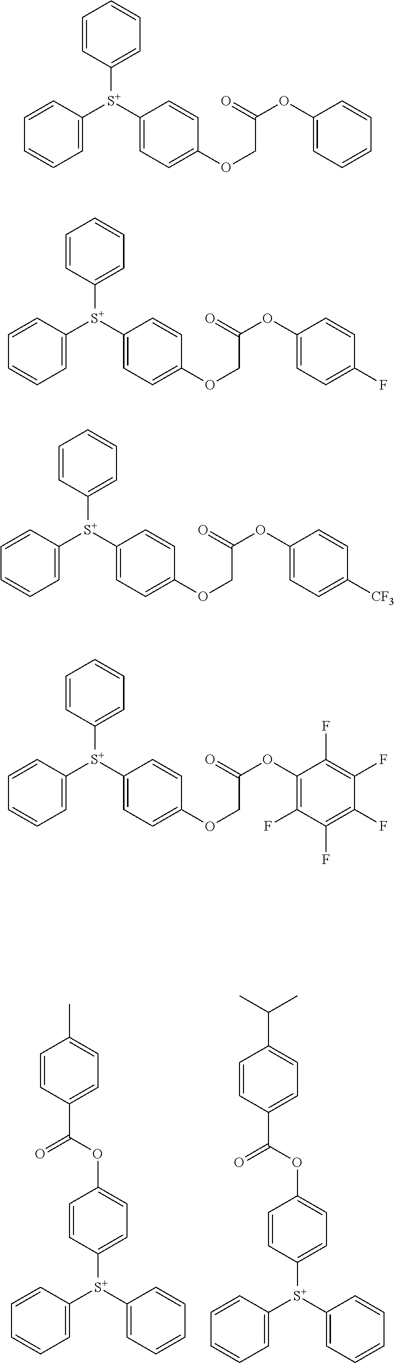 [SMILES: O=C(COc1ccc([S+](c2ccccc2)c2ccccc2)cc1)Oc1ccccc1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1]

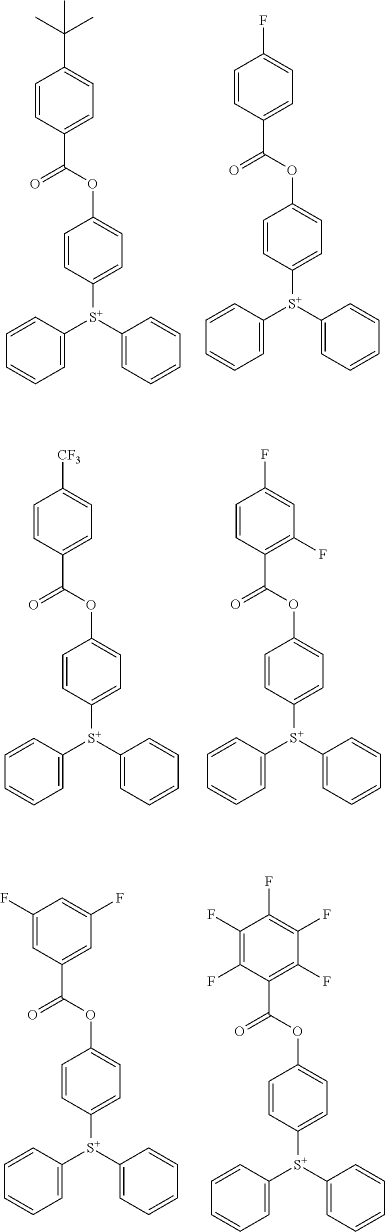 [SMILES: CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F ; O=C(Oc1ccc([S+](c2ccccc2)c2ccccc2)cc1)c1cc(F)cc(F)c1 ; O=C(Oc1ccc([S+](c2ccccc2)c2ccccc2)cc1)c1c(F)c(F)c(F)c(F)c1F]

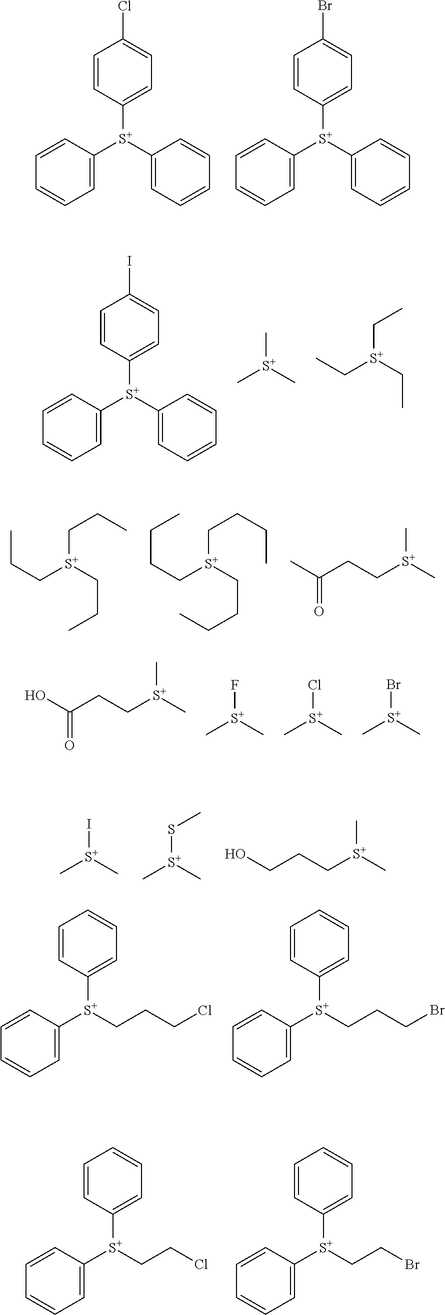

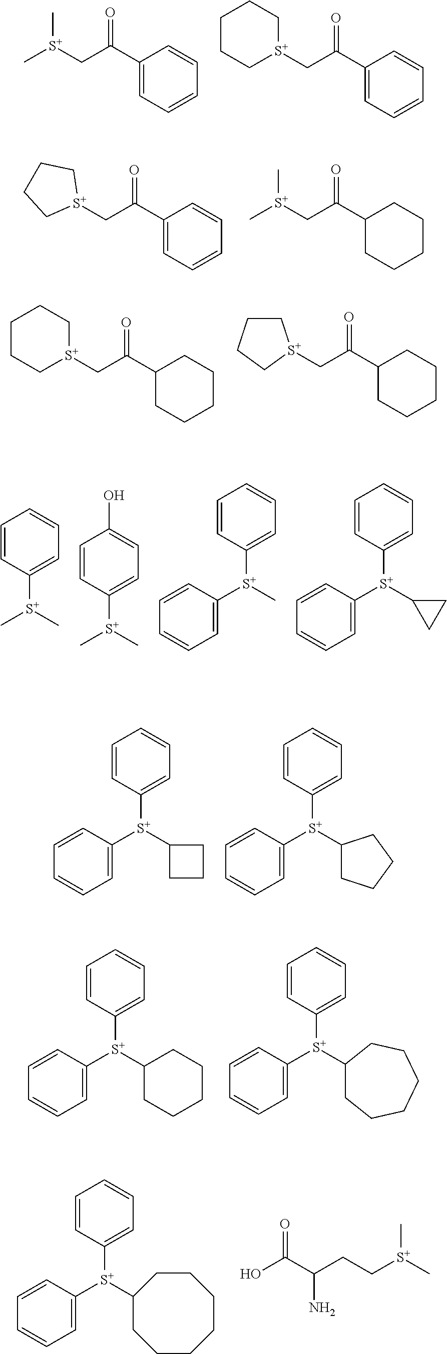

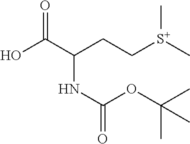 [SMILES: C[S+](C)CCC(NC(=O)OC(C)(C)C)C(=O)O]

Examples of a cation of the iodonium salt shown by the formula (10-2) include ones shown below, but are not limited thereto.

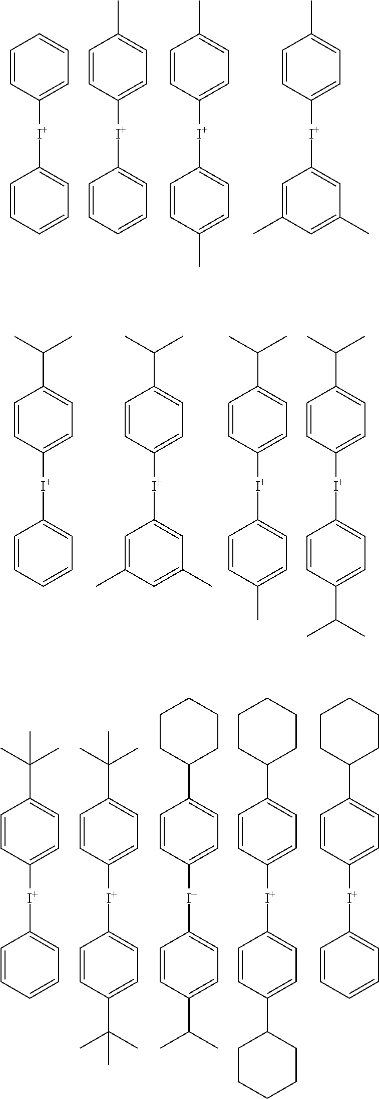

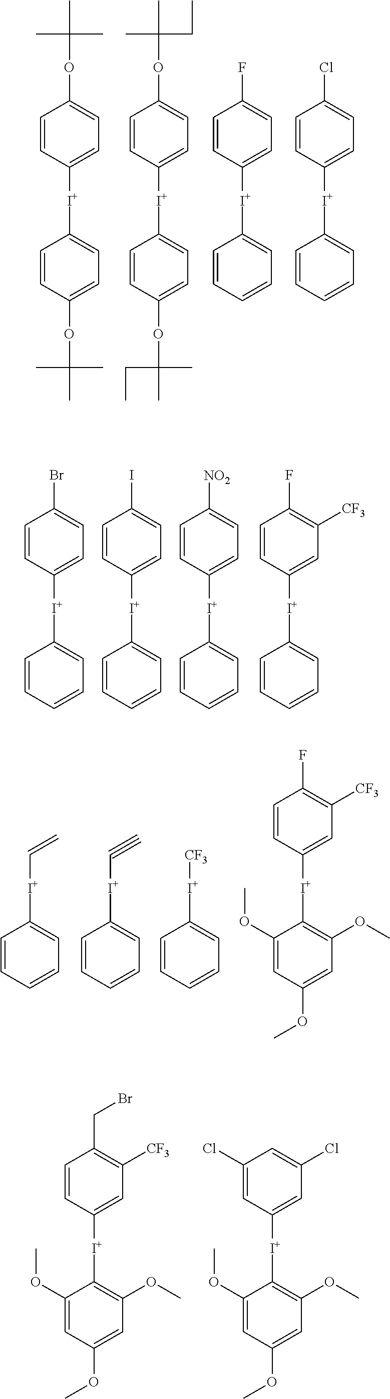

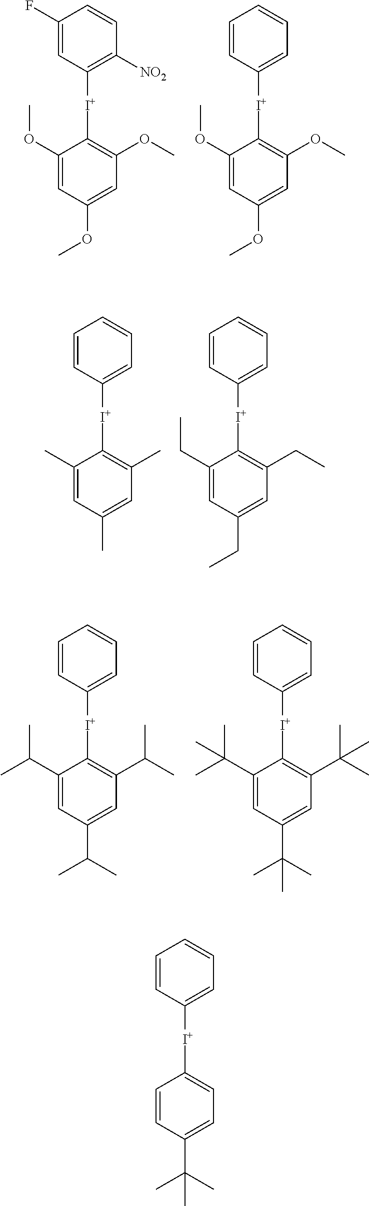

In the formulae (10-1) and (10-2), X⁻ represents an anion selected from the following formulae (1A) to (1D).

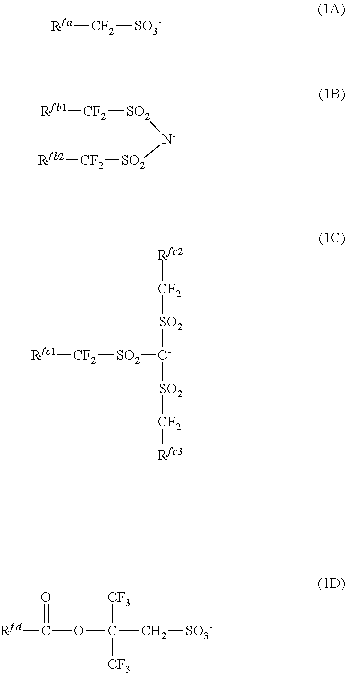

In the formula (1A), R^{fa} represents a fluorine atom, or a hydrocarbyl group having 1 to 40 carbon atoms and optionally containing a heteroatom. The hydrocarbyl group may be saturated or unsaturated, and may be linear, branched, or cyclic. Specific examples thereof include those to be described below as a hydrocarbyl group which R¹⁰⁷ represents in the formula (1A′).

The anion shown by the formula (1A) is preferably shown by the following formula (1A′).

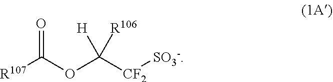

In the formula (1A′), R¹⁰⁶ represents a hydrogen atom or a trifluoromethyl group, preferably a trifluoromethyl group. R¹⁰⁷ represents a hydrocarbyl group having 1 to 38 carbon atoms and optionally containing a heteroatom. The heteroatom is preferably an oxygen atom, a nitrogen atom, a sulfur atom, a halogen atom, or the like, more preferably an oxygen atom. The hydrocarbyl group particularly preferably has 6 to 30 carbon atoms from the viewpoint of obtaining high resolution in fine pattern formation.

The hydrocarbyl group represented by R¹⁰⁷ may be saturated or unsaturated, and may be linear, branched, or cyclic. Specific examples thereof include alkyl groups such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; unsaturated hydrocarbyl groups such as an allyl group and a 3-cyclohexenyl group; aryl groups such as a phenyl group, a 1-naphthyl group, and a 2-naphthyl group; aralkyl groups such as a benzyl group and a diphenylmethyl group; etc.

In addition, these groups may have some or all of hydrogen atoms substituted with a group containing a heteroatom such as an oxygen atom, a sulfur atom, a nitrogen atom, or a halogen atom, while these groups may have some of carbon atoms substituted with a group containing a heteroatom such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester group, a carbonate group, a lactone ring, a sultone ring, carboxylic anhydride, a haloalkyl group, etc. Examples of the hydrocarbyl group containing a heteroatom include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, a 3-oxocyclohexyl group, etc.

The synthesis of the sulfonium salt containing the anion shown by the formula (1A′) is described in detail in JP 2007-145797 A, JP 2008-106045 A, JP 2009-7327 A, JP 2009-258695 A, etc. In addition, sulfonium salts disclosed in JP 2010-215608 A, JP 2012-41320 A, JP 2012-106986 A, JP 2012-153644 A, etc. are also suitably used.

Examples of the anion shown by the formula (1A) include ones exemplified as an anion shown by formula (1A) in JP 2018-197853 A.

In the formula (1B), R^{fb1} and R^{fb2} each independently represent a fluorine atom, or a hydrocarbyl group having 1 to 40 carbon atoms and optionally containing a heteroatom. The hydrocarbyl group may be saturated or unsaturated, and may be linear, branched, or cyclic. Specific examples thereof include those exemplified in the description of R¹⁰⁷ in the formula (1A′). R^{fb1} and R^{fb}z are preferably a fluorine atom or a linear fluorinated alkyl group having 1 to 4 carbon atoms. Alternatively, R^{fb1} and R^{fb2} may bond with each other to form a ring together with a group (—CF₂—SO₂—N—SO₂—CF₂—) bonded therewith. In this event, the group obtained by bonding R^{fb1} and R^{fb2} with each other is preferably a fluorinated ethylene group or a fluorinated propylene group.

In the formula (1C), R^{fc1}, R^{fc2}, and R^{fc3} each independently represent a fluorine atom, or a hydrocarbyl group having 1 to 40 carbon atoms and optionally containing a heteroatom. The hydrocarbyl group may be saturated or unsaturated, and may be linear, branched, or cyclic. Specific examples thereof include those exemplified in the description of R¹⁰⁷ in the formula (1A′). R^{fc1}, R^{fc2}, and R^{fc3} are preferably a fluorine atom or a linear fluorinated alkyl group having 1 to 4 carbon atoms. Alternatively, R^{fc1} and R^{fc2} may bond with each other to form a ring together with a group (—CF₂—SO₂—C⁻—SO₂—CF₂—) bonded therewith. In this event, the group obtained by bonding R^{fc1} and R^{fc2} with each other is preferably a fluorinated ethylene group or a fluorinated propylene group.

In the formula (1D), R^{fd} represents a hydrocarbyl group having 1 to 40 carbon atoms and optionally containing a heteroatom. The hydrocarbyl group may be saturated or unsaturated, and may be linear, branched, or cyclic. Specific examples thereof include those exemplified in the description of R¹⁰⁷ in the formula (1A′).

The synthesis of the sulfonium salt containing the anion shown by the formula (1D) is described in detail in JP 2010-215608 A and JP 2014-133723 A.

Examples of the anion shown by the formula (1D) include ones exemplified as an anion shown by formula (1D) in JP 2018-197853 A.

Note that the photo-acid generator containing the anion shown by the formula (1D) does not have fluorine at a position of the sulfo group, but has two trifluoromethyl groups at β position, thereby providing sufficient acidity to cut the acid labile group in the base polymer. Thus, this photo-acid generator is utilizable.

Furthermore, one shown by the following general formula (2) can also be used suitably as a photo-acid generator.

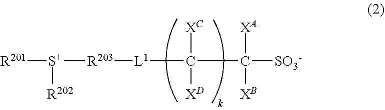

In the formula (2), R²⁰¹ and R²⁰² each independently represent a hydrocarbyl group having 1 to 30 carbon atoms and optionally containing a heteroatom. R²⁰³ represents a hydrocarbylene group having 1 to 30 carbon atoms and optionally containing a heteroatom. Alternatively, R²⁰¹ and R²⁰², or R²⁰¹ and R²⁰³, may bond with each other to form a ring together with a sulfur atom bonded therewith. In this event, examples of the ring include those exemplified as the ring which can be formed by bonding R¹⁰¹ and R¹⁰² together with the sulfur atoms in the description of the formula (10-1).

The hydrocarbyl group represented by R²⁰¹ and R²⁰² may be saturated or unsaturated, and may be linear, branched, or cyclic. Specific examples thereof include: alkyl groups such as a methyl group, an ethyl group, a propyl group, an isopropyl group, an n-butyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; aryl groups such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group, a tert-butylnaphthyl group, and an anthracenyl group; etc. Additionally, these groups may have some or all of hydrogen atoms substituted with a group containing a heteroatom, such as an oxygen atom, a sulfur atom, a nitrogen atom, or a halogen atom, while these groups may have some of carbon atoms substituted with a group containing a heteroatom, such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester group, a carbonate group, a lactone ring, a sultone ring, carboxylic anhydride, a haloalkyl group, etc.

The hydrocarbylene group represented by R²⁰³ may be saturated or unsaturated, and may be linear, branched, or cyclic. Specific examples thereof include alkanediyl groups such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; cyclic saturated hydrocarbylene groups such as a cyclopentanediyl group, a cyclohexanediyl group, a norbornanediyl group, and an adamantanediyl group; arylene groups such as a phenylene group, a methylphenylene group, an ethylphenylene group, an n-propylphenylene group, an isopropylphenylene group, an n-butylphenylene group, an isobutylphenylene group, a sec-butylphenylene group, a tert-butylphenylene group, a naphthylene group, a methylnaphthylene group, an ethylnaphthylene group, an n-propylnaphthylene group, an isopropylnaphthylene group, an n-butylnaphthylene group, an isobutylnaphthylene group, a sec-butylnaphthylene group, and a tert-butylnaphthylene group; etc. Additionally, these groups may have some or all of hydrogen atoms substituted with a group containing a heteroatom such as an oxygen atom, a sulfur atom, a nitrogen atom, or a halogen atom, while these groups may have some of carbon atoms substituted with a group containing a heteroatom such as an oxygen atom, a sulfur atom, or a nitrogen atom. Thus, the resulting hydrocarbylene group may contain a hydroxy group, a cyano group, a carbonyl group, an ether bond, an ester bond, a sulfonic acid ester group, a carbonate group, a lactone ring, a sultone ring, carboxylic anhydride, a haloalkyl group, etc. The heteroatom is preferably an oxygen atom.

In the formula (2), L¹ represents a single bond, an ether bond, or a hydrocarbylene group having 1 to 20 carbon atoms and optionally containing a heteroatom. The hydrocarbylene group may be saturated or unsaturated, and may be linear, branched, or cyclic. Specific examples thereof include those exemplified as the hydrocarbylene group represented by R²⁰³.

In the formula (2), X^{A}, X^{B}, X^{C}, and X^{D} each independently represent a hydrogen atom, a fluorine atom, or a trifluoromethyl group. Nevertheless, at least one of X^{A}, X^{B}, X^{C}, and X^{D} is a fluorine atom or a trifluoromethyl group.

In the formula (2), “k” represents an integer of 0 to 3.

The photo-acid generator shown by the formula (2) is preferably shown by the following formula (2′).

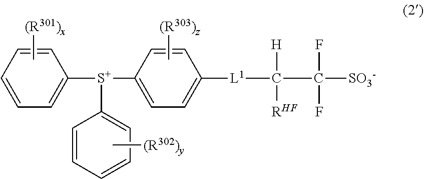

In the formula (2′), L¹ is as defined above. R^{HF} represents a hydrogen atom or a trifluoromethyl group, preferably a trifluoromethyl group. R³⁰¹, R³⁰², and R³⁰³ each independently represent a hydrogen atom, or a hydrocarbyl group having 1 to 20 carbon atoms and optionally containing a heteroatom. The hydrocarbyl group may be saturated or unsaturated, and may be linear, branched, or cyclic. Specific examples thereof include those exemplified in the description of R¹⁰⁷ in the formula (1A′). “x” and “y” each independently represent an integer of 0 to 5. “z” represents an integer of 0 to 4.

Examples of the photo-acid generator shown by the formula (2) include ones exemplified as a photo-acid generator shown by formula (2) in JP 2017-026980 A.

The photo-acid generators containing the anion shown by the formula (1A′) or (1D) are particularly preferable because of small acid diffusion and excellent solubility to a resist solvent. One shown by the formula (2′) is also particularly preferable because the acid diffusion is quite small.

Furthermore, a sulfonium salt or an iodonium salt each having an anion containing an iodine atom- or bromine atom-substituted aromatic ring can also be used as the photo-acid generator. Examples of such salts include ones shown by the following formula (3-1) or (3-2).

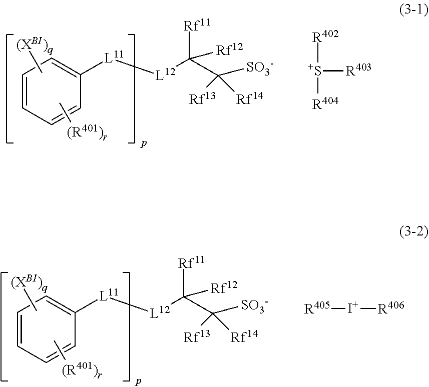

In the formulae (3-1) and (3-2), “p” represents an integer satisfying 1≤p≤3. “q” and “r” represent integers satisfying 1≤q≤5, 0≤r≤3, and 1≤q+r≤5. “q” is preferably an integer satisfying 1≤q≤3, more preferably 2 or 3. “r” is preferably an integer satisfying 0≤r≤2.

In the formulae (3-1) and (3-2), X^{BI} represents an iodine atom or a bromine atom. When “q” is 2 or more, X^{BI}'s may be identical to or different from one another.

In the formulae (3-1) and (3-2), L¹¹ represents a single bond, an ether bond, an ester bond, or a saturated hydrocarbylene group having 1 to 6 carbon atoms and optionally containing an ether bond or an ester bond. The saturated hydrocarbylene group may be linear, branched, or cyclic.

In the formulae (3-1) and (3-2), L¹² represents a single bond or a divalent linking group having 1 to 20 carbon atoms when “p” is 1. When “p” is 2 or 3, L¹² represents a trivalent or tetravalent linking group having 1 to 20 carbon atoms. This linking group optionally contains an oxygen atom, a sulfur atom, a nitrogen atom, a chlorine atom, a bromine atom, or an iodine atom.

In the formulae (3-1) and (3-2), R⁴⁰¹ represents: a hydroxy group, a carboxy group, a fluorine atom, a chlorine atom, a bromine atom, or an amino group; a saturated hydrocarbyl group having 1 to 20 carbon atoms, a saturated hydrocarbyloxy group having 1 to 20 carbon atoms, a saturated hydrocarbyloxycarbonyl group having 2 to 10 carbon atoms, a saturated hydrocarbylcarbonyloxy group having 2 to 20 carbon atoms, or a saturated hydrocarbylsulfonyloxy group having 1 to 20 carbon atoms, each of which optionally contains a fluorine atom, a chlorine atom, a bromine atom, a hydroxy group, an amino group, or an ether bond; or —NR^{401A}—C(═O)—R^{401B} or —NR^{401A}—C(═O)—O—R^{401B}. R^{401A} represents a hydrogen atom or a saturated hydrocarbyl group having 1 to 6 carbon atoms, and optionally contains a halogen atom, a hydroxy group, an alkoxy group having 1 to 6 carbon atoms, a saturated hydrocarbylcarbonyl group having 2 to 6 carbon atoms, or a saturated hydrocarbylcarbonyloxy group having 2 to 6 carbon atoms. R^{401B} represents an aliphatic hydrocarbyl group having 1 to 16 carbon atoms or an aryl group having 6 to 12 carbon atoms, and optionally contains a halogen atom, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms. The aliphatic hydrocarbyl group may be saturated or unsaturated, and may be linear, branched, or cyclic. The saturated hydrocarbyl groups, saturated hydrocarbyloxy groups, saturated hydrocarbyloxycarbonyl groups, saturated hydrocarbylcarbonyl groups, and saturated hydrocarbylcarbonyloxy groups may be linear, branched, or cyclic. When “p” and/or “r” are 2 or more, R⁴⁰¹'s may be identical to or different from one another.

Above all, R⁴⁰¹ is preferably a hydroxy group, —NR^{401A}—C(═O)—R^{401B}, —NR^{401A}—C(═O)—O—R^{401B}, a fluorine atom, a chlorine atom, a bromine atom, a methyl group, a methoxy group, or the like.

In the formulae (3-1) and (3-2), R^{f11} to R^{f14} each independently represent a hydrogen atom, a fluorine atom, or a trifluoromethyl group. At least one of R^{f11} to R^{f14} is a fluorine atom or a trifluoromethyl group. Alternatively, R^{f11} and R^{f12} may bond with each other to form a carbonyl group. Particularly preferably, both R^{f13} and R^{f14} are fluorine atoms.

In the formulae (3-1) and (3-2), R⁴⁰², R⁴⁰³, R⁴⁰⁴, R⁴⁰⁵, and R⁴⁰⁶ each independently represent a hydrocarbyl group having 1 to 20 carbon atoms and optionally containing a fluorine atom, a chlorine atom, a bromine atom, an iodine atom, or a heteroatom. The hydrocarbyl group may be saturated or unsaturated, and may be linear, branched, or cyclic. Specific examples thereof include those exemplified as hydrocarbyl groups represented by R¹⁰¹ to R¹⁰⁵ in the description of the formulae (10-1) and (10-2). Additionally, these groups may have some or all of hydrogen atoms substituted with a group containing a hydroxy group, a carboxy group, a halogen atom, a cyano group, a nitro group, a mercapto group, a sultone group, a sulfone group, or a sulfonium salt, while these groups may have some of carbon atoms substituted with an ether bond, an ester bond, a carbonyl group, an amide bond, a carbonate group, or a sulfonic acid ester group. Alternatively, R⁴⁰² and R⁴⁰³ may bond with each other to form a ring together with a sulfur atom bonded therewith. In this event, examples of the ring include those exemplified as the ring which can be formed by bonding R¹⁰¹ and R¹⁰² together with the sulfur atoms in the description of the formula (10-1).

Examples of the cation of the sulfonium salt shown by the formula (3-1) include those exemplified as cations of the sulfonium salt shown by the formula (10-1). Meanwhile, examples of the cation of the iodonium salt shown by the formula (3-2) include those exemplified as cations of the iodonium salt shown by the formula (10-2).

Examples of the anion of the onium salt shown by the formula (3-1) or (3-2) include ones shown below, but are not limited thereto. Note that, in the following formulae, X^{BI} is as defined above.

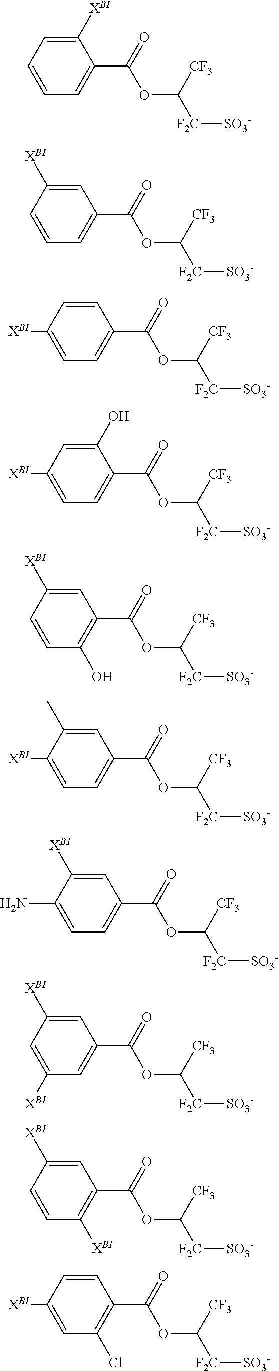

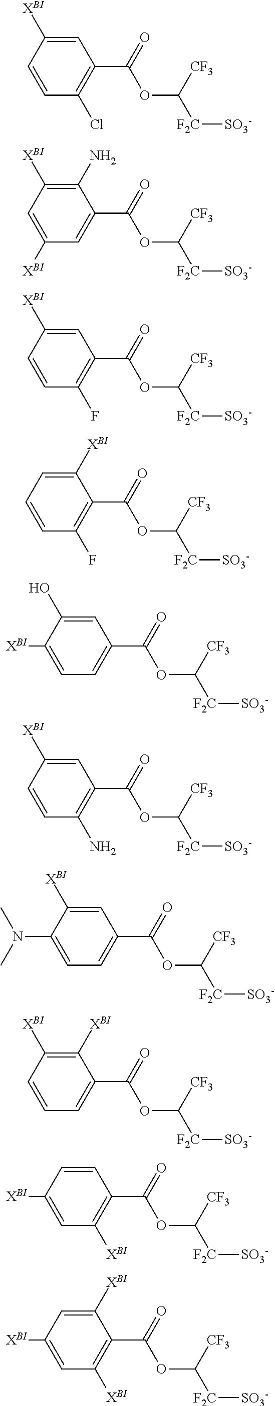

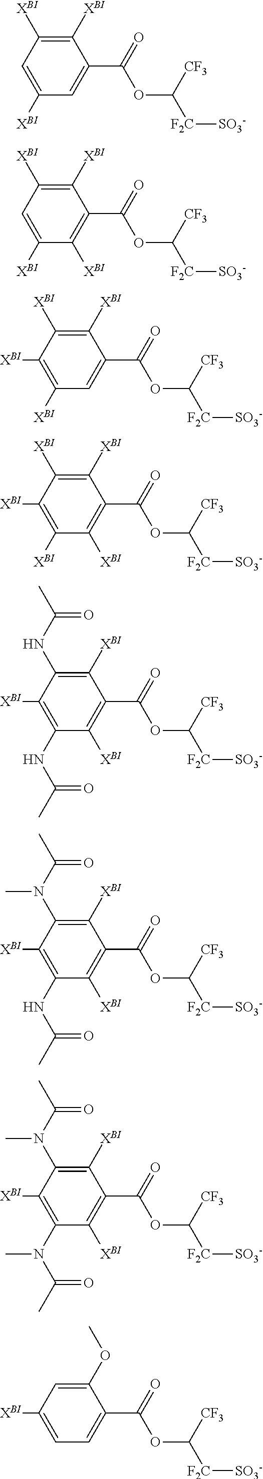

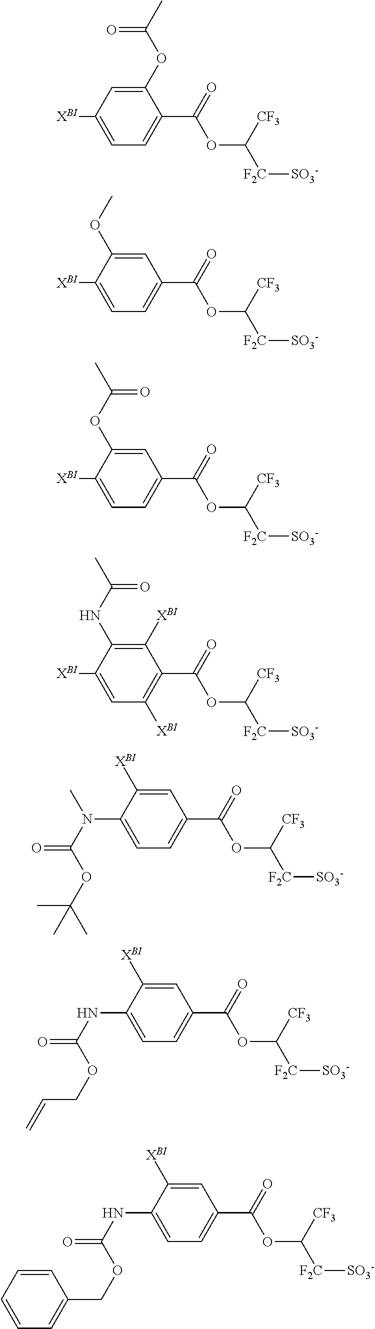

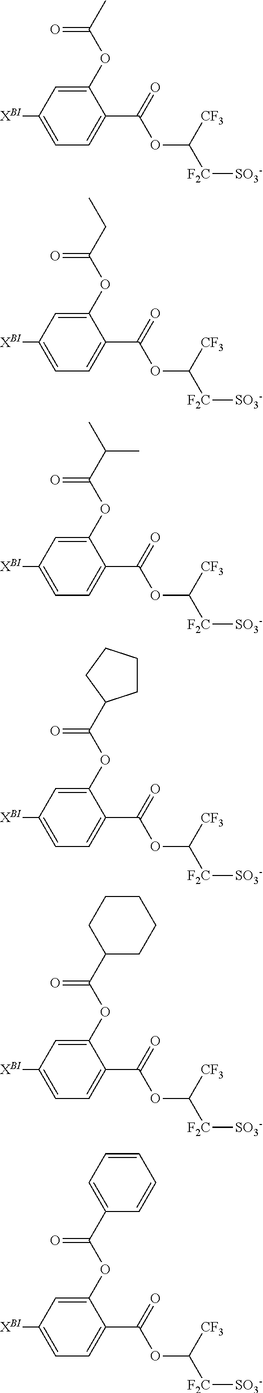

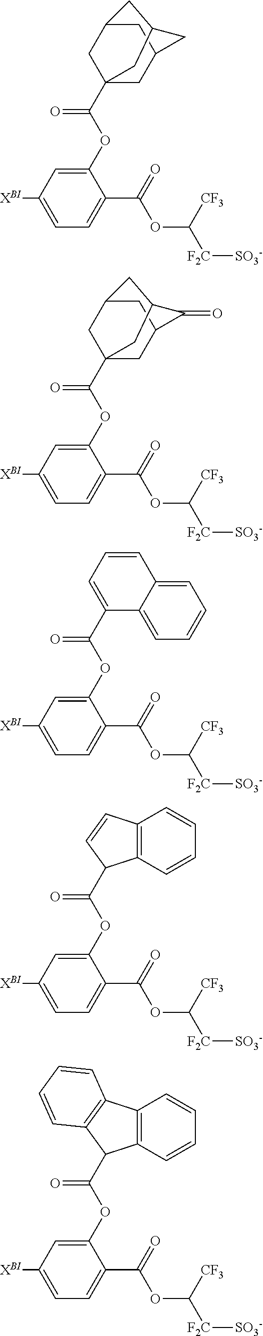

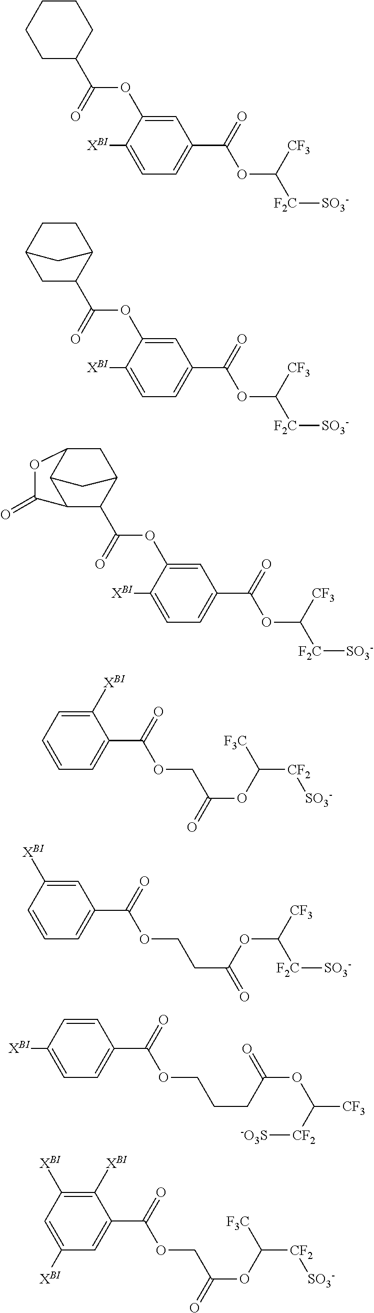

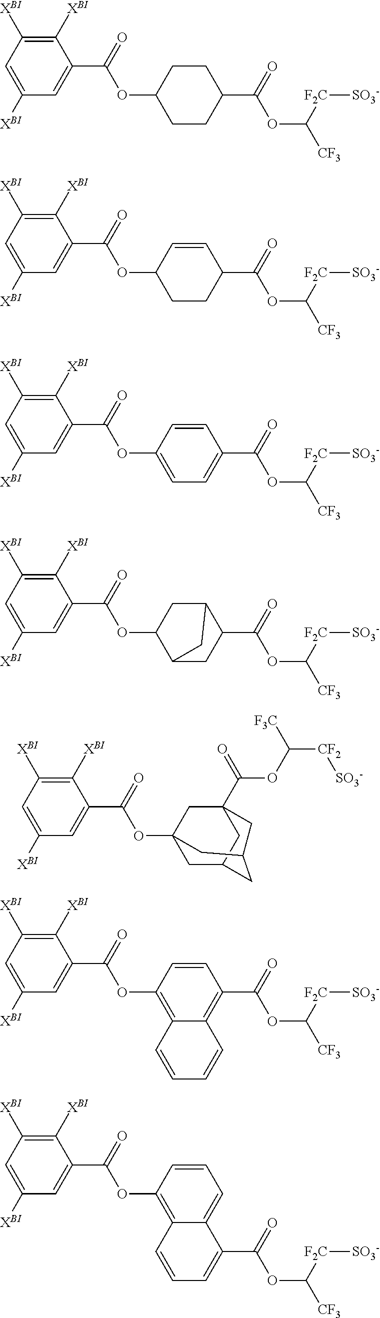

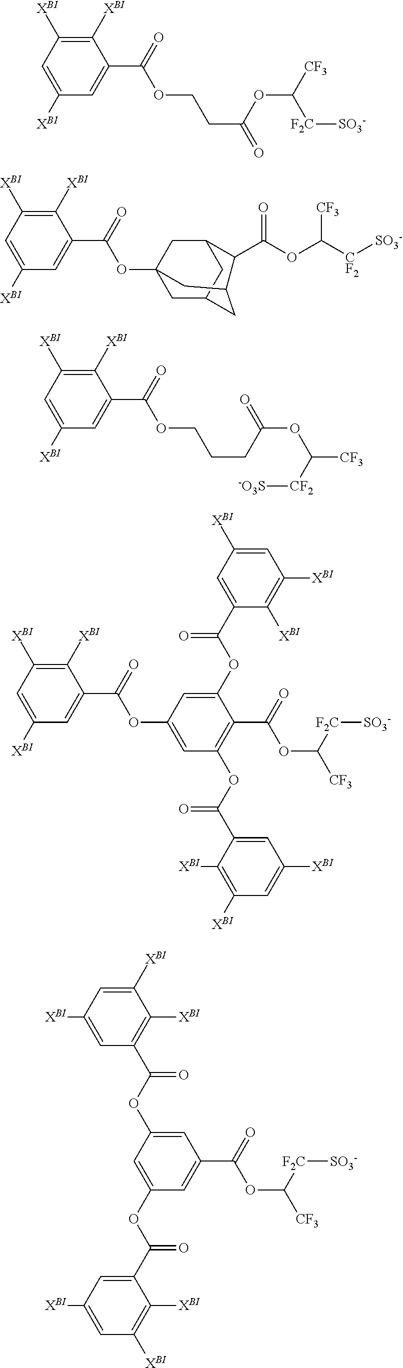

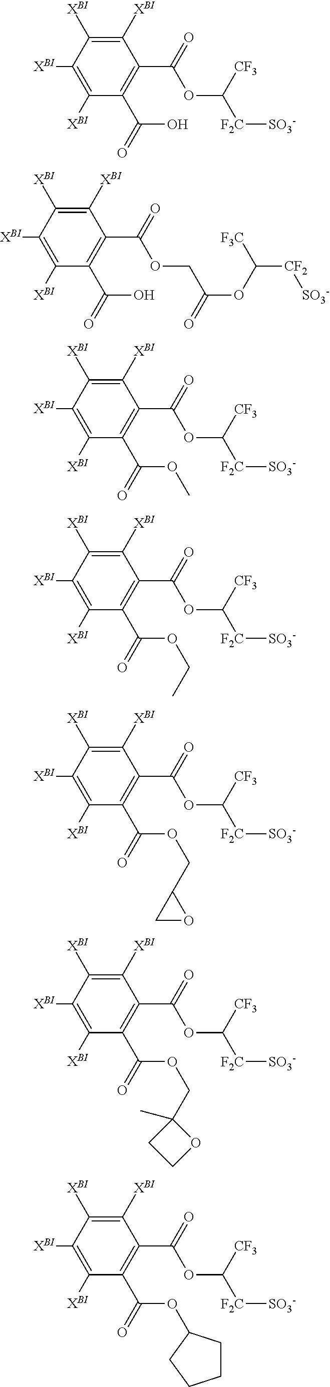

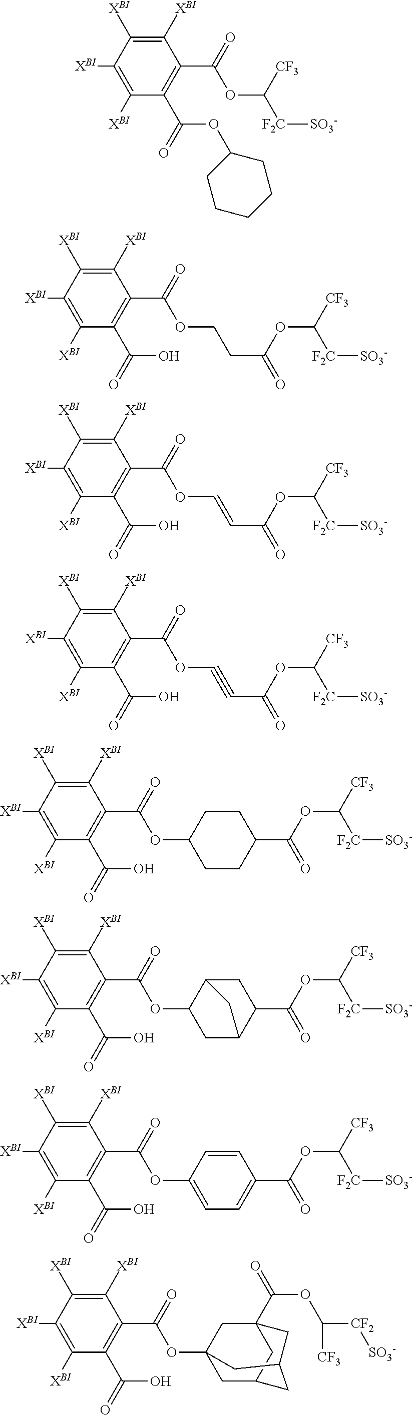

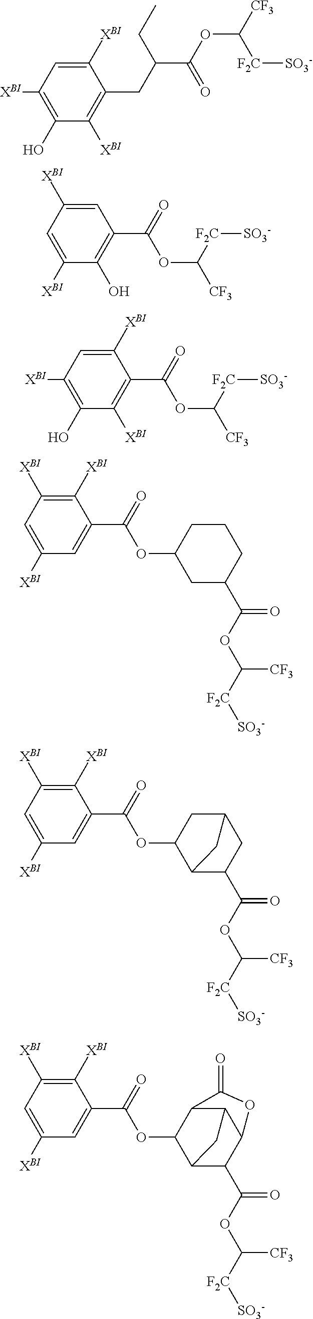

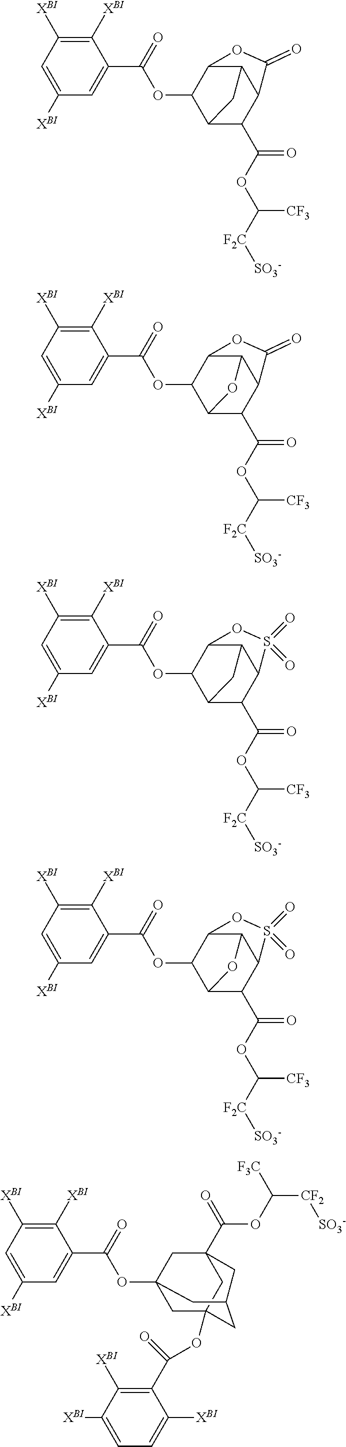

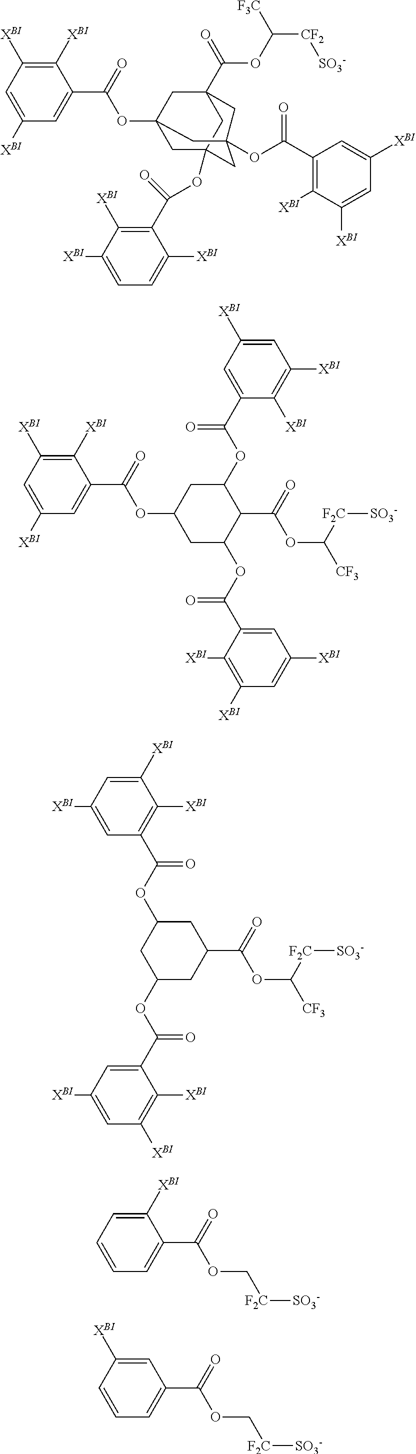

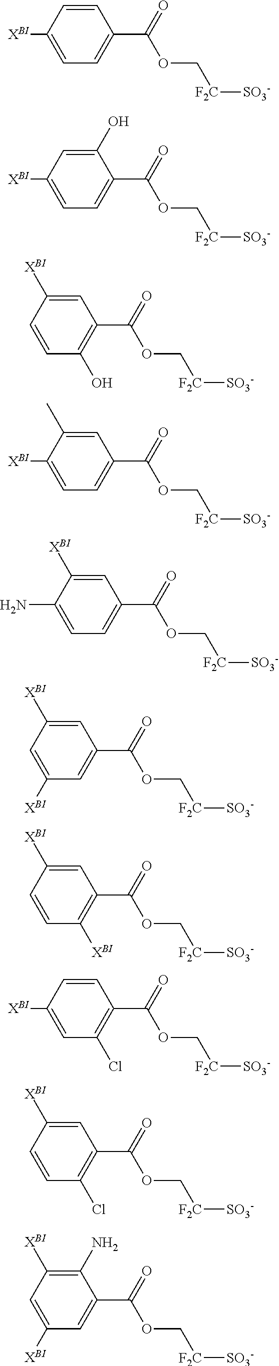

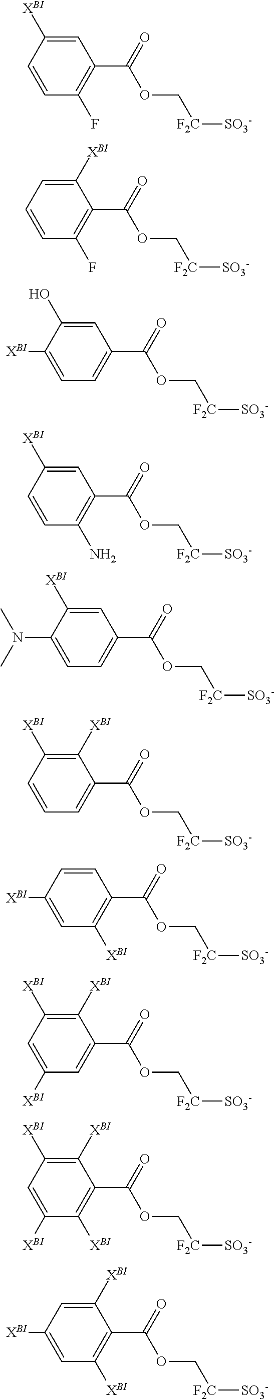

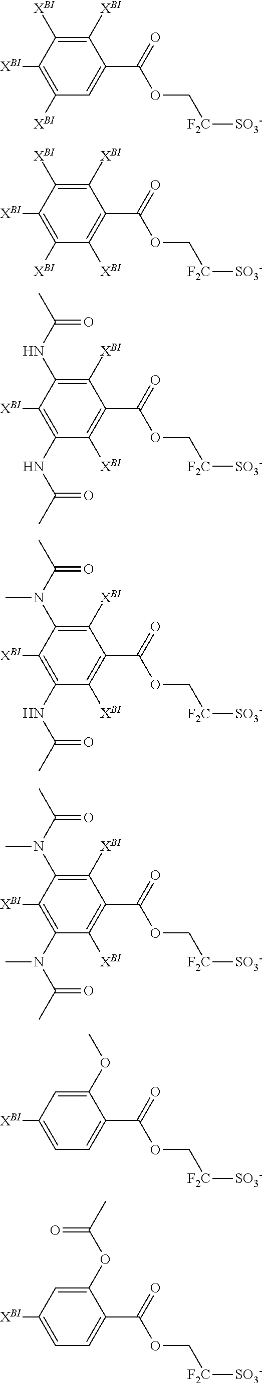

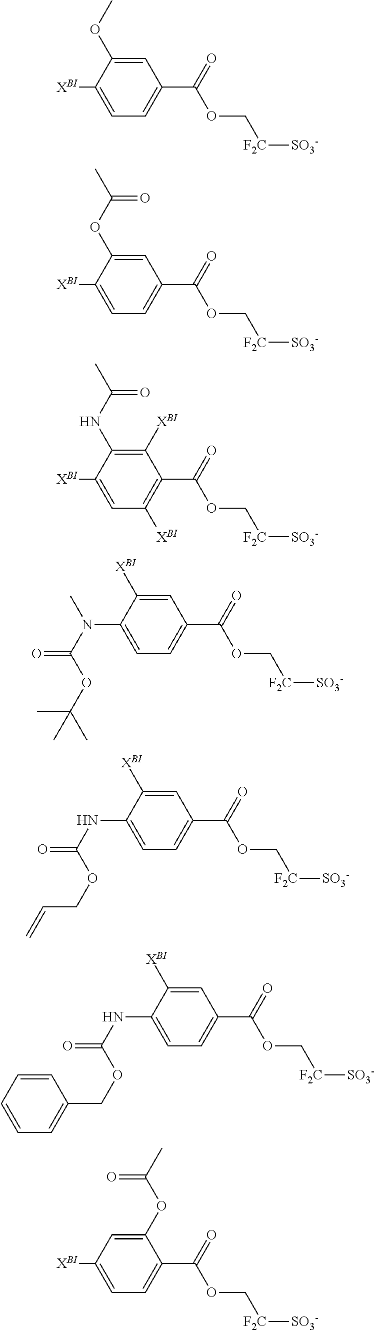

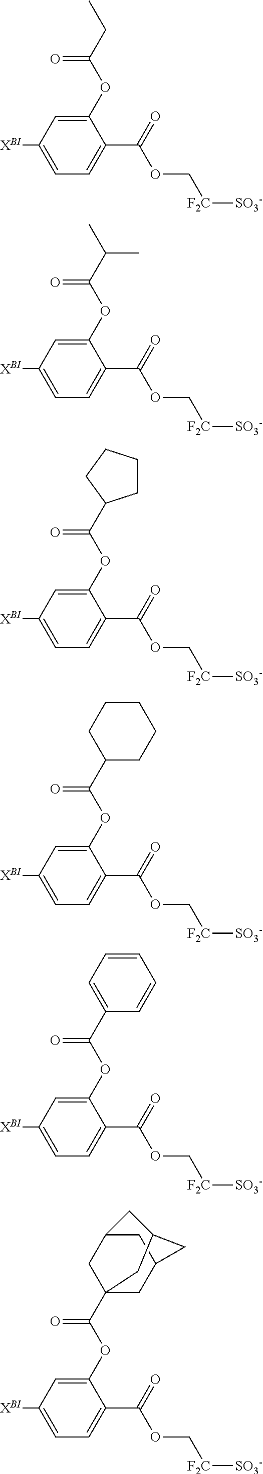

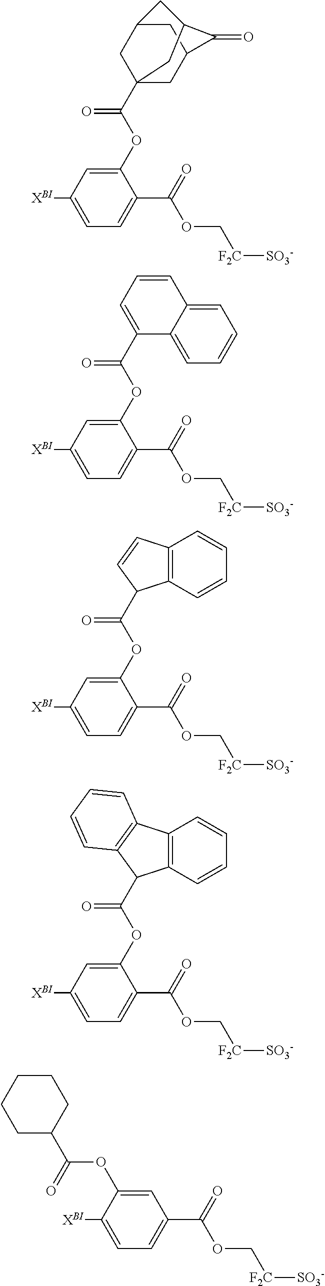

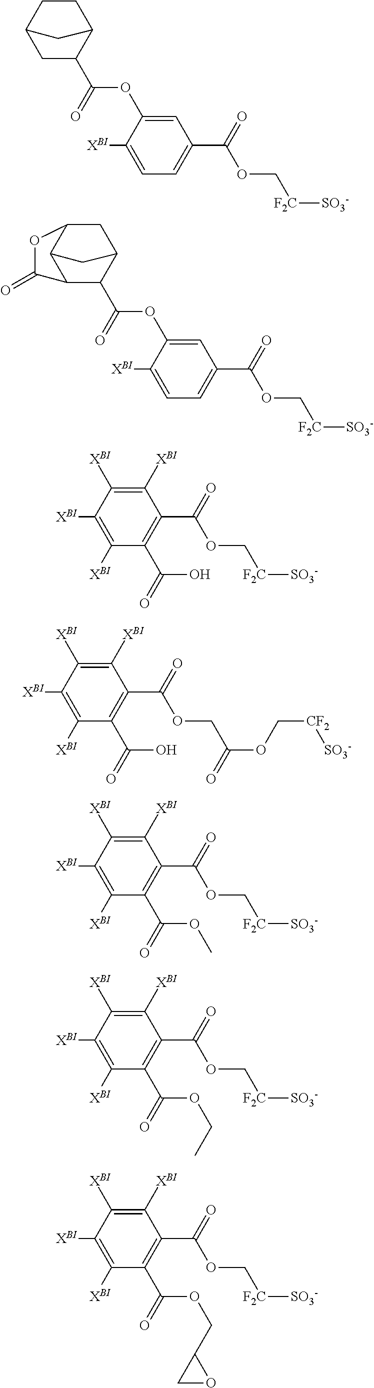

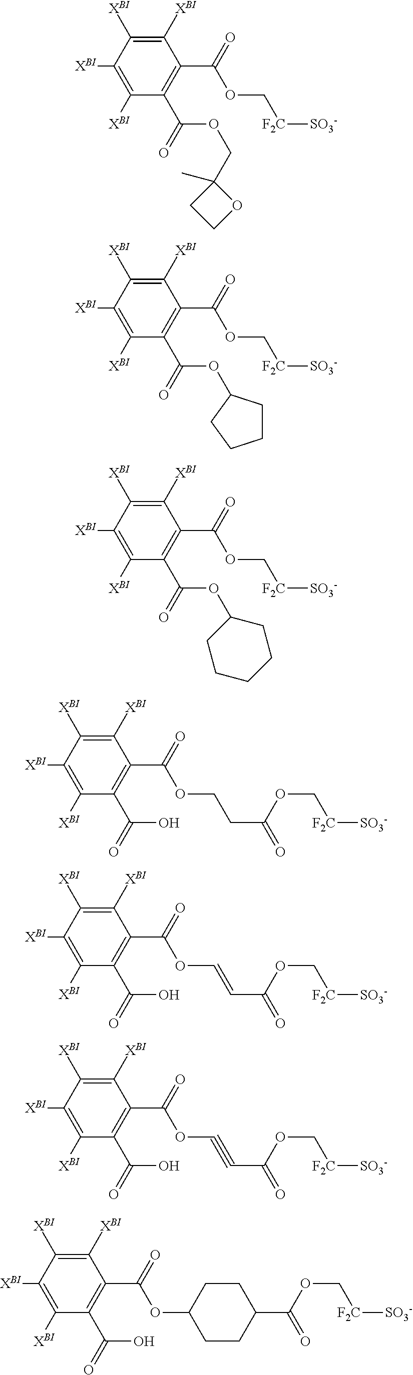

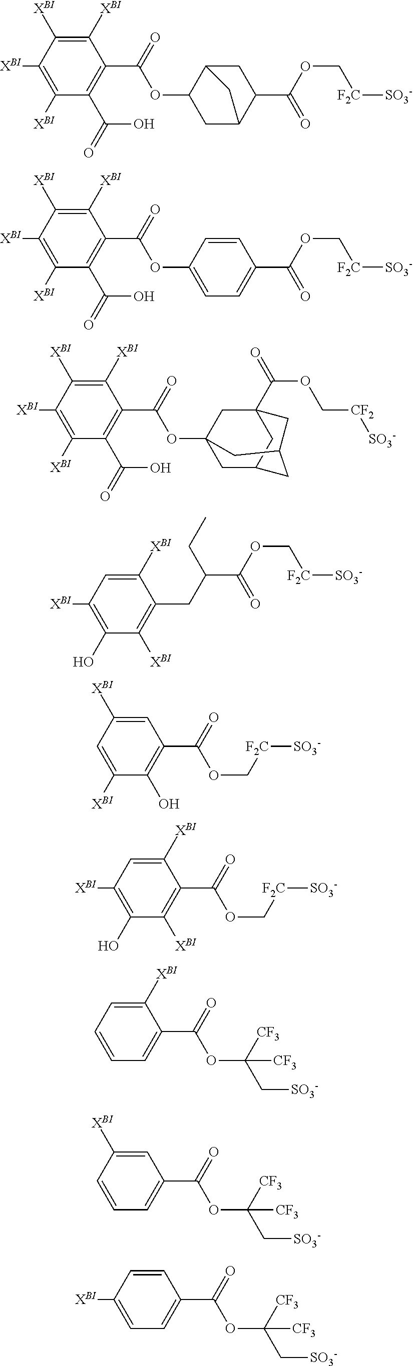

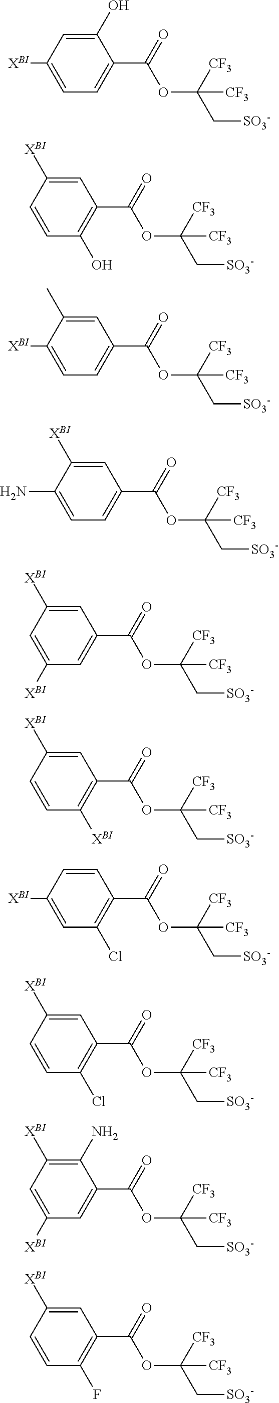

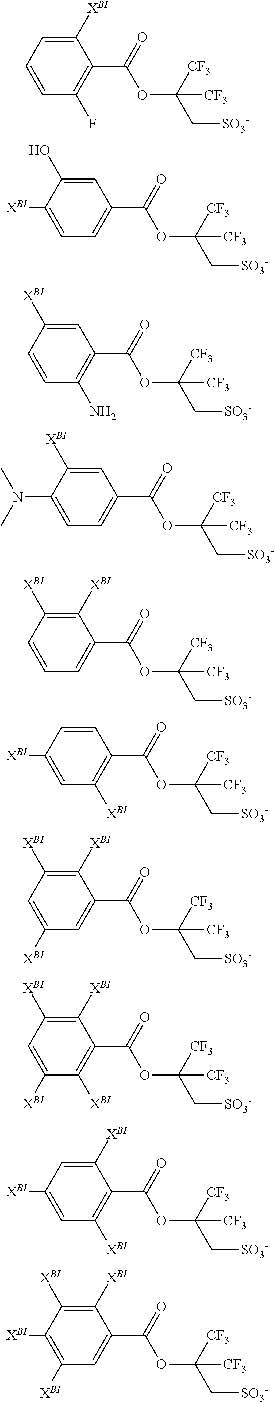

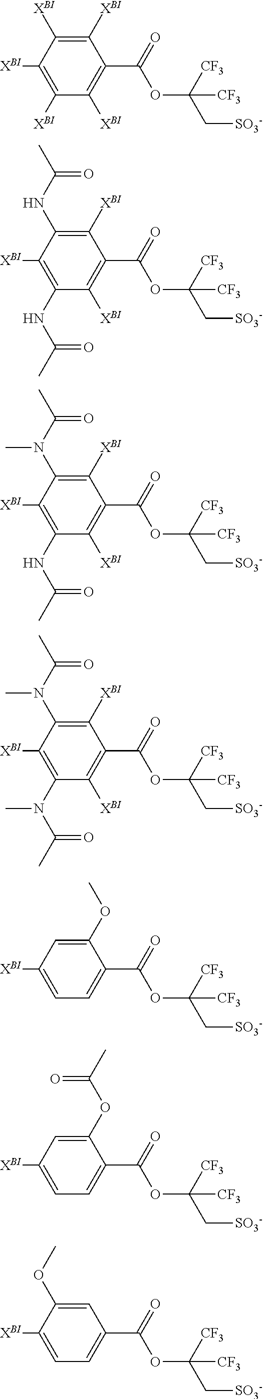

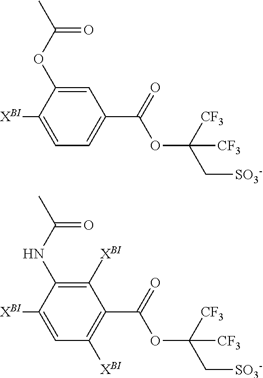

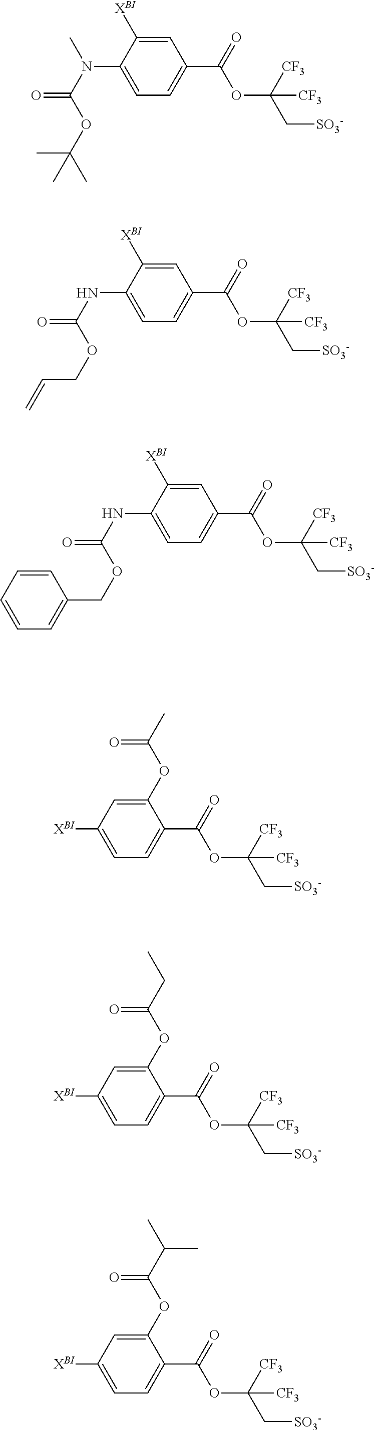

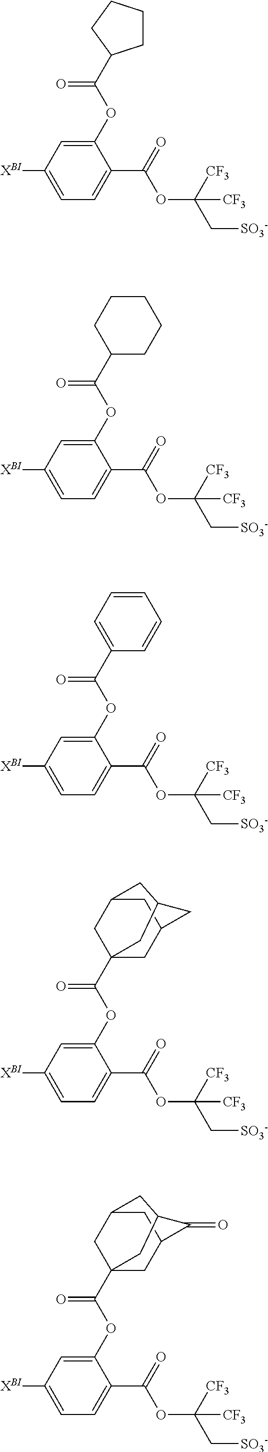

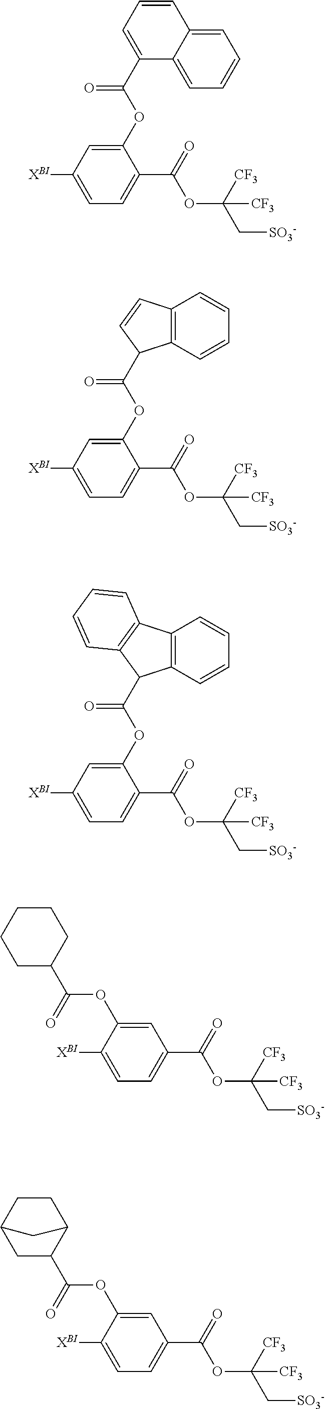

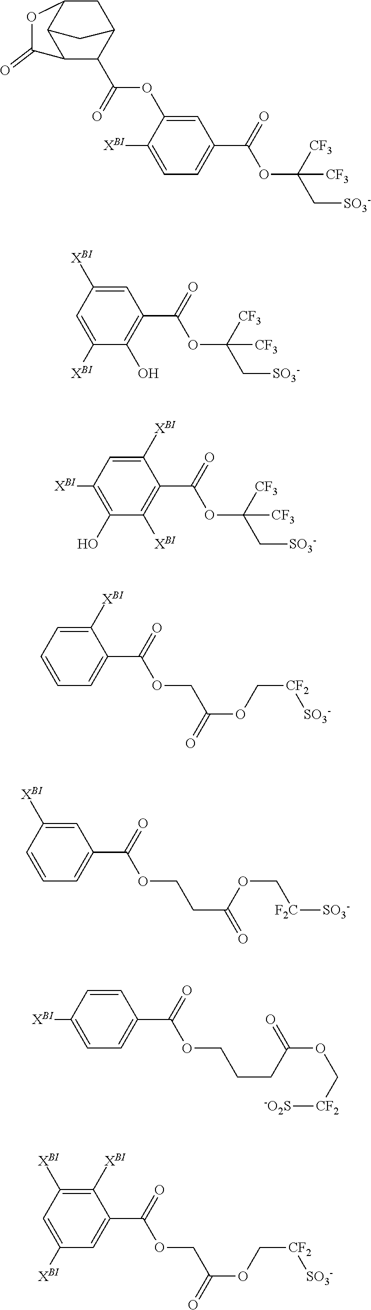

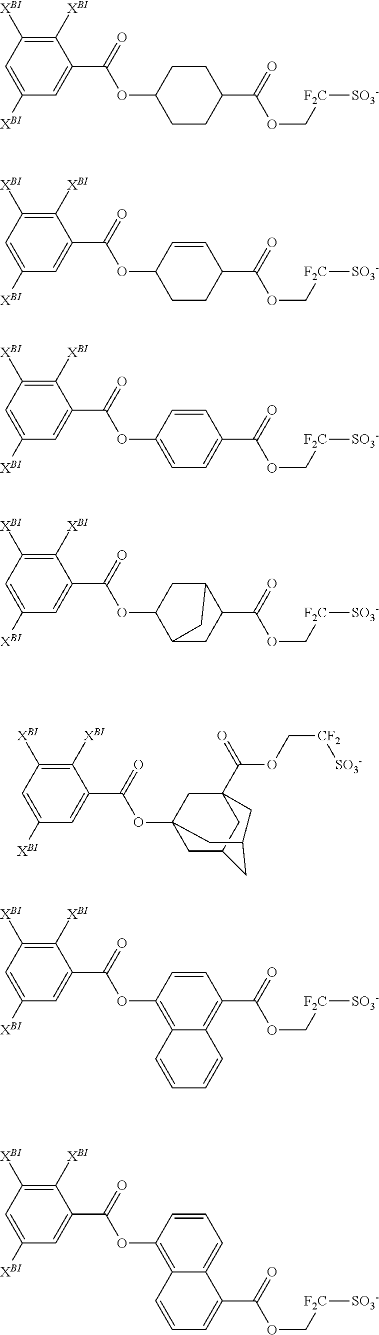

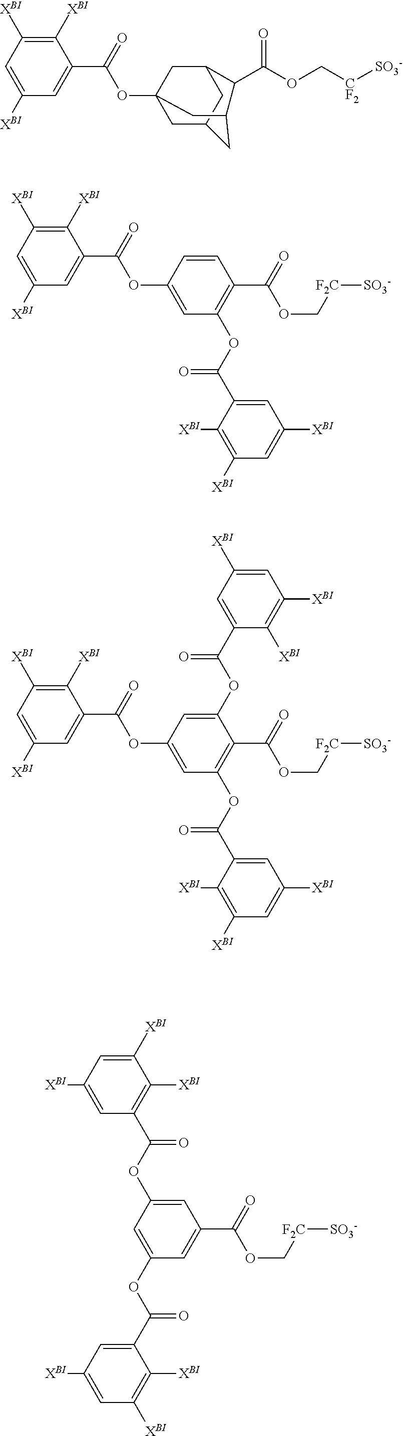

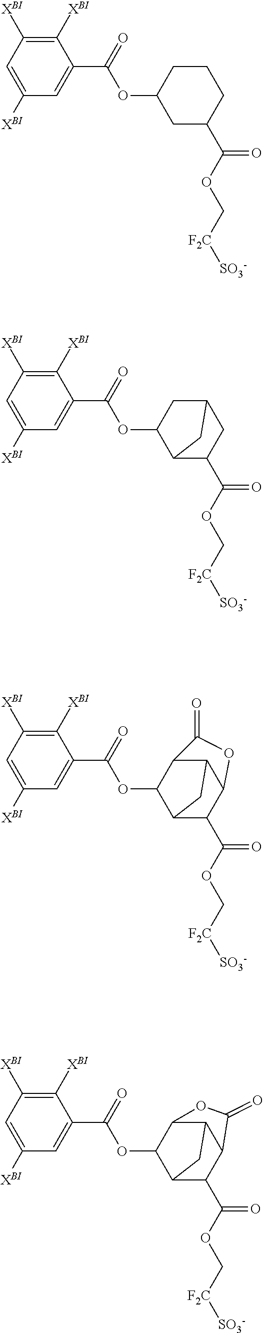

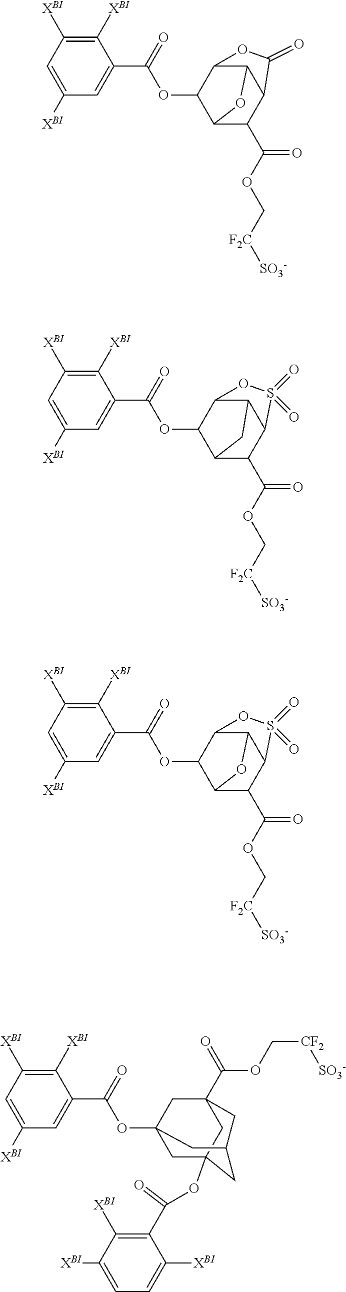

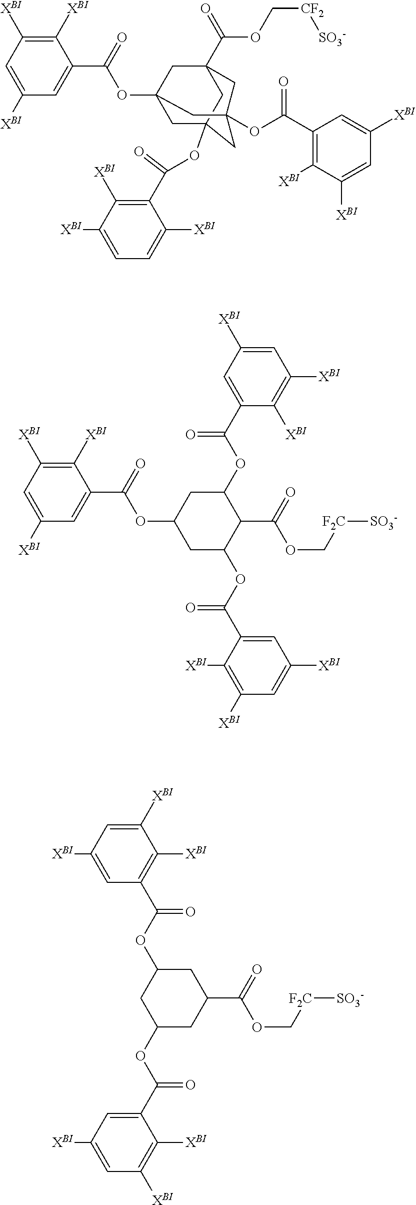

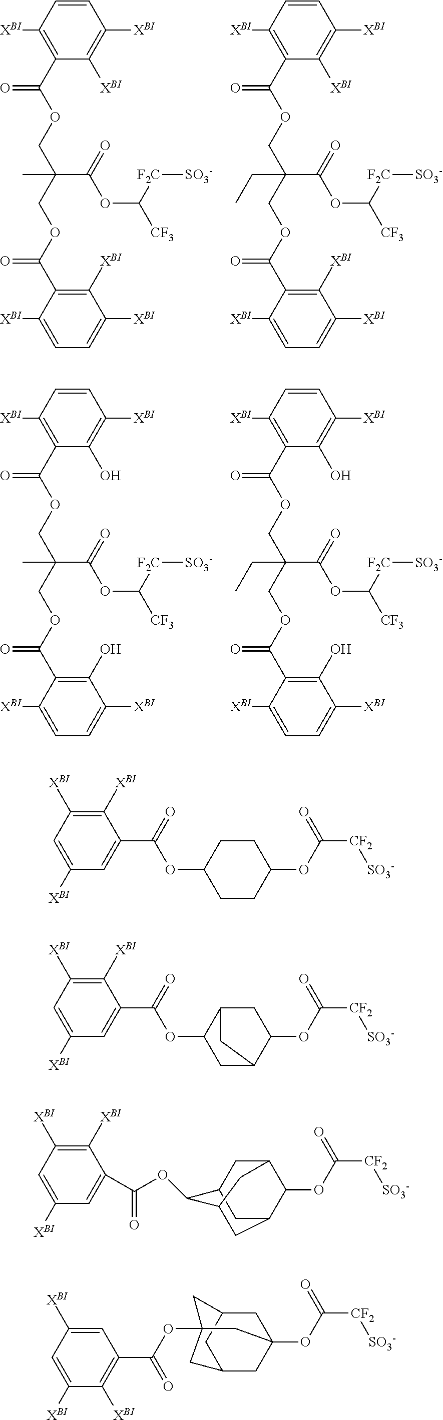

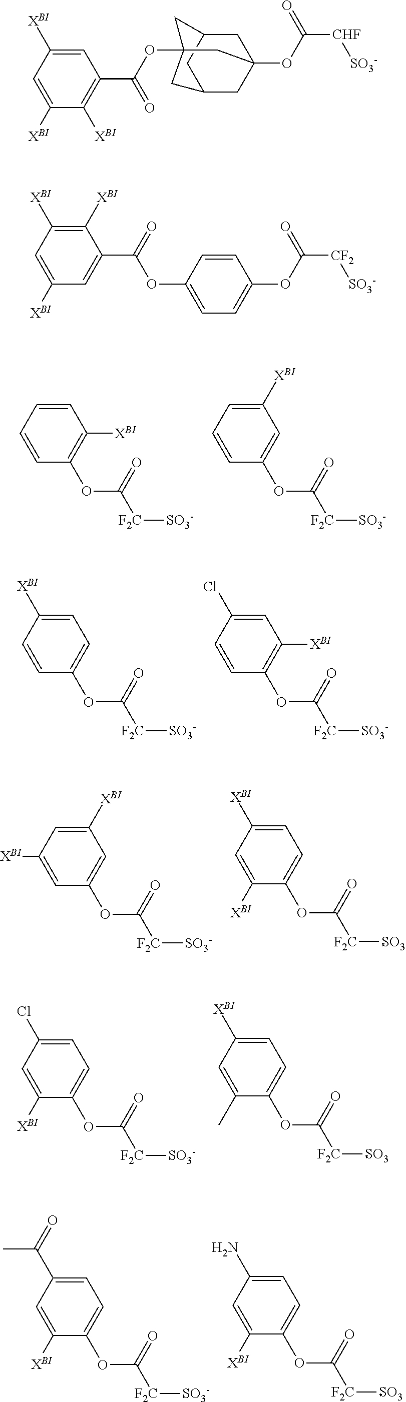

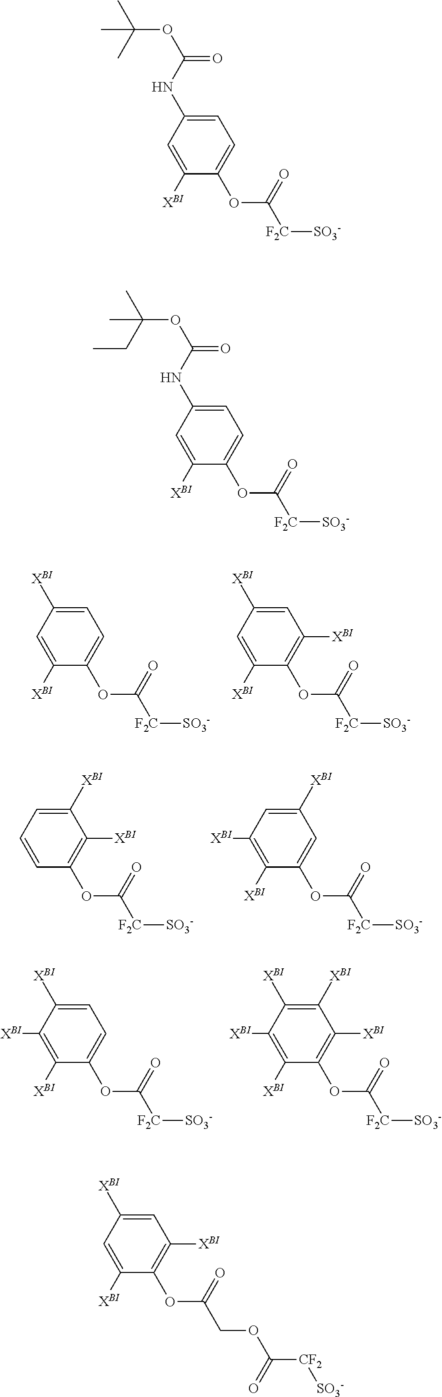

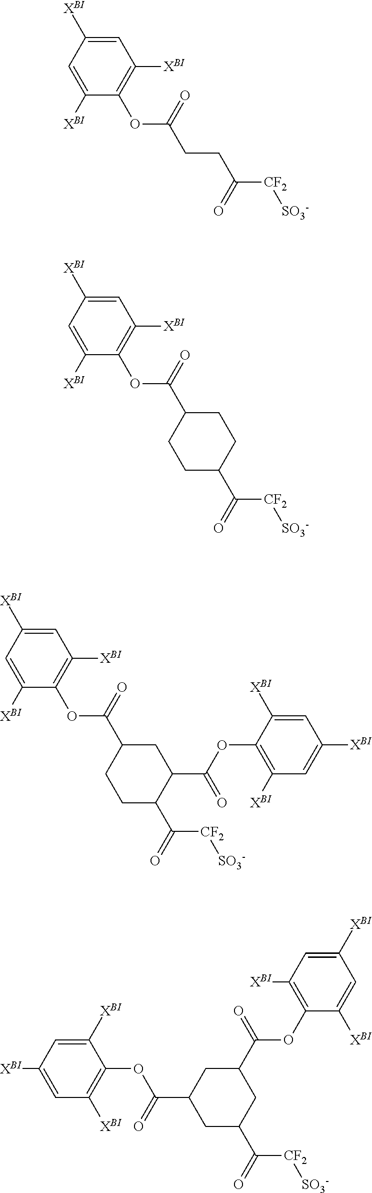

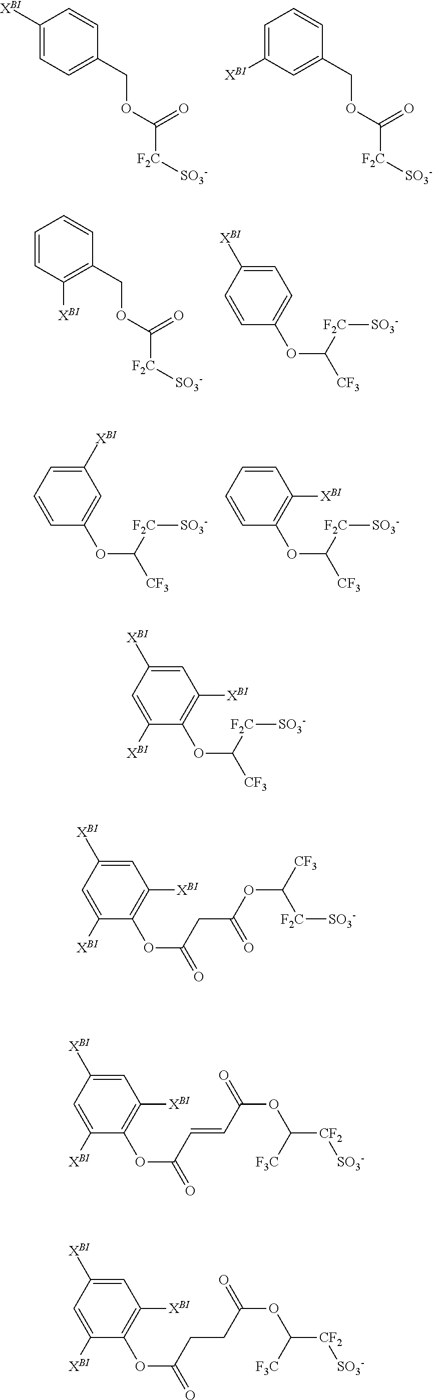

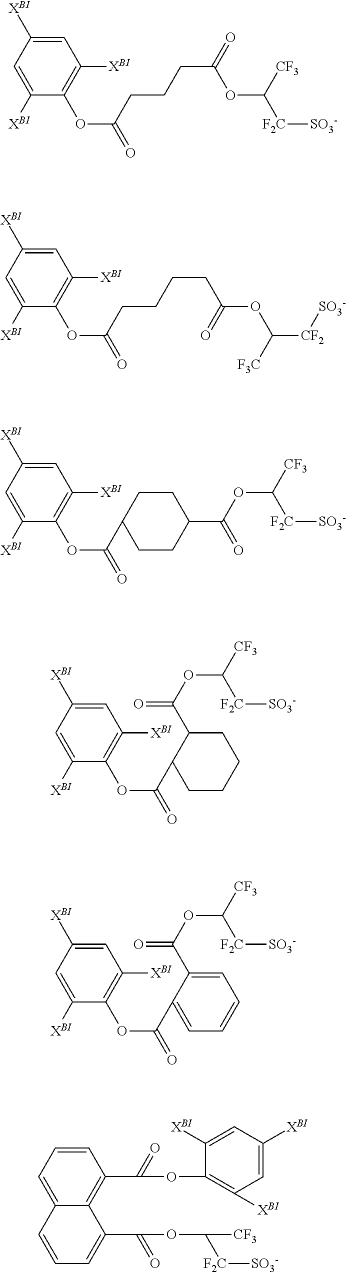

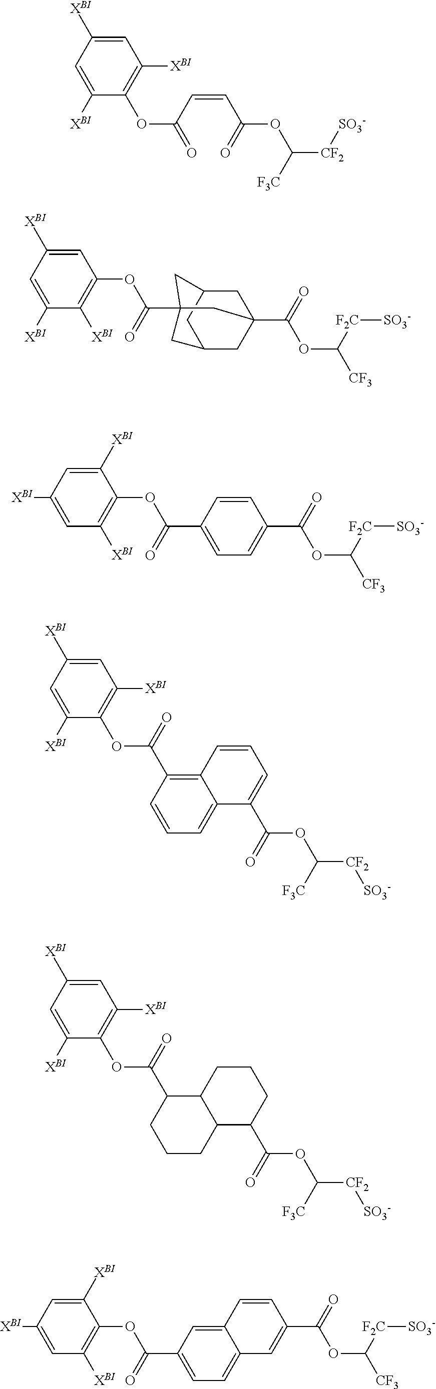

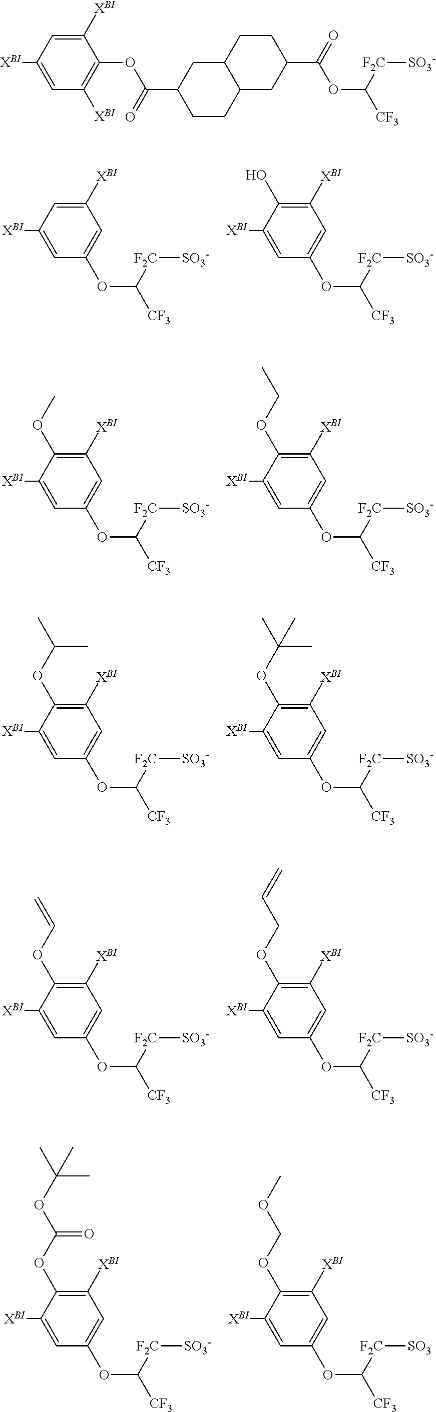

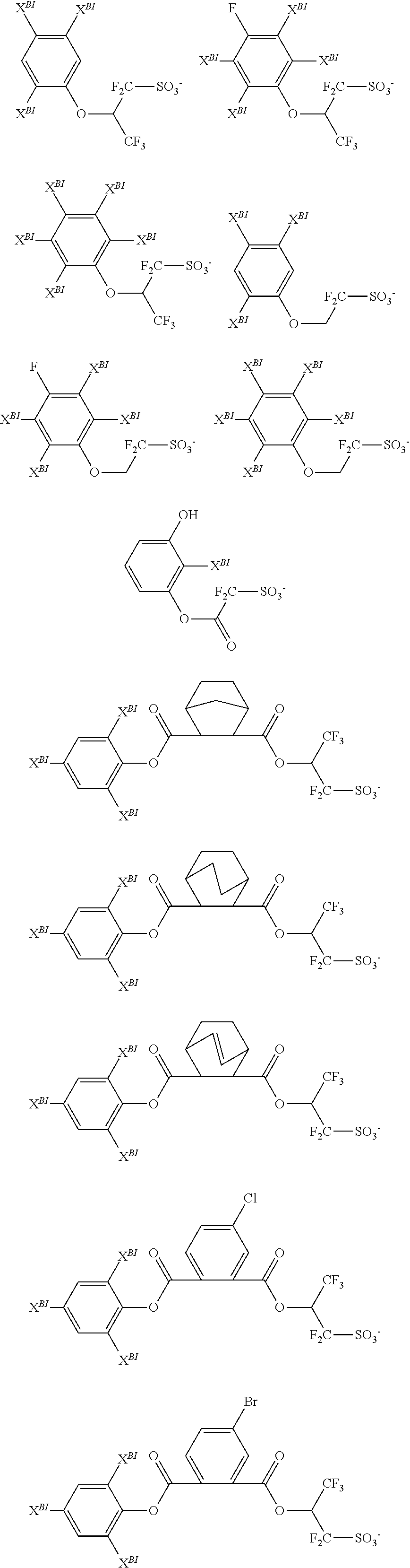

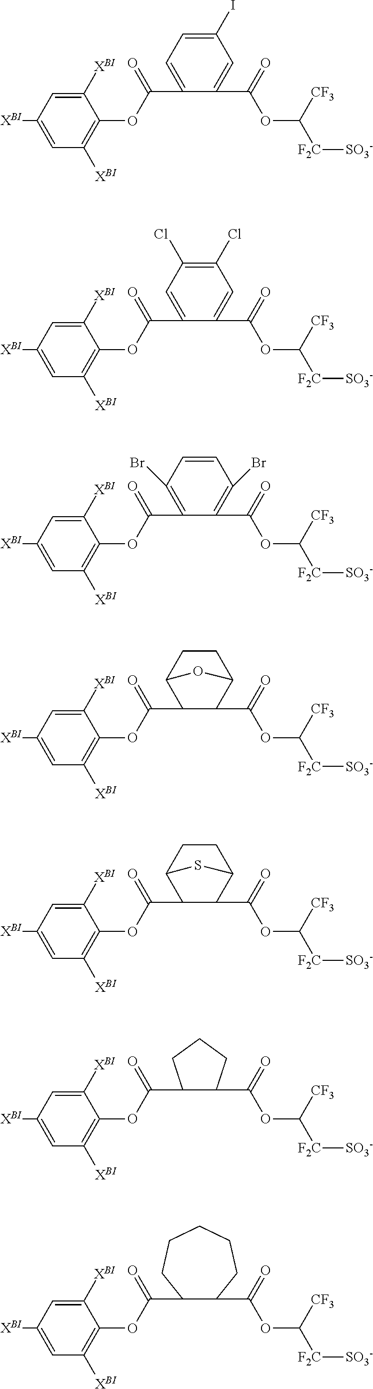

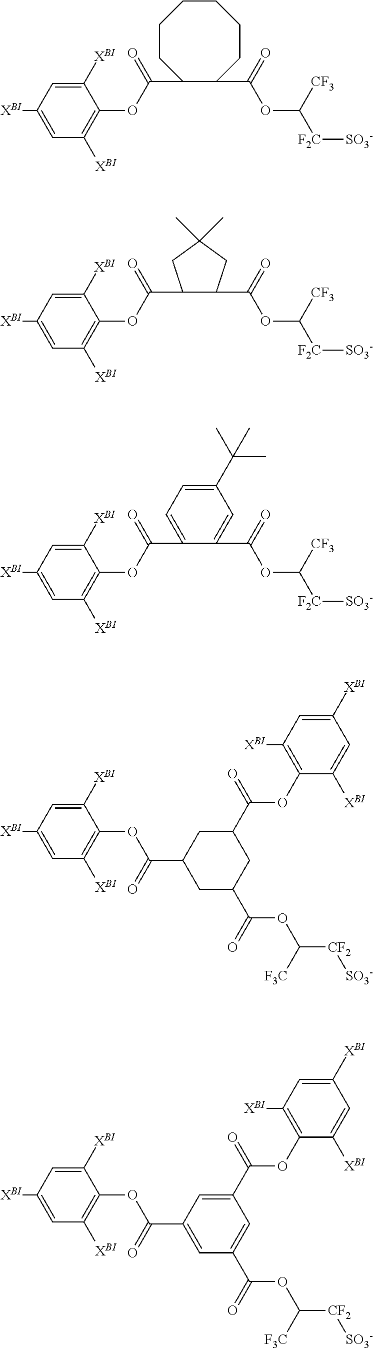

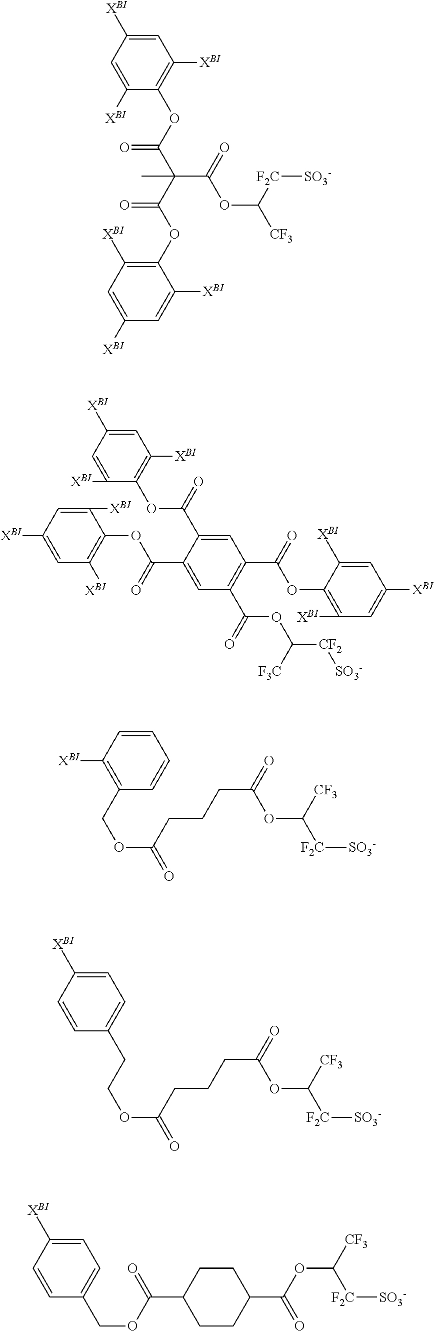

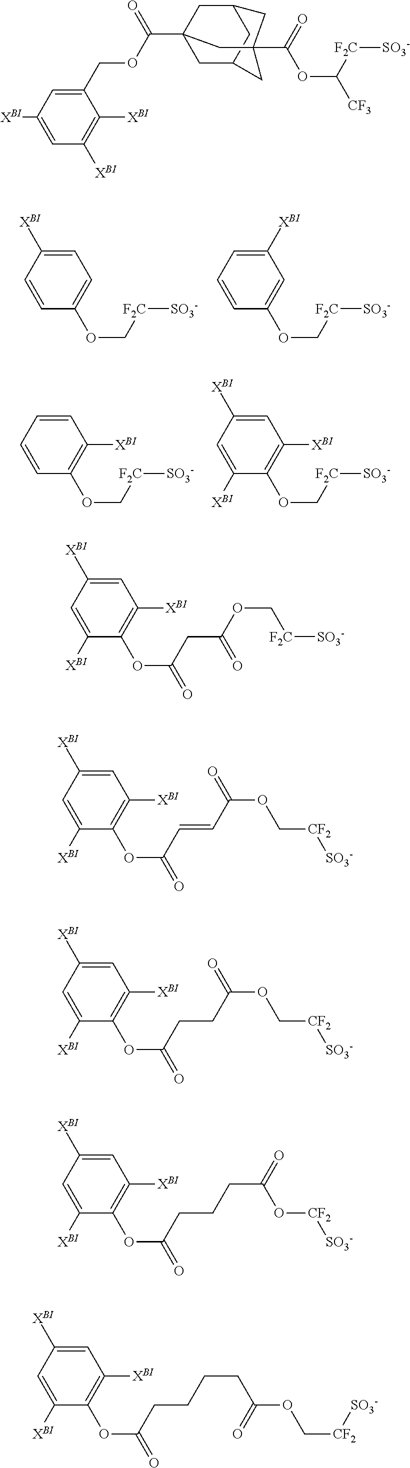

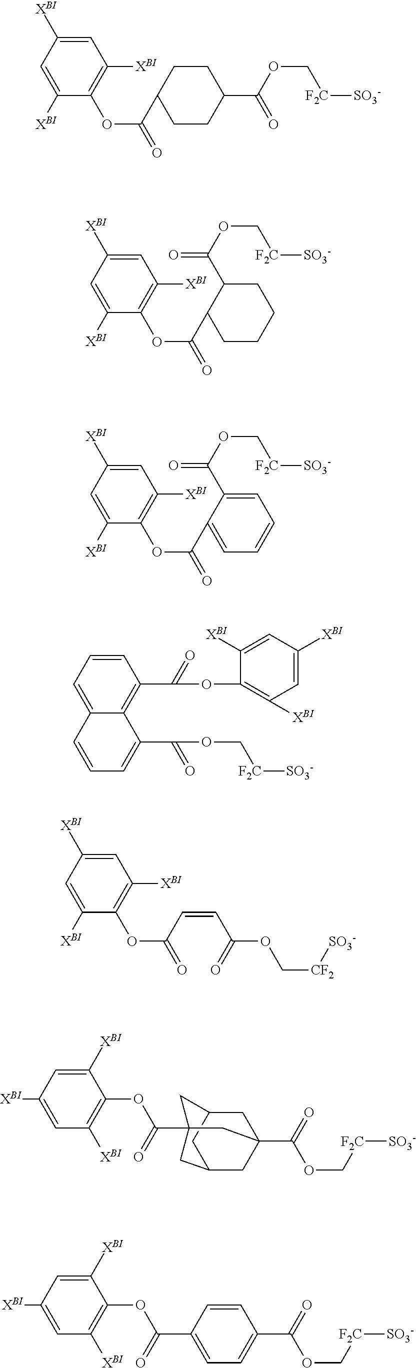

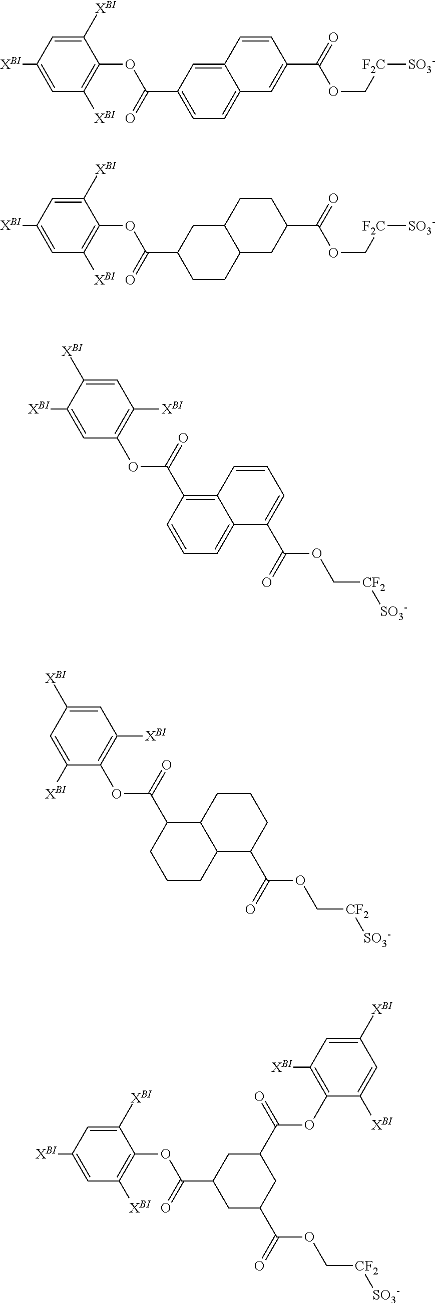

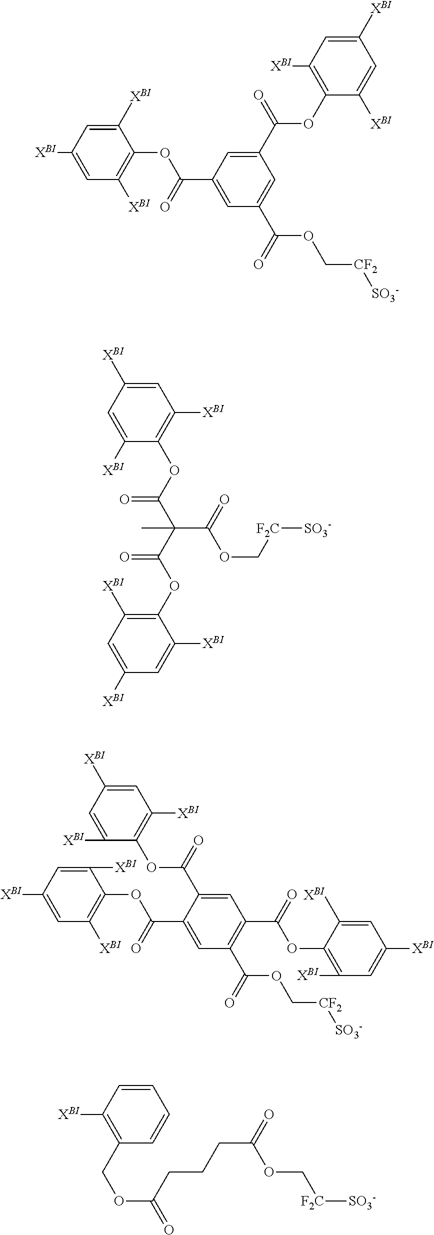

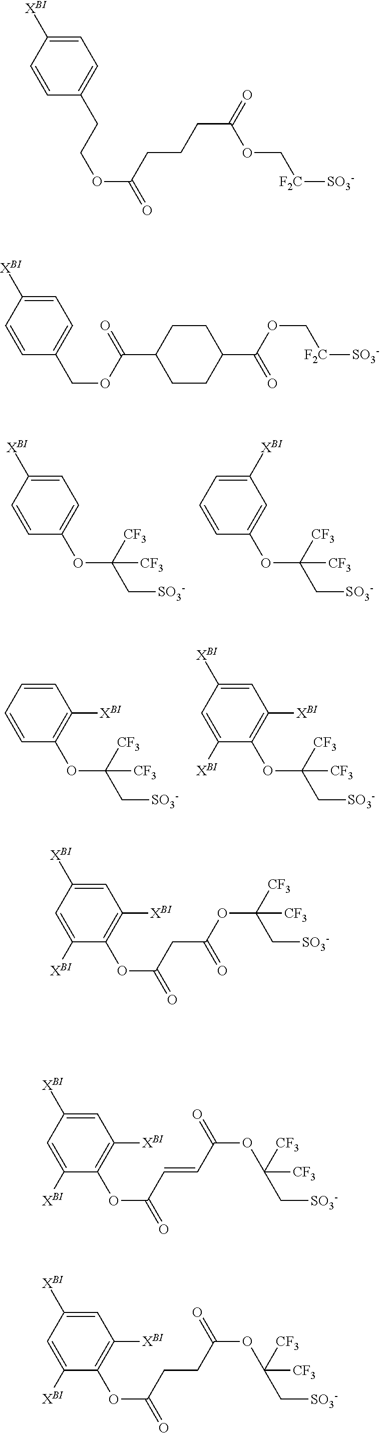

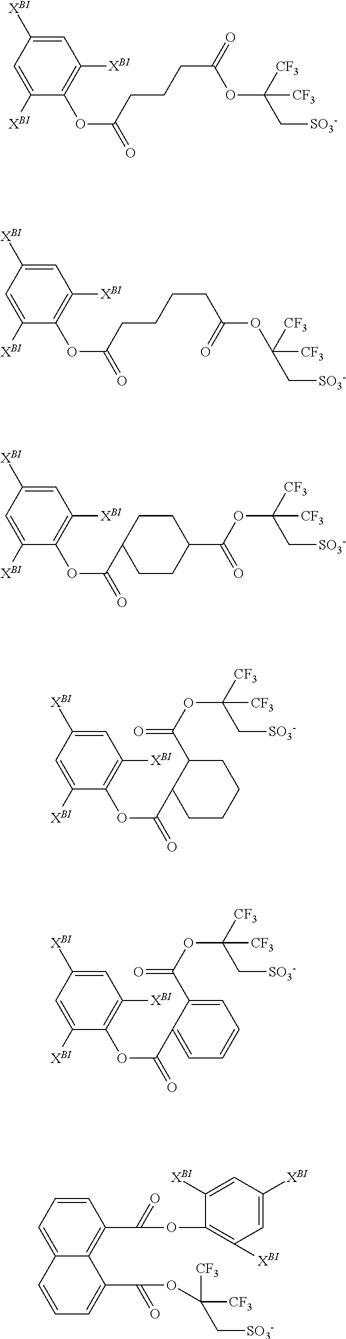

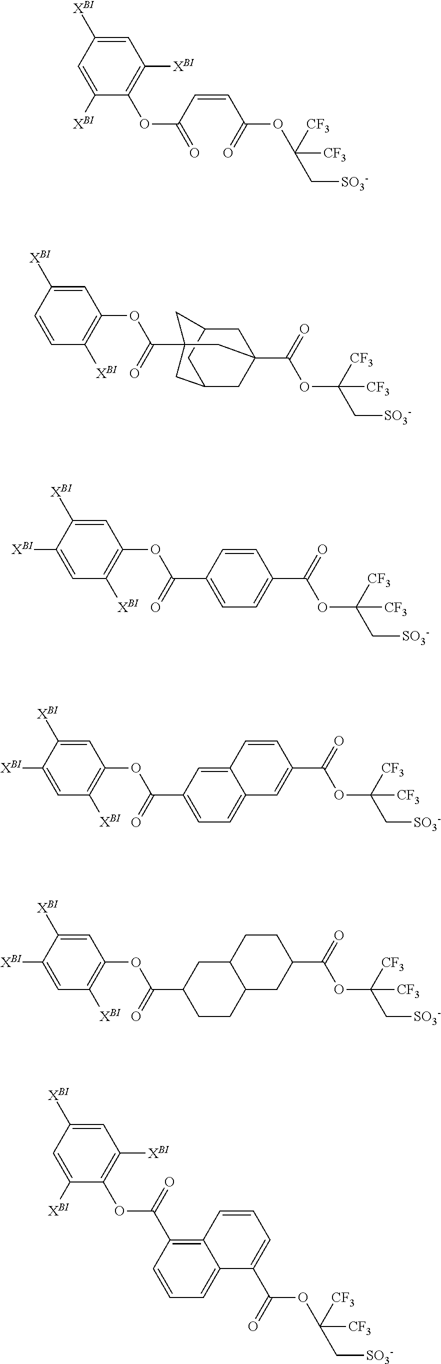

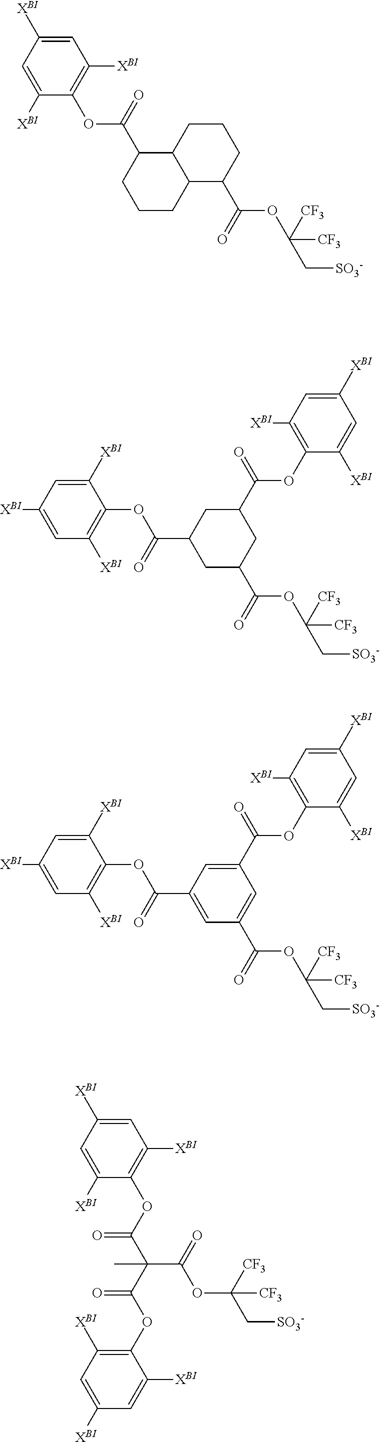

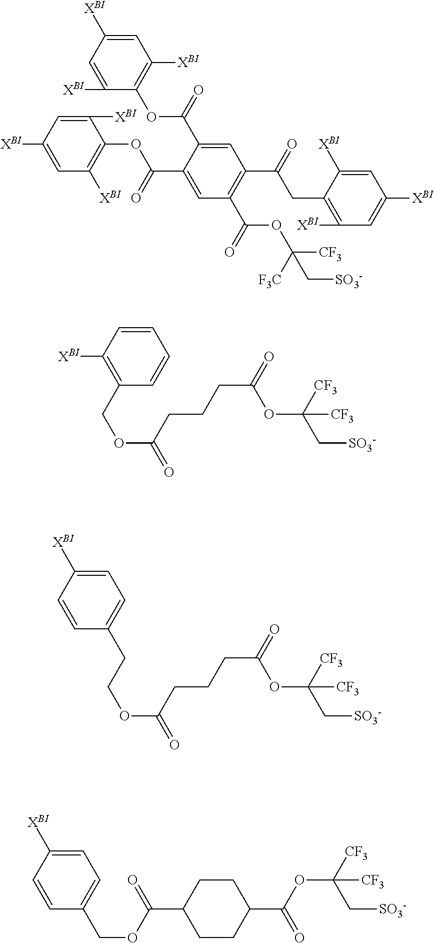

The inventive positive resist material contains the additive-type acid generator in an amount of preferably 0.1 to 50 parts by mass, more preferably 1 to 40 parts by mass, based on 100 parts by mass of the base polymer. Incorporating the repeating unit-a1 and/or -a2 into the base polymer, and in some cases incorporating the additive-type acid generator enables the inventive positive resist material to function as a chemically amplified positive resist material.

### [Organic Solvent]

The inventive positive resist material may be blended with an organic solvent. This organic solvent is not particularly limited, as long as it is capable of dissolving the above-described base polymer, as well as an additive-type acid generator and components described below, if contained. Examples of such an organic solvent include ones disclosed in paragraphs [0144] to [0145] of JP 2008-111103 A: ketones, such as cyclohexanone, cyclopentanone, and methyl-2-n-pentyl ketone, and 2-heptanone; alcohols, such as 3-methoxybutanol, 3-methyl-3-methoxybutanol, 1-methoxy-2-propanol, 1-ethoxy-2-propanol, and diacetone alcohol; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as γ-butyrolactone; mixed solvents thereof; etc.

The inventive positive resist material contains the organic solvent in an amount of preferably 100 to 10,000 parts by mass, more preferably 200 to 8,000 parts by mass, based on 100 parts by mass of the base polymer.

### [Quencher]

The inventive positive resist material may be blended with a quencher other than a quencher which is a sulfonium salt containing at least one fluorine atom in both an anion moiety of a carboxylate ion or a sulfonamide ion and a cation moiety of a sulfonium ion. Examples of the quencher include conventional basic compounds. Examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amides, imides, carbamates, etc. Particularly preferable are primary, secondary, and tertiary amine compounds disclosed in paragraphs [0146] to [0164] of JP 2008-111103 A; especially, amine compounds having a hydroxy group, an ether bond, an ester bond, a lactone ring, a cyano group, or a sulfonic acid ester group; compounds having a carbamate group disclosed in JP 3790649 B; etc. Adding such a basic compound can, for example, further suppress the acid diffusion rate in the resist film and correct the shape.

Other examples of the quencher include onium salts such as sulfonium salts, iodonium salts, and ammonium salts of carboxylic acids and sulfonic acids which are not fluorinated at α position as disclosed in JP 2008-158339 A. While α-fluorinated sulfonic acid, imide acid, or methide acid is necessary to deprotect the acid labile group of carboxylic acid ester, a carboxylic acid or sulfonic acid not fluorinated at a position is released by salt exchange with the onium salt not fluorinated at a position. Such carboxylic acid and sulfonic acid not fluorinated at a position hardly induce deprotection reaction, and thus function as quenchers.

Examples of such quenchers include a compound shown by the following general formula (4) (onium salt of sulfonic acid not fluorinated at a position) and a compound shown by the following general formula (5) (onium salt of carboxylic acid).

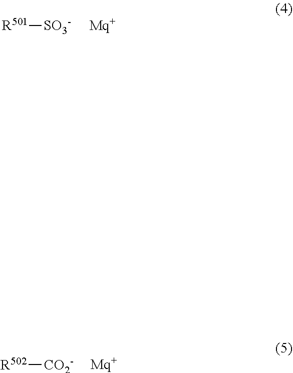

In the formula (4), R⁵⁰¹ represents a hydrogen atom or a hydrocarbyl group having 1 to 40 carbon atoms and optionally containing a heteroatom, but excludes groups in which a hydrogen atom bonded to the carbon atom at a position of the sulfo group is substituted with a fluorine atom or a fluoroalkyl group.

The hydrocarbyl group may be saturated or unsaturated, and may be linear, branched, or cyclic. Specific examples thereof include: alkyl groups such as a methyl group, an ethyl group, a propyl group, an isopropyl group, an n-butyl group, a sec-butyl group, a tert-butyl group, a tert-pentyl group, an n-pentyl group, an n-hexyl group, an n-octyl group, a 2-ethylhexyl group, an n-nonyl group, and an n-decyl group; cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups such as a vinyl group, an allyl group, a propenyl group, a butenyl group, and a hexenyl group; cyclic unsaturated aliphatic hydrocarbyl groups such as a cyclohexenyl group; aryl groups such as a phenyl group, a naphthyl group, alkylphenyl groups (such as a 2-methylphenyl group, a 3-methylphenyl group, a 4-methylphenyl group, a 4-ethylphenyl group, a 4-tert-butylphenyl group, and a 4-n-butylphenyl group), dialkylphenyl groups (such as a 2,4-dimethylphenyl group and a 2,4,6-triisopropylphenyl group), alkylnaphthyl groups (such as a methylnaphthyl group and an ethylnaphthyl group), and dialkylnaphthyl groups (such as a dimethylnaphthyl group and a diethylnaphthyl group); heteroaryl groups, such as a thienyl group; aralkyl groups, such as a benzyl group, a 1-phenylethyl group, and a 2-phenylethyl group; etc.

Moreover, these groups may have some of hydrogen atoms substituted with a group containing a heteroatom such as an oxygen atom, a sulfur atom, a nitrogen atom, or a halogen atom, while these groups may have some of carbon atoms substituted with a group containing a heteroatom such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester group, a carbonate bond, a lactone ring, a sultone ring, carboxylic anhydride, a haloalkyl group, etc. Examples of the hydrocarbyl group containing a heteroatom include: alkoxyphenyl groups such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups such as a methoxynaphthyl group, an ethoxynaphthyl group, an n-propoxynaphthyl group, and an n-butoxynaphthyl group; dialkoxynaphthyl groups such as a dimethoxynaphthyl group and a diethoxynaphthyl group; aryloxoalkyl groups such as 2-aryl-2-oxoethyl groups including a 2-phenyl-2-oxoethyl group, a 2-(1-naphthyl)-2-oxoethyl group, and a 2-(2-naphthyl)-2-oxoethyl group; etc.

In the formula (5), R⁵⁰² represents a hydrocarbyl group having 1 to 40 carbon atoms and optionally containing a heteroatom. Examples of the hydrocarbyl group represented by R⁵⁰² include those exemplified as the hydrocarbyl group represented by R⁵⁰¹. Other specific examples thereof include fluorine-containing alkyl groups such as a trifluoromethyl group, a trifluoroethyl group, a 2,2,2-trifluoro-1-methyl-1-hydroxyethyl group, and a 2,2,2-trifluoro-1-(trifluoromethyl)-1-hydroxyethyl group; fluorine-containing aryl groups such as pentafluorophenyl group and a 4-trifluoromethylphenyl group; etc. Mq⁺ represents an onium cation.

A sulfonium salt of a carboxylic acid containing an iodized benzene ring shown by the following general formula (6) can also be used suitably as a quencher.

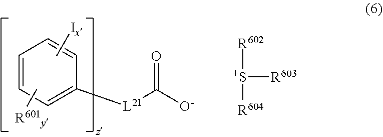

In the formula (6), R⁶⁰¹ represents: a hydroxy group, a fluorine atom, a chlorine atom, a bromine atom, an amino group, a nitro group, or a cyano group; a saturated hydrocarbyl group having 1 to 6 carbon atoms, a saturated hydrocarbyloxy group having 1 to 6 carbon atoms, a saturated hydrocarbylcarbonyloxy group having 2 to 6 carbon atoms, or a saturated hydrocarbylsulfonyloxy group having 1 to 4 carbon atoms, in each of which some or all of hydrogen atoms may be substituted with a halogen atom; or —NR^{601A}—C(═O)—R^{601B} or —NR^{601A}—C(═O)—O—R^{601B}. R^{601A} represents a hydrogen atom or a saturated hydrocarbyl group having 1 to 6 carbon atoms. R^{601B} represents a saturated hydrocarbyl group having 1 to 6 carbon atoms or an unsaturated aliphatic hydrocarbyl group having 2 to 8 carbon atoms.

In the formula (6), x′ represents an integer of 1 to 5. y′ represents an integer of 0 to 3. z′ represents an integer of 1 to 3. L²¹ represents a single bond or a linking group having a valency of (z′+1) with 1 to 20 carbon atoms, and optionally contains at least one selected from the group consisting of an ether bond, a carbonyl group, an ester bond, an amide bond, a sultone ring, a lactam ring, a carbonate group, a halogen atom, a hydroxy group, and a carboxy group. The saturated hydrocarbyl groups, saturated hydrocarbyloxy group, saturated hydrocarbylcarbonyloxy group, and saturated hydrocarbylsulfonyloxy group may be linear, branched, or cyclic. When y′ is 2 or more, R⁶⁰¹'s may be identical to or different from one another.

In the formula (6), R⁶⁰², R⁶⁰³, and R⁶⁰⁴ each independently represent a hydrocarbyl group having 1 to 20 carbon atoms and optionally containing a fluorine atom, a chlorine atoms, a bromine atom, an iodine atom, or a heteroatom. The hydrocarbyl group may be saturated or unsaturated, and may be linear, branched, or cyclic. Specific examples thereof include alkyl groups having 1 to 20 carbon atoms, alkenyl groups having 2 to 20 carbon atoms, aryl groups having 6 to 20 carbon atoms, aralkyl groups having 7 to 20 carbon atoms, etc. Additionally, these groups may gave some or all of hydrogen atoms substituted with a group containing a hydroxy group, a carboxy group, a halogen atom, an oxo group, a cyano group, a nitro group, a sultone group, a sulfone group, or a sulfonium salt, while these groups may have some of carbon atoms substituted with an ether bond, an ester bond, a carbonyl group, an amide bond, a carbonate group, or a sulfonic acid ester group. Alternatively, R⁶⁰² and R⁶⁰³ may bond with each other to form a ring together with a sulfur atom bonded therewith.

Specific examples of the compound shown by the formula (6) include ones disclosed in JP 2017-219836 A. Since an iodine atom considerably absorbs EUV with a wavelength of 13.5 nm, secondary electrons are generated therefrom during exposure, so that the energy of the secondary electrons is transferred to the acid generator and promotes the decomposition of the quencher. Thereby, the sensitivity can be enhanced.

As the quencher, it is also possible to use a polymeric quencher disclosed in JP 2008-239918 A. This quencher is oriented on the resist surface after coating, and enhances the rectangularity of the resist after patterning. The polymeric quencher also has effects of preventing rounding of pattern top and film thickness loss of pattern when a top coat for immersion exposure is applied.

The inventive positive resist material contains the quencher in an amount of preferably 0 to 5 parts by mass, more preferably 0 to 4 parts by mass, based on 100 parts by mass of the base polymer. One kind of the quencher can be used alone, or two or more kinds thereof can be used in combination.

### [Other Components]

In addition to the above-described components, a surfactant, a dissolution inhibitor, and so forth can be blended in appropriate combination depending on the purpose to formulate a positive resist material. Thereby, in an exposed area of the base polymer, the dissolution rate to a developer is accelerated by the catalytic reaction, so that the positive resist material has quite high sensitivity. In this case, the resist film has high dissolution contrast and resolution, exposure latitude, excellent process adaptability, and favorable pattern profile after exposure. Particularly, the positive resist material is capable of suppressing acid diffusion, resulting in a small difference in profile between isolated and nested. Because of these advantages, the inventive positive resist material is highly practical and very effective resist material for VLSI.

Examples of the surfactant include ones disclosed in paragraphs [0165] to [0166] of JP 2008-111103 A. Adding a surfactant can further enhance or control the coatability of the resist material. The inventive positive resist material contains the surfactant in an amount of preferably 0.0001 to 10 parts by mass, based on 100 parts by mass of the base polymer. One kind of the surfactant can be used alone, or two or more kinds thereof can be used in combination.

Blending a dissolution inhibitor can further increase the difference in dissolution rate between exposed and unexposed areas, and further enhance the resolution. Examples of the dissolution inhibitor include a compound The compounds each have a molecular weight of preferably 100 to 1,000, more preferably 150 to 800; and which contains two or more phenolic hydroxy groups per molecule, and in which 0 to 100 mol % of all the hydrogen atoms of the phenolic hydroxy groups are substituted with acid labile groups; or a compound which contains a carboxyl group in a molecule, and in which 50 to 100 mol % of all the hydrogen atoms of such carboxyl groups are substituted with acid labile groups on average. Specific examples include compounds obtained by substituting acid labile groups for hydrogen atoms of hydroxy groups or carboxy groups of bisphenol A, trisphenol, phenolphthalein, cresol novolak, naphthalenecarboxylic acid, adamantanecarboxylic acid, or cholic acid; etc. Examples of such compounds are disclosed in paragraphs [0155] to [0178] of JP 2008-122932 A.

The dissolution inhibitor is contained in an amount of preferably 0 to 50 parts by mass, more preferably 5 to 40 parts by mass, based on 100 parts by mass of the base polymer. One kind of the dissolution inhibitor can be used alone, or two or more kinds thereof can be used in combination.

The inventive positive resist material may be blended with a water-repellency enhancer for enhancing the water repellency on the resist surface after spin coating. The water-repellency enhancer can be employed in immersion lithography with no top coat. The water-repellency enhancer is preferably a polymer compound containing a fluorinated alkyl group, a polymer compound containing a 1,1,1,3,3,3-hexafluoro-2-propanol residue with a particular structure, etc., more preferably ones exemplified in JP 2007-297590 A, JP 2008-111103 A, etc. The water-repellency enhancer needs to be dissolved in an alkali developer or an organic solvent developer. The water-repellency enhancer having a particular 1,1,1,3,3,3-hexafluoro-2-propanol residue mentioned above has favorable solubility to developers. A polymer compound containing a repeating unit with an amino group or amine salt as a water-repellency enhancer exhibits high effects of preventing acid evaporation during PEB and opening failure of a hole pattern after development.

The inventive positive resist material contains the water-repellency enhancer in an amount of preferably 0 to 20 parts by mass, more preferably 0.5 to 10 parts by mass, based on 100 parts by mass of the base polymer. One kind of the water-repellency enhancer can be used alone, or two or more kinds thereof can be used in combination.

The inventive positive resist material may be blended with an acetylene alcohol. Examples of the acetylene alcohol include ones disclosed in paragraphs [0179] to [0182] of JP 2008-122932 A. The inventive positive resist material contains the acetylene alcohol in an amount of preferably 0 to 5 parts by mass based on 100 parts by mass of the base polymer.

### [Patterning Process]

When the inventive positive resist material is used for manufacturing various integrated circuits, known lithography techniques are applicable. An exemplary patterning process includes steps of:

forming a resist film on a substrate by using the above-described resist material;

exposing the resist film to a high-energy beam; and

developing the exposed resist film by using a developer.

First, the inventive positive resist material is applied onto a substrate (such as Si, SiO₂, SiN, SiON, TiN, WSi, BPSG, SOG, organic antireflective film) for manufacturing an integrated circuit or a substrate (such as Cr, CrO, CrON, MoSi₂, SiO₂) for manufacturing a mask circuit by an appropriate coating process such as spin coating, roll coating, flow coating, dip coating, spray coating, or doctor coating so that the coating film can have a thickness of 0.01 to 2 μm. The resultant is prebaked on a hot plate preferably at 60 to 150° C. for 10 seconds to 30 minutes, more preferably at 80 to 120° C. for 30 seconds to 20 minutes. In this manner, a resist film is formed.

Then, the resist film is exposed using a high-energy beam. Examples of the high-energy beam include ultraviolet ray, deep ultraviolet ray, EB, EUV, X-ray, soft X-ray, excimer laser beam, γ-ray, synchrotron radiation, etc. When ultraviolet ray, deep ultraviolet ray, EUV, X-ray, soft X-ray, excimer laser beam, γ-ray, synchrotron radiation, or the like is employed as the high-energy beam, the irradiation is performed directly or using a mask for forming a target pattern, at an exposure dose of preferably about 1 to 200 mJ/cm², more preferably about 10 to 100 mJ/cm². When EB is employed as the high-energy beam, the exposure dose is preferably about 0.1 to 100 pC/cm², more preferably about 0.5 to 50 pC/cm², and the writing is performed directly or using a mask for forming a target pattern. Note that the inventive positive resist material is particularly suitable for fine patterning with an i-line beam having a wavelength of 365 nm, a KrF excimer laser beam, an ArF excimer laser beam, an EB, an EUV having a wavelength of 3 to 15 nm, X-ray, soft X-ray, γ-ray, or synchrotron radiation among the high-energy beams, and is especially suitable for fine patterning with EB or EUV.

The exposure may be followed by PEB on a hot plate or in an oven preferably at 50 to 150° C. for 10 seconds to 30 minutes, more preferably at 60 to 120° C. for 30 seconds to 20 minutes.

After the exposure or PEB, development is performed using a developer of 0.1 to 10 mass %, preferably 2 to 5 mass % alkaline aqueous solution such as tetramethylammonium hydroxide (TMAH), tetraethylammonium hydroxide (TEAH), tetrapropylammonium hydroxide (TPAH), or tetrabutylammonium hydroxide (TBAH), for 3 seconds to 3 minutes, preferably 5 seconds to 2 minutes, by a conventional technique, such as dip, puddle, or spray method. Thereby, the portion irradiated with the light is dissolved by the developer, while the unexposed portion remains undissolved. In this way, the target positive pattern is formed on the substrate.

The positive resist material can also be used to perform negative development for obtaining a negative pattern by organic solvent development. Examples of the developer used in this event include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, benzyl formate, phenylethyl formate, methyl 3-phenylpropionate, benzyl propionate, phenylethyl acetate, 2-phenylethyl acetate, etc. One of these organic solvents can be used alone, or two or more thereof can be used in mixture.

When the development is completed, rinsing can be performed. The rinsing liquid is preferably a solvent that is miscible with the developer but does not dissolve the resist film. As such a solvent, it is preferable to use an alcohol having 3 to 10 carbon atoms, an ether compound having 8 to 12 carbon atoms, an and an alkane, alkene, alkyne and aromatic solvent, each having 6 to 12 carbon atoms.

Specific examples of the alcohol having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, 1-octanol, etc.

Examples of the ether compound having 8 to 12 carbon atoms include di-n-butyl ether, diisobutyl ether, di-sec-butyl ether, di-n-pentyl ether, diisopentyl ether, di-sec-pentyl ether, di-tert-pentyl ether, di-n-hexyl ether, etc.

Examples of the alkane having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, cyclononane, etc. Examples of the alkene having 6 to 12 carbon atoms include hexene, heptene, octene, cyclohexene, methylcyclohexene, dimethylcyclohexene, cycloheptene, cyclooctene, etc. Examples of the alkyne having 6 to 12 carbon atoms include hexyne, heptyne, octyne, etc.

Examples of the aromatic solvent include toluene, xylene, ethylbenzene, isopropylbenzene, tert-butylbenzene, mesitylene, etc.

The rinsing can reduce resist pattern collapse and defect formation. Meanwhile, the rinsing is not necessarily essential, and the amount of the solvent used can be reduced by not performing the rinsing.

After the development, a hole pattern or trench pattern can be shrunk by thermal flow, RELACS process, or DSA process. A shrink agent is applied onto the hole pattern, and the shrink agent undergoes crosslinking on the resist surface by diffusion of the acid catalyst from the resist layer during baking, so that the shrink agent is attached to sidewalls of the hole pattern. The baking temperature is preferably 70 to 180° C., more preferably 80 to 170° C. The baking time is preferably 10 to 300 seconds. The extra shrink agent is removed, and thus the hole pattern is shrunk.

### EXAMPLE

Hereinafter, the present invention will be specifically described with reference to Synthesis Examples, a Comparative Synthesis Example, Examples, and Comparative Examples. However, the present invention is not limited to the following Examples.

### [Synthesis Examples 1 to 14] Synthesis of Base Polymers (Polymers 1 to 14)

The monomers were combined to perform a copolymerization reaction in a solvent THF. A crystal was precipitated in methanol, furthermore, repeatedly washed with hexane, then isolated and dried to obtain a base polymer (Polymers 1 to 14) of the composition shown below. The composition of the obtained base polymer was identified by 1H-NMR, and the Mw and Mw/Mn were identified by GPC (solvent: THF, standard: polystyrene).

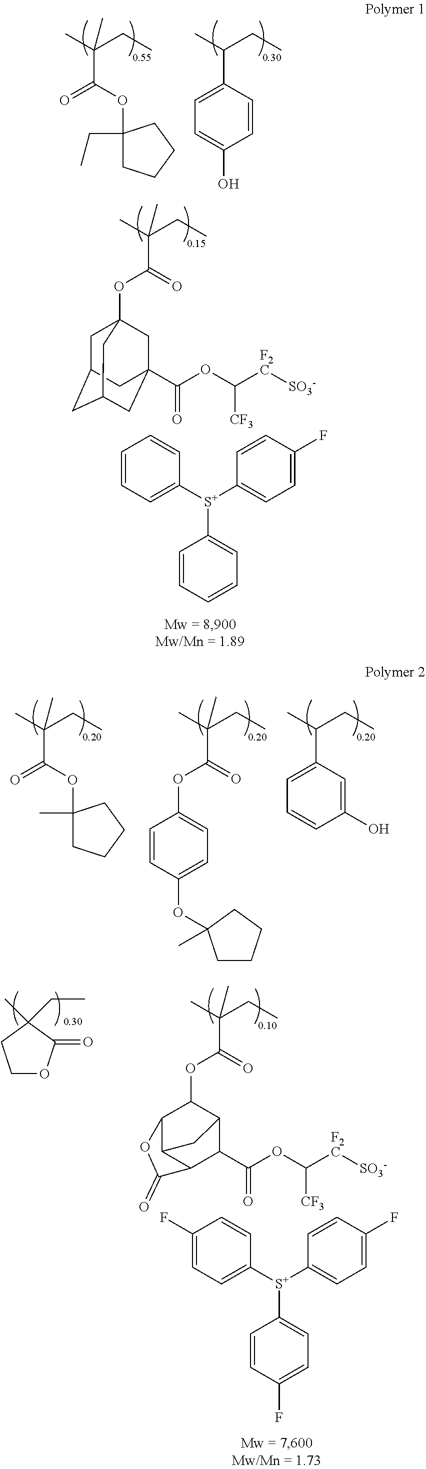

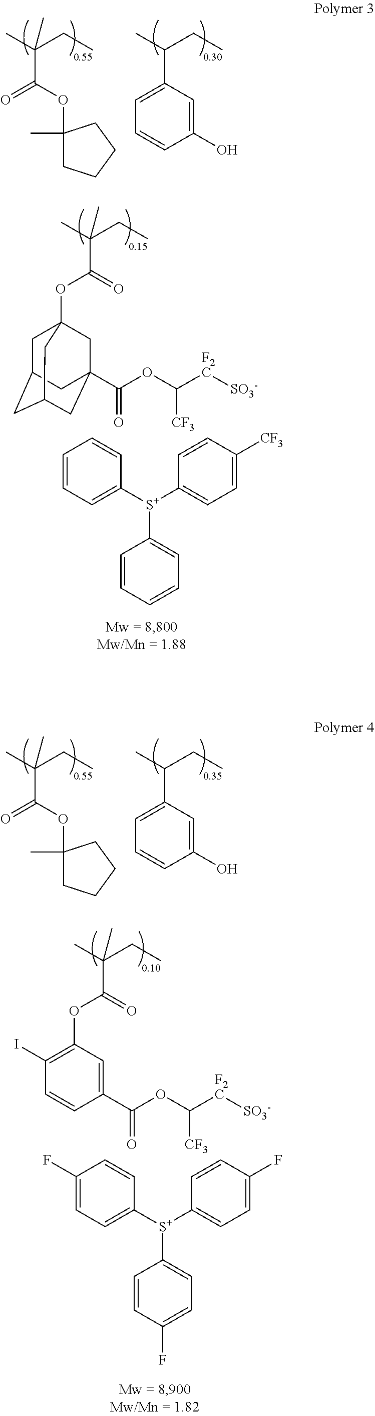

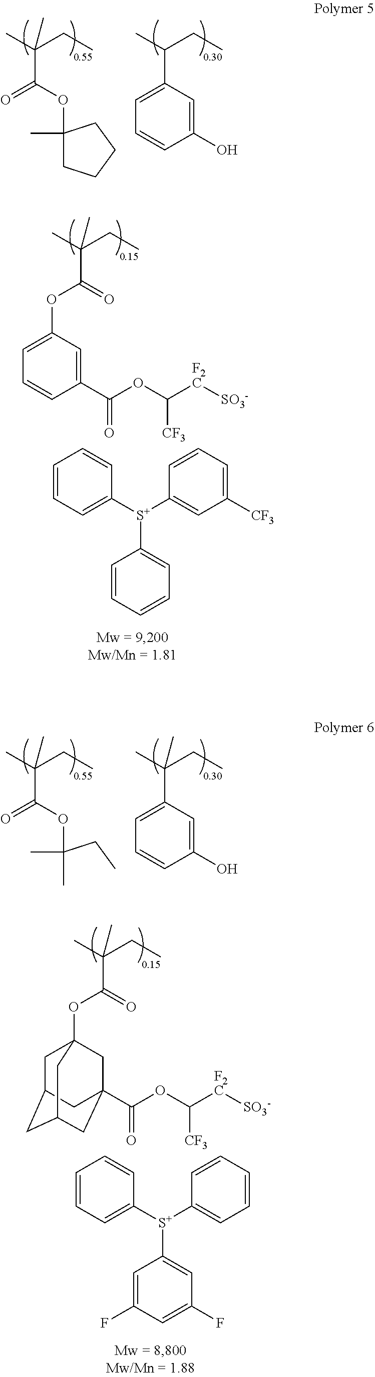

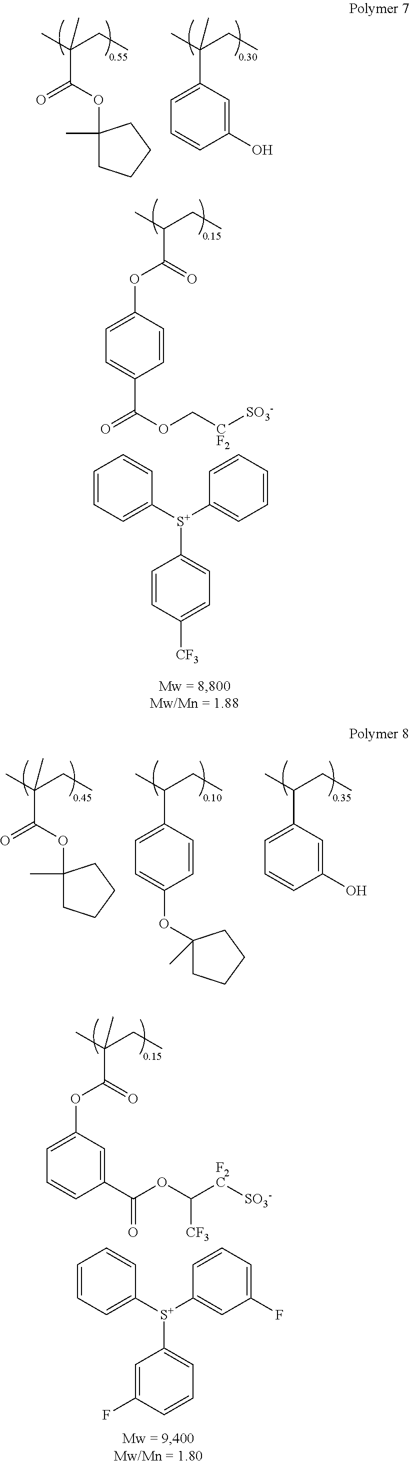

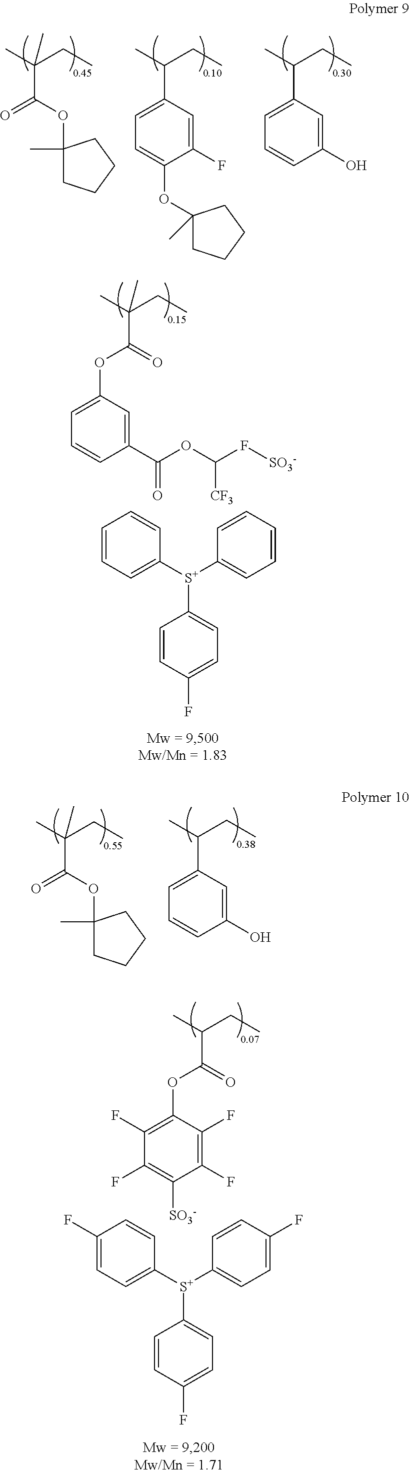

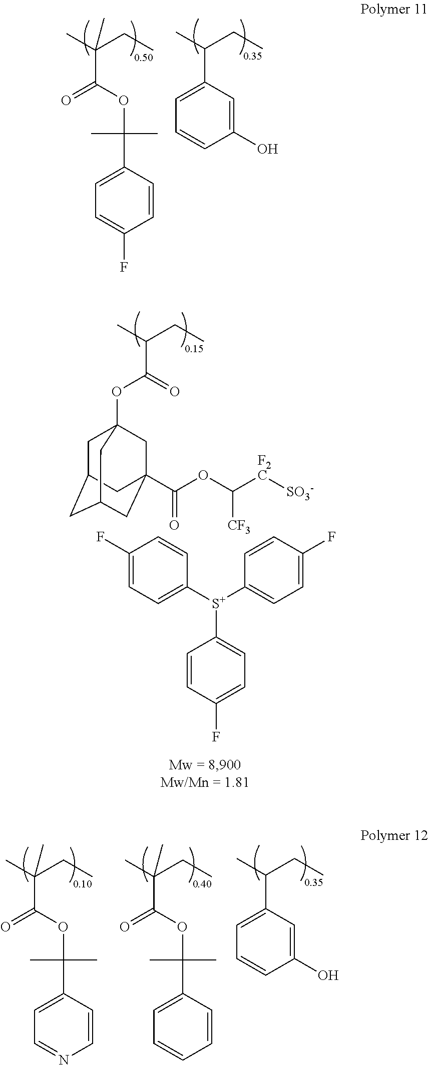

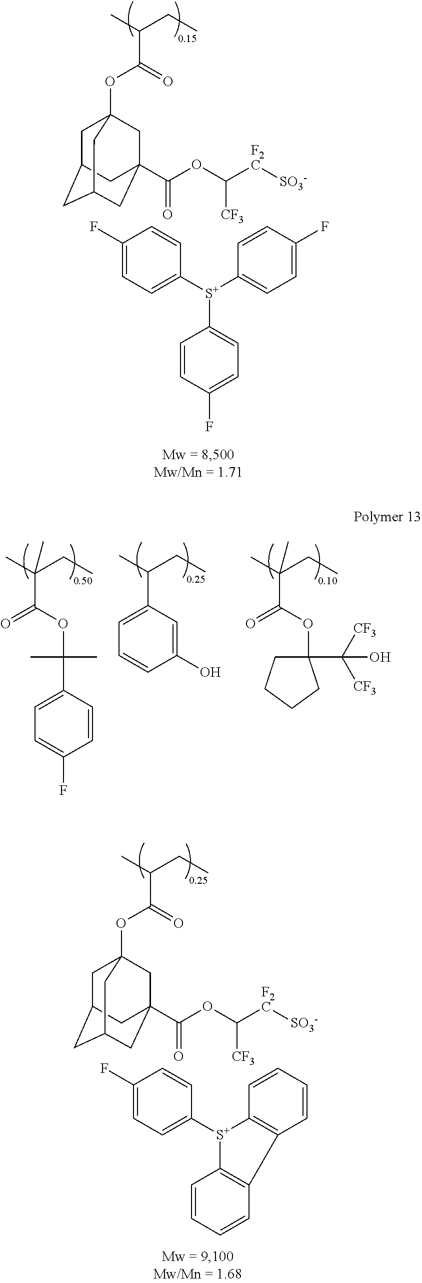

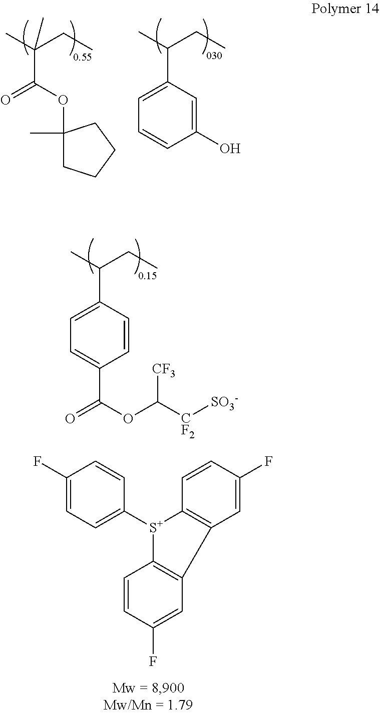

### Comparative Synthesis Example 1

Comparative Polymer 1 was synthesized by the same method. The composition of the Comparative Polymer 1 was identified by 1³C-NMR and 1H-NMR, and the Mw and Mw/Mn were identified by GPC.

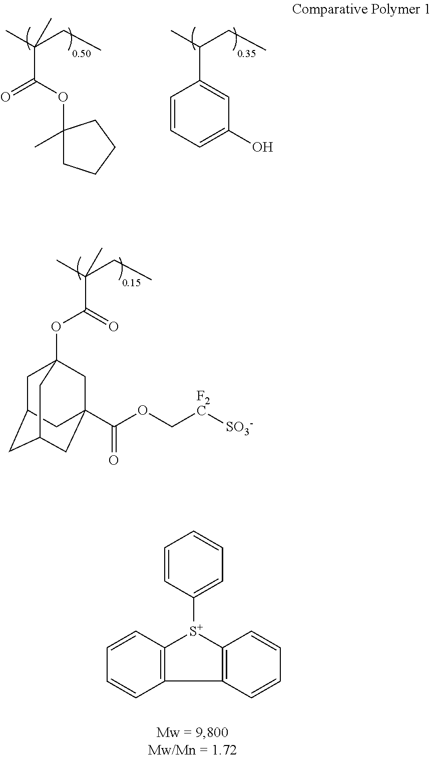

### Examples 1 to 42, Comparative Examples 1 to 4

### (1) Preparation of Positive Resist Materials

According to the composition shown in Table 1 and Table 2, components were dissolved in a solvent in which 50 ppm of a surfactant Polyfox 636 manufactured by OMNOVA Solutions Inc. had been dissolved. The resulting solution was filtered through a filter having a pore size of 0.2 μm. In this manner, positive resist materials were prepared.

Components in Table 1 and Table 2 are as follows.

Organic solvents:
PGMEA (propylene glycol monomethyl ether acetate)
DAA (diacetone alcohol)
EL (ethyl lactate)

Quenchers: Q-1 to Q-30, comparative quenchers: CQ-1 to CQ-3

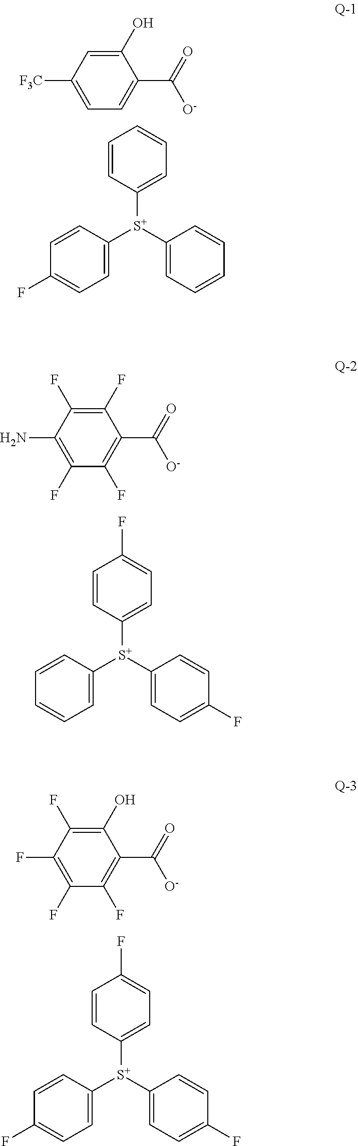 [SMILES: O=C([O-])c1ccc(C(F)(F)F)cc1O ; Fc1ccc([S+](c2ccccc2)c2ccccc2)cc1 ; Nc1c(F)c(F)c(C(=O)[O-])c(F)c1F ; Fc1ccc([S+](c2ccccc2)c2ccc(F)cc2)cc1 ; O=C([O-])c1c(O)c(F)c(F)c(F)c1F ; Fc1ccc([S+](c2ccc(F)cc2)c2ccc(F)cc2)cc1]

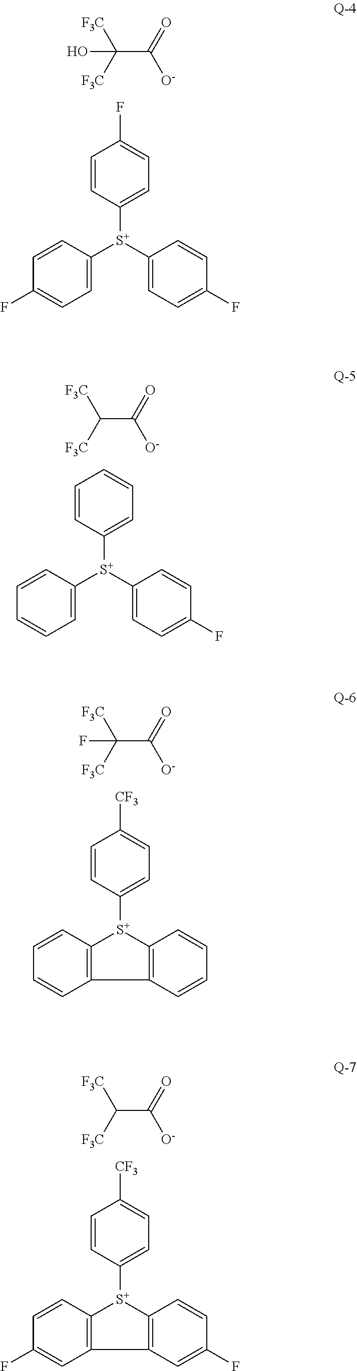

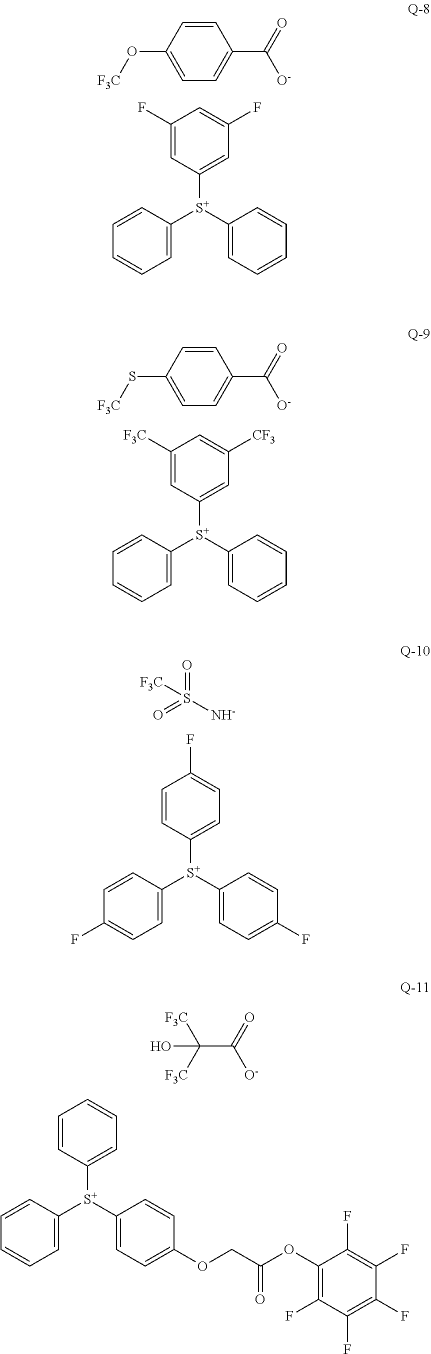

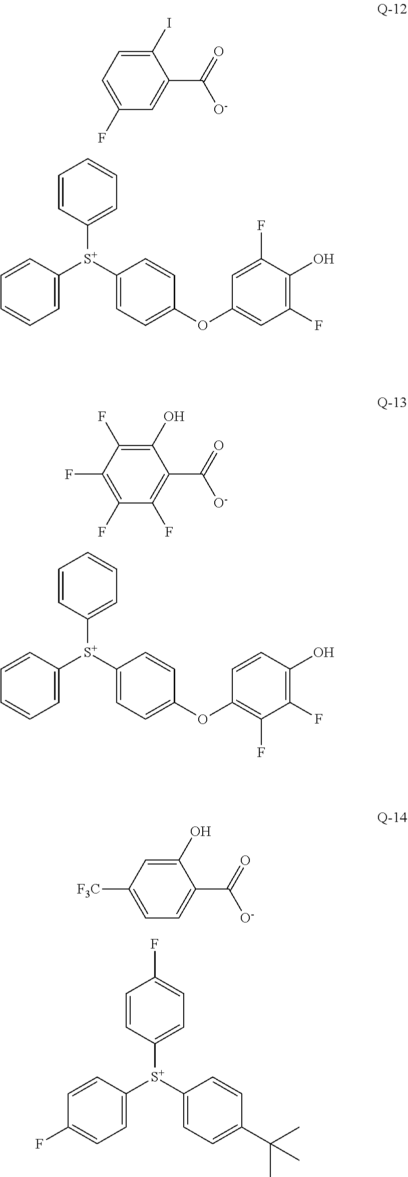 [SMILES: O=C([O-])c1cc(F)ccc1I ; Oc1c(F)cc(Oc2ccc([S+](c3ccccc3)c3ccccc3)cc2)cc1F ; O=C([O-])c1c(O)c(F)c(F)c(F)c1F ; Oc1ccc(Oc2ccc([S+](c3ccccc3)c3ccccc3)cc2)c(F)c1F ; O=C([O-])c1ccc(C(F)(F)F)cc1O ; CC(C)(C)c1ccc([S+](c2ccc(F)cc2)c2ccc(F)cc2)cc1]

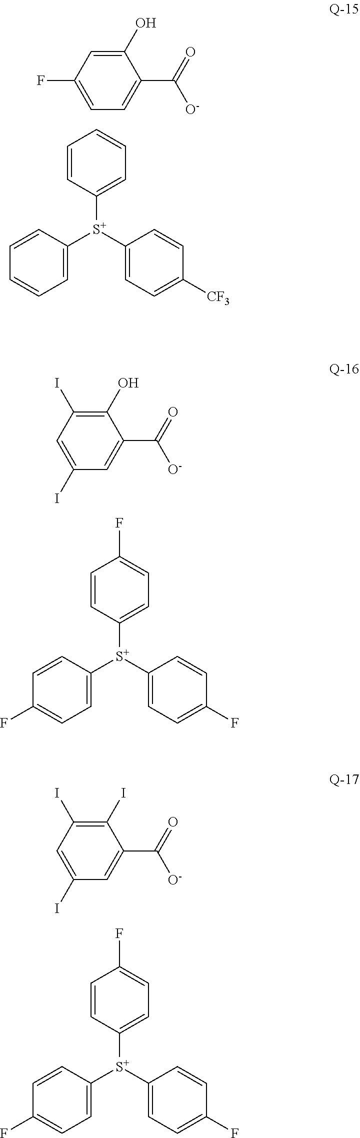 [SMILES: O=C([O-])c1ccc(F)cc1O ; FC(F)(F)c1ccc([S+](c2ccccc2)c2ccccc2)cc1 ; O=C([O-])c1cc(I)cc(I)c1O ; Fc1ccc([S+](c2ccc(F)cc2)c2ccc(F)cc2)cc1 ; O=C([O-])c1cc(I)cc(I)c1I ; Fc1ccc([S+](c2ccc(F)cc2)c2ccc(F)cc2)cc1]

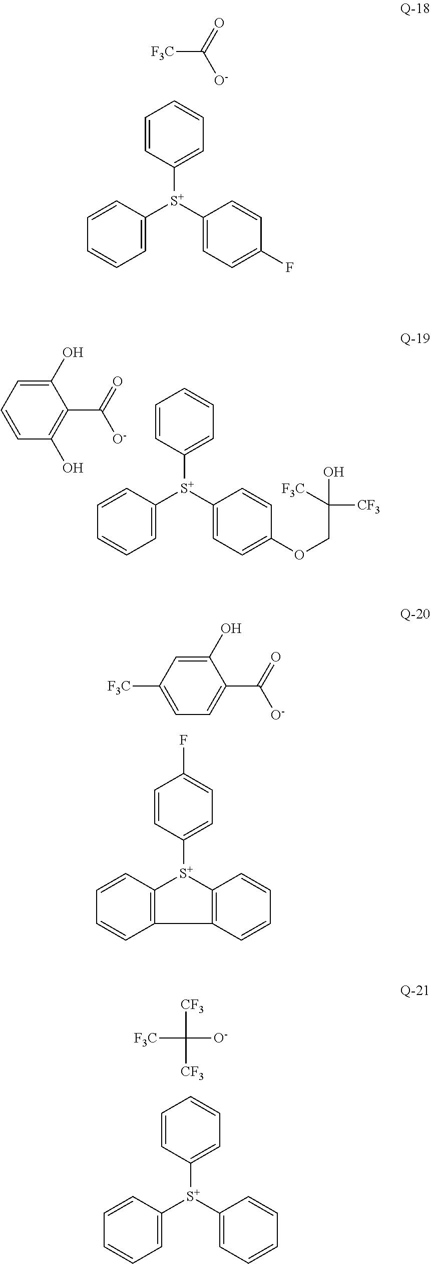

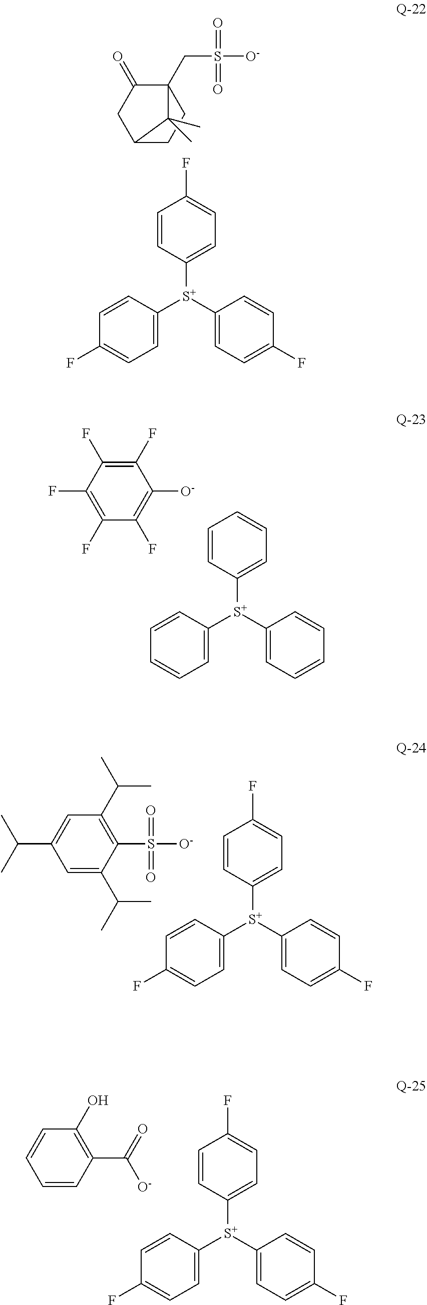

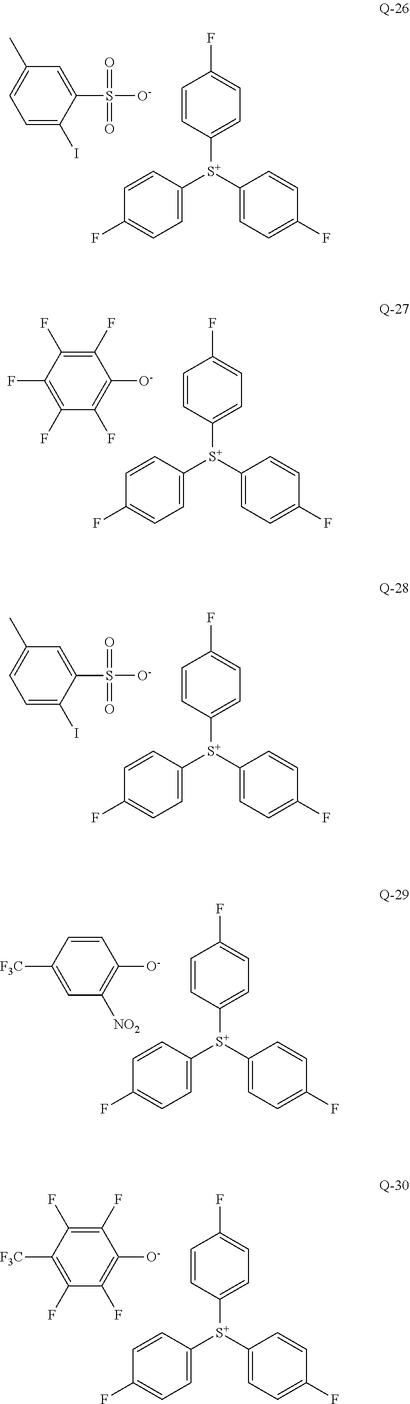

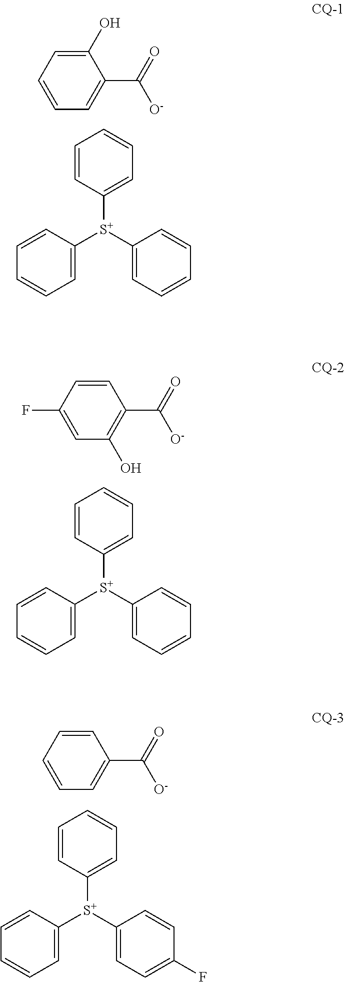 [SMILES: O=C([O-])c1ccccc1O ; c1ccc([S+](c2ccccc2)c2ccccc2)cc1 ; O=C([O-])c1ccc(F)cc1O ; c1ccc([S+](c2ccccc2)c2ccccc2)cc1 ; O=C([O-])c1ccccc1 ; Fc1ccc([S+](c2ccccc2)c2ccccc2)cc1]

Acid generators: PAG 1, 2 (see structural formulae below)

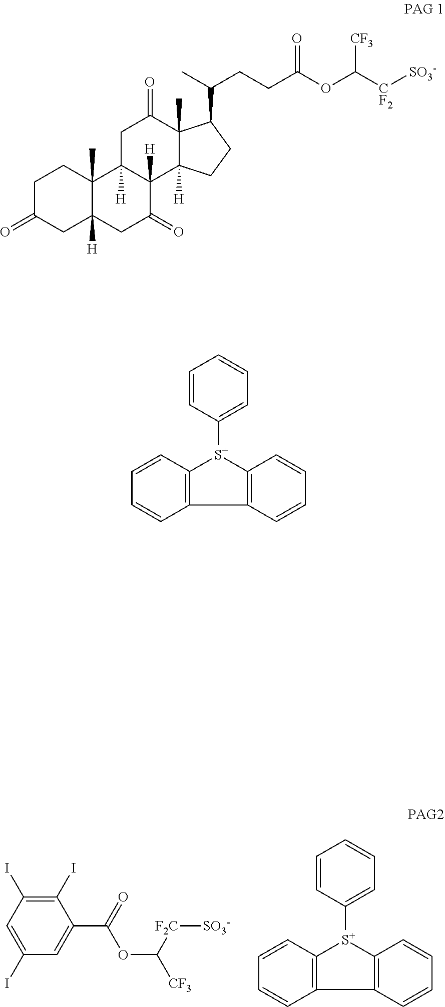

### (2) EUV Lithography Evaluation

A silicon substrate with a silicon-containing spin-on hard mask SHB-A940 (silicon content: 43 mass %) manufactured by Shin-Etsu Chemical Co., Ltd. formed to have a film thickness of 20 nm was spin-coated with each resist material shown in Table 1 and Table 2. The resultant was prebaked using a hot plate at 105° C. for 60 seconds to prepare a resist film having a film thickness of 60 nm. The resist film was exposed using an EUV scanner NXE3400 (NA: 0.33, σ: 0.9/0.6, quadrupole illumination, with a mask having a hole pattern with a pitch of 46 nm and +20% bias (on-wafer size)) manufactured by ASML, followed by PEB on the hot plate at a temperature shown in Table 1 for 60 seconds, and development with a 2.38 mass % TMAH aqueous solution for 30 seconds to obtain a hole pattern with a dimension of 23 nm.

An exposure dose at which the hole dimension of 23 nm was formed was determined as sensitivity. Moreover, the dimensions of 50 holes were measured using a measurement SEM (CG5000) manufactured by Hitachi High-Technologies Corporation. Based on this result, the triple value (3σ) of the standard deviation (σ) was calculated and determined as dimensional variation (critical dimension uniformity: CDU). The results are also shown in Table 1 and Table 2.

TABLE 1

| | | Acid | | | | | |
|---|---|---|---|---|---|---|---|
| | Polymer | generator | Quencher | | PEB | | |
| | (parts by | (parts by | (parts by | Organic solvent | temperature | Sensitivity | CDU |
| | mass) | mass) | mass) | (parts by mass) | (° C.) | (mJ/cm²) | (nm) |
| Example 1 | Polymer 1 | — | Q-1 | PGMEA(2,000) | 80 | 27 | 2.6 |
| | (100) | | (4.86) | DAA(500) | | | |
| Example 2 | Polymer 1 | — | Q-2 | PGMEA(2,000) | 80 | 26 | 2.7 |
| | (100) | | (5.07) | DAA(500) | | | |
| Example 3 | Polymer 1 | — | Q-3 | PGMEA(2,000) | 80 | 26 | 2.6 |
| | (100) | | (5.55) | DAA(500) | | | |
| Example 4 | Polymer 1 | — | Q-4 | PGMEA(2,000) | 80 | 25 | 2.5 |
| | (100) | | (5.28) | DAA(500) | | | |
| Example 5 | Polymer 1 | — | Q-5 | PGMEA(2,000) | 80 | 32 | 2.6 |
| | (100) | | (4.76) | DAA(500) | | | |
| Example 6 | Polymer 1 | — | Q-6 | PGMEA(2,000) | 80 | 30 | 2.2 |
| | (100) | | (5.42) | DAA(500) | | | |
| Example 7 | Polymer 1 | — | Q-7 | PGMEA(2,000) | 80 | 27 | 2.3 |
| | (100) | | (2.42) | DAA(500) | | | |
| | | | Q-8 | | | | |
| | | | (2.52) | | | | |
| Example 8 | Polymer 1 | — | Q-9 | PGMEA(2,000) | 80 | 31 | 2.4 |
| | (100) | | (6.20) | DAA(500) | | | |
| Example 9 | Polymer 1 | — | Q-10 | PGMEA(2,000) | 80 | 30 | 2.4 |
| | (100) | | (4.63) | DAA(500) | | | |
| Example 10 | Polymer 1 | — | Q-11 | PGMEA(2,000) | 80 | 31 | 2.2 |
| | (100) | | (7.14) | DAA(500) | | | |
| Example 11 | Polymer 1 | — | Q-12 | PGMEA(2,000) | 80 | 31 | 2.4 |
| | (100) | | (6.72) | DAA(500) | | | |
| Example 12 | Polymer 1 | — | Q-13 | PGMEA(2,000) | 80 | 29 | 2.2 |
| | (100) | | (6.16) | DAA(500) | | | |
| Example 13 | Polymer 2 | — | Q-4 | PGMEA(2,000) | 80 | 28 | 2.4 |
| | (100) | | (5.28) | DAA(500) | | | |
| Example 14 | Polymer 3 | — | Q-4 | PGMEA(2,000) | 85 | 27 | 2.4 |
| | (100) | | (5.28) | DAA(500) | | | |
| Example 15 | Polymer 4 | — | Q-4 | PGMEA(2,000) | 85 | 26 | 2.3 |
| | (100) | | (5.28) | DAA(500) | | | |
| Example 16 | Polymer 5 | — | Q-4 | PGMEA(2,000) | 85 | 28 | 2.3 |
| | (100) | | (5.28) | DAA(500) | | | |
| Example 17 | Polymer 6 | — | Q-4 | PGMEA(2,000) | 85 | 28 | 2.3 |
| | (100) | | (5.28) | DAA(500) | | | |
| Example 18 | Polymer 7 | — | Q-4 | PGMEA(2,000) | 85 | 26 | 2.5 |
| | (100) | | (5.28) | DAA(500) | | | |
| Example 19 | Polymer 8 | — | Q-4 | PGMEA(2,000) | 85 | 28 | 2.4 |
| | (100) | | (5.28) | DAA(500) | | | |
| Example 20 | Polymer 9 | — | Q-4 | PGMEA(2,000) | 85 | 29 | 2.3 |
| | (100) | | (5.28) | DAA(500) | | | |
| Example 21 | Polymer 10 | PAG1(8.74) | Q-4 | PGMEA(2,000) | 85 | 29 | 2.4 |
| | (100) | | (5.28) | DAA(500) | | | |
| Example 22 | Polymer 10 | PAG2(9.72) | Q-4 | PGMEA(2,000) | 85 | 26 | 2.4 |
| | (100) | | (5.28) | DAA(500) | | | |

TABLE 2

| | | Acid | | | | | |
|---|---|---|---|---|---|---|---|
| | Polymer | generator | Quencher | | PEB | | |
| | (parts by | (parts by | (parts by | Organic solvent | temperature | Sensitivity | CDU |
| | mass) | mass) | mass) | (parts by mass) | (° C.) | (mJ/cm²) | (nm) |
| Example 23 | Polymer 11 | — | Q-4 | PGMEA(2,000) | 80 | 24 | 2.3 |
| | (100) | | (5.28) | DAA(500) | | | |
| Example 24 | Polymer 12 | — | Q-4 | PGMEA(2,000) | 80 | 28 | 2.2 |
| | (100) | | (5.28) | DAA(500) | | | |
| Example 25 | Polymer 13 | — | Q-4 | PGMEA(2,000) | 80 | 28 | 2.2 |
| | (100) | | (5.28) | DAA(500) | | | |
| Example 26 | Polymer 14 | — | Q-14 | PGMEA(2,000) | 80 | 28 | 2.4 |
| | (100) | | (4.54) | DAA(500) | | | |
| Example 27 | Polymer 1 | — | Q-15 | PGMEA(2,000) | 80 | 28 | 2.6 |
| | (100) | | (4.54) | DAA(500) | | | |
| Example 28 | Polymer 1 | — | Q-16 | PGMEA(2,000) | 80 | 24 | 2.4 |
| | (100) | | (7.06) | DAA(500) | | | |
| Example 29 | Polymer 1 | — | Q-17 | PGMEA(2,000) | 80 | 25 | 2.5 |
| | (100) | | (8.16) | DAA(500) | | | |
| Example 30 | Polymer 1 | — | Q-18 | PGMEA(2,000) | 80 | 29 | 2.4 |
| | (100) | | (3.94) | DAA(500) | | | |
| Example 31 | Polymer 1 | — | Q-19 | PGMEA(2,000) | 80 | 24 | 2.5 |
| | (100) | | (6.12) | DAA(500) | | | |
| Example 32 | Polymer 1 | — | Q-20 | EL(2,000) | 80 | 26 | 2.3 |
| | (100) | | (4.54) | DAA(500) | | | |
| Example 33 | Polymer 1 | — | Q-21 | EL(2,000) | 80 | 28 | 2.3 |
| | (100) | | (4.98) | DAA(500) | | | |
| Example 34 | Polymer 1 | — | Q-22 | EL(2,000) | 80 | 26 | 2.1 |
| | (100) | | (5.48) | DAA(500) | | | |
| Example 35 | Polymer 1 | — | Q-23 | EL(2,000) | 80 | 26 | 2.6 |
| | (100) | | (4.46) | DAA(500) | | | |
| Example 36 | Polymer 1 | — | Q-24 | PGMEA(1,000) | 80 | 27 | 2.5 |
| | (100) | | (6.00) | DAA(500) | | | |
| | | | | EL(1,000) | | | |
| Example 37 | Polymer 1 | — | Q-25 | PGMEA(1,000) | 80 | 28 | 2.4 |
| | (100) | | (4.54) | DAA(500) | | | |
| | | | | EL(1,000) | | | |
| Example 38 | Polymer 1 | — | Q-26 | PGMEA(1,000) | 80 | 26 | 2.3 |
| | (100) | | (6.13) | DAA(500) | | | |
| | | | | EL(1,000) | | | |
| Example 39 | Polymer 1 | — | Q-27 | PGMEA(1,000) | 80 | 28 | 2.4 |
| | (100) | | (5.00) | DAA(500) | | | |
| | | | | EL(1,000) | | | |
| Example 40 | Polymer 1 | — | Q-28 | PGMEA(1,000) | 80 | 25 | 2.2 |
| | (100) | | (6.14) | DAA(500) | | | |
| | | | | EL(1,000) | | | |
| Example 41 | Polymer 1 | — | Q-29 | PGMEA(1,000) | 80 | 27 | 2.4 |
| | (100) | | (5.23) | DAA(500) | | | |
| | | | | EL(1,000) | | | |
| Example 42 | Polymer 1 | — | Q-30 | PGMEA(1,000) | 80 | 27 | 2.2 |
| | (100) | | (5.50) | DAA(500) | | | |
| | | | | EL(1,000) | | | |
| Comparative | Comparative | — | Q-1 | PGMEA(2,000) | 85 | 33 | 3.0 |
| Example 1 | Polymer 1 | | (4.86) | DAA(500) | | | |
| | (100) | | | | | | |
| Comparative | Polymer 1 | — | CQ-1 | PGMEA(2,000) | 80 | 34 | 2.9 |
| Example 2 | (100) | | (4.00) | DAA(500) | | | |
| Comparative | Polymer 1 | — | CQ-2 | PGMEA(2,000) | 80 | 33 | 2.9 |
| Example 3 | (100) | | (4.02) | DAA(500) | | | |
| Comparative | Polymer 1 | — | CQ-3 | PGMEA(2,000) | 80 | 34 | 2.9 |
| Example 4 | (100) | | (4.02) | DAA(500) | | | |

From the results shown in Table 1 and Table 2, high sensitivity and favorable CDU were achieved by the positive resist materials each containing: an acid generator, being a sulfonium salt having at least one fluorine atom in both the anion moiety of the sulfonic acid bonded to a polymer main chain and the cation moiety; and a quencher, being a sulfonium salt of a carboxylate ion, a sulfonamide ion, an alkoxide ion, or a sulfonate ion having no fluorine at a position, the sulfonium salt having two or more fluorine atoms in the anion and the cation.

On the other hand, in Comparative Example 1, using an acid generator not having a fluorine atom in the cation moiety of the sulfonium ion, and in Comparative Examples 2 to 4, using a quencher having fewer than two fluorine atoms in the anion moiety of the carboxylate ion and/or the cation moiety of the sulfonium ion had poor sensitivity and CDU compared with the Examples.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A positive resist material comprising:
an acid generator, being a sulfonium salt having at least one fluorine atom in both an anion moiety of a sulfonate ion bonded to a polymer main chain and a cation moiety of a sulfonium ion; and
a quencher, being a sulfonium salt comprising an anion moiety of a carboxylate ion, a sulfonamide ion, an alkoxide ion, or a sulfonate ion having no fluorine atom at a position and a cation moiety of a sulfonium ion, the quencher having a total of two or more fluorine atoms in the anion moiety and the cation moiety.

2. The positive resist material according to claim 1, wherein the quencher is a quencher which is a sulfonium salt having a total of three or more fluorine atoms in an anion moiety and a cation moiety.

3. The positive resist material according to claim 1, wherein the quencher is a sulfonium salt having two or more fluorine atoms in the cation moiety or having a total of five or more fluorine atoms in the anion moiety and the cation moiety.

4. The positive resist material according to claim 2, wherein the quencher is a sulfonium salt having two or more fluorine atoms in the cation moiety or having a total of five or more fluorine atoms in the anion moiety and the cation moiety.

5. A positive resist material comprising:
an acid generator, being a sulfonium salt having at least one fluorine atom in both an anion moiety of a sulfonate ion and a cation moiety of a sulfonium ion; and
a quencher, being a sulfonium salt comprising at least one fluorine atom in both an anion moiety of a carboxylate ion or a sulfonamide ion and a cation moiety of a sulfonium ion.

6. The positive resist material according to claim 1, wherein the acid generator is contained in a base polymer comprising a repeating unit represented by the following general formula (a1) and/or (a2), 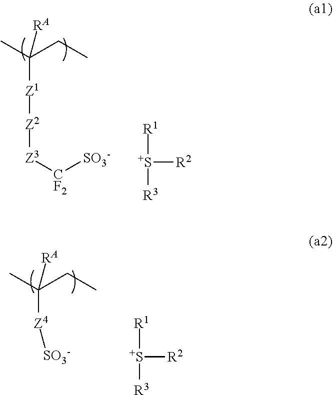
wherein each R^{A} independently represents a hydrogen atom or a methyl group; Z¹ represents a single bond, an ester bond, or a phenylene group; Z² represents a single bond, —Z²¹—C(═O)—O—, —Z²¹—O—, or —Z²¹—O—C(═O)—; Z²¹ represents a hydrocarbylene group having 1 to 12 carbon atoms, a phenylene group, or a group which is a combination thereof having 7 to 18 carbon atoms, the Z²¹ optionally containing a carbonyl group, an ester bond, an ether bond, a sulfur atom, an oxygen atom, a bromine atom, or an iodine atom; Z³ represents a methylene group, a 2,2,2-trifluoro-1,1-ethanediyl group, a hydrocarbon group having 2 to 4 carbon atoms optionally substituted with fluorine, or a carbonyl group; Z⁴ represents a fluorinated phenylene group, a trifluoromethyl group, a phenylene group substituted with an iodine atom, —O—Z⁴¹—, —C(═O)—O—Z⁴¹—, or —C(═O)—NH—Z⁴¹—, and has at least one fluorine atom; Z⁴¹ represents a fluorinated phenylene group, a phenylene group substituted with a trifluoromethyl group or an iodine atom, or a hydrocarbylene group having 1 to 15 carbon atoms substituted with a halogen atom, optionally containing an ester group or an aromatic hydrocarbon group therein; R¹ to R³ each independently represent a hydrocarbyl group having 1 to 20 carbon atoms, and optionally have an oxygen atom, a sulfur atom, a nitrogen atom, or a halogen atom other than fluorine; and R¹ and R², or R¹ and R³ are optionally bonded with each other to form a ring with a sulfur atom that is bonded thereto, wherein at least one fluorine atom is contained among R¹ to R³.

7. The positive resist material according to claim 5, wherein the acid generator is contained in a base polymer comprising a repeating unit represented by the following general formula (a1) and/or (a2), 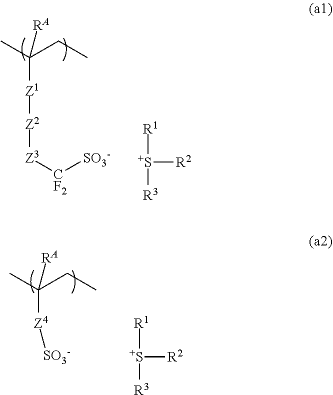
wherein each R^{A} independently represents a hydrogen atom or a methyl group; Z¹ represents a single bond, an ester bond, or a phenylene group; Z² represents a single bond, —Z²¹—C(═O)—O—, —Z²¹—O—, or —Z²¹—O—C(═O)—; Z²¹ represents a hydrocarbylene group having 1 to 12 carbon atoms, a phenylene group, or a group which is a combination thereof having 7 to 18 carbon atoms, the Z²¹ optionally containing a carbonyl group, an ester bond, an ether bond, a sulfur atom, an oxygen atom, a bromine atom, or an iodine atom; Z³ represents a methylene group, a 2,2,2-trifluoro-1,1-ethanediyl group, a hydrocarbon group having 2 to 4 carbon atoms optionally substituted with fluorine, or a carbonyl group; Z⁴ represents a fluorinated phenylene group, a trifluoromethyl group, a phenylene group substituted with an iodine atom, —O—Z⁴¹—, —C(═O)—O—Z⁴¹—, or —C(═O)—NH—Z⁴¹—, and has at least one fluorine atom; Z⁴¹ represents a fluorinated phenylene group, a phenylene group substituted with a trifluoromethyl group or an iodine atom, or a hydrocarbylene group having 1 to 15 carbon atoms substituted with a halogen atom, optionally containing an ester group or an aromatic hydrocarbon group therein; R¹ to R³ each independently represent a hydrocarbyl group having 1 to 20 carbon atoms, and optionally have an oxygen atom, a sulfur atom, a nitrogen atom, or a halogen atom other than fluorine; and R¹ and R², or R¹ and R³ are optionally bonded with each other to form a ring with a sulfur atom that is bonded thereto, wherein at least one fluorine atom is contained among R¹ to R³.

8. The positive resist material according to claim 6, wherein the base polymer comprises a repeating unit represented by the following general formula (b1) in which a hydrogen atom of a carboxy group is substituted with an acid labile group and/or a repeating unit represented by the following general formula (b2) in which a hydrogen atom of a phenolic hydroxy group is substituted with an acid labile group, 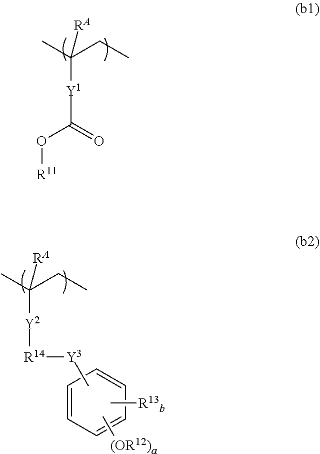
wherein each R^{A} independently represents a hydrogen atom or a methyl group; Y¹ represents a single bond, a phenylene group, a naphthylene group, or a linking group having 1 to 15 carbon atoms containing at least one selected from an ester bond, an ether bond, and a lactone ring; Y² represents a single bond, an ester bond, or an amide bond; Y³ represents a single bond, an ether bond, or an ester bond; R¹¹ and R¹² each represent an acid labile group; R¹³ represents a fluorine atom, a trifluoromethyl group, a cyano group, or a saturated hydrocarbyl group having 1 to 6 carbon atoms; R¹⁴ represents a single bond or an alkanediyl group having 1 to 6 carbon atoms, and some of the carbon atoms are optionally substituted with an ether bond or an ester bond; and “a” represents 1 or 2, and “b” represents an integer of 0 to 4, with 1≤a+b≤5.

9. The positive resist material according to claim 7, wherein the base polymer comprises a repeating unit represented by the following general formula (b1) in which a hydrogen atom of a carboxy group is substituted with an acid labile group and/or a repeating unit represented by the following general formula (b2) in which a hydrogen atom of a phenolic hydroxy group is substituted with an acid labile group, 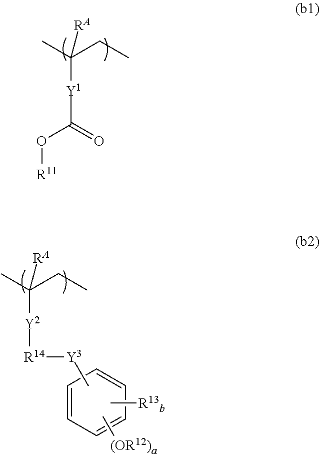
wherein each R^{A} independently represents a hydrogen atom or a methyl group; Y¹ represents a single bond, a phenylene group, a naphthylene group, or a linking group having 1 to 15 carbon atoms containing at least one selected from an ester bond, an ether bond, and a lactone ring; Y² represents a single bond, an ester bond, or an amide bond; Y³ represents a single bond, an ether bond, or an ester bond; R¹¹ and R¹² each represent an acid labile group; R¹³ represents a fluorine atom, a trifluoromethyl group, a cyano group, or a saturated hydrocarbyl group having 1 to 6 carbon atoms; R¹⁴ represents a single bond or an alkanediyl group having 1 to 6 carbon atoms, and some of the carbon atoms are optionally substituted with an ether bond or an ester bond; and “a” represents 1 or 2, and “b” represents an integer of 0 to 4, with 1≤a+b≤5.

10. The positive resist material according to claim 6, wherein the base polymer further comprises a repeating unit comprising an adhesive group selected from a hydroxy group, a carboxy group, a lactone ring, a carbonate group, a thiocarbonate group, a carbonyl group, a cyclic acetal group, an ether bond, an ester bond, a sulfonic acid ester group, a cyano group, an amide bond, —O—C(═O)—S—, and —O—C(═O)—NH—.

11. The positive resist material according to claim 7, wherein the base polymer further comprises a repeating unit comprising an adhesive group selected from a hydroxy group, a carboxy group, a lactone ring, a carbonate group, a thiocarbonate group, a carbonyl group, a cyclic acetal group, an ether bond, an ester bond, a sulfonic acid ester group, a cyano group, an amide bond, —O—C(═O)—S—, and —O—C(═O)—NH—.

12. The positive resist material according to claim 1, wherein the quencher is represented by one of the following general formulae (1)-1 to (1)-4, 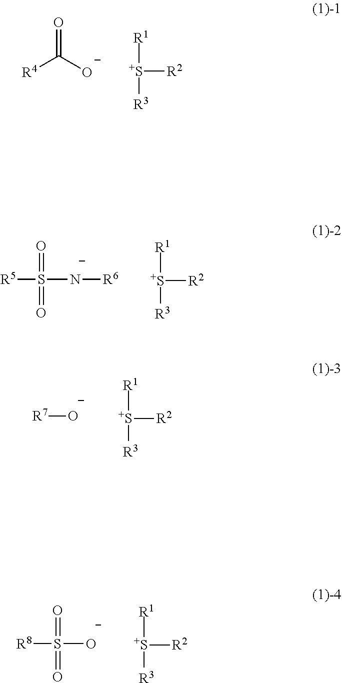
wherein R⁴ and R⁵ each represent a fluorine atom or a hydrocarbyl group having 1 to 40 carbon atoms, and optionally have an oxygen atom, a sulfur atom, a nitrogen atom, or a halogen atom; R⁶ represents a hydrogen atom or a hydrocarbyl group having 1 to 20 carbon atoms, and these optionally have an oxygen atom, a sulfur atom, a nitrogen atom, or a halogen atom; R⁷ represents a linear, branched, or cyclic alkyl group or aryl group having 1 to 8 carbon atoms, and has at least two fluorine atoms; R⁷ optionally has a nitro group; R⁸ represents a linear, branched, or cyclic alkyl group or aryl group having 1 to 12 carbon atoms, optionally having an amino group, an ether group, or an ester group, and optionally substituted with a halogen atom, a hydroxy group, a carboxy group, an alkoxy group, an acyl group, or an acyloxy group; no fluorine atom is contained at a position of a sulfo group; and R¹ to R³ are the same as above.

13. The positive resist material according to claim 5, wherein the quencher is represented by one of the following general formulae (1)-1 to (1)-4, 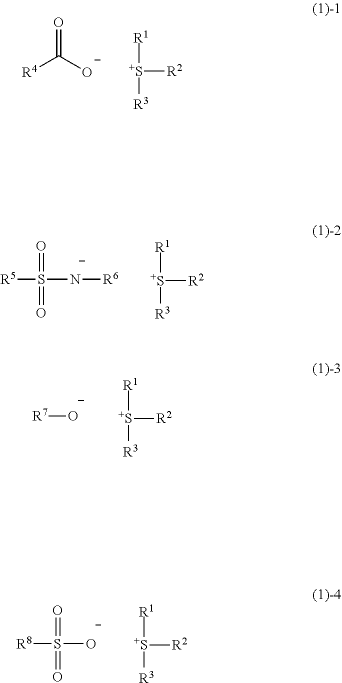
wherein R⁴ and R⁵ each represent a fluorine atom or a hydrocarbyl group having 1 to 40 carbon atoms, and optionally have an oxygen atom, a sulfur atom, a nitrogen atom, or a halogen atom; R⁶ represents a hydrogen atom or a hydrocarbyl group having 1 to 20 carbon atoms, and these optionally have an oxygen atom, a sulfur atom, a nitrogen atom, or a halogen atom; R⁷ represents a linear, branched, or cyclic alkyl group or aryl group having 1 to 8 carbon atoms, and has at least two fluorine atoms; R⁷ optionally has a nitro group; R⁸ represents a linear, branched, or cyclic alkyl group or aryl group having 1 to 12 carbon atoms, optionally having an amino group, an ether group, or an ester group, and optionally substituted with a halogen atom, a hydroxy group, a carboxy group, an alkoxy group, an acyl group, or an acyloxy group; no fluorine atom is contained at a position of a sulfo group; and R¹ to R³ are the same as above.

14. The positive resist material according to claim 12, wherein R⁴ and R⁵ in the general formulae (1)-1 and (1)-2 each represent a hydrocarbyl group having 1 to 40 carbon atoms, optionally having an oxygen atom, a sulfur atom, a nitrogen atom, or a halogen atom other than fluorine, and having at least one fluorine atom.

15. The positive resist material according to claim 13, wherein R⁴ and R⁵ in the general formulae (1)-1 and (1)-2 each represent a hydrocarbyl group having 1 to 40 carbon atoms, optionally having an oxygen atom, a sulfur atom, a nitrogen atom, or a halogen atom other than fluorine, and having at least one fluorine atom.

16. The positive resist material according to claim 1, further comprising one or more out of an acid generator other than the acid generator being the sulfonium salt, an organic solvent, a quencher other than the quencher being the sulfonium salt, and a surfactant.

17. The positive resist material according to claim 5, further comprising one or more out of an acid generator other than the acid generator being the sulfonium salt, an organic solvent, a quencher other than the quencher being the sulfonium salt, and a surfactant.

18. A patterning process comprising:
forming a resist film on a substrate by using the positive resist material according to claim 1;
exposing the resist film to a high-energy beam; and
developing the exposed resist film by using a developer.

19. A patterning process comprising:
forming a resist film on a substrate by using the positive resist material according to claim 5;
exposing the resist film to a high-energy beam; and
developing the exposed resist film by using a developer.

20. The patterning process according to claim 18, wherein the high-energy beam is an i-line beam, a KrF excimer laser beam, an ArF excimer laser beam, an electron beam, or an extreme ultraviolet ray having a wavelength of 3 to 15 nm.
